(19) United States
(12) Patent Application Publication
(10) Pub. No.: US 2025/0248216 A1
(43) Pub. Date: Jul. 31, 2025

(54) SEMICONDUCTOR DEVICE

(71) Applicant: Semiconductor Energy Laboratory Co., Ltd., Atsugi-shi (JP)

(72) Inventor: Atsushi UMEZAKI, Isehara (JP)

(21) Appl. No.: 19/032,827

(22) Filed: Jan. 21, 2025

(30) Foreign Application Priority Data
Jan. 25, 2024 (JP) 2024-009561
Feb. 15, 2024 (JP) 2024-021212

(51) Int. Cl. H10K 59/121; G09G 3/3233; H10D 86/40

(52) U.S. Cl. CPC H10K 59/1213; G09G 3/3233; H10K 59/1216; G09G 2300/0852; G09G 2310/08; G09G 2320/0223; G09G 2330/021; H10D 86/423

(57) ABSTRACT

A novel semiconductor device is provided. The semiconductor device includes a first transistor including a gate and a back gate, and a light-emitting element. The semiconductor device is configured to perform a first operation for supplying a first potential to the back gate of the first transistor, a second operation for fixing a gate potential and a source potential of the first transistor and establishing electrical continuity between a drain and the back gate of the first transistor to set a back gate potential to a second potential corresponding to a difference between the source potential and the gate potential of the first transistor, a third operation for supplying a video signal to the gate of the first transistor, and a fourth operation for supplying a current corresponding to the video signal to the light-emitting element. The second operation is performed less frequently than the third and fourth operations.

### BACKGROUND OF THE INVENTION

### 1. Field of the Invention

One embodiment of the present invention relates to a semiconductor device.

Note that one embodiment of the present invention is not limited to the above technical field. Examples of the technical field of one embodiment of the present invention include a semiconductor device, a display apparatus, a light-emitting device, a power storage device, a memory device, an electronic device, a lighting device, an input device (e.g., a touch sensor), an input/output device (e.g., a touch panel), a driving method thereof, and a manufacturing method thereof.

### 2. Description of the Related Art

In recent years, self-luminous display apparatuses using light-emitting elements such as light-emitting diodes (LEDs) in pixels have been actively researched and developed. In particular, active-matrix display apparatuses using organic electroluminescence (EL) elements as light-emitting elements have attracted attention. In general, a self-luminous active-matrix display apparatus includes a pixel circuit including a light-emitting element. The pixel circuit includes, for example, a transistor (a driving transistor) that controls the amount of current supplied to the light-emitting element, in accordance with a video signal.

The emission luminance of the light-emitting element depends on the amount of drain current of the driving transistor. Thus, when the electrical characteristics (e.g., threshold voltages) of the driving transistors are varied between a plurality of pixels in a screen of the display apparatus, the pixels have different emission luminances even when supplied with the same video signal. The variation in electrical characteristics of the driving transistors between the plurality of pixels is one factor of low display quality of the display apparatus.

To reduce the variation in electrical characteristics of driving transistors between a plurality of pixels, pixel circuits with various structures have been proposed. Patent Document 1 discloses a structure in which a transistor including a gate and a back gate is used as a driving transistor to reduce the variation in electrical characteristics of the driving transistors.

### REFERENCE

### Patent Document

[Patent Document 1] Japanese Published Patent Application No. 2015-132816

### SUMMARY OF THE INVENTION

Patent Document 1 discloses a structure in which a source of the driving transistor is connected to an organic EL element, and the potential of the source is changed with the potential of the back gate of the driving transistor being fixed, to obtain the threshold voltage of the driving transistor. The organic EL element has a structure in which a light-emitting layer is interposed between an anode and a cathode, and thus has capacitance. Thus, in the structure disclosed in Patent Document 1, the capacitance of the organic EL element needs to be charged in order to obtain the threshold voltage of the driving transistor. Thus causes a problem in that a period for obtaining the threshold voltage tends to be long.

An object of one embodiment of the present invention is to provide a semiconductor device in which the influence of variation in characteristics is reduced. Another object is to provide a semiconductor device with low power consumption. Another object is to provide a highly reliable semiconductor device. Another object is to provide a novel semiconductor device. Another object is to provide a display apparatus with high display quality. Another object is to provide a display apparatus with low power consumption. Another object is to provide a novel display apparatus.

Note that the description of the above objects does not preclude the existence of other objects. Those skilled in the art can find and extract other objects from the description of the specification, the drawings, the claims, and the like. Note that one embodiment of the present invention does not necessarily achieve all of these objects (the above objects and the other objects).
(1) One embodiment of the present invention is a semiconductor device including a first transistor including a gate and a back gate, and a light-emitting element. The semiconductor device is configured to perform a first operation for supplying a first potential to the back gate of the first transistor, a second operation for fixing a gate potential and a source potential of the first transistor and establishing electrical continuity between a drain and the back gate of the first transistor to set a potential of the back gate to a second potential, a third operation for supplying a video signal to the gate of the first transistor, and a fourth operation for supplying a current corresponding to the video signal to the light-emitting element. The second potential corresponds to a difference between the source potential and the gate potential of the first transistor. The second operation is performed less frequently than the third operation. The second operation is performed less frequently than the fourth operation.

In (1), for example, the second potential is lower than the first potential.
(2) Another embodiment of the present invention is a semiconductor device including a first transistor, a second transistor, a third transistor, a fourth transistor, a fifth transistor, a sixth transistor, and a seventh transistor, a first capacitor and a second capacitor, and a light-emitting element. The first transistor includes a gate, a back gate, a first terminal, and a second terminal. The second transistor, the third transistor, the fourth transistor, the fifth transistor, the sixth transistor, the seventh transistor, the first capacitor, the second capacitor, and the light-emitting element each include a first terminal and a second terminal. The first terminal of the first transistor is electrically connected to the second terminal of the second transistor and the first terminal of the third transistor. The second terminal of the third transistor is electrically connected to the back gate of the first transistor, the first terminal of the seventh transistor, and the first terminal of the second capacitor. The second terminal of the second capacitor is electrically connected to the first terminal of the fourth transistor, the second terminal of the first transistor, the first terminal of the light-emitting element, and the second terminal of the first capacitor. The gate of the first transistor is electrically connected to the first terminal of the first capacitor, the second terminal of the fifth transistor, and the first terminal of the sixth transistor. W/L of the third transistor is smaller than W/L of the fifth transistor. The W/L of the third transistor is smaller than W/L of the sixth transistor. W/L of the seventh transistor is smaller than the W/L of the fifth transistor. The W/L of the seventh transistor is smaller than the W/L of the sixth transistor.

In (2), the first capacitor is configured to maintain a difference between a potential of the second terminal of the first transistor and a potential of the gate of the first transistor. The second capacitor is configured to maintain a difference between the potential of the second terminal of the first transistor and a potential of the back gate of the first transistor.

In (2), the first terminal of the second transistor is electrically connected to a first wiring. The first terminal of the fifth transistor is electrically connected to a second wiring. The second terminal of the sixth transistor is electrically connected to a third wiring. The second terminal of the seventh transistor is electrically connected to a fourth wiring. The second terminal of the fourth transistor is electrically connected to a fifth wiring. The second terminal of the light-emitting element is electrically connected to a sixth wiring. The first wiring is configured to supply a first potential. The second wiring is configured to supply a video signal. The third wiring is configured to supply a second potential. The fourth wiring is configured to supply a third potential. The fifth wiring is configured to supply a fourth potential. The sixth wiring is configured to supply a fifth potential.

In (1) and (2), the first transistor can be an n-type transistor. The first transistor can include an oxide semiconductor in a semiconductor layer where a channel is formed. The light-emitting element can be an organic EL element.

According to one embodiment of the present invention, a semiconductor device in which the influence of variation in characteristics is reduced can be provided. A semiconductor device with low power consumption can be provided. A highly reliable semiconductor device can be provided. A novel semiconductor device can be provided. A display apparatus with high display quality can be provided. A display apparatus with low power consumption can be provided. A novel display apparatus can be provided.

Note that the description of the above effects does not preclude the existence of other effects. Those skilled in the art can find and extract other effects from the description of the specification, the drawings, the claims, and the like. Note that one embodiment of the present invention does not necessarily have all of these effects (the above effects and the other effects).

### BRIEF DESCRIPTION OF THE DRAWINGS

In the accompanying drawings:

FIGS. 1A and 1B are diagrams showing circuit configuration examples of a semiconductor device;

FIG. 2 is a diagram showing a circuit configuration example of a semiconductor device;

FIG. 3 is a timing chart showing an operation example of a semiconductor device;

FIGS. 4A and 4B are diagrams showing an operation example of a semiconductor device;

FIGS. 5A and 5B are diagrams showing an operation example of a semiconductor device;

FIG. 6A is a timing chart showing an operation example of a semiconductor device, and FIG. 6B is a diagram showing the operation example of the semiconductor device;

FIG. 7A is a timing chart showing an operation example of a semiconductor device, and FIG. 7B is a diagram showing the operation example of the semiconductor device;

FIG. 8A is a timing chart showing an operation example of a semiconductor device, and FIG. 8B is a diagram showing the operation example of the semiconductor device;

FIG. 9A is a timing chart showing an operation example of a semiconductor device, and FIG. 9B is a diagram showing the operation example of the semiconductor device;

FIG. 10 is a timing chart showing an operation example of a semiconductor device;

FIGS. 11A and 11B are diagrams showing an operation example of a semiconductor device;

FIGS. 12A and 12B are diagrams showing an operation example of a semiconductor device;

FIG. 13 is a diagram showing a circuit configuration example of a semiconductor device;

FIG. 14A is a timing chart showing an operation example of a semiconductor device, and FIG. 14B is a diagram showing the operation example of the semiconductor device;

FIGS. 15A and 15B are diagrams showing circuit configuration examples of a semiconductor device;

FIG. 16A is a timing chart showing an operation example of a semiconductor device, and FIG. 16B is a diagram showing the operation example of the semiconductor device;

FIGS. 17A and 17B are diagrams showing an operation example of the semiconductor device;

FIGS. 18A and 18B are diagrams showing circuit configuration examples of a semiconductor device;

FIG. 19 is a diagram showing a circuit configuration example of a semiconductor device;

FIGS. 20A and 20B are diagrams showing circuit configuration examples of a semiconductor device;

FIG. 21 is a diagram showing a circuit configuration example of a semiconductor device;

FIG. 22 is a diagram showing a circuit configuration example of a semiconductor device;

FIG. 23A is a diagram showing a circuit configuration example of a semiconductor device, and FIGS. 23B and 23C are diagrams showing circuit symbols of transistors;

FIG. 24 is a diagram showing a circuit configuration example of a semiconductor device;

FIGS. 25A and 25B are diagrams showing circuit symbols of transistors;

FIG. 26 is a timing chart showing an operation example of a semiconductor device;

FIG. 27 is a diagram showing a circuit configuration example of a semiconductor device;

FIGS. 28A1 to 28A7 and FIGS. 28B1 to 28B6 are diagrams for explaining electrical connection;

FIGS. 29A to 29C are diagrams illustrating a structure of a transistor;

FIGS. 30A to 30C are diagrams illustrating a structure of a transistor;

FIGS. 31A and 31B are diagrams illustrating a structure of a transistor;

FIGS. 32A and 32B are diagrams illustrating a structure of a transistor;

FIGS. 33A to 33C are diagrams illustrating a structure of a transistor;

FIGS. 34A to 34C are diagrams illustrating a structure of a transistor;

FIGS. 35A to 35E are diagrams showing a structure example of a transistor;

FIGS. 36A and 36B are diagrams showing a structure example of a transistor;

FIGS. 37A to 37E are diagrams showing a structure example of a transistor;

FIG. 38 is a diagram showing a structure example of a transistor;

FIGS. 39A to 39E are diagrams showing a structure example of a transistor;

FIGS. 40A to 40D are cross-sectional views illustrating a method for forming a metal oxide;

FIGS. 41A to 41D are cross-sectional views illustrating a method for forming a metal oxide;

FIG. 42 is a diagram showing a planar structure example of a semiconductor device;

FIGS. 43A and 43B are diagrams showing a planar structure example of a semiconductor device;

FIG. 44 is a diagram showing a cross-sectional structure example of a semiconductor device;

FIG. 45 is a diagram showing a cross-sectional structure example of a semiconductor device;

FIG. 46A is a perspective view showing a structure example of a display apparatus, and FIGS. 46B to 46F are plan views showing examples of pixel arrangement;

FIGS. 47A to 47D are diagrams showing structure examples of a light-emitting device;

FIGS. 48A to 48D are diagrams showing structure examples of a light-emitting device;

FIGS. 49A to 49D are diagrams showing structure examples of a light-emitting device;

FIGS. 50A to 50C are diagrams showing structure examples of a light-emitting device;

FIG. 51 is a block diagram showing a configuration example of a display apparatus;

FIGS. 52A and 52B are block diagrams showing configuration examples of display apparatuses;

FIGS. 53A and 53B are block diagrams showing configuration examples of display apparatuses;

FIGS. 54A to 54C and 54E are circuit diagrams showing a structure example of a semiconductor device, and FIG. 54D is a timing chart showing an operation example of the semiconductor device;

FIG. 55 is a cross-sectional view showing a structure example of a display apparatus;

FIGS. 56A and 56B are cross-sectional views showing structure examples of display apparatuses;

FIGS. 57A and 57B are cross-sectional views showing structure examples of display apparatuses;

FIGS. 58A and 58B are diagrams showing a structure example of a display apparatus;

FIGS. 59A to 59D are diagrams showing examples of electronic devices;

FIGS. 60A to 60F are diagrams showing examples of electronic devices; and

FIGS. 61A to 61G are diagrams showing examples of electronic devices.

### DETAILED DESCRIPTION OF THE INVENTION

Embodiments will be described below with reference to the drawings. Note that the embodiments can be implemented with many different modes, and it will be readily understood by those skilled in the art that modes and details thereof can be changed in various ways without departing from the spirit and scope thereof. Therefore, the present invention should not be construed as being limited to the description of embodiments below.

In this specification and the like, a semiconductor device refers to a device that utilizes semiconductor characteristics, and means a circuit including a semiconductor element (e.g., a transistor, a diode, or a photodiode), a device including the circuit, and the like. The semiconductor device also means devices that can function by utilizing semiconductor characteristics. For example, an integrated circuit, a chip including an integrated circuit, and an electronic component including a chip in a package are examples of the semiconductor device. In some cases, a memory device, a display apparatus, a light-emitting device, a lighting device, an electronic device, and the like themselves are semiconductor devices and also include a semiconductor device.

In the drawings and the like related to this specification, the size, the layer thickness, or the region is exaggerated for clarity in some cases. Therefore, embodiments of the present invention are not limited to the size, aspect ratio, or the like shown in the drawings. The drawings are schematic views showing ideal examples, and embodiments of the present invention are not limited to shapes, values, or the like shown in the drawings.

Note that in the structures of the invention described in the embodiments, the same portions or portions having similar functions are denoted by the same reference numerals in different drawings and the description of such portions is not repeated in some cases. The same hatching pattern is used for portions having similar functions, and the portions are not denoted by specific reference numerals in some cases. Moreover, some components may be omitted in a perspective view, a plan view, or the like for easy understanding of the diagrams.

Ordinal numbers such as “first” and “second” in this specification and the like are used in order to avoid confusion among components. Thus, the terms do not limit the number of components. The terms do not limit the order of components, either. For example, a “first” component in one embodiment in this specification and the like can be referred to as a “second” component in other embodiments, claims, or the like. As another example, a “first” component in one embodiment in this specification and the like can be omitted in other embodiments, claims, or the like. A term without an ordinal number in this specification might be provided with an ordinal number in a claim in order to avoid confusion among components. A term with an ordinal number in this specification might be provided with a different ordinal number in a claim. Moreover, a term with an ordinal number in this specification might not be provided with any ordinal number in a claim and the like.

In this specification and the like, terms for describing arrangement, such as “over”, “under”, “above”, and “below”, are sometimes used for convenience to describe the positional relation between components with reference to drawings. The positional relation between components is changed as appropriate in accordance with the direction from which each component is described. Thus, the positional relation is not limited to that described with a term used in this specification and the like and can be explained with another term as appropriate depending on the situation. For example, the expression “an insulator over (on) the top surface of a conductor” can be replaced with the expression “an insulator on the bottom surface of a conductor” when the direction of a diagram showing these components is rotated by 180°.

The term such as “over” or “under” does not necessarily mean that a component is placed directly on or under and directly in contact with another component. For example, the expression “an electrode B over an insulating layer A” does not necessarily mean that the electrode B is on and in direct contact with the insulating layer A, and can mean the case where another component is provided between the insulating layer A and the electrode B.

The term “overlap”, for example, in this specification and the like does not limit a state such as the stacking order of components. For example, the expression “electrode B overlapping with insulating layer A” does not necessarily mean the state where the electrode B is formed over the insulating layer A, and includes the case where the electrode B is formed under the insulating layer A and the case where the electrode B is formed on the right (or left) side of the insulating layer A.

In this specification and the like, the terms “film” and “layer” can be interchanged with each other depending on circumstances. For example, the term “conductive layer” can be changed into the term “conductive film” in some cases. The term “insulating film” can be changed into the term “insulating layer” in some cases, for example. Moreover, such terms can be replaced with a word not including the term “film” or “layer” depending on the case or circumstances. For example, the term “conductive layer” or “conductive film” can be changed into the term “conductor” in some cases. Alternatively, the term “conductor” can be changed into the term “conductive layer” or “conductive film” in some cases. For example, the term “insulating layer” or “insulating film” can be changed into the term “insulator” in some cases. For example, the term “insulator” can be changed into the term “insulating layer” or “insulating film” in some cases.

In this specification and the like, the terms “electrode”, “wiring”, “terminal”, and the like do not limit the functions of components. For example, an “electrode” is used as part of a “wiring” in some cases, and vice versa. Furthermore, the term “electrode” or “wiring” can also mean a combination of a plurality of “electrodes” or “wirings” provided in an integrated manner, for example. For another example, a “terminal” can be used as part of a “wiring” or an “electrode”, and vice versa. Furthermore, the term “terminal” includes the case where a plurality of “electrodes”, “wirings”, “terminals”, and the like are formed in an integrated manner. Therefore, for example, an “electrode” can be part of a “wiring” or a “terminal”, and a “terminal” can be part of a “wiring” or an “electrode”. Moreover, the terms “electrode”, “wiring”, and “terminal” are sometimes replaced with the term “region” and “conductive layer”, for example.

In this specification and the like, the terms “wiring”, “signal line”, “power source line”, and the like can be interchanged with each other depending on the case or in accordance with circumstances. For example, the term “wiring” can be changed into the term “signal line” in some cases. For another example, the term “wiring” can be changed into the term such as “power supply line” in some cases. Inversely, the term “signal line”, “power source line”, and the like can be changed into the term “wiring” in some cases. The term “power supply line” or the like can be changed into the term “signal line” or the like in some cases. Inversely, the term “signal line” or the like can be changed into the term “power source line” or the like in some cases. The term “potential” that is applied to a wiring can be changed into the term “signal” or the like depending on the case or in accordance with circumstances. Inversely, the term “signal” or the like can be changed into the term “potential” in some cases.

In this specification, a “source” refers to a source region, a source electrode, or a source wiring. A source region refers to one of two regions adjacent to a channel formation region in a semiconductor layer. A source electrode refers to a conductive layer including part connected to a source region.

In this specification, a “drain” refers to a drain region, a drain electrode, or a drain wiring. A drain region refers to the other of two regions adjacent to a channel formation region in a semiconductor layer. A drain electrode refers to a conductive layer including part connected to a drain region.

In this specification, a “gate” refers to a gate electrode or a gate wiring. A gate electrode refers to an electrode that overlaps with a semiconductor layer of a transistor and has a function of controlling the resistance between a source and a drain of the transistor with use of a supplied voltage.

In this specification, in some cases, one of a source and a drain of a transistor is referred to as a “first terminal of a transistor” and the other of the source and the drain of the transistor is referred to as a “second terminal of a transistor”.

In this specification, “parallel” indicates a state where the angle formed between two straight lines is greater than or equal to −10° and less than or equal to 10°. Thus, the case where the angle is greater than or equal to −5° and less than or equal to 5° is also included. The terms “approximately parallel” and “substantially parallel” indicate that the angle formed between two straight lines is greater than or equal to −15° and less than or equal to 15°. The term “perpendicular” indicates that the angle formed between two straight lines is greater than or equal to 80° and less than or equal to 100°. Thus, the case where the angle is greater than or equal to 85° and less than or equal to 95° is also included. The terms “approximately perpendicular” and “substantially perpendicular” indicate that the angle formed between two straight lines is greater than or equal to 60° and less than or equal to 120°.

A voltage refers to a difference between a given potential and a reference potential (e.g., a ground potential or a source potential) in many cases. Therefore, the terms “voltage” and “potential” can be replaced with each other in many cases. In this specification and the like, “voltage” and “potential” can be replaced with each other unless otherwise specified.

In this specification and the like, a high power supply potential VDD (hereinafter also simply referred to as “VDD”) is a power supply potential higher than a low power supply potential VSS. The low power supply potential VSS (hereinafter also simply referred to as “VSS”) is a power supply potential lower than the high power supply potential VDD. In addition, a ground potential GND (hereinafter also simply referred to as “GND”) can be used as VDD or VSS. For example, VSS is a potential lower than GND when VDD is GND, and VDD is a potential higher than GND when VSS is GND.

In this specification, an “on state” of a transistor refers to a state where electrical continuity is established between a source and a drain of the transistor (a state where a current can flow between the source and the drain). Furthermore, an “off state” of a transistor refers to a state where electrical continuity is not established between a source and a drain of the transistor (a state where the source and the drain can be regarded as being electrically disconnected).

In this specification and the like, “on-state current” means a current that flows between a source and a drain when a transistor is on. In addition, “off-state current” means a current that flows between a source and a drain when a transistor is off.

In this specification and the like, a potential H is a potential with which an n-channel field-effect transistor (also referred to as an “n-type transistor”) is turned on and also a potential with which a p-channel field-effect transistor (also referred to as a “p-type transistor”) is turned off. A potential L is a potential with which an n-type transistor is turned off and a p-type transistor is turned on. Thus, the potential H is higher than the potential L. The potential H is sometimes equal to VDD. The potential L is sometimes equal to VSS. Unless otherwise specified, transistors described in this specification are enhancement (normally-off) n-type transistors.

In the drawings and the like, for easy understanding of the potentials of a wiring and an electrode, “H” representing the potential H or “L” representing the potential L is sometimes written near the wiring, the electrode, and the like. In addition, enclosed “H” or “L” is sometimes written near a wiring, an electrode, and the like whose potentials are changed. Moreover, a symbol “x” is sometimes written on a transistor in an off state. Furthermore, arrows indicating the direction of current flowing are shown in some cases.

In this specification and the like, the terms “identical”, “the same”, “equal”, “uniform”, and the like (including synonyms thereof) used in describing calculation values and actual measurement values allow for a margin of error of ±10% unless otherwise specified.

In the drawings for this specification and the like, arrows indicating the X direction, the Y direction, and the Z direction are illustrated in some cases. In this specification and the like, the “X direction” is a direction along the X axis, and unless otherwise specified, the forward direction and the reverse direction are not distinguished in some cases. The same applies to the “Y direction” and the “Z direction”. The X direction, the Y direction, and the Z direction are directions intersecting with each other. For example, the X direction, the Y direction, and the Z direction are directions orthogonal to each other. In this specification and the like, one of the X direction, the Y direction, and the Z direction is referred to as a “first direction” in some cases. Another one of the directions is referred to as a “second direction” in some cases. The remaining one of the directions is referred to as a “third direction” in some cases.

In general, “capacitance” has a structure in which two electrodes face each other with an insulator (dielectric) therebetween. This specification and the like include a case where “capacitance” is the above-described “capacitor”. That is, in this specification and the like, the “capacitor” includes one having a structure in which two electrodes face each other with an insulator therebetween, one having a structure in which two wirings face each other with an insulator therebetween, or one having a structure in which two wirings are placed with an insulator therebetween. In this specification, one electrode of a capacitor may be referred to as a “first terminal of a capacitor”, and the other electrode of the capacitor may be referred to as a “second terminal of a capacitor”.

In this specification and the like, a “switch” includes a plurality of terminals and has a function of switching (selecting) electrical continuity and discontinuity between the terminals. For example, in the case where a switch includes two terminals and electrical continuity is established between the two terminals, the switch is “on”. In the case where electrical continuity is not established between the two terminals, the switch is “off”. Note that switching to one of electrical continuity and discontinuity or maintaining one of electrical continuity and discontinuity is sometimes referred to as “controlling electrical continuity”. In the case where a switch includes two terminals in this specification, for example, one of the terminals may be referred to as a “first terminal of a switch” and the other terminal may be referred to as a “second terminal of a switch”.

That is, a switch has a function of controlling electrical continuity. Alternatively, a switch has a function of selecting and changing a current path. For example, an electrical switch or a mechanical switch can be used. That is, a switch is not limited to a certain element and can be any element capable of controlling a current.

As the switch, an electrical switch, a mechanical switch, or the like can be used. Examples of an electrical switch include a transistor (e.g., a bipolar transistor and a MOS transistor), a diode (e.g., a PN diode, a PIN diode, a Schottky diode, a metal-insulator-metal (IM) diode, a metal-insulator-semiconductor (MIS) diode, and a diode-connected transistor), and a logic circuit in which such elements are combined. A “conduction state” of a transistor refers to a state where a source and a drain of the transistor are short-circuited. Furthermore, a “non-conduction state” of the transistor refers to a state where the source and the drain of the transistor are electrically disconnected. In the case where a transistor operates just as a switch, there is no particular limitation on the polarity (conductivity type) of the transistor.

An example of a mechanical switch is a switch using a MEMS (microelectromechanical systems) technology. Such a switch includes an electrode that can be moved mechanically, and its conduction or non-conduction is selected with movement of the electrode.

In this specification, when a plurality of components denoted by the same reference numerals need to be distinguished from each other, identification signs such as “A”, “b”, “_1”, “[n]”, and “[m,n]” are sometimes added to the reference numerals.

The expression “connection” in this specification includes “electrical connection”, for example. When the expression “electrical connection” is used to specify the connection relation of a circuit element as an object, “electrical connection” includes “direct connection” and “indirect connection”, for example. The expression “A and B are directly connected” means that A and B are connected to each other without a circuit element (e.g., a transistor or a switch; a wiring is not a circuit element) therebetween, for example. Meanwhile, the expression “A and B are indirectly connected” means that A and B are connected to each other with at least one circuit element therebetween, for example.

Here, in the case where a connection relation is specified as “A and B are indirectly connected”, the following connection relations are included, for example. That is, on the assumption that a circuit is in operation, the circuit can be specified as “A and B are indirectly connected” as an object when electric signal transmission and reception, potential interaction, or the like between A and B occurs at some point during the operation period of the circuit. Note that even when neither electric signal transmission and reception nor potential interaction between A and B occurs at some point during the operation of the circuit, the circuit can be specified as “A and B are indirectly connected” as long as electric signal transmission and reception or potential interaction between A and B occurs at another point during the operation period of the circuit. Note that the expression “A and B are indirectly connected” specifies the connection relation of a circuit element as an object. Thus, even when a circuit is not supplied with a power supply voltage and is not in operation, for example, the circuit can be specified as “A and B are indirectly connected” as an object (note that this specification is limited to, for example, the case where electric signal transmission and reception, potential interaction, or the like between A and B occurs during the operation period of the circuit when the circuit is supplied with a power supply voltage to be in operation).

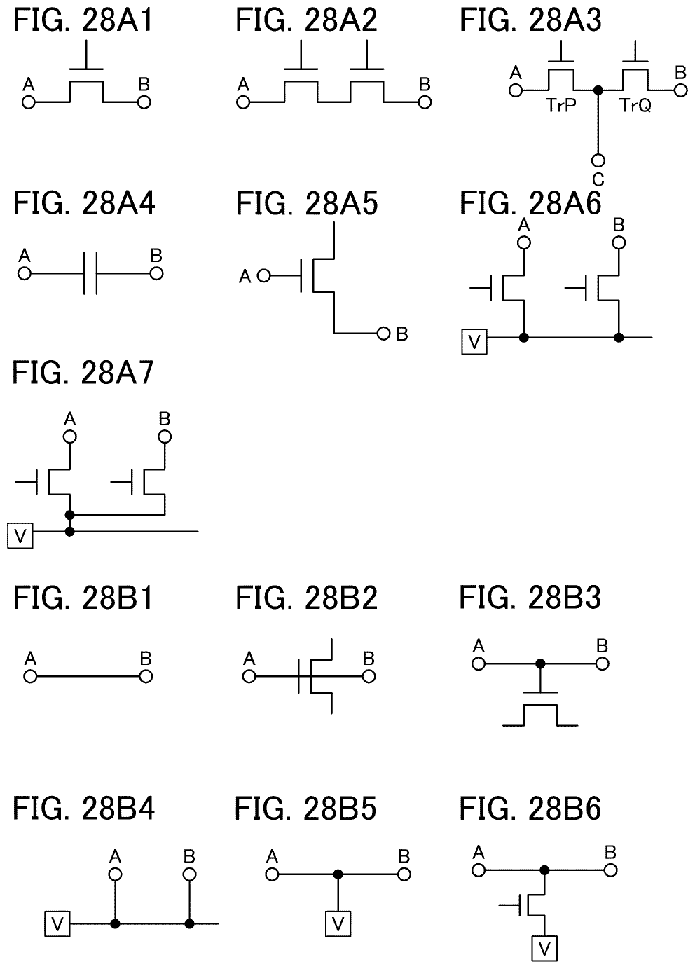

Specific examples of the case of “indirect connection” are described below. First, examples of the case where the expression “A and B are indirectly connected” can be used include the case where A and B are connected to each other through a source and a drain of at least one transistor as in FIG. 28A1 and FIG. 28A2. Another example thereof is the case where A and B are connected to each other with at least one switch therebetween. In the case where the expression “A and B are indirectly connected” can be used, one transistor between A and B is brought into the on state, the conduction state, or the state where a current can flow at least once on the assumption that a circuit is in operation. The case where the expression “A and B are indirectly connected” can be used may include a period at which the one transistor between A and B is brought into the off state or the non-conduction state. In the case where the expression “A and B are indirectly connected” can be used, each of a plurality of transistors between A and B is brought into the on state, the conduction state, or the state where a current can flow at least once when the plurality of transistors are connected between A and B on the assumption that a circuit is in operation. That is, in the case where the expression “A and B are indirectly connected” can be used, it is not necessary that all of the plurality of transistors be brought into the on state, the conduction state, or the state where a current can flow at the same time. Accordingly, in the case where the expression “A and B are indirectly connected” can be used, the plurality of transistors between A and B may be brought into the off state or the non-conduction state at the same time or at different times. As another example, when A and C are connected to each other through a source and a drain of a transistor TrP and B and C are connected to each other through a source and a drain of a transistor TrQ as illustrated in FIG. 28A3, it can be specified as “A and C are indirectly connected”, “B and C are indirectly connected”, or “A and B are indirectly connected”. Note that in the case where a constant potential V is supplied to C from a power source, GND, or the like as described later, the expression “A and C are indirectly connected” or “B and C are indirectly connected” can be used; however, the expression “A and B are indirectly connected” cannot be used.

The examples of the cases where the expression “indirect connection” can be used and cannot be used are described above, and another example of the case where the expression “indirect connection” cannot be used is described below. Even when electric signal transmission and reception, potential interaction, or the like between A and B occurs during the operation period of the circuit, the expression “A and B are indirectly connected” cannot be used in some cases exceptionally. Examples of the exceptional case include the case where A and B are connected to each other with an insulator therebetween. That is, in the case where A and B are connected to each other with an insulator therebetween, the expression “A and B are indirectly connected” cannot be used. A specific example of the case where A and B are connected to each other with an insulator therebetween is the case where a capacitor is connected between A and B as in FIG. 28A4. Another example thereof is the case where there is a gate insulating film of a transistor or the like between A and B as in FIG. 28A5. In that case, the expression “A (a gate of the transistor) and B (a source or a drain of the transistor) are indirectly connected” cannot be used.

Another example of the case where the expression “A and B are indirectly connected” cannot be used is the case where neither electric signal transmission and reception nor potential interaction between A and B occurs. For example, a plurality of transistors are connected through their sources and drains on the path from A to B and a constant potential V is supplied from a power source, GND, or the like to a node between one of the transistors and another one of the transistors as in FIGS. 28A6 and 28A7. In that case, the expression “A and B are indirectly connected” cannot be used; however, the expression “A and V are indirectly connected” or “B and V are indirectly connected” can be used. Note that in FIG. 28A3, when A and C are connected to each other through the source and the drain of the transistor TrP, B and C are connected to each other through the source and the drain of the transistor TrQ, and a constant potential V is supplied to C from a power source, GND, or the like, the same connection relation as that in FIG. 28A6 and FIG. 28A7 is established; thus, the expression “A and B are indirectly connected” cannot be used; however, the expression “A and C are indirectly connected” or “B and C are indirectly connected” can be used.

The examples of “indirect connection” are described above. The specification of “indirect connection” is included in the specification of “electrical connection”, for example; thus in the case where the expression “A and B are indirectly connected” is used, the expression “A and B are electrically connected” can also be used.

Next, specific examples of the case of “direct connection” are described. Examples of the case where the expression “A and B are directly connected” can be used include the case where A and B are connected to each other without a circuit element therebetween as in FIGS. 28B1, 28B2, and 28B3. When A and B are connected to a power source, GND, or the like from which a constant potential V is supplied without a circuit element therebetween as in FIGS. 28B4 and 28B5, the expression “A and B are directly connected”, “A and V are directly connected”, or “B and V are directly connected” can be used. Note that when A (or B) is connected to a constant potential V through a source and a drain of a transistor as in FIG. 28B6, the expression “A and B are directly connected” can also be used. Note that A and V or B and V are connected to each other through the source and the drain of the transistor and thus they cannot be regarded as being in direct connection, and the expression “A and V are indirectly connected” or “B and V are indirectly connected” can be used.

The examples of “direct connection” are described above. The specification of “direct connection” is included in the specification of “electrical connection”, for example; thus in the case where the expression “A and B are directly connected” is used, the expression “A and B are electrically connected” can also be used.

Note that one embodiment of the present invention includes a structure in which at least one of a gate, a source, and a drain of one or more transistors is connected to nothing or a given node. One embodiment of the present invention also includes a structure in which nothing, a given signal, or a given voltage is input to one or more wirings.

### Embodiment 1

In this embodiment, a semiconductor device 10A of one embodiment of the present invention will be described with reference to drawings. The semiconductor device 10A can be used for a pixel of a display apparatus, for example.

### Configuration Example

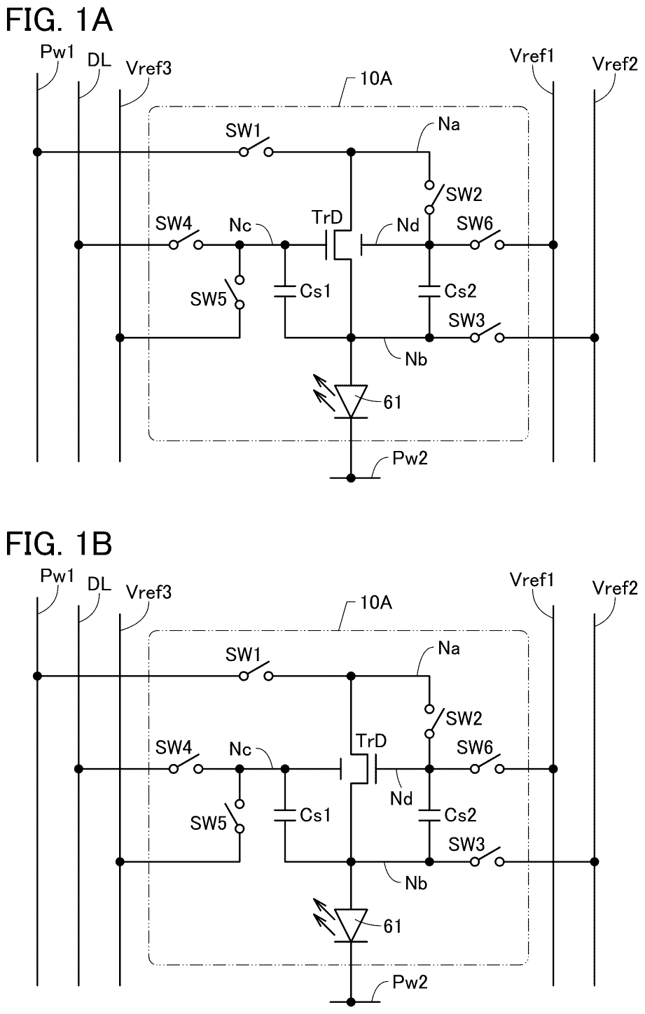

FIG. 1A shows a circuit configuration example of the semiconductor device 10A. The semiconductor device 10A includes a switch SW1 to a switch SW6, a transistor TrD, a capacitor Cs1, a capacitor Cs2, and a light-emitting element 61. The switch SW1 to the switch SW6 each include a first terminal and a second terminal.

The first terminal of the switch SW1 is connected to a wiring Pw1, and the second terminal of the switch SW1 is connected to the first terminal of the switch SW2 and one of a source and a drain of the transistor TrD. The second terminal of the switch SW2 is connected to the first terminal of the switch SW6, a back gate of the transistor TrD, and a first terminal of the capacitor Cs2. The second terminal of the switch SW6 is connected to a wiring Vref1. A second terminal of the capacitor Cs2 is connected to the first terminal of the switch SW3, the other of the source and the drain of the transistor TrD, a second terminal of the capacitor Cs1, and a first terminal of the light-emitting element 61. The second terminal of the switch SW3 is connected to a wiring Vref2. A second terminal of the light-emitting element 61 is connected to a wiring Pw2. Note that in the light-emitting element 61 in FIG. 1A, the first terminal and the second terminal function as an anode and a cathode, respectively.

The first terminal of the switch SW4 is connected to a wiring DL, and the second terminal of the switch SW4 is connected to a gate of the transistor TrD, a first terminal of the capacitor Cs1, and the first terminal of the switch SW5. The second terminal of the switch SW5 is connected to a wiring Vref3.

In FIG. 1A, a node Na refers to a region where the second terminal of the switch SW1, the first terminal of the switch SW2, and the one of the source and the drain of the transistor TrD are connected to each other and always have the same potential.

A node Nb refers to a region where the other of the source and the drain of the transistor TrD, the second terminal of the capacitor Cs1, the second terminal of the capacitor Cs2, and the first terminal of the light-emitting element 61 are connected to each other and always have the same potential.

A node Nc refers to a region where the second terminal of the switch SW4, the first terminal of the switch SW5, the first terminal of the capacitor Cs1, and the gate of the transistor TrD are connected to each other and always have the same potential.

A node Nd refers to a region where the second terminal of the switch SW2, the first terminal of the switch SW6, the first terminal of the capacitor Cs2, and the back gate of the transistor TrD are connected to each other and always have the same potential.

The transistor TrD includes the back gate. In general, in a transistor including a back gate, a gate and the back gate are placed so that a channel formation region in a semiconductor layer is sandwiched therebetween. The gate and the back gate are each formed using a conductive layer or a semiconductor layer with low resistivity. The back gate can function in a manner similar to that of the gate.

Thus, the gate and the back gate of the transistor TrD can be interchanged with each other as in the semiconductor device 10A illustrated in FIG. 1B. In the case where the gate is used for controlling the on state and the off state of the transistor, the back gate can have the same potential as the gate.

In the case of turning on the transistor, for example, supplying a potential with which the transistor is turned on to both the gate and the back gate can increase the amount of the on-state current as compared with the case of supplying the potential to only one of them. By controlling the back gate potential independently of the gate potential, the threshold voltage of the transistor can be adjusted.

In a transistor including a back gate, a gate and the back gate are formed using conductive layers or the like; thus, when a channel formation region in a semiconductor layer is sandwiched between the gate and the back gate, an electric field generated outside the transistor is less likely to act on the channel formation region (such an effect is also referred to as an “electric field blocking effect”). For this reason, a transistor including a back gate operates stably. Moreover, when transistors include back gates, variation in characteristics of the transistors is reduced. A transistor including a back gate can be highly reliable. Accordingly, a semiconductor device including the transistor can be highly reliable. Note that the electric field blocking effect can be obtained even when one or both of a gate and a back gate are in an electrically floating state (also referred to as a “floating state”); the effect can be enhanced by supplying a potential to the gate and the back gate.

The electrical characteristics of a transistor might change when light enters a channel formation region of the transistor. Moreover, the electrical characteristics of the transistor might deteriorate when light enters the channel formation region while a voltage is applied to the transistor. That is, the reliability of the transistor might be decreased. A transistor whose gate and back gate each include a light-blocking conductive material suffers from less deterioration of electrical characteristics and thus has higher reliability.

Although FIGS. 1A and 1B illustrate the circuit configurations in which the transistor TrD is an n-type transistor, a p-type transistor can also be used as the transistor TrD. Compared with an n-type transistor, a p-type transistor easily has normally-off characteristics and enables relatively easy circuit design. Meanwhile, an n-type transistor has higher field-effect mobility than a p-type transistor, and thus can increase the operation speed of the semiconductor device 10A.

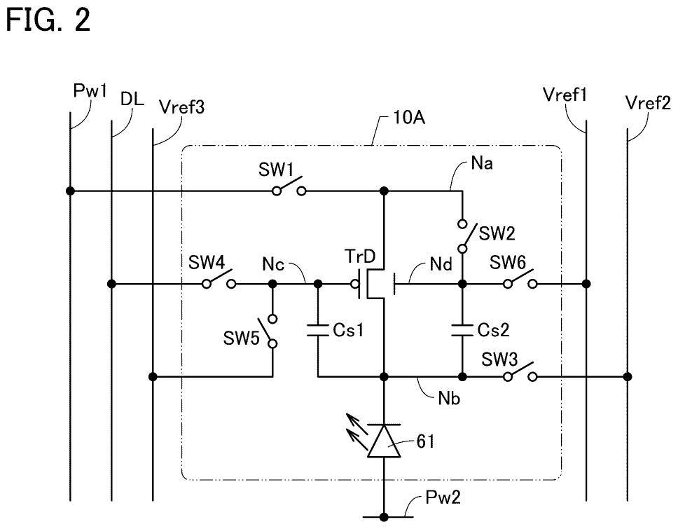

The wirings Pw1 and Pw2 function as power supply lines. Note that in the case where the transistor TrD is a p-type transistor as illustrated in FIG. 2, the first terminal of the light-emitting element 61 is connected to the wiring Pw2, and the second terminal of the light-emitting element 61 is connected to the node Nb. In the case where the transistor TrD is an n-type transistor, a potential H or VDD is supplied to the wiring Pw1, and a potential L or VSS is supplied to the wiring Pw2. In the case where the transistor TrD is a p-type transistor, a potential H or VDD is supplied to the wiring Pw2, and a potential L or VSS is supplied to the wiring Pw1.

### Operation Examples

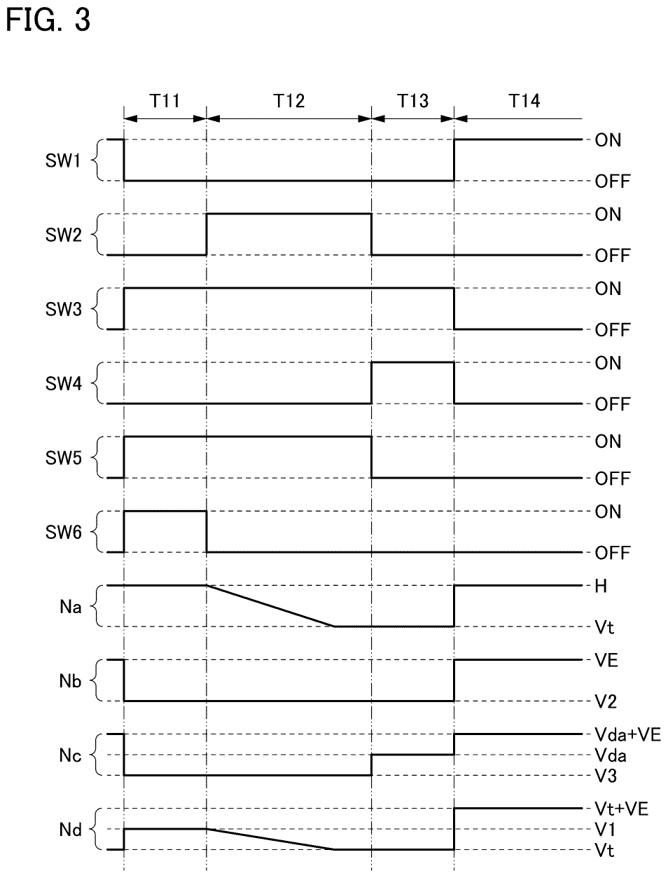

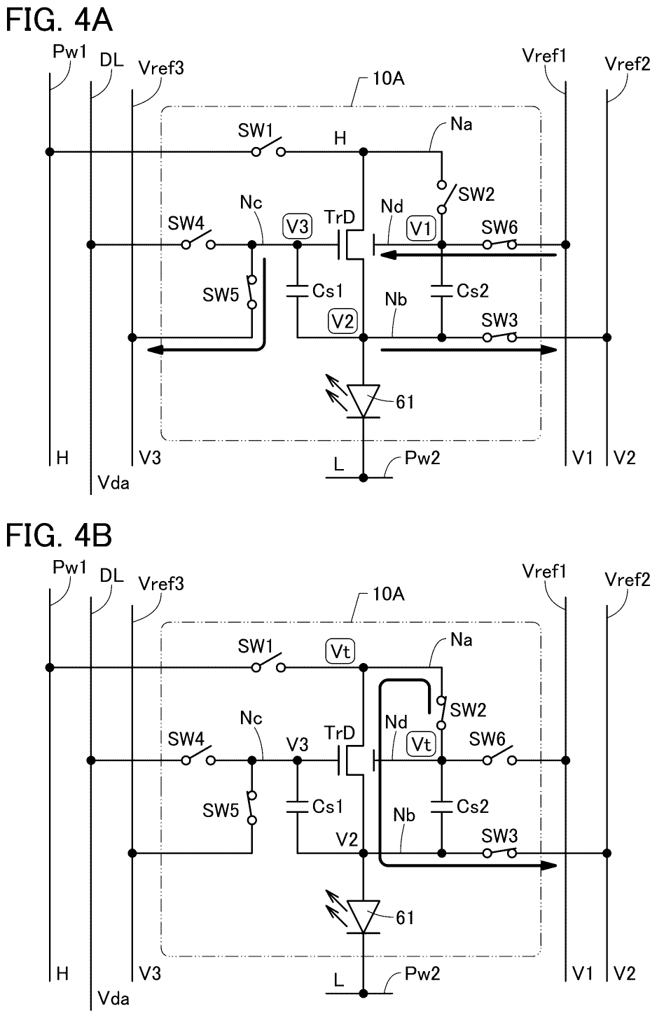

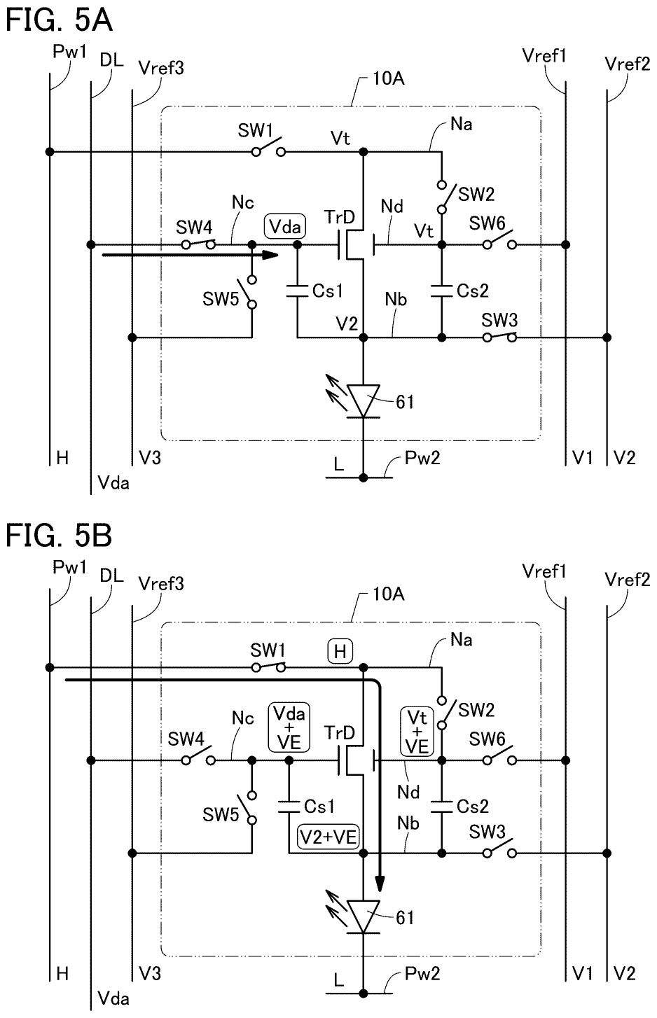

Next, operation examples of the semiconductor device 10A illustrated in FIG. 1A will be described with reference to drawings. FIG. 3 is a timing chart showing the operation example of the semiconductor device 10A illustrated in FIG. 1A. FIGS. 4A and 4B and FIGS. 5A and 5B are circuit diagrams illustrating the operation example of the semiconductor device 10A illustrated in FIG. 1A. Note that one embodiment of the present invention is all or part of the circuit configurations described in this specification and the like. Thus, one embodiment of the present invention satisfies both the support requirements and the clarity requirements even when not including all or part of the operations described in this specification and the like.

A potential V1, a potential V2, and a potential V3 are supplied to the wiring Vref1, the wiring Vref2, and the wiring Vref3, respectively. The potential V1 is a potential with which the transistor TrD is turned on. Thus, the potential V1 may be a potential H or VDD. The potential V2 is a potential for making the potential of the node Nb lower than or equal to a potential L. More specifically, the potential V2 has a value smaller than or equal to the sum of the values of the potential L and the threshold voltage of the light-emitting element 61. The potential V3 is preferably a reference potential (e.g., 0 V).

The potential H and the potential L are supplied to the wiring Pw1 and the wiring Pw2, respectively. Note that the difference between the potential H and the potential L is assumed to be sufficiently higher than the threshold voltage of the light-emitting element 61. Furthermore, a video signal Vda is supplied to the wiring DL. The video signal Vda is a potential higher than or equal to the potential V3 and lower than or equal to the potential H. The amount of the drain current of the transistor TrD depends on the video signal Vda. That is, the amount of current flowing through the light-emitting element 61 depends on the video signal Vda.

In the initial state, the switch SW1 is on and the switches SW2 to SW6 are off. The node Na has the potential H, the node Nb has a potential VE, the node Nc has the video signal Vda+the potential VE, and the node Nd has a potential Vt. The potential VE is a potential with which a current flows through the light-emitting element 61. The potential Vt corresponds to the threshold voltage of the transistor TrD.

### [Period T11]

A period T11 is a period during which the potentials of the nodes Nb, Nc, and Nd of the semiconductor device 10A are reset (or “initialized”) before the threshold voltage of the transistor TrD is set.

In the period T11, the switch SW1 is turned off and the switches SW3, SW5, and SW6 are turned on (see FIG. 3 and FIG. 4A). In the period T11, the potential of the node Nb becomes the potential V2, the potential of the node Nc becomes the potential V3, and the potential of the node Nd becomes the potential V1. That is, electrical continuity is established between the two terminals when the switch is turned on, and electrical continuity is broken between the two terminals when the switch is turned off.

### [Period T12]

A period T12 is a period for controlling the potential of the node Nd. Specifically, the period T12 is a period during which the potential of the node Nd is controlled in accordance with the threshold voltage of the transistor TrD so that the threshold voltage of the transistor TrD in a period T13 and a period T14 is set to the potential V3−the potential V2. For example, when the potential V3 is equal to the potential V2, the threshold voltage of the transistor TrD in the period T13 and the period T14 can be set to 0 V.

In the period T12, the switch SW2 is turned on and the switch SW6 is turned off (see FIG. 3 and FIG. 4B). Since the switch SW5 remains on, the potential of the node Ne remains the potential V3. Since the switch SW3 remains on, the potential of the node Nb remains the potential V2.

In the period T12, when the switch SW2 is turned on and the switch SW6 is turned off, a current flows from the node Nd to the wiring Vref2 through the switch SW2, the transistor TrD, and the switch SW3. Then, the potential of the node Nd decreases from the potential V1. The potential of the node Nd decreases until the transistor TrD is turned off. When the transistor TrD is turned off, the node Nd is brought into a floating state, so that the potential of the node Nd stops decreasing. Note that the node Na between the node Nd and the transistor TrD is also brought into a floating state. Here, the nodes Na and Nd each have the potential Vt. In this manner, the potential of the node Nd is set to the potential V3−the potential V2. By obtaining the potential Vt, the threshold voltage of the transistor TrD is set to the potential V3−the potential V2. That is, by obtaining the potential Vt, the influence of the variation in the threshold voltages of the transistors TrD can be reduced.

In the semiconductor device 10A of one embodiment of the present invention, the threshold voltage of the transistor TrD is set to the potential V3−the potential V2 in the following manner: the potential of the node Nc connected to the gate of the transistor TrD and the potential of the node Nb connected to the source of the transistor TrD are fixed, electrical continuity is established between the node Na connected to the drain of the transistor TrD and the node Nd connected to the back gate of the transistor TrD, and the nodes Na and Nd are charged and discharged. Since the parasitic capacitances of the nodes Na and Nd are each smaller than that of the node Nb, a period for obtaining the threshold voltage can be shorter than that in a circuit in which the node Nb is charged and discharged. Thus, the time required for the period T12 can be shortened.

### [Period T13]

The period T13 is a period during which the video signal Vda is set at the node Nc.

In the period T13, the switches SW2 and SW5 are turned off and the switch SW4 is turned on (see FIG. 3 and FIG. 5A). By turning on the switch SW4, the video signal Vda is set at the node Nc. When the switch SW2 is turned off, the node Nd is brought into a floating state, so that the potential of the node Nd (the potential Vt) is retained. Since the switch SW3 remains on, the potential of the node Nb remains the potential V2. Thus, the difference between the gate potential and the source potential of the transistor TrD functioning as a driving transistor is Vda-V2. The difference between the back gate potential and the source potential of the driving transistor is Vt−V2.

Here, the capacitance value of the capacitor Cs2 is preferably larger than the capacitance value obtained when the gate capacitance and the back gate capacitance of the transistor TrD are connected in series. In the case where the former capacitance is equivalent to or smaller than the latter capacitance, the potential of the node Nd may change in accordance with a change in the potential of the node Nc. The capacitance value of the capacitor Cs2 is preferably 5 times or more, further preferably 10 times or more the capacitance value obtained when the gate capacitance and the back gate capacitance of the transistor TrD are connected in series.

### [Period T14]

The period T14 is a period during which a current corresponding to the video signal Vda is supplied to the light-emitting element 61 so that the light-emitting element 61 emits light.

In the period T14, the switch SW1 is turned on and the switches SW3 and SW4 are turned off (see FIG. 3 and FIG. 5B). When the switch SW1 is turned on, the potential of the node Na becomes the potential H. When the switch SW3 is turned off, the node Nb is brought into a floating state. When the switch SW4 is turned off, the node Nc is brought into a floating state, so that the video signal Vda set at the node Nc is retained.

Here, the capacitor Cs1 retains the difference between the potential of the node Nc and the potential of the node Nb, and the capacitor Cs2 retains the difference between the potential of the node Nd and the potential of the node Nb. By obtaining the potential Vt in the period T12, the threshold voltage of the transistor TrD is set to the potential V3−the potential V2. When the potential of the node Nb is the potential V2 and the potential of the node Nc is the video signal Vda, the drain current (Id) of the transistor TrD is expressed by Formula (1).

$$[ Formula 1 ]$$

$$Id = \frac{1}{2} \times \frac{W}{L} \times μ \times {C}_{OX} \times {[ ( Vda - V 2 ) - ( V 3 - V 2 ) ]}^{2} \qquad ( 1 )$$

In Formula (1), Id represents the drain current of the transistor TrD, W represents the channel width of the transistor TrD, L represents the channel length of the transistor TrD, μ represents the mobility of the transistor TrD, and Cox represents the gate capacitance of the transistor TrD. Formula (1) can be rewritten into Formula (2).

$$[ Formula 2 ]$$

$$Id = \frac{1}{2} \times \frac{W}{L} \times μ \times {C}_{OX} \times {( Vda - V 3 )}^{2} \qquad ( 2 )$$

According to Formula (2), the value of the drain current of the transistor TrD is proportional to the square of the difference between the video signal Vda and the potential V3. Here, Formula (2) does not include the threshold voltage of the transistor TrD. This indicates that the influence of the variation in the threshold voltages of the transistors TrD can be significantly reduced in the semiconductor device 10A of one embodiment of the present invention.

When the drain current of the transistor TrD starts to flow, the potential of the node Nb increases to be the potential VE. For example, in the case where the potential V2 is 0 V, the potential of the node Nb increases by the potential VE. That is, the source potential of the transistor TrD increases. Note that since the node Nb and the node Nc are coupled through the capacitor Cs1, the potential of the node Nc also increases by the potential VE. Thus, the difference between the potential of the node Nc and the potential of the node Nb is maintained. Similarly, since the node Nb and the node Nd are coupled through the capacitor Cs2, the potential of the node Nd also increases by the potential VE. Thus, the difference between the potential of the node Nd and the potential of the node Nb is maintained.

In this case, the capacitance of the capacitor Cs1 is preferably larger than the gate capacitance of the transistor TrD. When the capacitance of the capacitor Cs1 is equivalent to or smaller than the gate capacitance, a change in the potential of the node Nb is not accurately transmitted to the node Nc in some cases. The capacitance of the capacitor Cs1 is preferably 5 times or more, further preferably 10 times or more the gate capacitance of the transistor TrD. Similarly, the capacitance of the capacitor Cs2 is preferably larger than the back gate capacitance of the transistor TrD. When the capacitance of the capacitor Cs2 is equivalent to or smaller than the back gate capacitance, a change in the potential of the node Nb is not accurately transmitted to the node Nd in some cases. The capacitance of the capacitor Cs2 is preferably 5 times or more, further preferably 10 times or more the back gate capacitance of the transistor TrD.

With use of the semiconductor device 10A of one embodiment of the present invention as a pixel, a display apparatus can achieve high display quality. By obtaining the threshold voltage every frame or every certain period, a decrease in display quality is inhibited and high display quality can be maintained for a long period. Thus, with use of the semiconductor device 10A of one embodiment of the present invention as a pixel, a display apparatus can achieve high reliability.

In the semiconductor device 10A of one embodiment of the present invention, the threshold voltage of the transistor TrD is obtained by charging and discharging not the node Nb but the node Nd. Since the parasitic capacitance of the node Nd is smaller than that of the node Nb, a period for obtaining the threshold voltage can be shorter than that in a circuit in which the node Nb is charged and discharged. Since the period for obtaining the threshold voltage is short, the semiconductor device 10A consumes less power.

In the semiconductor device 10A of one embodiment of the present invention, electrical continuity is established between the node Nc and a wiring, which is different between the period T12 and the period T13. Thus, the threshold voltage can be obtained from a certain row while the video signal Vda is written in another row. That is, the operation of the period T13 in a certain row and the operation of the period T12 in another row can be performed concurrently. Thus, the time required for the period T12 can be shortened. Accordingly, the use of the semiconductor device 10A of one embodiment of the present invention as a pixel can improve the frame rate and the resolution, enabling a display apparatus with high display quality.

From the period T11 to the period T13, the potential V2 is set lower than the potential L, so that reverse bias can be applied to the light-emitting element 61. The application of reverse bias to the light-emitting element 61 can inhibit deterioration of the light-emitting element 61.

In the period T14, the transistor TrD operates in a saturation region. Thus, the drain current of the transistor TrD is less likely to change even when the potential of the wiring Pw1 changes. Therefore, the influence of the voltage drop of the wiring Pw1 can be reduced.

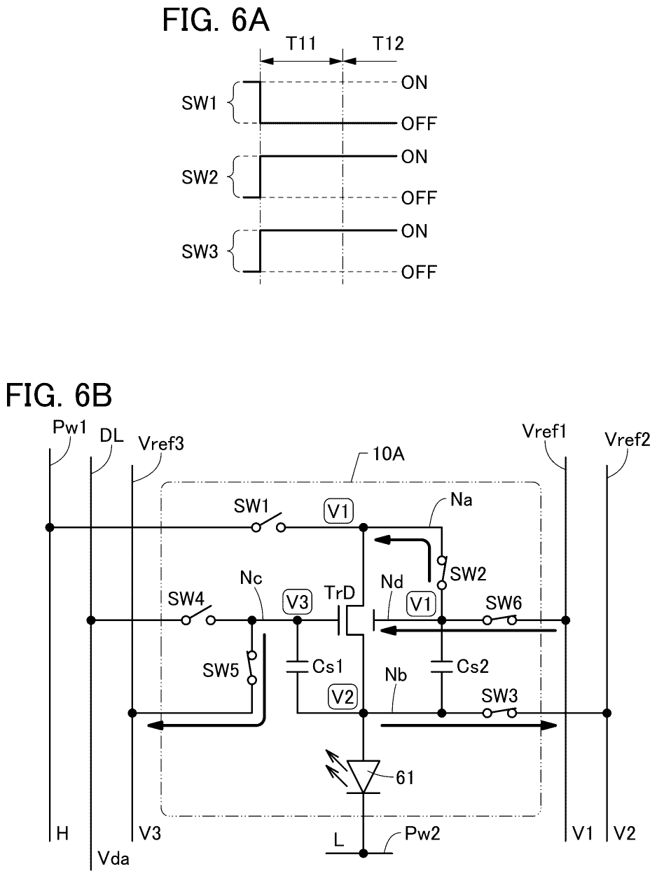

FIG. 6A is a timing chart showing a modification example of the operation in the period T11. FIG. 6B is a circuit diagram showing the operation in the period T11 shown in FIG. 6A. In the period T11, the switch SW2 can be turned on. By turning on the switch SW2, the potential of the node Na can be set to the potential V1, which is the same as the potential of the node Nd.

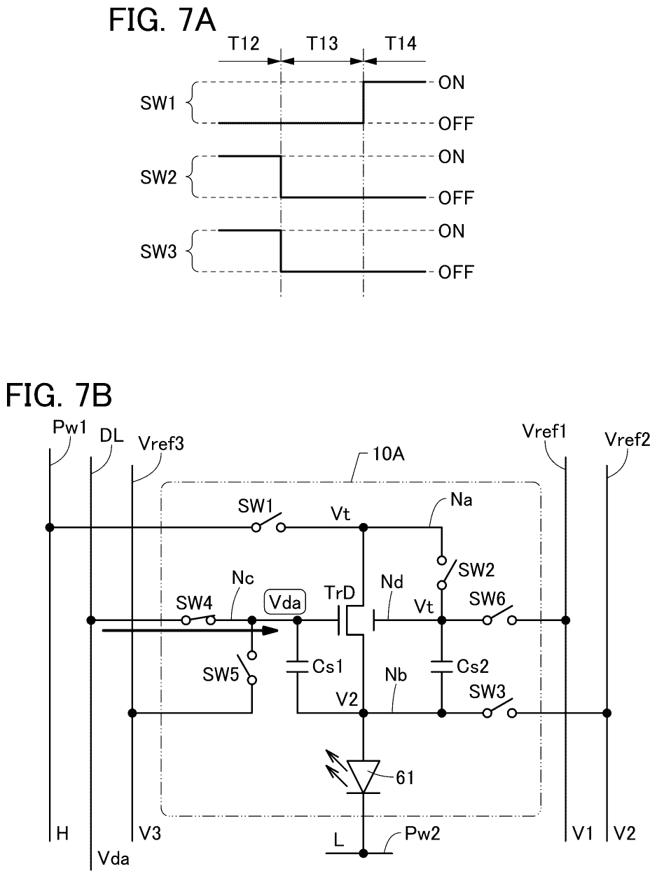

FIG. 7A is a timing chart showing a modification example of the operation in the period T13. FIG. 7B is a circuit diagram showing the operation in the period T13 shown in FIG. 7A. In the period T13, the switch SW3 can be turned off. In the period T13 of this case, the transistor TrD is turned on and a current flows from the wiring Pw1 to the node Nb through the switch SW1 and the transistor TrD. Thus, the potential of the node Nd slightly increases from the potential V2. The potential of the node Nd increases in accordance with the mobility of the transistor TrD. The higher the mobility of the transistor TrD is, the larger the increase in the potential of the node Nd is. The larger the increase in the potential of the node Nd is, the smaller the difference between the gate potential and the source potential of the transistor TrD is. The smaller the difference between the gate potential and the source potential of the transistor TrD is, the lower the drain current of the transistor TrD is. In this manner, the influence of the variation in the mobilities of the transistors TrD can be reduced.

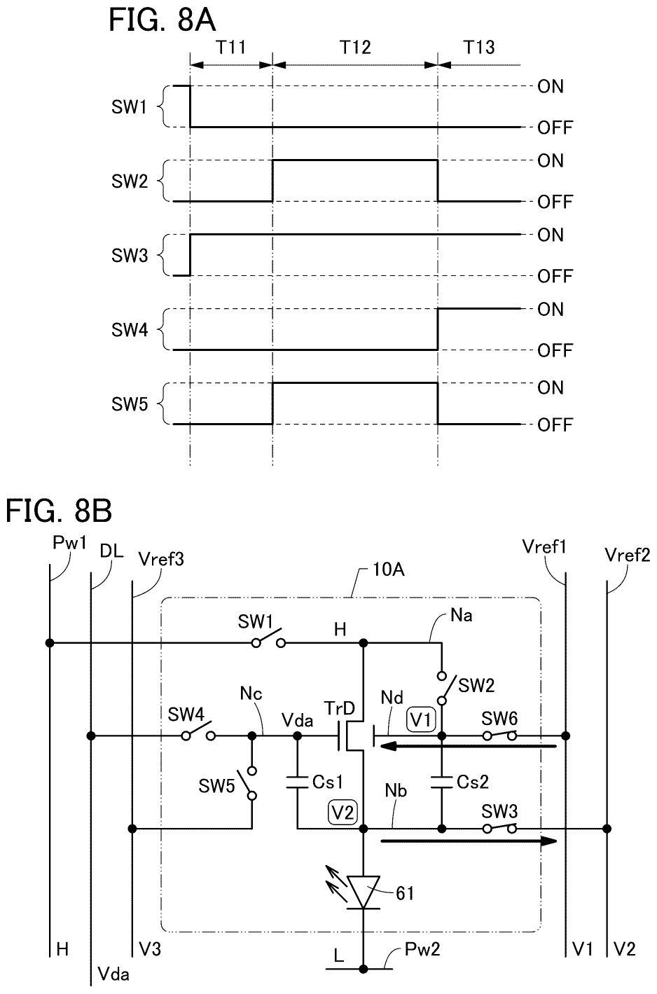

FIG. 8A is a timing chart showing a modification example of the operation in the period T11. FIG. 8B is a circuit diagram showing the operation in the period T11 shown in FIG. 8A. In the period T11, the switch SW5 can be turned off.

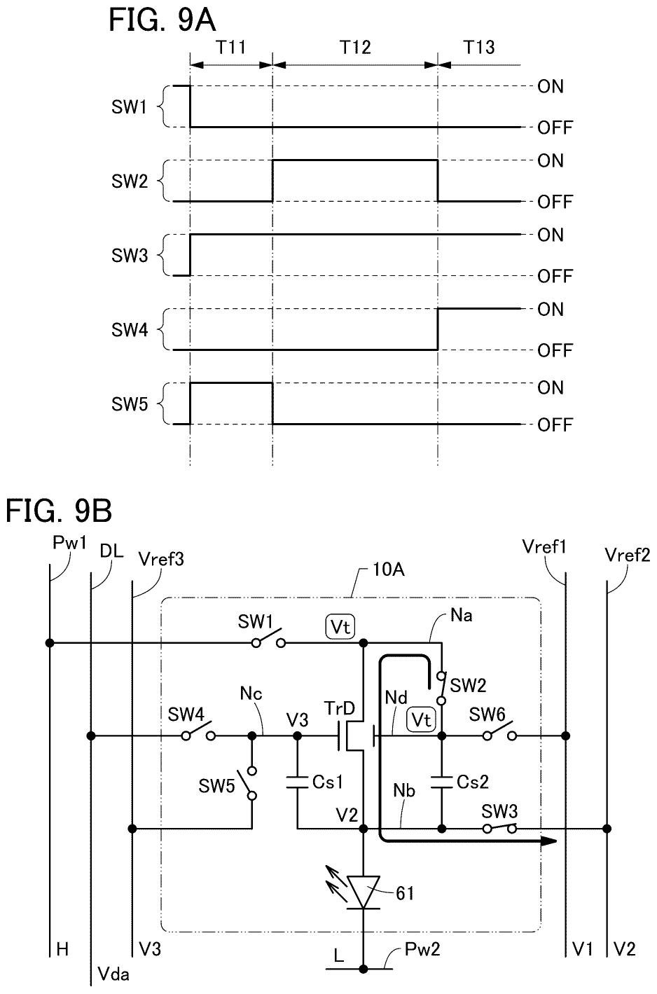

FIG. 9A is a timing chart showing a modification example of the operation in the period T12. FIG. 9B is a circuit diagram showing the operation in the period T12 shown in FIG. 9A. In the period T12, the switch SW5 can be turned off.

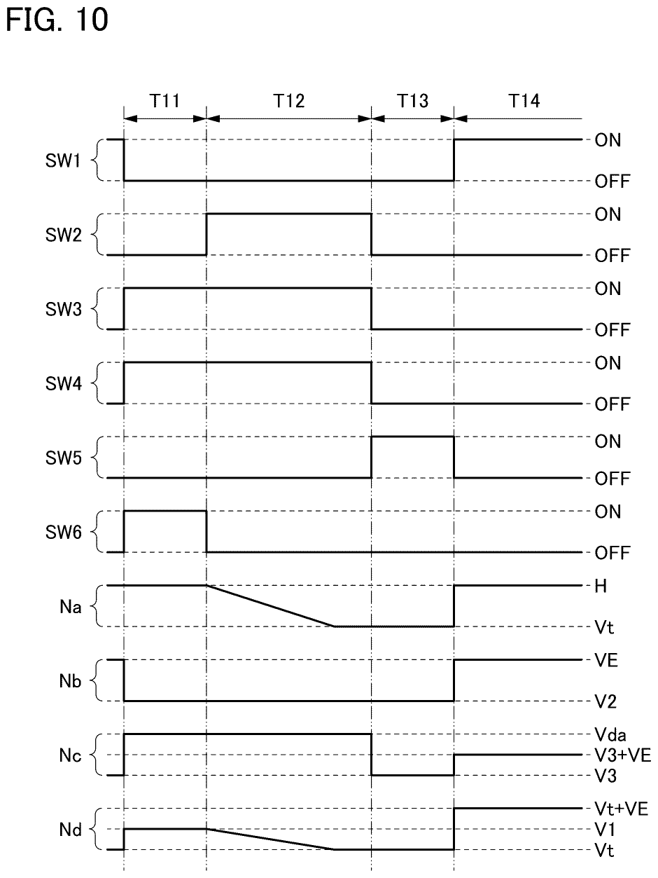

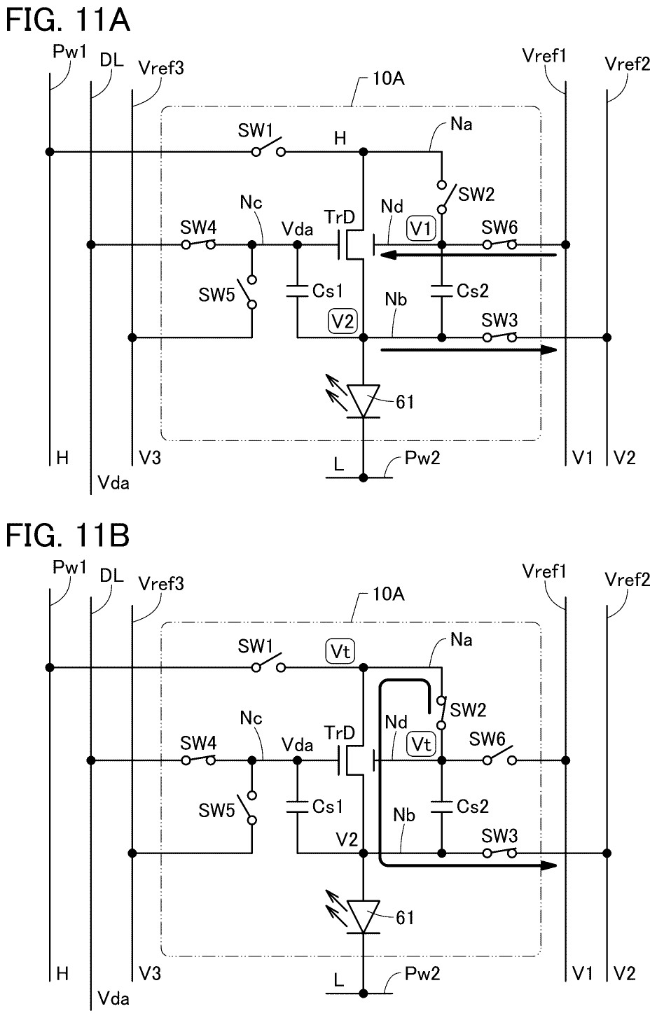

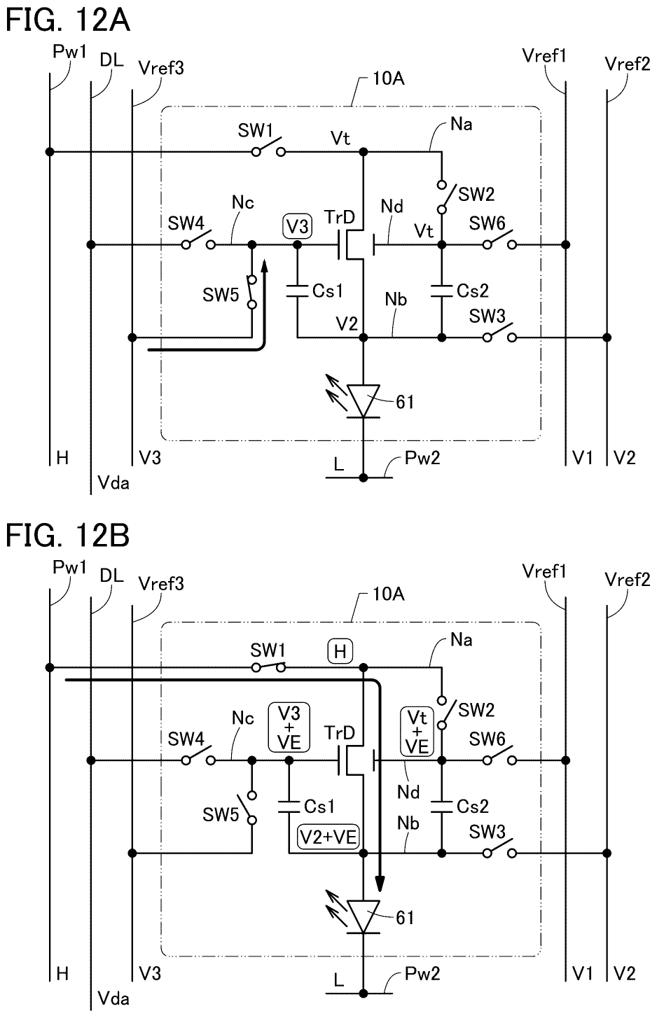

FIG. 10 is a timing chart showing a modification example of the operation of the semiconductor device 10A shown in FIG. 3. FIGS. 11A and 11B and FIGS. 12A and 12B are circuit diagrams showing the modification example of the operation of the semiconductor device 10A shown in FIGS. 4A and 4B and FIGS. 5A and 5B.

In the semiconductor device 10A illustrated in FIG. 1A, the switch SW4 can remain on and the switch SW5 can remain off in the periods T11 and T12 (see FIG. 10 and FIGS. 11A and 11B). In this case, the threshold voltage of the transistor TrD in the periods T13 and T14 is set to the video signal Vda−the potential V2. Then, in the period T13, the switch SW4 is turned off and the switch SW5 is turned on, whereby the potential V3 is supplied to the node Nc (see FIG. 10 and FIG. 12A). When a current flows through the light-emitting element 61 in the period T14, the potential of the node Nb is changed to the potential VE, whereby the potential of the node Nc becomes the potential V3+the potential VE, and the potential of the node Nd becomes the potential Vt+the potential VE (scc FIG. 10 and FIG. 12B). Also in the operation example shown in FIG. 10, FIGS. 11A and 11B, and FIGS. 12A and 12B, the influence of the variation in the threshold voltages of the transistors TrD can be reduced.

The structures described in this embodiment can be used in combination with any of the structures described in the other embodiments as appropriate.

### Embodiment 2

In this embodiment, modification examples of the semiconductor device 10A of one embodiment of the present invention will be described. In order to avoid repeated description, a description is mainly made on portions different from those of the semiconductor device 10A.

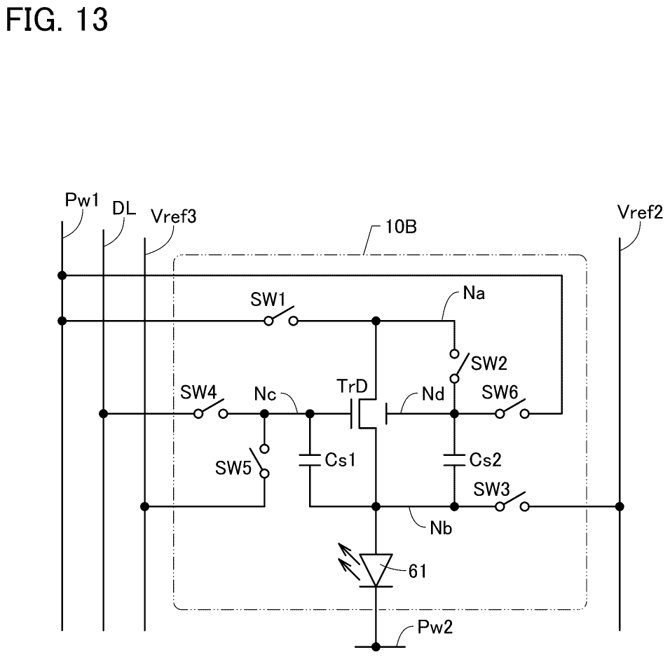

FIG. 13 is a circuit diagram of a semiconductor device 10B, which is a modification example of the semiconductor device 10A illustrated in FIG. 1A. The semiconductor device 10B is different from the semiconductor device 10A illustrated in FIG. 1A in that the second terminal of the switch SW6 is connected to the wiring Pw1. When the second terminal of the switch SW6 is connected to the wiring Pw1, the wiring Vref1 can be omitted. The semiconductor device 10B not including the wiring Vref1 has a small footprint and thus can have a high degree of integration. For example, a display apparatus using the semiconductor device 10B in a display portion can have high resolution and/or high definition. In the semiconductor device 10B, the potential of the node Nd becomes a potential H at the time of initialization in the period T11.

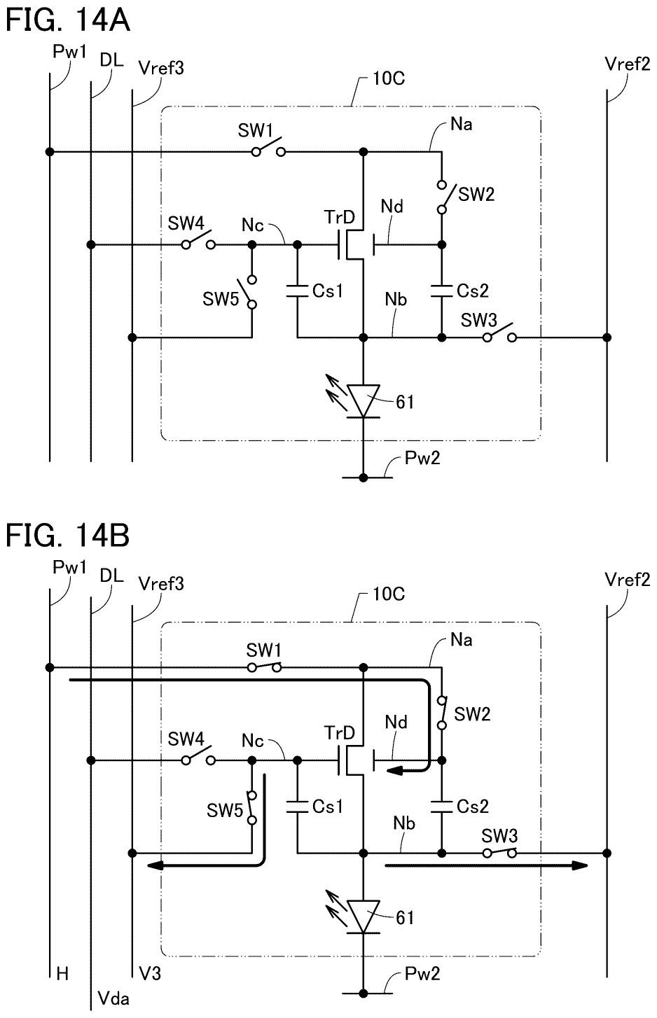

FIG. 14A is a circuit diagram of a semiconductor device 10C, which is a modification example of the semiconductor device 10A illustrated in FIG. 1A. The semiconductor device 10C is different from the semiconductor device 10A illustrated in FIG. 1A in not including the switch SW6 and the wiring Vref1. The semiconductor device 10C not including the switch SW6 and the wiring Vref1 can have a high degree of integration. For example, a display apparatus using the semiconductor device 10C in a display portion can have high resolution and/or high definition. Note that the semiconductor device 10C is also a modification example of the semiconductor device 10B. The semiconductor device 10C not including the switch SW6 can have a smaller footprint than the semiconductor device 10B.

FIG. 14B is a circuit diagram showing an operation example of the semiconductor device 10C in the period T11. By turning on the switches SW1 and SW2 in the period T11, the potential H can be supplied to the node Nd.

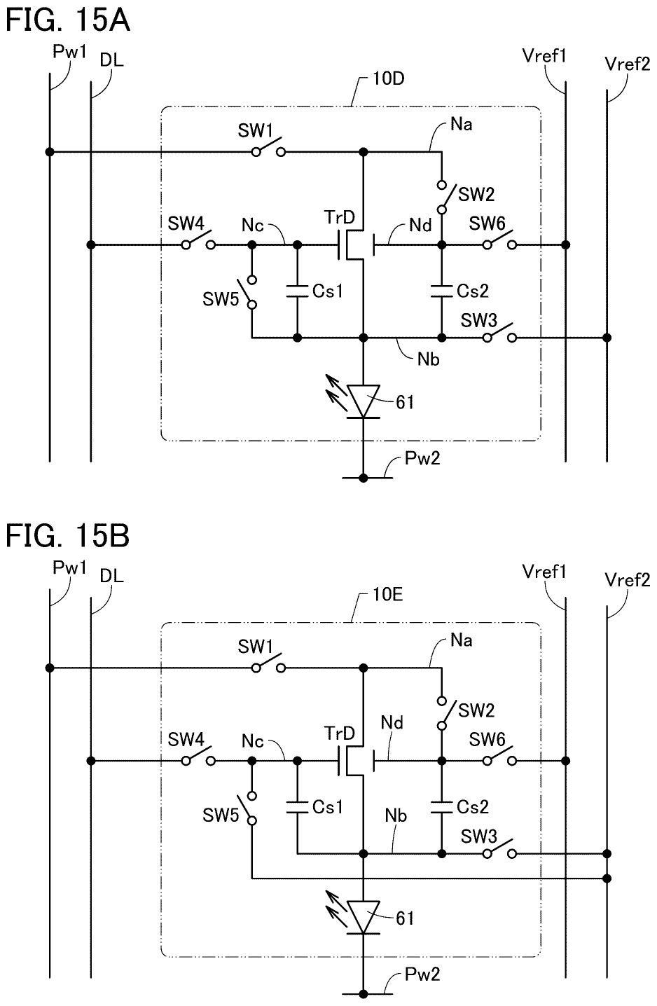

FIG. 15A is a circuit diagram of a semiconductor device 10D, which is a modification example of the semiconductor device 10A illustrated in FIG. 1A. The semiconductor device 10D is different from the semiconductor device 10A illustrated in FIG. 1A in that the second terminal of the switch SW5 is connected to the node Nb.

When the second terminal of the switch SW5 is connected to the node Nb, the wiring Vref3 can be omitted. The semiconductor device 10D not including the wiring Vref3 has a small footprint and thus can have a high degree of integration. For example, a display apparatus using the semiconductor device 10D in a display portion can have high resolution and/or high definition.

FIG. 15B is a circuit diagram of a semiconductor device 10E, which is a modification example of the semiconductor device 10A illustrated in FIG. 1A. The semiconductor device 10E is different from the semiconductor device 10A illustrated in FIG. 1A in that the second terminal of the switch SW5 is connected to the wiring Vref2. Note that the semiconductor device 10E is also a modification example of the semiconductor device 10D.

When the second terminal of the switch SW5 is connected to the wiring Vref2, the wiring Vref3 can be omitted. The semiconductor device 10E not including the wiring Vref3 has a small footprint and thus can have a high degree of integration. For example, a display apparatus using the semiconductor device 10E in a display portion can have high resolution and/or high definition.

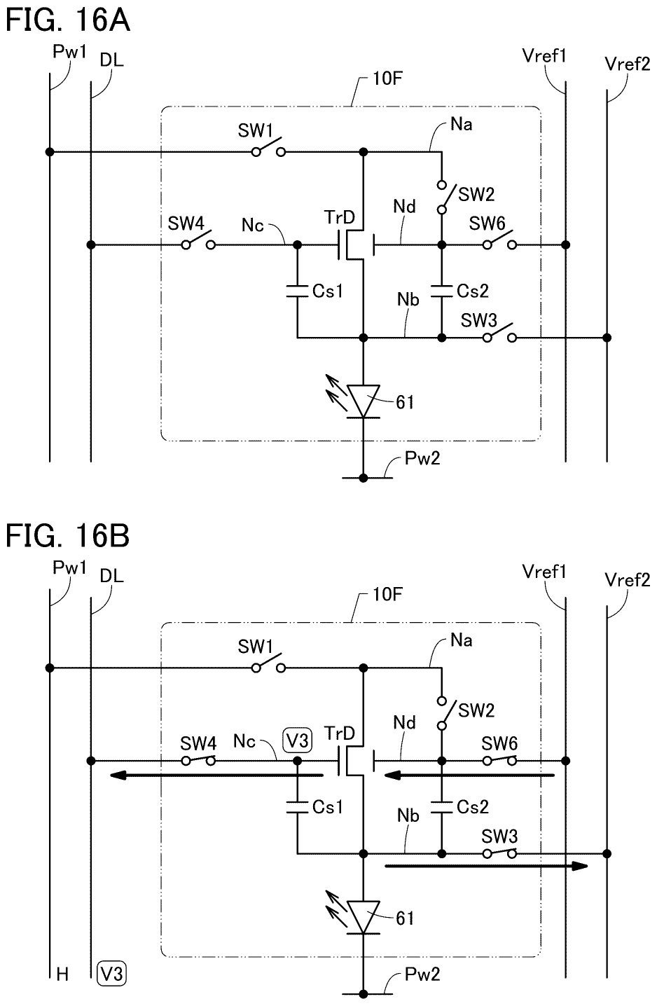

FIG. 16A is a circuit diagram of a semiconductor device 10F, which is a modification example of the semiconductor device 10A illustrated in FIG. 1A. The semiconductor device 10F is different from the semiconductor device 10A illustrated in FIG. 1A in not including the switch SW5 and the wiring Vref3. The semiconductor device 10F not including the switch SW5 and the wiring Vref3 can have a high degree of integration. For example, a display apparatus using the semiconductor device 10F in a display portion can have high resolution and/or high definition. Note that the semiconductor device 10F is also a modification example of the semiconductor device 10D. The semiconductor device 10F not including the switch SW5 can have a smaller footprint than the semiconductor device 10D.

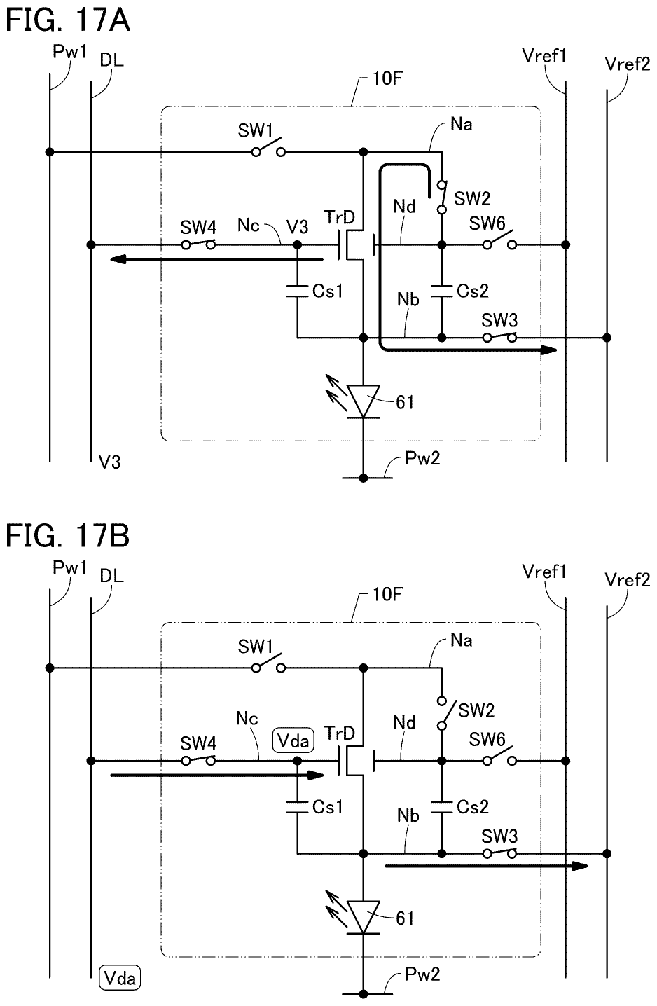

FIG. 16B, FIG. 17A, and FIG. 17B are circuit diagrams showing operation examples of the semiconductor device 10F in the period T11, the period T12, and the period T13, respectively. As illustrated in FIG. 16B and FIG. 17A, the switch SW4 is on in the periods T11 and T12, so that the potential V3 is supplied to the wiring DL. As illustrated in FIG. 17B, the switch SW4 is on in the period T13, so that the video signal Vda is supplied from the wiring DL to the node Nc.

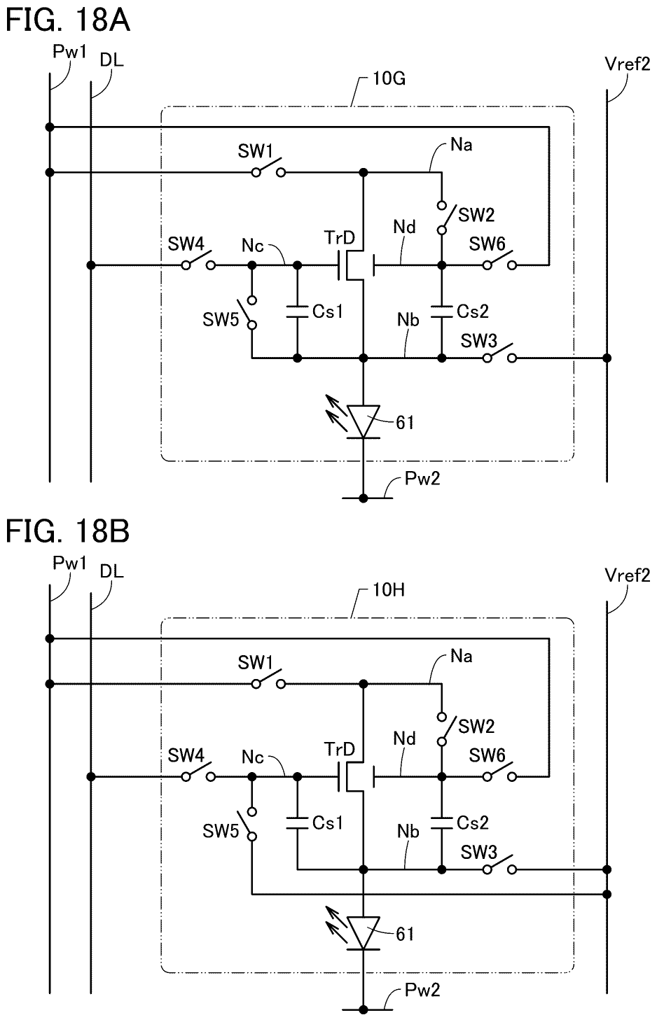

FIG. 18A is a circuit diagram of a semiconductor device 10G, which is a modification example of the semiconductor device 10A illustrated in FIG. 1A. The semiconductor device 10G is different from the semiconductor device 10A illustrated in FIG. 1A in that the second terminal of the switch SW6 is connected to the wiring Pw1 and the second terminal of the switch SW5 is connected to the node Nb. Note that the semiconductor device 10G can be regarded as having a structure obtained by combining the semiconductor devices 10B and 10D.

In the circuit configuration of the semiconductor device 10G, the wirings Vref1 and Vref3 can be omitted. The semiconductor device 10G not including the wirings Vref1 and Vref3 can have a high degree of integration. For example, a display apparatus using the semiconductor device 10G in a display portion can have high resolution and/or high definition.

FIG. 18B is a circuit diagram of a semiconductor device 10H, which is a modification example of the semiconductor device 10A illustrated in FIG. 1A. The semiconductor device 10H is different from the semiconductor device 10A illustrated in FIG. 1A in that the second terminal of the switch SW6 is connected to the wiring Pw1 and the second terminal of the switch SW5 is connected to the wiring Vref2. Note that the semiconductor device 10H can be regarded as having a structure obtained by combining the semiconductor devices 10B and 10E.

In the circuit configuration of the semiconductor device 10H, the wirings Vref1 and Vref3 can be omitted. The semiconductor device 10H not including the wirings Vref1 and Vref3 can have a high degree of integration. For example, a display apparatus using the semiconductor device 10H in a display portion can have high resolution and/or high definition.

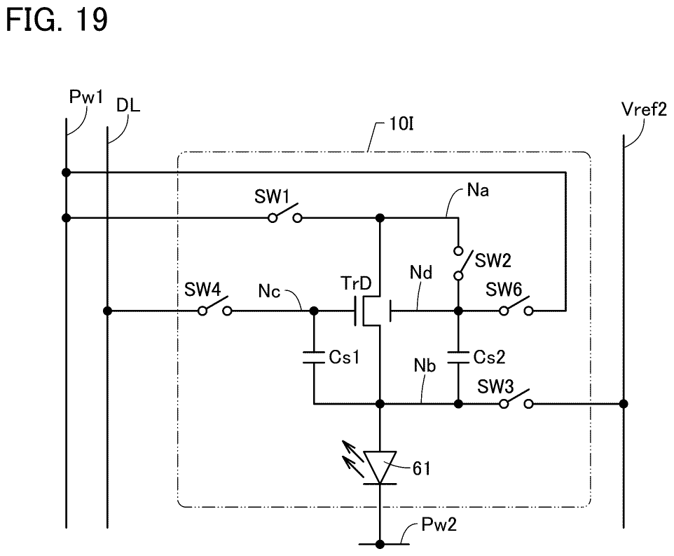

FIG. 19 is a circuit diagram of a semiconductor device 10I, which is a modification example of the semiconductor device 10A illustrated in FIG. 1A. The semiconductor device 10I is different from the semiconductor device 10A illustrated in FIG. 1A in that the second terminal of the switch SW6 is connected to the wiring Pw1 and the switch SW5 is omitted. Note that the semiconductor device 10I can be regarded as having a structure obtained by combining the semiconductor devices 10B and 10D. The semiconductor device 10I can be regarded as having a structure obtained by removing the switch SW5 from the semiconductor device 10G.

In the circuit configuration of the semiconductor device 10I, the wirings Vref1 and Vref3 can be omitted. The semiconductor device 10I not including the wirings Vref1 and Vref3 can have a high degree of integration. For example, a display apparatus using the semiconductor device 10I in a display portion can have high resolution and/or high definition.

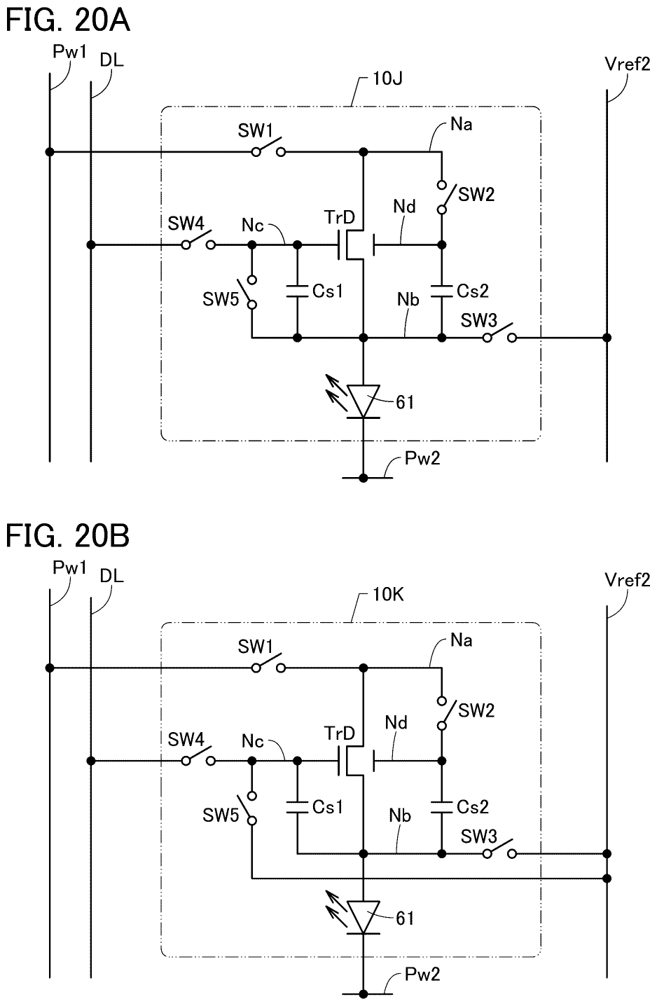

FIG. 20A is a circuit diagram of a semiconductor device 10J, which is a modification example of the semiconductor device 10A illustrated in FIG. 1A. The semiconductor device 10J is also a modification example of the semiconductor device 10G. The semiconductor device 10J is different from the semiconductor device 10G in not including the switch SW6. The semiconductor device 10J not including the switch SW6 can have a smaller footprint than the semiconductor device 10G. Thus, the semiconductor device 10J can have a higher degree of integration than the semiconductor device 10G. For example, a display apparatus using the semiconductor device 10J in a display portion can have high resolution and/or high definition.

FIG. 20B is a circuit diagram of a semiconductor device 10K, which is a modification example of the semiconductor device 10A illustrated in FIG. 1A. The semiconductor device 10K is also a modification example of the semiconductor device 10H. The semiconductor device 10K is different from the semiconductor device 10H in not including the switch SW6. The semiconductor device 10K not including the switch SW6 can have a smaller footprint than the semiconductor device 10H. Thus, the semiconductor device 10K can have a higher degree of integration than the semiconductor device 10H. For example, a display apparatus using the semiconductor device 10K in a display portion can have high resolution and/or high definition.

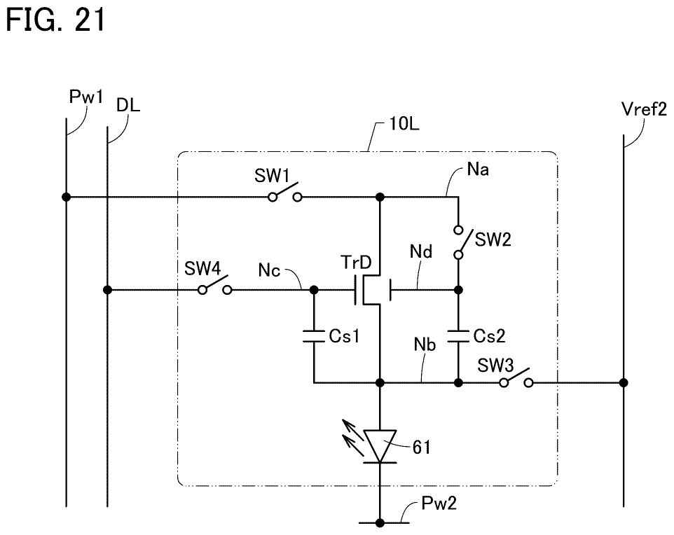

FIG. 21 is a circuit diagram of a semiconductor device 10L, which is a modification example of the semiconductor device 10A illustrated in FIG. 1A. The semiconductor device 10L is also a modification example of the semiconductor device 10J. The semiconductor device 10L is different from the semiconductor device 10J in not including the switch SW5. The semiconductor device 10L not including the switch SW5 can have a smaller footprint than the semiconductor device 10J. Thus, the semiconductor device 10L can have a higher degree of integration than the semiconductor device 10J. For example, a display apparatus using the semiconductor device 10L in a display portion can have high resolution and/or high definition.

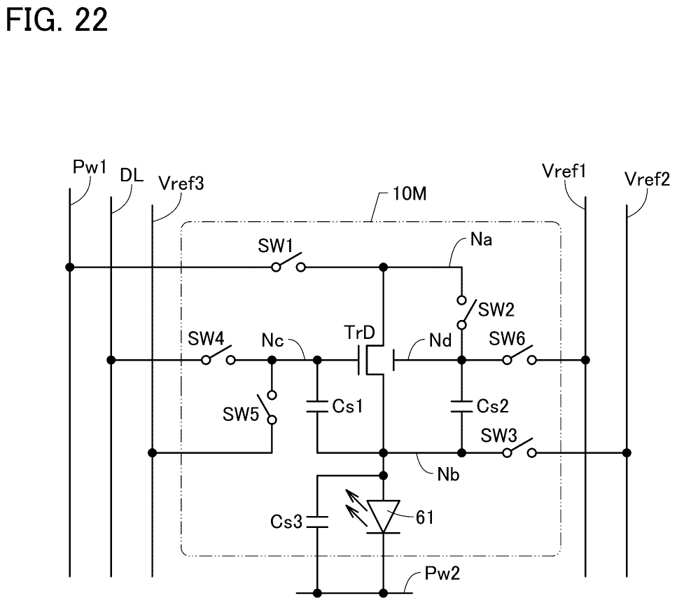

FIG. 22 is a circuit diagram of a semiconductor device 10M, which is a modification example of the semiconductor device 10A illustrated in FIG. 1A. The semiconductor device 10M is different from the semiconductor device 10A in that a capacitor Cs3 is connected in parallel to the light-emitting element 61. Specifically, a first terminal and a second terminal of the capacitor Cs3 are connected to the first terminal and the second terminal of the light-emitting element 61, respectively.

In the case where the semiconductor device 10A is used as a pixel, the capacitance of the light-emitting element 61 may depend on the emission color of the light-emitting element 61. When the capacitor Cs3 is connected in parallel to the light-emitting element 61 as in the semiconductor device 10M, the variation in luminance between pixels is reduced, leading to higher display quality of a display apparatus using the semiconductor device 10M in a display portion.

As the switches SW1 to SW6, transistors can be used, for example. The semiconductor device 10A illustrated in FIG. 1A can include a transistor Tr1 to a transistor Tr6, the transistor TrD, the capacitor Cs1, the capacitor Cs2, and the light-emitting element 61. For example, one of a source and a drain of the transistor Tr1 functions as the first terminal of the switch SW1, and the other of the source and the drain of the transistor Tr1 functions as the second terminal of the switch SW1.

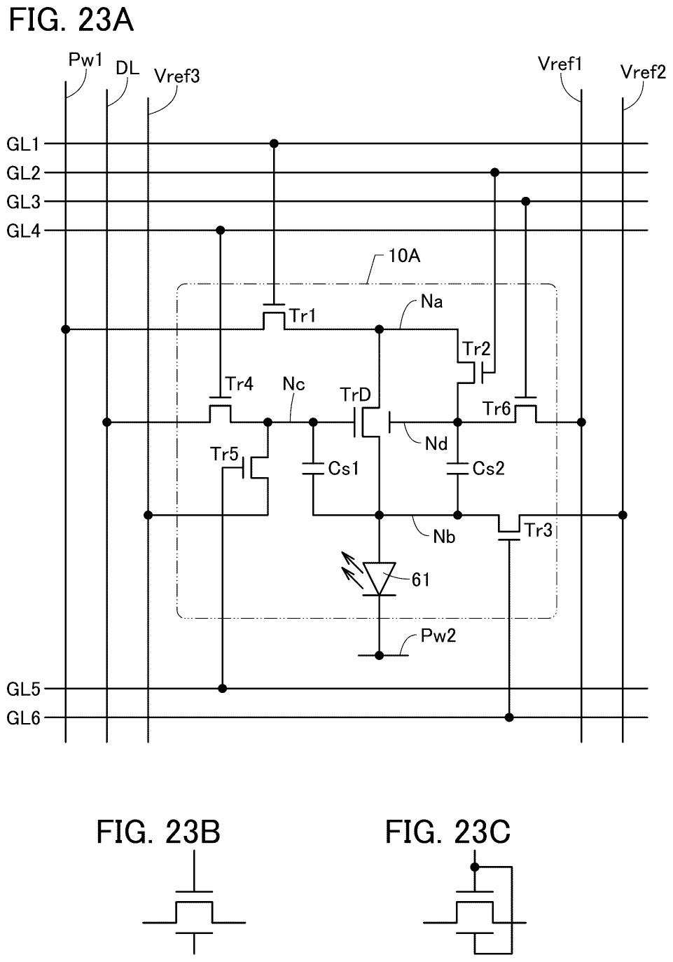

FIG. 23A shows a circuit configuration example where the transistors Tr1 to Tr6 are used as the switches SW1 to SW6 of the semiconductor device 10A illustrated in FIG. 1A.

Although the semiconductor device 10A is described as an example with reference to FIG. 23A and the like, the description of the semiconductor device 10A can be applied to all the semiconductor devices 10 (the semiconductor devices 10A to 10M).

In FIG. 23A, a gate of the transistor Tr1 is connected to a wiring GL1, and one of a source and a drain of the transistor Tr1 is connected to the wiring Pw1. The other of the source and the drain of the transistor Tr1 is connected to one of the source and the drain of the transistor TrD and one of a source and a drain of the transistor Tr2. A gate of the transistor Tr2 is connected to a wiring GL2. The other of the source and the drain of the transistor Tr2 is connected to the back gate of the transistor TrD, one of a source and a drain of the transistor Tr6, and the first terminal of the capacitor Cs2. The other of the source and the drain of the transistor Tr6 is connected to the wiring Vref1, and a gate of the transistor Tr6 is connected to a wiring GL3.

The second terminal of the capacitor Cs2 is connected to one of a source and a drain of the transistor Tr3, the other of the source and the drain of the transistor TrD, the first terminal of the light-emitting element 61, and the second terminal of the capacitor Cs1. The other of the source and the drain of the transistor Tr3 is connected to the wiring Vref2, and a gate of the transistor Tr3 is connected to a wiring GL6. The second terminal of the light-emitting element 61 is connected to the wiring Pw2. A gate of the transistor Tr4 is connected to a wiring GL4, and one of a source and a drain of the transistor Tr4 is connected to the wiring DL. The other of the source and the drain of the transistor Tr4 is connected to one of a source and a drain of the transistor Tr5, the first terminal of the capacitor Cs1, and the gate of the transistor TrD.

The transistor TrD includes the back gate. The transistors Tr1 to Tr6 can also include back gates. Since the transistor TrD includes the back gate, the transistors Tr1 to Tr6 can be provided with back gates without increasing the number of processes. FIG. 23B shows a circuit symbol example of a transistor including a back gate. A gate that is connected to the back gate as illustrated in FIG. 23C can always have the same potential as the back gate.

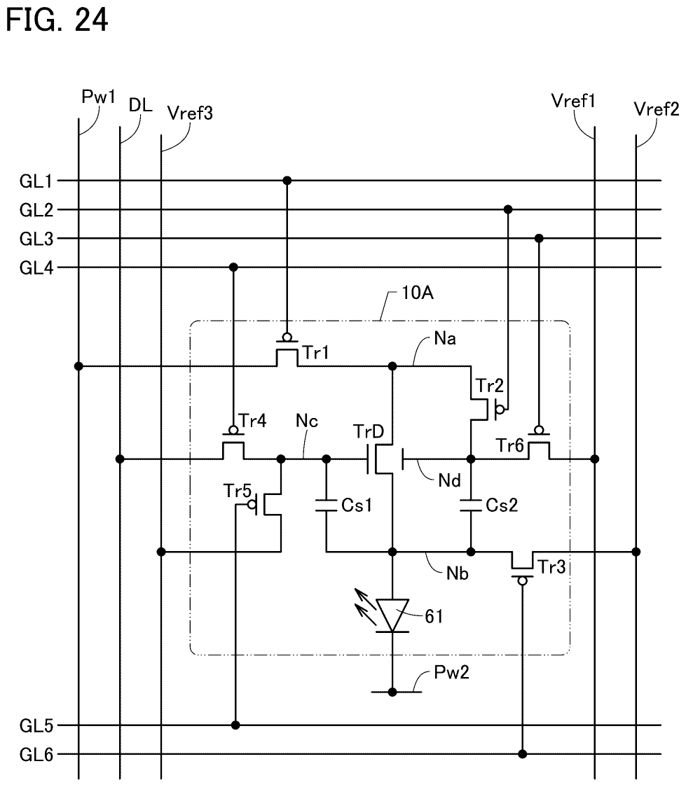

Although the transistors Tr1 to Tr6 are n-type transistors in the example shown in FIG. 23A, the transistors Tr1 to Tr6 can be p-type transistors as shown in FIG. 24. Furthermore, some of the transistors Tr1 to Tr6 can be n-type transistors, and the rest can be p-type transistors.

An n-type transistor has higher field-effect mobility than a p-type transistor, and thus can increase the operation speed of the semiconductor device 10A. Meanwhile, compared with an n-type transistor, a p-type transistor easily has normally-off characteristics and enables relatively easy circuit design.

The semiconductor device 10A of one embodiment of the present invention can use transistors with various structures. For example, any of transistors with various structures such as a planar type, a FIN-type, a top-gate type, and a bottom-gate type can be used. In addition, a MOS transistor, a junction transistor, a bipolar transistor, or the like can be used as the transistor of one embodiment of the present invention.

In the case where an n-type transistor is used as the transistor included in the semiconductor device 10A, the n-type transistor is preferably an OS transistor (a transistor including an oxide semiconductor in a semiconductor layer where a channel is formed). An oxide semiconductor has a band gap of 2 eV or more, achieving an extremely low off-state current. Specifically, the off-state current per micrometer of channel width of an OS transistor can be lower than or equal to 1 pA (1×10⁻¹² A), lower than or equal to 1 aA (1×10⁻¹⁸ A), lower than or equal to 1 zA (1×10⁻²¹ A), or lower than or equal to 1 yA (1×10⁻²⁴ A) in a room-temperature environment.

When an OS transistor is used as the transistor included in the semiconductor device 10A, charge written to each node can be retained for a long period. For example, in the case where a display apparatus including the semiconductor device 10A displays a still image for which rewriting every frame is not required, the image can be continuously displayed even when the operation of a peripheral driver circuit is stopped. Such a driving method in which the operation of a peripheral driver circuit is stopped during displaying a still image is also referred to as idling stop driving. The power consumption of the display apparatus can be reduced by performing idling stop driving.

In particular, when the transistors Tr2 and Tr6 are OS transistors, charge written to the node Nd can be retained for a long period. When the transistors Tr4 and Tr5 are OS transistors, charge written to the node Nc can be retained for a long period.

The off-state current of the OS transistor hardly increases even in a high temperature environment, specifically, at temperatures higher than or equal to room temperature and lower than or equal to 200° C. In addition, the on-state current of the OS transistor is less likely to decrease even in a high-temperature environment. A semiconductor device including an OS transistor operates stably and has high reliability even in a high-temperature environment.

Moreover, the transistor TrD can be an OS transistor. Alternatively, the transistor TrD can be a Si transistor (a transistor containing silicon in a semiconductor layer where a channel is formed). Since a Si transistor has higher mobility than an OS transistor, a larger amount of drain current can flow through the Si transistor than through the OS transistor. The transistors Tr1 to Tr6 can also be Si transistors. The semiconductor device 10A including a Si transistor can operate at high speed.

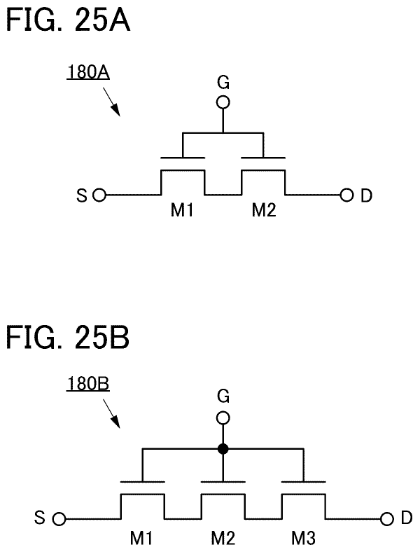

The semiconductor device 10A can include a single-gate transistor including one gate between a source and a drain. Besides, a double-gate transistor can be used. FIG. 25A shows a circuit symbol example of a double-gate transistor 180A.

The transistor 180A has a structure in which a transistor M1 and a transistor M2 are connected in series. In FIG. 25A, one of a source and a drain of the transistor M1 is connected to a terminal S, the other of the source and the drain of the transistor M1 is connected to one of a source and a drain of the transistor M2, and the other of the source and the drain of the transistor M2 is connected to a terminal D. Moreover, in FIG. 25A, gates of the transistors M1 and M2 are connected to each other and connected to a terminal G.

The transistor 180A illustrated in FIG. 25A has a function of switching electrical continuity and discontinuity between the terminal S and the terminal D by changing the potential of the terminal G. Thus, the transistor 180A that is a double-gate transistor serves as one transistor including the transistor M1 and the transistor M2 that are connected in series. That is, it can be said that in FIG. 25A, one of a source and a drain of the transistor 180A is connected to the terminal S, the other of the source and the drain of the transistor 180A is connected to the terminal D, and a gate of the transistor 180A is connected to the terminal G. Since a double-gate transistor includes the transistor M1 and the transistor M2 that are connected in series, the withstand voltage between the terminal S and the terminal D is high. Thus, the double-gate transistor is highly reliable.

The transistor included in the semiconductor device 10A may be a triple-gate transistor. FIG. 25B shows a circuit symbol example of a triple-gate transistor 180B.

The transistor 180B has a structure in which the transistor M1, the transistor M2, and a transistor M3 are connected in series. In FIG. 25B, one of the source and the drain of the transistor M1 is connected to the terminal S, the other of the source and the drain of the transistor M1 is connected to one of the source and the drain of the transistor M2, the other of the source and the drain of the transistor M2 is connected to one of a source and a drain of the transistor M3, and the other of the source and the drain of the transistor M3 is connected to the terminal D. Moreover, in FIG. 25B, the gate of the transistor M1, the gate of the transistor M2, and a gate of the transistor M3 are connected to each other and connected to the terminal G.

The transistor 180B illustrated in FIG. 25B has a function of switching electrical continuity and discontinuity between the terminal S and the terminal D by changing the potential of the terminal G. Thus, the transistor 180B that is a triple-gate transistor serves as one transistor including the transistor M1, the transistor M2, and the transistor M3 that are connected in series. That is, it can be said that in FIG. 25B, one of a source and a drain of the transistor 180B is connected to the terminal S, the other of the source and the drain of the transistor 180B is connected to the terminal D, and a gate of the transistor 180B is connected to the terminal G. A triple-gate transistor has a higher withstand voltage between the terminal S and the terminal D and thus has higher reliability than a double-gate transistor.

The transistor included in the semiconductor device 10A may have a structure in which four or more transistors are connected in series.

Note that the transistors M1 to M3 are n-type transistors in FIGS. 25A and 25B; even when the transistors M1 to M3 are p-type transistors, an effect similar to that described with reference to FIGS. 25A and 25B can be obtained.

Like the transistors 180A and 180B, a transistor including a plurality of gates connected to each other is referred to as a “multi-gate type transistor” or a “multi-gate transistor” in some cases.

A multi-gate transistor is equivalent to a transistor having a long channel length. Thus, a multi-gate transistor has more favorable electrical characteristics in a saturation region (also referred to as “saturation characteristics”) than a single-gate transistor. Thus, a multi-gate transistor can be used to improve the saturation characteristics of the transistor.

Specifically, when the transistor TrD is a multi-gate transistor, the transistor TrD can have improved saturation characteristics. The improved saturation characteristics of the transistor TrD enable the improved reproducibility of the luminance of the light emission from the light-emitting element 61 in response to a video signal written to the semiconductor device 10A. Consequently, a display apparatus including the semiconductor device 10A can have high display quality.

Each of the transistors Tr2 and Tr6 has a function of enabling retaining the charge in the node Nd, and thus preferably has a low off-state current. With regard to this, a multi-gate transistor can have a lower off-state current than a single-gate transistor. Thus, the transistors Tr2 and Tr6 are preferably multi-gate transistors. Each of the transistors Tr4 and Tr5 has a function of enabling retaining the charge in the node Nc, and thus preferably has a low off-state current. Thus, the transistors Tr4 and Tr5 are preferably multi-gate transistors. Note that the transistors Tr1 and Tr3 can also be multi-gate transistors.

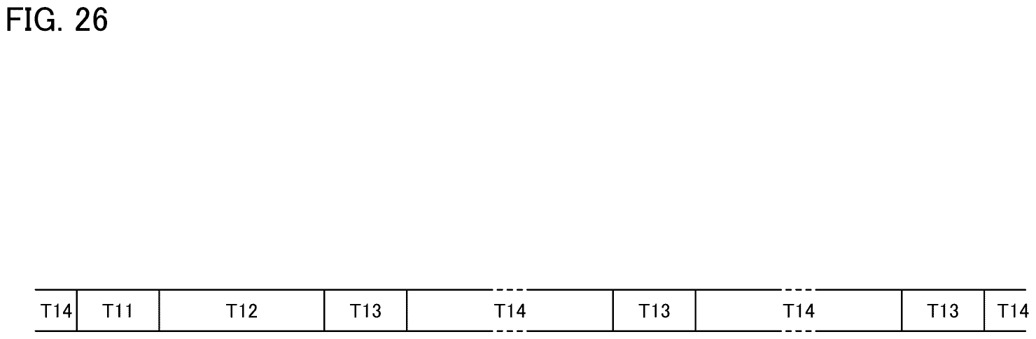

Here, in the periods T11 and T12, the threshold voltage of the transistor TrD is set to the potential V3−the potential V2. The threshold voltage of the transistor TrD needs to be set only once and does not need to be set repeatedly. Therefore, the operations in the periods T11 and T12 are performed only once after the power is turned on, and after that, the operations in the periods T11 and T12 can be omitted. Even when the operations in the periods T11 and T12 are repeated, the operations in the periods T11 and T12 can be repeated less frequently than the operations in the periods T13 and T14. FIG. 26 shows an example of a timing chart of the case where after the operations in the periods T11, T12, T13, and T14 are performed, the operations in the periods T11 and T12 are omitted and the operations in the periods T13 and T14 are repeated. Such a reduction in the frequency of performing the operations in the periods T11 and T12 can reduce the power consumed by the operations in the periods T11 and T12. Furthermore, the period T13 can be lengthened, which enables a larger number of pixels and a larger display portion, for example.

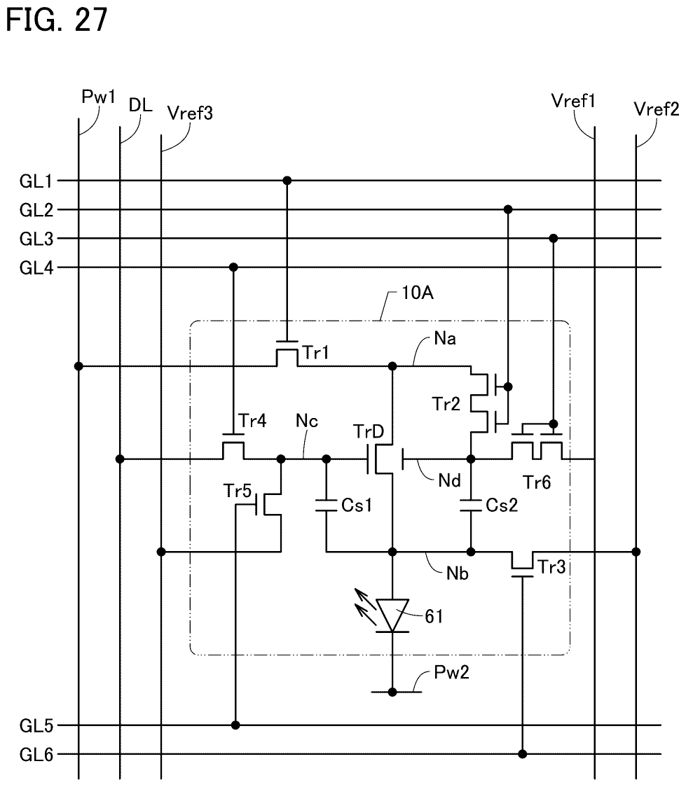

The node Nd may retain charge for a longer time than the node Nc. Thus, the off-state currents of the transistors Tr2 and Tr6 each having a function of enabling retaining the charge in the node Nd are preferably lower than the off-state currents of the transistors Tr4 and Tr5 each having a function of enabling retaining the charge in the node Nc. For example, W/L of the transistor Tr2 is preferably smaller than W/L of the transistor Tr4. For example, the W/L of the transistor Tr2 is preferably smaller than W/L of the transistor Tr5. For example, W/L of the transistor Tr6 is preferably smaller than the W/L of the transistor Tr4. In FIG. 27, each of the transistors Tr2 and Tr6 is a multi-gate transistor, and thus has a longer channel length than the transistors Tr4 and Tr5.

With a short channel length L, the transistors Tr1 to Tr6 functioning as switches can each have a high operation speed (switching speed between an on state and an off state, transfer speed of a signal, or the like). Thus, when the transistors Tr1 to Tr6 each have a shorter channel length L than the transistor TrD, the operation speed of the semiconductor device 10A and the reproducibility of the luminance of the light emission from the light-emitting element 61 in response to the video signal Vda can be improved.

As the light-emitting element 61, it is possible to use any of various display elements such as an EL element (an EL element containing an organic material and an inorganic material, an organic EL element, or an inorganic EL element), an LED (e.g., a white LED, a red LED, a green LED, and a blue LED), a micro LED, a quantum-dot light-emitting diode (QLED), and an electron emitter device.

The structures described in this embodiment can be used in combination with any of the structures described in the other embodiments as appropriate.

### Embodiment 3

In this embodiment, a transistor that can be used for a semiconductor device of one embodiment of the present invention will be described.

### <Structure Example 1 of Transistor>

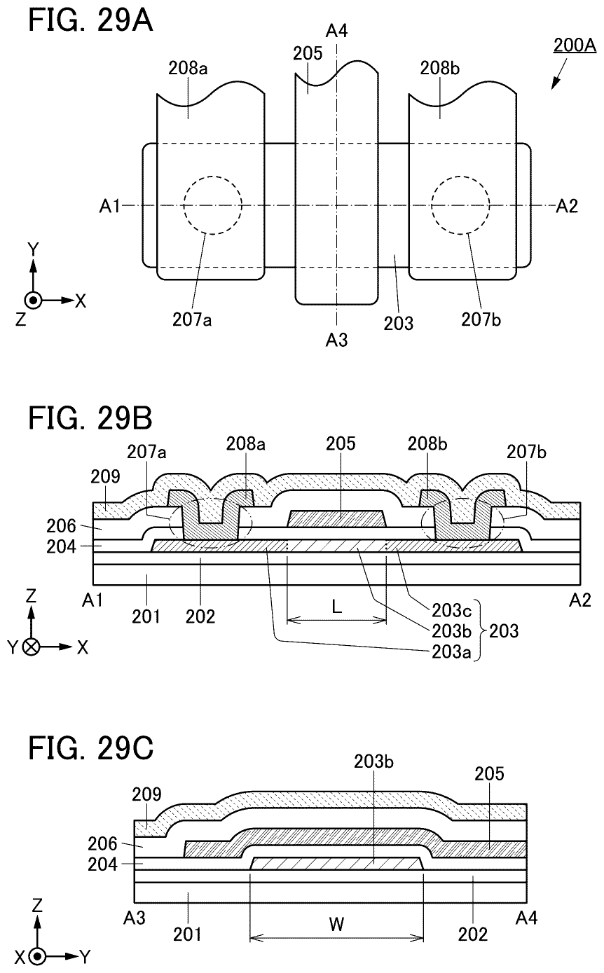

FIG. 29A is a plan view of a transistor 200A that can be used in a semiconductor device of one embodiment of the present invention. The transistor 200A is an example of a planar transistor. In this specification, a planar transistor has a structure in which a source electrode and a drain electrode are positioned at the same or substantially the same height and a current flowing through a semiconductor contains components in the lateral direction.

FIG. 29B is a cross-sectional view taken along dashed-dotted line A1-A2 in FIG. 29A. FIG. 29C is a cross-sectional view taken along dashed-dotted line A3-A4 in FIG. 29A. Note that for simplification, some components are not illustrated in the plan view of FIG. 29A. Some components may be omitted also in other plan views.

In the transistor 200A, an insulating layer 202 is provided over a substrate 201 and a semiconductor layer 203 is provided over the insulating layer 202. An insulating layer 204 is provided over the insulating layer 202 and the semiconductor layer 203. A conductive layer 205 is provided over the insulating layer 204. The semiconductor layer 203 and the conductive layer 205 partly overlap with each other with the insulating layer 204 therebetween.

The semiconductor layer 203 includes a region 203a, a channel formation region 203b, and a region 203c. The region 203a functions as one of a source region and a drain region. The region 203c functions as the other of the source region and the drain region. The region of the semiconductor layer 203 that overlaps with the conductive layer 205 functions as the channel formation region 203b. Thus, the conductive layer 205 functions as a gate electrode of the transistor 200A. The insulating layer 204 functions as a gate insulating layer of the transistor 200A.

The length of the channel formation region 203b in the X direction corresponds to the channel length L of the transistor 200A (see FIG. 29B). The length of the channel formation region 203b in the Y direction is the channel width W of the transistor 200A (see FIG. 29C).

Furthermore, an insulating layer 206 is provided over the insulating layer 204 and the conductive layer 205. The insulating layer 204 and the insulating layer 206 are provided with an opening 207a in a region overlapping with the region 203a of the semiconductor layer 203. The insulating layer 204 and the insulating layer 206 are provided with an opening 207b in a region overlapping with the region 203c of the semiconductor layer 203.

A conductive layer 208a is provided over the insulating layer 206 and the opening 207a, and a conductive layer 208b is provided over the insulating layer 206 and the opening 207b. The conductive layer 208a is connected to the region 203a of the semiconductor layer 203 at a bottom portion of the opening 207a. The conductive layer 208b is connected to the region 203c of the semiconductor layer 203 at a bottom portion of the opening 207b. Thus, the conductive layer 208a functions as one of a source electrode and a drain electrode of the transistor 200A, and the conductive layer 208b functions as the other of the source electrode and the drain electrode of the transistor 200A.

An insulating layer 209 is provided over the insulating layer 206 and the conductive layers 208 (the conductive layers 208a and 208b).

### <Structure Example 2 of Transistor>

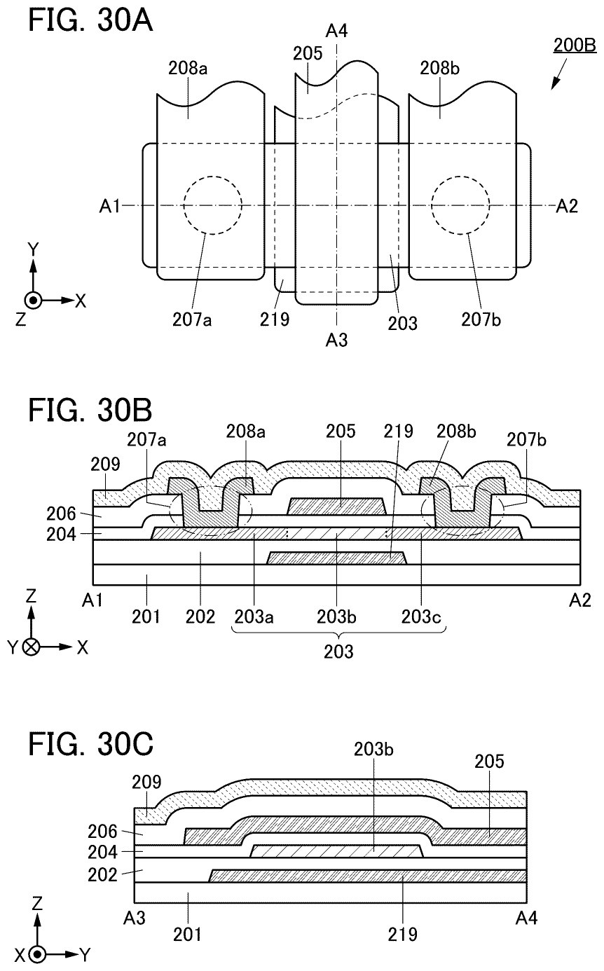

FIG. 30A is a plan view of a transistor 200B that can be used in a semiconductor device of one embodiment of the present invention. The transistor 200B is a modification example of the transistor 200A. In order to reduce repeated description, a description is mainly made on portions of the transistor 200B different from those of the transistor 200A.

FIG. 30B is a cross-sectional view taken along dashed-dotted line A1-A2 in FIG. 30A. FIG. 30C is a cross-sectional view taken along dashed-dotted line A3-A4 in FIG. 30A.

The transistor 200B is different from the transistor 200A in that a conductive layer 219 is provided between the substrate 201 and the insulating layer 202. The conductive layer 219 functions as a back gate electrode of the transistor 200B. Thus, the conductive layer 219 overlaps with the channel formation region 203b. The conductive layer 219 preferably extends beyond an end portion of the channel formation region 203b. That is, the conductive layer 219 preferably cover the channel formation region 203b. When the conductive layer 219 covers the channel formation region 203b, the electric field blocking effect described in the above embodiment can be enhanced.

### <Structure Example 3 of Transistor>

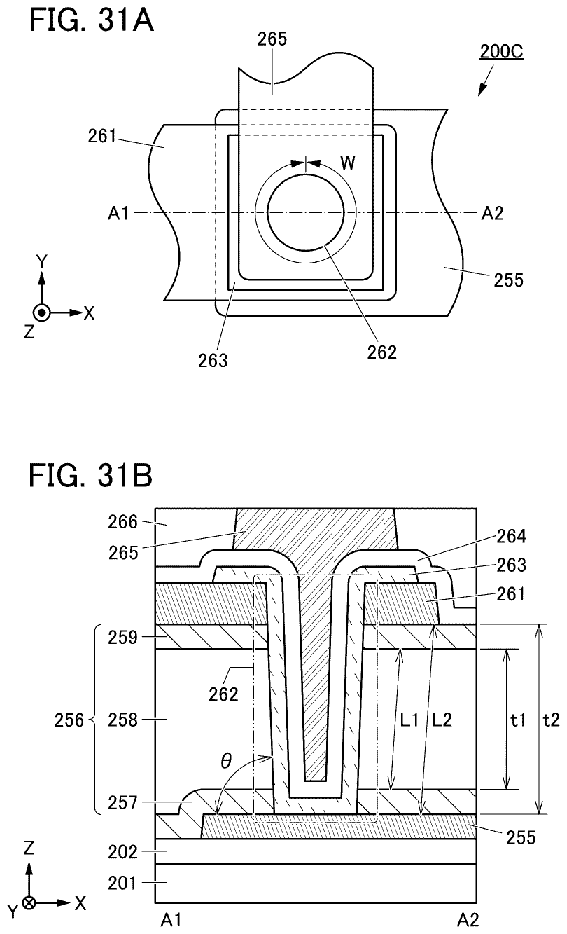

FIG. 31A is a plan view of a transistor 200C that can be used in a semiconductor device of one embodiment of the present invention. FIG. 31B is a cross-sectional view taken along dashed-dotted line A1-A2 in FIG. 31A.

In the transistor 200C, the insulating layer 202 is provided over the substrate 201 and a conductive layer 255 is provided over the insulating layer 202. An insulating layer 257 is provided over the conductive layer 255, an insulating layer 258 is provided over the insulating layer 257, and an insulating layer 259 is provided over the insulating layer 258. Note that in this specification, the insulating layers 257, 258, and 259 are collectively referred to as an insulating layer 256 or a spacer layer in some cases. A conductive layer 261 is provided over the insulating layer 259.

The conductive layer 261 and the insulating layers 259, 258, and 257 are penetrated by an opening 262 in a region overlapping with part of the conductive layer 255. A semiconductor layer 263 is provided to cover the inner wall of the opening 262.

The semiconductor layer 263 includes a region overlapping with a bottom portion of the opening 262 and a region overlapping with the side surface of the opening 262. That is, the semiconductor layer 263 includes a region in contact with the insulating layer 256 inside the opening 262. In addition, the semiconductor layer 263 includes a region in contact with the conductive layer 255 and a region in contact with the conductive layer 261 inside the opening 262.

An insulating layer 264 is provided over the insulating layer 259, the conductive layer 261, and the semiconductor layer 263. A conductive layer 265 is provided over the insulating layer 264. The conductive layer 265 includes a region overlapping with the semiconductor layer 263. The conductive layer 265 includes a region overlapping with the semiconductor layer 263 with the insulating layer 264 therebetween.

The insulating layer 264 and the conductive layer 265 each include a region overlapping with the opening 262. The insulating layer 264 and the conductive layer 265 each include a region overlapping with the inner side of the opening 262. Inside the opening 262, the semiconductor layer 263 includes a region overlapping with the conductive layer 265 with the insulating layer 264 therebetween and a region overlapping with the side surface of the opening 262 (the side surface of the insulating layer 256).

An insulating layer 266 is provided over the insulating layer 264. Note that the top surface of the insulating layer 266 is preferably flat. The top surfaces of the insulating layer 266 and the conductive layer 265 are preferably level or substantially level with each other (i.e., the positions of the top surfaces are preferably aligned or substantially aligned with each other in the Z direction (the direction perpendicular to the substrate surface)). Chemical mechanical polishing (CMP) treatment or the like can improve the planarity of the top surface of the insulating layer 266, for example. Moreover, the CMP treatment can make the positions of the top surfaces of the insulating layer 266 and the conductive layer 265 be aligned or substantially aligned with each other. The CMP treatment can reduce unevenness of a surface, so that coverage with an insulating layer and a conductive layer to be formed later can be increased.

In the case of using an oxide semiconductor for the semiconductor layer 263, a conductive material that makes the oxide semiconductor have n-type conductivity is preferably used for each of the conductive layers 255 and 261 that are in contact with the semiconductor layer 263. For example, a conductive material containing nitrogen may be used. For example, a conductive material containing nitrogen and titanium or tantalum may be used. Another conductive material can be provided so as to overlap with the conductive material containing nitrogen.

In the case of using an oxide semiconductor for the semiconductor layer 263, a material in which hydrogen is reduced and oxygen is contained is preferably used for the insulating layer 258. For example, a material containing silicon and oxygen may be used. Specifically, silicon oxide, silicon oxynitride, or the like may be used. Since hydrogen is an impurity element in an oxide semiconductor, when the semiconductor layer 263, which is an oxide semiconductor, and the insulating layer 258, in which the amount of hydrogen is reduced, are in contact with each other, the semiconductor layer 263 is less likely to have n-type conductivity. Furthermore, when the semiconductor layer 263, which is an oxide semiconductor, and the insulating layer 258 containing oxygen are in contact with each other, oxygen vacancies in the semiconductor layer 263 are reduced and the transistor has stable characteristics, improving the reliability.

In the case of using an oxide semiconductor for the semiconductor layer 263, the insulating layer 258 preferably contains excess oxygen. In this specification, excess oxygen refers to oxygen that is released by heating. A material that releases oxygen by heating is a material in which the amount of released oxygen converted into oxygen atoms is greater than or equal to 1.0×10¹⁸ atoms/cm³, preferably greater than or equal to 1.0×10¹⁹ atoms/cm³, further preferably greater than or equal to 2.0×10¹⁹ atoms/cm³ or greater than or equal to 3.0×10²⁰ atoms/cm³ in thermal desorption spectroscopy (TDS) analysis. Note that the temperature of the film surface in the TDS analysis is preferably in the range of 100° C. to 700° C. or 100° C. to 400° C.

In the case of using a material containing excess oxygen for the insulating layer 258, a material through which oxygen is less likely to pass is preferably used for each of the insulating layers 257 and 259. Examples of the material through which oxygen is less likely to pass include a nitride of silicon and an oxide containing aluminum and/or hafnium. With the use of the material through which oxygen is less likely to pass for each of the insulating layers 257 and 259, excess oxygen contained in the insulating layer 258 is less likely to be released to a lower layer or an upper layer. Thus, sufficient oxygen can be supplied to the oxide semiconductor. For example, an insulating layer containing silicon and oxygen (the insulating layer 258) is preferably provided between two insulating layers containing silicon and nitrogen (the insulating layer 257 and the insulating layer 259). For the insulating layer containing silicon and nitrogen, silicon nitride, silicon nitride oxide, or the like can be used. Alternatively, for the insulating layer containing silicon and oxygen, silicon oxide, silicon oxynitride, or the like can be used.

In the case of using an oxide semiconductor for the semiconductor layer 263 and using a material containing hydrogen for each of the insulating layers 257 and 259, hydrogen is supplied to a region of the semiconductor layer 263 that is in contact with the insulating layer 257 and a region of the semiconductor layer 263 that is in contact with the insulating layer 259, whereby the regions of the semiconductor layer 263 have n-type conductivity. Thus, the region of the semiconductor layer 263 that is in contact with the conductive layer 261 and the region of the semiconductor layer 263 that is in contact with the insulating layer 259 function as one of a source region and a drain region. The region of the semiconductor layer 263 that is in contact with the conductive layer 255 and the region of the semiconductor layer 263 that is in contact with the insulating layer 257 function as the other of the source region and the drain region.

The conductive layer 261 functions as one of a source electrode and a drain electrode of the transistor 200C. The conductive layer 255 functions as the other of the source electrode and the drain electrode of the transistor 200C. The source electrode and the drain electrode are provided in the Z direction in the transistor 200C. That is, a source and a drain of the transistor 200C are provided at different levels. In other words, the source and the drain of the transistor 200C are provided in different positions in the Z direction. Such a transistor is also referred to as a “vertical-channel transistor”, a “vertical transistor”, or a “vertical field-effect transistor (VFET)”.

In the transistor 200C, which is a VFET having the above structure, the length of the side surface of the insulating layer 158 seen from the X direction or the Y direction corresponds to the channel length L (channel length L1) (see FIG. 31B). Thus, the channel length L of the transistor 200C depends on the thickness t1 of the insulating layer 258.

A material that contains no hydrogen or an extremely small amount of hydrogen is preferably used for each of the insulating layers 257 and 259. For example, silicon nitride that contains an extremely small amount of hydrogen or silicon nitride oxide that contains an extremely small amount of hydrogen is preferably used. In this case, the regions of the semiconductor layer 263 that are in contact with the insulating layers 257 and 259 do not have n-type conductivity. Thus, the region of the semiconductor layer 263 that is in contact with the conductive layer 261 functions as one of the source region and the drain region. The region of the semiconductor layer 263 that is in contact with the conductive layer 255 functions as the other of the source region and the drain region. The region of the semiconductor layer 263 that is in contact with the insulating layer 258 functions as a channel formation region.

In this case, the total length of the side surfaces of the insulating layers 257, 258, and 259 seen from the X direction or the Y direction corresponds to the channel length L (channel length L2). Thus, the channel length L of the transistor 200C depends on the thickness t2, which is the total thickness of the insulating layers 257, 258, and 259. In this manner, the channel formation region of the transistor 200C includes a region along the side surface of the insulating layer 256.

Since the semiconductor layer 263 is provided in the opening 262, the length of the circumference of the opening 262 seen from the Z direction corresponds to the channel width W of the transistor 200C (see FIG. 31A). The length of the circumference is obtained in a position corresponding to the half of the thickness t1 of the insulating layer 258 or the half of the thickness t2, for example. Note that the length of the circumference of the opening 262 in an arbitrary position can be regarded as the channel width W as necessary. For example, the length of the circumference of the lowest portion or the uppermost portion of the opening 262 can be regarded as the channel width W. Although the outline (the planar shape) of the opening 262 seen from the Z direction is circular in FIG. 31A, the outline is not limited to this. For example, the outline of the opening 262 seen from the Z direction can be elliptical or rectangular.

In the semiconductor device of one embodiment of the present invention, the channel length L is preferably shorter than at least the channel width W. The channel length L in one embodiment of the present invention is greater than or equal to 0.1 times and less than or equal to 0.99 times, preferably greater than or equal to 0.5 times and less than or equal to 0.8 times the channel width W.

In order to improve the coverage with the semiconductor layer 263, the insulating layer 264, and the conductive layer 265 that are formed inside the opening 262, the taper angle θ of the side surface of the opening 262, that is, the taper angle θ of the side surface of each of the insulating layers 257, 258, and 259 is set to greater than or equal to 45° and less than 90°, preferably greater than or equal to 50° and less than or equal to 75°. The side surfaces of the insulating layers 257, 258, and 259 can have the same taper angle θ or different taper angles θ. Note that the taper angle θ of the side surface of a layer (an insulating layer, a conductive layer, or a semiconductor layer) refers to an angle formed between the bottom surface and the side surface of the layer (see FIG. 31B).

A vertical transistor can have a smaller footprint than a transistor whose channel formation region, source region, and drain region are provided separately on the XY plane (such a transistor is also referred to as a “horizontal transistor”). Thus, a semiconductor device including a vertical-channel transistor can have a small footprint. Furthermore, a semiconductor device including a vertical-channel transistor can have a high degree of integration.

In a horizontal transistor, the channel length is limited by the light exposure limit of photolithography. In the vertical-channel transistor of one embodiment of the present invention, the channel length can be set by the thickness of the insulating layer 256 or the insulating layer 258. Thus, the transistor can have an extremely small channel length less than or equal to the light exposure limit of photolithography (e.g., less than or equal to 60 nm, less than or equal to 50 nm, less than or equal to 40 nm, less than or equal to 30 nm, less than or equal to 20 nm, or less than or equal to 10 nm, and greater than or equal to 1 nm, or greater than or equal to 5 nm). Accordingly, the transistor 200C can have a higher on-state current and higher frequency characteristics. With the use of a vertical-channel transistor, a semiconductor device with a high operation speed can be provided.

### <Structure Example 4 of Transistor>

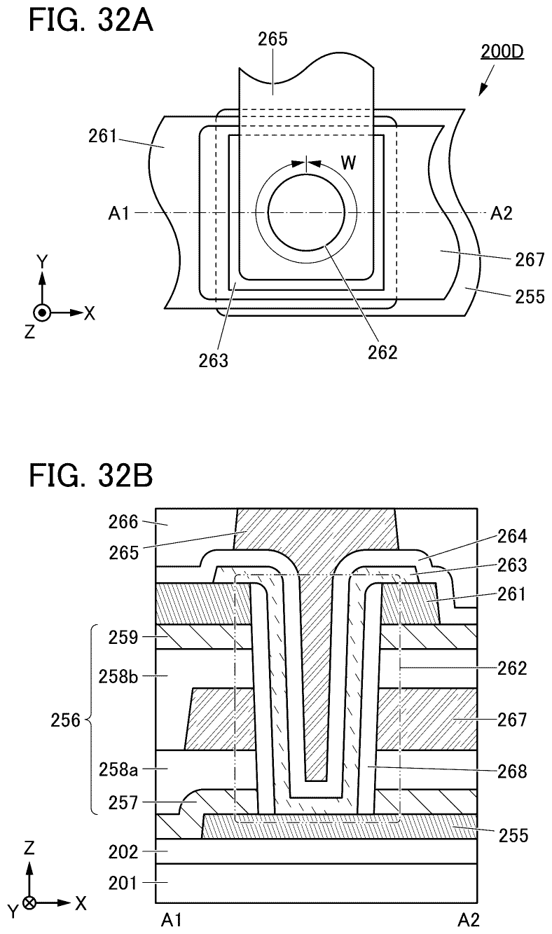

FIG. 32A is a plan view of a transistor 200D that can be used in a semiconductor device of one embodiment of the present invention. FIG. 32B is a cross-sectional view taken along dashed-dotted line A1-A2 in FIG. 32A. The transistor 200D is a modification example of the transistor 200C. In order to reduce repeated description, a description is mainly made on portions of the transistor 200D different from those of the transistor 200C.

The transistor 200D includes an insulating layer 258a and an insulating layer 258b between the insulating layer 257 and the insulating layer 259, and a conductive layer 267 between the insulating layer 258a and the insulating layer 258b. The insulating layer 258a and the insulating layer 258b can be formed using a material and a method similar to those of the insulating layer 258. In the transistor 200D, the conductive layers 261 and 267 and the insulating layers 259, 258b, 258a, and 257 are penetrated by the opening 262 in a region overlapping with part of the conductive layer 255.

In the transistor 200D, an insulating layer 268 is provided along the side surface of the opening 262. Inside the opening 262, the insulating layer 268 includes a region overlapping with the side surface of the conductive layer 261, a region overlapping with the side surface of the insulating layer 259, a region overlapping with the side surface of the insulating layer 258b, a region overlapping with the side surface of the conductive layer 267, a region overlapping with the side surface of the insulating layer 258a, and a region overlapping with the side surface of the insulating layer 257.

In the transistor 200D, the semiconductor layer 263 includes a region overlapping with the side surface of the conductive layer 261, a region overlapping with the side surface of the insulating layer 259, a region overlapping with the side surface of the insulating layer 258b, a region overlapping with the side surface of the conductive layer 267, a region overlapping with the side surface of the insulating layer 258a, and a region overlapping with the side surface of the insulating layer 257 inside the opening 262 with the insulating layer 268 therebetween.

In the case where the conductive layer 265 is used as a gate electrode, the conductive layer 267 functions as a back gate electrode. In the case where the conductive layer 267 is used as a gate electrode, the conductive layer 265 functions as a back gate electrode. One of the insulating layers 264 and 268 functions as a gate insulating layer, and the other functions as a back gate insulating layer. The insulating layer 268 can be formed using a material and a method similar to those of the insulating layer 264.

### <Structure Example 5 of Transistor>

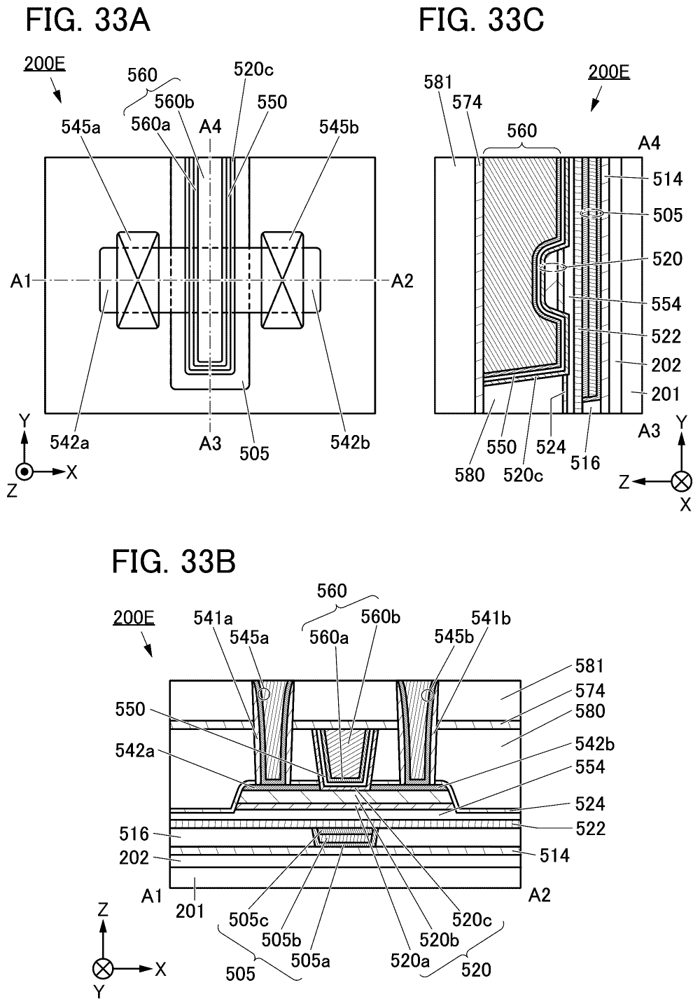

FIG. 33A is a plan view of a transistor 200E that can be used in a semiconductor device of one embodiment of the present invention. FIG. 33B is a cross-sectional view taken along dashed-dotted line A1-A2 in FIG. 33A. FIG. 33C is a cross-sectional view taken along dashed-dotted line A3-A4 in FIG. 33A. FIG. 33A is a cross-sectional view of the transistor 200E in the channel length direction, and FIG. 33C is a cross-sectional view of the transistor 200E in the channel width direction.

As illustrated in FIGS. 33A to 33C, the transistor 200E includes a semiconductor layer 520a placed over the substrate 201; a semiconductor layer 520b placed over the semiconductor layer 520a; a conductive layer 542a and a conductive layer 542b placed apart from each other over the semiconductor layer 520b; an insulating layer 580 that is placed over the conductive layer 542a and the conductive layer 542b and has an opening between the conductive layer 542a and the conductive layer 542b; a conductive layer 560 placed in the opening; an insulating layer 550 placed between the conductive layer 560 and each of the semiconductor layer 520b, the conductive layer 542a, the conductive layer 542b, and the insulating layer 580; and a semiconductor layer 520c placed between the insulating layer 550 and each of the semiconductor layer 520b, the conductive layer 542a, the conductive layer 542b, and the insulating layer 580. Here, as illustrated in FIGS. 33B and 33C, the top surface of the conductive layer 560 is substantially aligned with the top surfaces of the insulating layer 550, the semiconductor layer 520c, and the insulating layer 580. Note that hereinafter, the semiconductor layers 520a, 520b, and 520c are sometimes collectively referred to as a semiconductor layer 520. The conductive layers 542a and 542b are sometimes collectively referred to as a conductive layer 542.

As illustrated in FIGS. 33A to 33C, an insulating layer 524 is placed between the insulating layer 580 and each of an insulating layer 554, the semiconductor layer 520a, the semiconductor layer 520b, the conductive layer 542a, and the conductive layer 542b. The insulating layer 524 is in contact with the side surface of the semiconductor layer 520c, the top and side surfaces of the conductive layer 542a, the top and side surfaces of the conductive layer 542b, the side surfaces of the semiconductor layer 520a and the semiconductor layer 520b, and the top surface of the insulating layer 554.

The transistor 200E employs a structure in which the three layers of the semiconductor layers 520a, 520b, and 520c are stacked in a channel formation region and its vicinity; however, the present invention is not limited to this structure. For example, a two-layer structure of the semiconductor layers 520b and 520c or a stacked-layer structure of four or more layers can be employed. Moreover, each of the semiconductor layers 520a, 520b, and 520c can have a stacked-layer structure of two or more layers.

In the case where an oxide semiconductor, which is one kind of a metal oxide, is used for the semiconductor layer 520 and the semiconductor layer 520c has a stacked-layer structure of a first metal oxide and a second metal oxide over the first metal oxide, for example, the first metal oxide and the second metal oxide preferably have compositions similar to those of the semiconductor layer 520b and the semiconductor layer 520a, respectively.

Here, the conductive layer 560 functions as a gate electrode of the transistor, and the conductive layer 542a and the conductive layer 542b function as a source electrode and a drain electrode. As described above, the conductive layer 560 is formed to be embedded in the opening in the insulating layer 580 and the region between the conductive layer 542a and the conductive layer 542b. Here, the conductive layer 560, the conductive layer 542a, and the conductive layer 542b are positioned in a self-aligned manner with respect to the opening in the insulating layer 580. That is, in the transistor 200E, the gate electrode can be placed between the source electrode and the drain electrode in a self-aligned manner. Thus, the conductive layer 560 can be formed without an alignment margin, resulting in a reduction in the footprint of the transistor 200E. This can reduce the footprint of the semiconductor device. In addition, the degree of integration of the semiconductor device can be increased.

As illustrated in FIGS. 33A to 33C, the conductive layer 560 includes a conductive layer 560a provided inside the insulating layer 550 and a conductive layer 560b provided to be embedded inside the conductive layer 560a. Although the conductive layer 560 has a two-layer structure in the transistor 200E, the present invention is not limited thereto. For example, the conductive layer 560 may have a single-layer structure or a stacked-layer structure of three or more layers.

The transistor 200E includes the insulating layer 202 placed over the substrate 201; an insulating layer 514 placed over the insulating layer 202; an insulating layer 516 placed over the insulating layer 514; a conductive layer 505 placed to be embedded in the insulating layer 516; an insulating layer 522 placed over the insulating layer 516 and the conductive layer 505; and the insulating layer 524 placed over the insulating layer 522. The semiconductor layer 520a is placed over the insulating layer 524.

An insulating layer 574 and an insulating layer 581 functioning as interlayer films are provided over the transistor 200E. The insulating layer 574 is provided in contact with the top surfaces of the conductive layer 560, the insulating layer 550, the semiconductor layer 520c, and the insulating layer 580.

In the case of using an oxide semiconductor for the semiconductor layer 520, an insulating layer having a function of inhibiting diffusion of hydrogen (e.g., at least one of hydrogen atoms and hydrogen molecules) is preferably used as each of the insulating layers 522, 554, and 574. For example, as each of the insulating layers 522, 554, and 574, an insulating layer having a lower hydrogen permeability than the insulating layers 524, 550, and 580 is preferably used. Silicon nitride, silicon nitride oxide, or the like can be used, for example.

Alternatively, an insulating layer having a function of inhibiting diffusion of oxygen (e.g., at least one of oxygen atoms and oxygen molecules) is preferably used as each of the insulating layers 522 and 554. For example, as each of the insulating layers 522 and 554, an insulating layer having a lower oxygen permeability than the insulating layers 524, 550, and 580 is preferably used. Silicon nitride, silicon nitride oxide, or the like can be used, for example. Here, the insulating layer 524, the semiconductor layer 520, and the insulating layer 550 are separated from each other by the insulating layers 522 and 574. This can inhibit entry of excess oxygen and impurities such as hydrogen contained in layers above the insulating layer 574 and layers below the insulating layer 522 into the insulating layer 524, the semiconductor layer 520, and the insulating layer 550.

FIG. 33B shows an example where a conductive layer 545 (a conductive layer 545a and a conductive layer 545b) that is connected to the transistor 200E and functions as a plug is provided. Note that in this example, an insulating layer 541 (an insulating layer 541a and an insulating layer 541b) is provided in contact with the side surface of the conductive layer 545 functioning as a plug. In other words, the insulating layer 541 is provided in contact with the inner wall of an opening in the insulating layers 554, 580, 574, and 581. Moreover, in FIG. 33B, a first conductive layer of the conductive layer 545 is provided in contact with the side surface of the insulating layer 541, and a second conductive layer of the conductive layer 545 is provided on the inner side of the first conductive layer.

Here, the top surface of the conductive layer 545 and the top surface of the insulating layer 581 can be substantially level with each other. Although the transistor 200E has a structure in which the first conductive layer of the conductive layer 545 and the second conductive layer of the conductive layer 545 are stacked, the present invention is not limited thereto. For example, the conductive layer 545 can have a single-layer structure or a stacked-layer structure of three or more layers. In the case where a component has a stacked-layer structure, layers may be distinguished by ordinal numbers corresponding to the formation order.

The semiconductor layer 520b in a region that does not overlap with the conductive layer 542 sometimes has smaller thickness than the semiconductor layer 520b in a region that overlaps with the conductive layer 542. The thin region is formed when part of the top surface of the semiconductor layer 520b is removed at the time of forming the conductive layer 542a and the conductive layer 542b. When a conductive film to be the conductive layer 542 is formed, a low-resistance region is sometimes formed on the top surface of the semiconductor layer 520b in the vicinity of the interface with the conductive film. Removing the low-resistance region, which is positioned between the conductive layer 542a and the conductive layer 542b in a plan view, in this manner can prevent formation of the channel in the region.

Next, the structure of the transistor 200E that can be used in the semiconductor device of one embodiment of the present invention is described in detail.

The conductive layer 505 is placed to partly overlap with the conductive layer 560 with the semiconductor layer 520 therebetween. When the conductive layer 505 is provided to be embedded in the insulating layer 516, generation of unevenness on the conductive layer 505 and the insulating layer 516 is reduced, and thus the coverage with a layer to be formed in a later step can be increased.

The conductive layer 505 includes a conductive layer 505a, a conductive layer 505b, and a conductive layer 505c. The conductive layer 505a is provided in contact with the bottom surface and a sidewall of an opening provided in the insulating layer 516. The conductive layer 505b is provided to be embedded in a depressed portion formed by the conductive layer 505a. Here, the level of the top surface of the conductive layer 505b is lower than the levels of the top surfaces of the conductive layer 505a and the insulating layer 516. The conductive layer 505c is provided in contact with the top surface of the conductive layer 505b and the side surface of the conductive layer 505a. Here, the top surface of the conductive layer 505c is level or substantially level with the top surfaces of the conductive layer 505a and the insulating layer 516. That is, the conductive layer 505b is surrounded by the conductive layers 505a and 505c.

In the case of using an oxide semiconductor for the semiconductor layer 520, a conductive material having a function of inhibiting diffusion of impurities such as a hydrogen atom, a hydrogen molecule, a water molecule, a nitrogen atom, a nitrogen molecule, a nitrogen oxide molecule (e.g., N₂O, NO, and NO₂), and a copper atom is used for each of the conductive layers 505a and 505c. Alternatively, a conductive material having a function of inhibiting diffusion of oxygen (e.g., at least one of oxygen atoms and oxygen molecules) is used.

When a conductive material having a function of inhibiting diffusion of hydrogen is used for each of the conductive layers 505a and 505c, impurities such as hydrogen contained in the conductive layer 505b can be inhibited from being diffused into the semiconductor layer 520 through the insulating layer 524 and the like. When a conductive material having a function of inhibiting diffusion of oxygen is used for each of the conductive layers 505a and 505c, the conductivity of the conductive layer 505b can be inhibited from being lowered because of oxidation. As the conductive material having a function of inhibiting diffusion of oxygen, for example, titanium, titanium nitride, tantalum, tantalum nitride, ruthenium, or ruthenium oxide can be used. Thus, the conductive layer 505a can be a single layer or a stacked layer of the above conductive materials. Titanium nitride can be used for the conductive layer 505a, for example.

A conductive material containing tungsten, copper, or aluminum as its main component is preferably used for the conductive layer 505b. For example, tungsten is preferably used for the conductive layer 505b. In the case where the conductive layer 560 is used as a gate electrode, the conductive layer 505 functions as a back gate electrode.

The conductive layer 505 is preferably provided to be larger than the channel formation region in the semiconductor layer 520. In particular, it is preferable that the conductive layer 505 extend beyond an end portion of the semiconductor layer 520 that intersects with the channel width direction, as illustrated in FIG. 33C. That is, the conductive layer 505 and the conductive layer 560 preferably overlap with each other with the insulating layer therebetween, in a region beyond the side surface of the semiconductor layer 520 in the channel width direction.

With the above structure, the channel formation region in the semiconductor layer 520 can be surrounded by an electric field of the conductive layer 560 functioning as the gate electrode and an electric field of the conductive layer 505 functioning as the back gate electrode.

The conductive layer 505 can extend beyond the end portion of the semiconductor layer 520 and be used as a wiring. However, without limitation to this structure, a structure in which a conductive layer functioning as a wiring is provided below the conductive layer 505 can be employed.

For the insulating layer 514, an insulating material functioning as a barrier insulating film that inhibits entry of impurities such as water or hydrogen to the transistor 200E from the substrate side is preferably used. Accordingly, for the insulating layer 514, an insulating material having a function of inhibiting diffusion of impurities such as a hydrogen atom, a hydrogen molecule, a water molecule, a nitrogen atom, a nitrogen molecule, a nitrogen oxide molecule (e.g., N₂O, NO, and NO₂), and a copper atom (an insulating material through which the above impurities are less likely to pass) is preferably used. Alternatively, an insulating material having a function of inhibiting diffusion of oxygen (e.g., at least one of oxygen atoms and oxygen molecules) (an insulating material through which oxygen is less likely to pass) is preferably used.

For example, aluminum oxide or silicon nitride is used for the insulating layer 514. Accordingly, it is possible to inhibit diffusion of impurities such as water or hydrogen to the transistor 200E side from the substrate side through the insulating layer 514. Alternatively, it is possible to inhibit diffusion of oxygen contained in the insulating layer 524 and the like to the substrate side through the insulating layer 514.

For each of the insulating layers 516, 580, and 581 functioning as interlayer films, an insulating material having a lower permittivity than the insulating layer 514 is preferably used. When a material with a low permittivity is used for an interlayer film, parasitic capacitance generated between wirings can be reduced. For example, for each of the insulating layers 516, 580, and 581, silicon oxide, silicon oxynitride, silicon nitride oxide, silicon nitride, silicon oxide to which fluorine is added, silicon oxide to which carbon is added, silicon oxide to which carbon and nitrogen are added, porous silicon oxide, or the like is used as appropriate.

In the case where the conductive layer 560 is used as a gate electrode, the insulating layers 522 and 524 function as gate insulating layers.

Here, the insulating layer 524 in contact with the semiconductor layer 520 preferably contains excess oxygen. For example, silicon oxide or silicon oxynitride is used as appropriate for the insulating layer 524. When an insulating layer containing oxygen is provided in contact with the semiconductor layer 520, oxygen vacancies in the semiconductor layer 520 are reduced, whereby the reliability of the transistor 200E is improved.

As illustrated in FIG. 33C, the insulating layer 524 is sometimes thinner in a region overlapping with neither the insulating layer 554 nor the semiconductor layer 520b than in the other regions. In the insulating layer 524, the region overlapping with neither the insulating layer 554 nor the semiconductor layer 520b preferably has a thickness with which the above oxygen can be adequately diffused.

Like the insulating layer 514 or the like, the insulating layer 522 is formed using an insulating material functioning as a barrier insulating film that inhibits entry of impurities such as water or hydrogen to the transistor 200E from the substrate side. For example, a material having a lower hydrogen permeability than the insulating layer 524 is used for the insulating layer 522. When the insulating layer 524, the semiconductor layer 520, the insulating layer 550, and the like are surrounded by the insulating layers 522, 554, and 574, entry of impurities such as water or hydrogen into the transistor 200E from the outside can be inhibited.

Moreover, a material having a function of inhibiting diffusion of oxygen (e.g., at least one of oxygen atoms and oxygen molecules) (a material through which oxygen is less likely to pass) is preferably used for the insulating layer 522. For example, a material having a lower oxygen permeability than the insulating layer 524 is used for the insulating layer 522. When the insulating layer 522 has a function of inhibiting diffusion of oxygen and impurities, diffusion of oxygen from the semiconductor layer 520 to the substrate side can be inhibited. Moreover, the conductive layer 505 can be inhibited from reacting with oxygen contained in the insulating layer 524 or the semiconductor layer 520.

As the insulating layer 522, an insulating layer containing an oxide of one or both of aluminum and hafnium, which is an insulating material, is preferably used. As the insulating layer containing an oxide of one or both of aluminum and hafnium, aluminum oxide, hafnium oxide, an oxide containing aluminum and hafnium (hafnium aluminate), or the like is preferably used. The insulating layer 522 formed using such a material functions as a layer that inhibits release of oxygen from the semiconductor layer 520 and entry of impurities such as hydrogen from the periphery of the transistor 200E into the semiconductor layer 520.

Alternatively, aluminum oxide, bismuth oxide, germanium oxide, niobium oxide, silicon oxide, titanium oxide, tungsten oxide, yttrium oxide, or zirconium oxide can be added to the insulating layer 522, for example. Alternatively, the insulating layer 522 can be subjected to nitriding treatment. Silicon oxide, silicon oxynitride, or silicon nitride can be stacked over the insulating layer 522. For example, the insulating layer 522 can have a three-layer structure in which silicon nitride, silicon oxide, and aluminum oxide are stacked in this order.

The insulating layer 522 can have a single-layer structure or a stacked-layer structure using an insulating layer containing what is called a high-k material, such as aluminum oxide, hafnium oxide, tantalum oxide, zirconium oxide, lead zirconate titanate (PZT), strontium titanate (SrTiO₃), or (Ba,Sr)TiO₃ (BST), for example. With further miniaturization and higher integration of a transistor, a problem such as generation of a leakage current may arise because of a thinned gate insulating layer. When a high-k material is used for an insulating layer functioning as a gate insulating layer, a gate potential during operation of the transistor can be reduced while the physical thickness is maintained.

Note that the insulating layers 522 and 524 can each have a stacked-layer structure of two or more layers. In that case, without limitation to a stacked-layer structure formed of the same material, a stacked-layer structure formed of different materials can be employed.

The semiconductor layer 520 includes the semiconductor layer 520a, the semiconductor layer 520b over the semiconductor layer 520a, and the semiconductor layer 520c over the semiconductor layer 520b. When the semiconductor layer 520a is provided below the semiconductor layer 520b, impurities can be inhibited from being diffused into the semiconductor layer 520b from the structures formed below the semiconductor layer 520a. When the semiconductor layer 520c is provided over the semiconductor layer 520b, impurities can be inhibited from being diffused into the semiconductor layer 520b from the structures formed above the semiconductor layer 520c.

In the case of using an oxide semiconductor for the semiconductor layer 520, the semiconductor layer 520 preferably has a stacked-layer structure of oxide layers which differ in the atomic ratio of metal atoms. For example, in the case where the semiconductor layer 520 contains at least indium (In) and an element M, the proportion of the number of atoms of the element M contained in the semiconductor layer 520a to the number of atoms of all elements that constitute the semiconductor layer 520a is higher than the proportion of the number of atoms of the element M contained in the semiconductor layer 520b to the number of atoms of all elements that constitute the semiconductor layer 520b. In addition, the atomic ratio of the element M to In in the semiconductor layer 520a is higher than the atomic ratio of the element M to In in the semiconductor layer 520b. Here, for the semiconductor layer 520c, a metal oxide that can be used for the semiconductor layer 520a or the semiconductor layer 520b can be used.

The energy of the conduction band minimum of each of the semiconductor layers 520a and 520c is preferably higher than that of the semiconductor layer 520b. That is, the electron affinity of each of the semiconductor layers 520a and 520c is preferably less than that of the semiconductor layer 520b. In this case, a metal oxide that can be used for the semiconductor layer 520a is used for the semiconductor layer 520c. Specifically, the proportion of the number of atoms of the element M contained in the semiconductor layer 520c to the number of atoms of all elements that constitute the semiconductor layer 520c is preferably higher than the proportion of the number of atoms of the element M contained in the semiconductor layer 520b to the number of atoms of all elements that constitute the semiconductor layer 520b. In addition, the atomic ratio of the element M to In in the semiconductor layer 520c is preferably higher than the atomic ratio of the element M to In in the semiconductor layer 520b.

Here, the energy level of the conduction band minimum gradually changes at a junction portion of the semiconductor layers 520a, 520b, and 520c. In other words, the energy level of the conduction band minimum at a junction portion of the semiconductor layers 520a, 520b, and 520c is continuously varied or continuously connected. To obtain this, the density of defect states in a mixed layer formed at the interface between the semiconductor layer 520a and the semiconductor layer 520b and a mixed layer formed at the interface between the semiconductor layer 520b and the semiconductor layer 520c is preferably made low.

Specifically, when the semiconductor layers 520a and 520b or the semiconductor layers 520b and 520c contain the same element (as a main component) in addition to oxygen, a mixed layer with a low density of defect states can be formed. For example, in the case where the semiconductor layer 520b is an In—Ga—Zn oxide, it is possible to use an In—Ga—Zn oxide, a Ga—Zn oxide, gallium oxide, or the like for each of the semiconductor layers 520a and 520c. Furthermore, the semiconductor layer 520c can have a stacked-layer structure. For example, the semiconductor layer 520c can have a stacked-layer structure of an In—Ga—Zn oxide and a Ga—Zn oxide over the In—Ga—Zn oxide, or a stacked-layer structure of an In—Ga—Zn oxide and gallium oxide over the In—Ga—Zn oxide. In other words, the semiconductor layer 520c can have a stacked-layer structure of an In—Ga—Zn oxide and an oxide that does not contain In.

Specifically, for the semiconductor layer 520a, a metal oxide having an atomic ratio of In:Ga:Zn=1:3:4 or a neighborhood thereof or In:Ga:Zn=1:1:0.5 or a neighborhood thereof is used. As the semiconductor layer 520b, a metal oxide having an atomic ratio of In:Ga:Zn=4:2:3 or a neighborhood thereof, In:Ga:Zn=3:1:2 or a neighborhood thereof, or In:Ga:Zn=1:1:1 or a neighborhood thereof is used. As the semiconductor layer 520c, a metal oxide having an atomic ratio of In:Ga:Zn=1:3:4 or a neighborhood thereof, In:Ga:Zn=4:2:3 or a neighborhood thereof, Ga:Zn=2:1 or a neighborhood thereof, or Ga:Zn=2:5 or a neighborhood thereof is used. Specific examples of a stacked-layer structure of the semiconductor layer 520c include a stacked-layer structure of a layer having an atomic ratio of In:Ga:Zn=4:2:3 or a neighborhood thereof and a layer having an atomic ratio of Ga:Zn=2:1 or a neighborhood thereof, a stacked-layer structure of a layer having an atomic ratio of In:Ga:Zn=4:2:3 or a neighborhood thereof and a layer having an atomic ratio of Ga:Zn=2:5 or a neighborhood thereof, and a stacked-layer structure of a layer having an atomic ratio of In:Ga:Zn=4:2:3 or a neighborhood thereof and gallium oxide.

At this time, the semiconductor layer 520b serves as a main carrier path. When the semiconductor layers 520a and 520c have the above structures, the density of defect states at the interface between the semiconductor layers 520a and 520b and the interface between the semiconductor layers 520b and 520c can be made low. This reduces the influence of interface scattering on carrier conduction, and the transistor 200E can have a high on-state current and high frequency characteristics. Note that in the case where the semiconductor layer 520c has a stacked-layer structure, not only the density of defect state at the interface between the semiconductor layers 520b and 520c would be made low, but also the constituent element of the semiconductor layer 520c would be inhibited from being diffused into the insulating layer 550 side. More specifically, since the semiconductor layer 520c has a stacked-layer structure in which the oxide in the upper layer does not contain In, In can be inhibited from being diffused to the insulating layer 550 side. Since the insulating layer 550 functions as a gate insulating layer, the transistor would show poor characteristics when In is diffused into the insulating layer 550. Thus, the semiconductor layer 520c having a stacked-layer structure allows the semiconductor device to have high reliability.

The conductive layers 542 (the conductive layer 542a and the conductive layer 542b) functioning as the source electrode and the drain electrode are provided over the semiconductor layer 520b. In the case of using an oxide semiconductor for the semiconductor layer 520b, a conductive material that is less likely to be oxidized or a material that maintains the conductivity even after absorbing oxygen is preferably used for the conductive layer 542.

A region of the semiconductor layer 520 that is in contact with the conductive layer 542 functions as a source region or a drain region of the transistor 200E. Here, a region between the conductive layer 542a and the conductive layer 542b is formed to overlap with the opening in the insulating layer 580. Accordingly, the conductive layer 560 can be placed in a self-aligned manner between the conductive layer 542a and the conductive layer 542b.

The insulating layer 550 functions as a gate insulating layer. The insulating layer 550 is placed in contact with the top surface of the semiconductor layer 520c. For the insulating layer 550, silicon oxide, silicon oxynitride, silicon nitride oxide, silicon nitride, silicon oxide to which fluorine is added, silicon oxide to which carbon is added, silicon oxide to which carbon and nitrogen are added, or porous silicon oxide can be used. For example, silicon oxide or silicon oxynitride is used for the insulating layer 550.

Like the insulating layer 524, the insulating layer 550 is formed using an insulating material in which the concentration of impurities such as water or hydrogen is reduced. The thickness of the insulating layer 550 is greater than or equal to 1 nm and less than or equal to 20 nm.

A metal oxide is preferably provided between the insulating layer 550 and the conductive layer 560. The metal oxide inhibits diffusion of oxygen from the insulating layer 550 to the conductive layer 560. Thus, oxidation of the conductive layer 560 due to oxygen in the insulating layer 550 can be inhibited.

Although the conductive layer 560 has a two-layer structure in FIGS. 33A to 33C, the conductive layer 560 can have a single-layer structure or a stacked-layer structure of three or more layers.

The above-described conductive material having a function of inhibiting diffusion of impurities such as a hydrogen atom, a hydrogen molecule, a water molecule, a nitrogen atom, a nitrogen molecule, a nitrogen oxide molecule (e.g., N₂O, NO, and NO₂), and a copper atom is preferably used for the conductive layer 560a. Alternatively, a conductive material having a function of inhibiting diffusion of oxygen (e.g., at least one of oxygen atoms and oxygen molecules) is preferably used.

When the conductive layer 560a has a function of inhibiting diffusion of oxygen, the conductivity of the conductive layer 560b can be inhibited from being lowered because of oxidation due to oxygen contained in the insulating layer 550. As the conductive material having a function of inhibiting diffusion of oxygen, for example, tantalum, tantalum nitride, ruthenium, or ruthenium oxide can be used.

A conductive material containing, for example, tungsten, copper, or aluminum as its main component can be used for the conductive layer 560b. The conductive layer 560 also functions as a wiring and thus is preferably a conductive layer having high conductivity. The conductive layer 560b can have a stacked-layer structure, for example, a stacked-layer structure of titanium or titanium nitride and the above conductive material.

As illustrated in FIGS. 33B and 33C, the side surface of the semiconductor layer 520 is covered with the conductive layer 560 in a region where the semiconductor layer 520b does not overlap with the conductive layer 542 when seen from the Z direction, that is, the channel formation region in the semiconductor layer 520. Accordingly, electric field of the conductive layer 560 functioning as the gate electrode of the transistor 200E is likely to act on the side surface of the semiconductor layer 520. Hence, the transistor 200E can have a higher on-state current and higher frequency characteristics.

Like the insulating layer 514 or the like, the insulating layer 554 is formed using an insulating material that inhibits entry of impurities such as water or hydrogen to the transistor 200E from the insulating layer 580 side. For example, an insulating material having a lower hydrogen permeability than the insulating layer 524 is used for the insulating layer 554. Furthermore, as illustrated in FIGS. 33B and 33C, the insulating layer 554 is provided in contact with the side surface of the semiconductor layer 520c, the top and side surfaces of the conductive layer 542a, the top and side surfaces of the conductive layer 542b, the side surfaces of the semiconductor layer 520a and the semiconductor layer 520b, and the top surface of the insulating layer 524. Such a structure can inhibit entry of hydrogen contained in the insulating layer 580 into the semiconductor layer 520 through the top surfaces or the side surfaces of the conductive layer 542a, the conductive layer 542b, the semiconductor layer 520a, the semiconductor layer 520b, and the insulating layer 524.

Moreover, an insulating material having a function of inhibiting diffusion of oxygen (e.g., at least one of oxygen atoms and oxygen molecules) (an insulating material through which oxygen is less likely to pass) is used for the insulating layer 554. For example, an insulating material having a lower oxygen permeability than the insulating layer 580 or the insulating layer 524 is used for the insulating layer 554.

In the case of using an oxide semiconductor for the semiconductor layer 520, the insulating layer 554 can be formed by a sputtering method. When the insulating layer 554 is formed by a sputtering method in an oxygen-containing atmosphere, oxygen can be added to the vicinity of a region of the insulating layer 524 that is in contact with the insulating layer 554. Thus, oxygen can be supplied from the region to the semiconductor layer 520 through the insulating layer 524. Here, with the insulating layer 554 having a function of inhibiting upward oxygen diffusion, oxygen can be prevented from being diffused from the semiconductor layer 520 into the insulating layer 580. In addition, with the insulating layer 522 having a function of inhibiting downward oxygen diffusion, oxygen can be prevented from being diffused from the semiconductor layer 520 to the substrate side. In the above manner, oxygen is supplied to the channel formation region in the semiconductor layer 520. Accordingly, oxygen vacancies in the semiconductor layer 520 can be reduced, so that the transistor can be inhibited from having normally-on characteristics.

As the insulating layer 554, an insulating layer containing an oxide of one or both of aluminum and hafnium is formed. As the insulating layer containing an oxide of one or both of aluminum and hafnium, aluminum oxide, hafnium oxide, an oxide containing aluminum and hafnium (hafnium aluminate), or the like can be used.

The insulating layer 580 is provided over the insulating layer 524, the semiconductor layer 520, and the conductive layer 542 with the insulating layer 554 therebetween. For example, for the insulating layer 580, silicon oxide, silicon oxynitride, silicon nitride oxide, silicon oxide to which fluorine is added, silicon oxide to which carbon is added, silicon oxide to which carbon and nitrogen are added, porous silicon oxide, or the like is used. Silicon oxide and silicon oxynitride are particularly preferred because of their thermal stability. In particular, materials such as silicon oxide, silicon oxynitride, and porous silicon oxide are preferably used, in which case a region containing oxygen released by heating can be easily formed.

Like the insulating layer 514 or the like, the insulating layer 574 is formed using an insulating material functioning as a barrier insulating film that inhibits entry of impurities such as water or hydrogen to the insulating layer 580 from above. For the insulating layer 574, an insulating material that can be used for the insulating layer 514 or the insulating layer 554 can be used, for example.

FIGS. 33A to 33C show an example where the insulating layer 581 functioning as an interlayer film is provided over the insulating layer 574. Like the insulating layer 524 or the like, the insulating layer 581 is formed using an insulating material in which the concentration of impurities such as water or hydrogen is reduced.

The conductive layer 545a and the conductive layer 545b are placed in the openings formed in the insulating layers 581, 574, 580, and 554. The conductive layer 545a and the conductive layer 545b are provided to face each other with the conductive layer 560 therebetween in a plan view. Note that the top surfaces of the conductive layer 545a and the conductive layer 545b are preferably on the same plane as the top surface of the insulating layer 581.

The insulating layer 541a is provided in contact with the inner wall of the opening in the insulating layers 581, 574, 580, and 554, and the first conductive layer of the conductive layer 545a is formed in contact with the side surface of the insulating layer 541a. The conductive layer 542a is positioned on at least part of the bottom portion of the opening, and the conductive layer 545a is in contact with the conductive layer 542a. Similarly, the insulating layer 541b is provided in contact with the inner wall of the opening in the insulating layers 581, 574, 580, and 554, and the first conductive layer of the conductive layer 545b is formed in contact with the side surface of the insulating layer 541b. The conductive layer 542b is positioned on at least part of the bottom portion of the opening, and the conductive layer 545b is in contact with the conductive layer 542b.

A conductive material containing tungsten, copper, or aluminum as its main component is preferably used for each of the conductive layers 545a and 545b. The conductive layers 545a and 545b can each have a stacked-layer structure of two or more layers.

In the case where the conductive layer 545 has a stacked-layer structure, a conductive layer having a function of inhibiting diffusion of impurities such as water or hydrogen is preferably used as the conductive layer in contact with the semiconductor layer 520a, the semiconductor layer 520b, the conductive layer 542, the insulating layer 554, the insulating layer 580, the insulating layer 574, and the insulating layer 581. For example, tantalum, tantalum nitride, titanium, titanium nitride, ruthenium, or ruthenium oxide is used. The use of the conductive material can inhibit oxygen contained in the insulating layer 580 from being absorbed by the conductive layers 545a and 545b. Moreover, impurities such as water or hydrogen can be inhibited from entering the semiconductor layer 520 through the conductive layers 545a and 545b from a layer above the insulating layer 581.

As each of the insulating layers 541a and 541b, for example, an insulating layer that can be used as the insulating layer 554 or the like is used. Since the insulating layers 541a and 541b are provided in contact with the insulating layer 554, impurities such as water or hydrogen can be inhibited from entering the semiconductor layer 520 from the insulating layer 580 or the like through the conductive layers 545a and 545b. Furthermore, oxygen contained in the insulating layer 580 can be inhibited from being absorbed by the conductive layers 545a and 545b.

### <Structure Example 6 of Transistor>

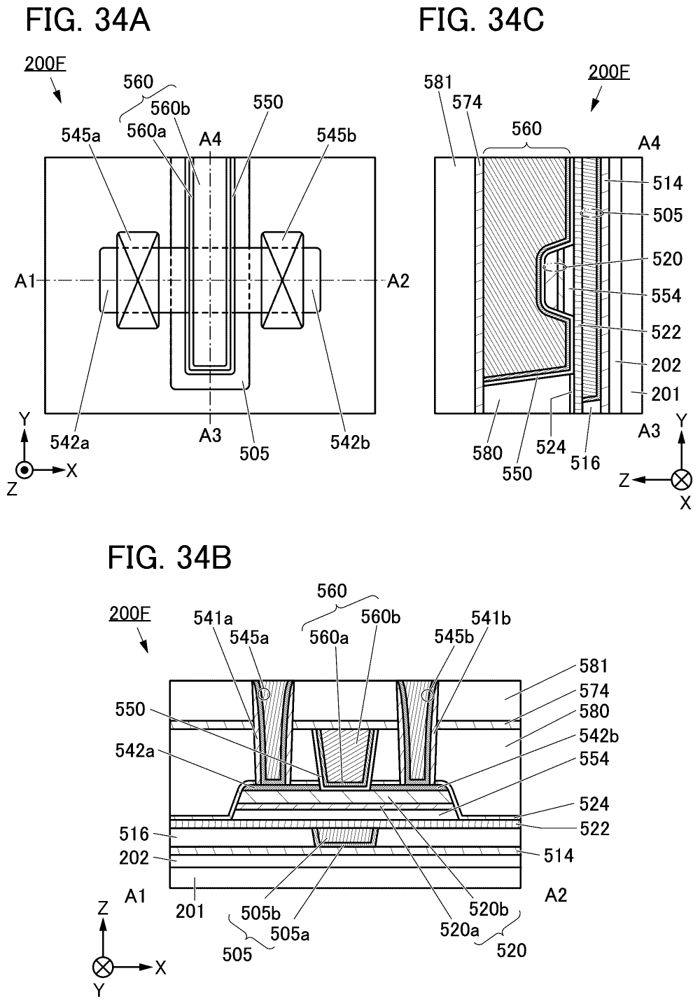

FIGS. 34A to 34C show a modification example of the transistor 200E illustrated in FIGS. 33A to 33C. FIG. 34A is a plan view of a transistor 200F, which is a modification example of the transistor 200E. FIG. 34B is a cross-sectional view taken along dashed-dotted line A1-A2 in FIG. 34A. FIG. 34C is a cross-sectional view taken along dashed-dotted line A3-A4 in FIG. 34A. Since the transistor 200F is a modification example of the transistor 200E, a description is mainly made on portions of the transistor 200F different from those of the transistor 200E.

The transistor 200F has a structure in which the semiconductor layer 520c and the conductive layer 505c are removed from the structure of the transistor 200E. A reduction in the number of components of a transistor can reduce the manufacturing cost. Furthermore, the manufacturing process is shortened when the number of components of the transistor is reduced, leading to an improvement in the manufacturing yield.

The transistor 200F includes a region where the insulating layer 554 and the insulating layer 522 are in contact with each other outside the semiconductor layer 520, and has a structure in which the side surface of the insulating layer 524 is covered with the insulating layer 554. In the case of using an oxide semiconductor for the semiconductor layer 520 and the side surface of the insulating layer 524 is covered with the insulating layer 554, oxygen can be prevented from being diffused to the outside through the insulating layer 524, and excess oxygen supply from the insulating layer 524 side to the semiconductor layer 520 can be prevented as well.

An insulating layer is preferably provided between the insulating layer 550 and the insulating layer 580, the insulating layer 554, the conductive layer 542, and the semiconductor layer 520b. For the insulating layer, aluminum oxide, hafnium oxide, or the like is preferably used. Providing the insulating layer can inhibit release of oxygen from the semiconductor layer 520 to the insulating layer 550 side, supply of excess oxygen from the insulating layer 550 side to the semiconductor layer 520, oxidation of the conductive layer 542, and the like.

### <Structure Example 7 of Transistor>

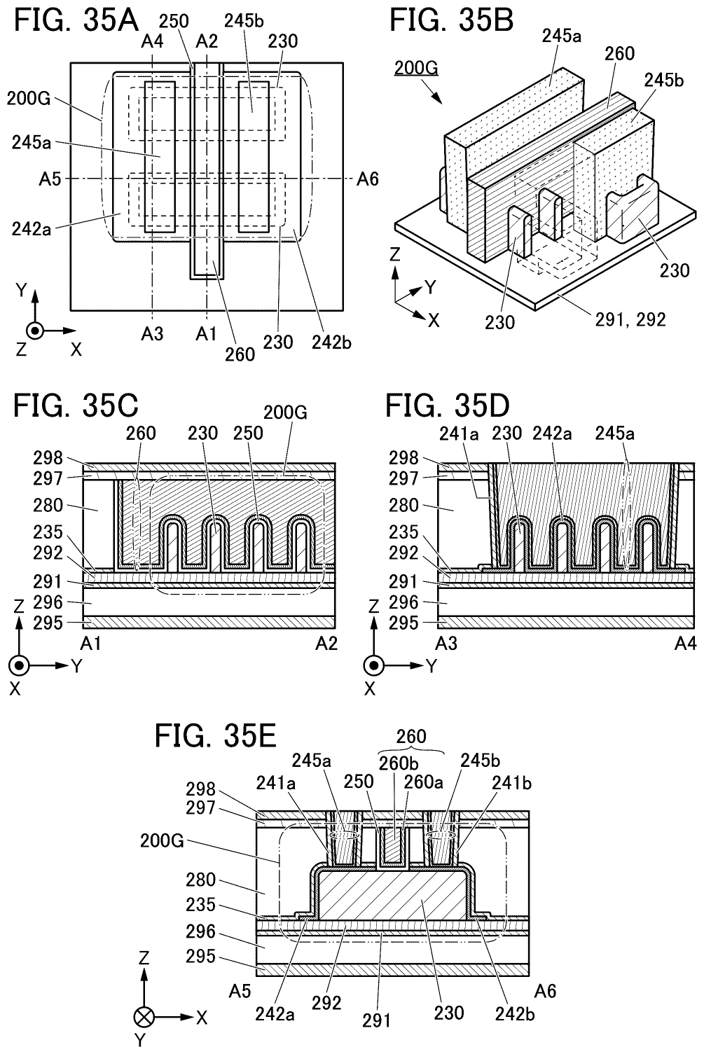

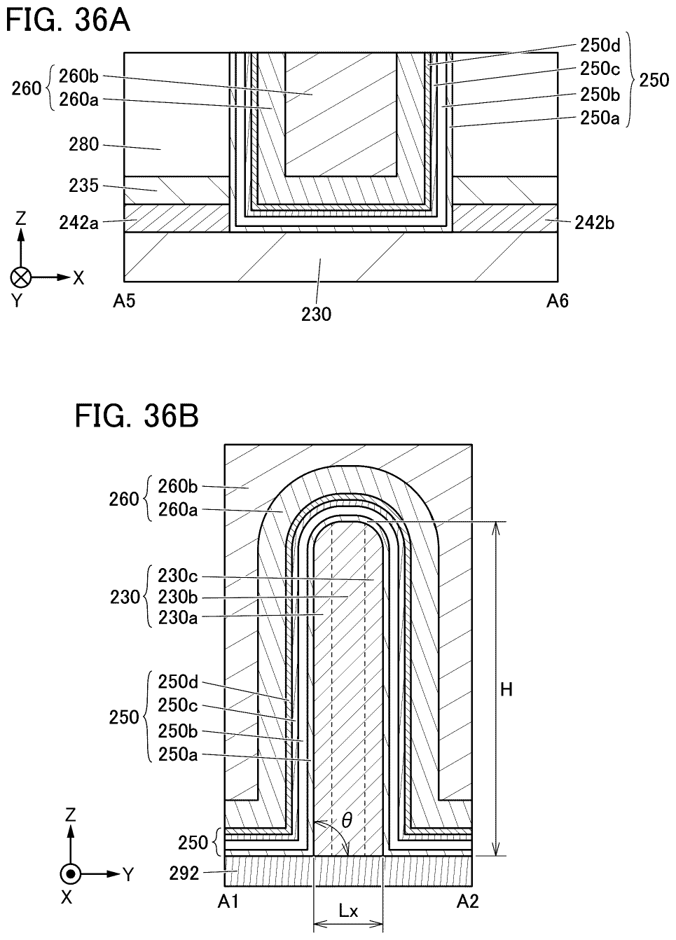

FIG. 35A is a plan view of a transistor 200G that can be used in the semiconductor device of one embodiment of the present invention. FIG. 35B is a schematic perspective view of the transistor 200G. FIGS. 35C to 35E are cross-sectional views of the transistor 200G. FIG. 35C is a cross-sectional view taken along dashed-dotted line A1-A2 in FIG. 35A, which corresponds to a cross-sectional view of the transistor 200G in the channel length direction (the Y direction). FIG. 35D is a cross-sectional view taken along dashed-dotted line A3-A4 in FIG. 35A, which corresponds to a cross-sectional view in the channel width direction of the transistor 200G. FIG. 35E is a cross-sectional view taken along dashed-dotted line A5-A6 in FIG. 35A, which corresponds to a cross-sectional view of the transistor 200G in the channel length direction (the X direction). Dashed-dotted line A5-A6 is orthogonal to dashed-dotted line A1-A2 and dashed-dotted line A3-A4, and dashed-dotted line A1-A2 is parallel to dashed-dotted line A3-A4. Note that some components are not illustrated in the plan view of FIG. 35A and the schematic perspective view of FIG. 35B. FIG. 36A is an enlarged view of the conductive layer 260 in FIG. 35E and its vicinity. FIG. 36B is an enlarged view of the semiconductor layer 230 in FIG. 35C and its vicinity.

The transistor 200G includes an insulating layer 295 over a substrate (not illustrated), an insulating layer 296 over the insulating layer 295, an insulating layer 291 over the insulating layer 296, an insulating layer 292 over the insulating layer 291, the semiconductor layer 230 over the insulating layer 292, a conductive layer 242a and a conductive layer 242b over the semiconductor layer 230 and the insulating layer 292, the insulating layer 250 over the semiconductor layer 230, and the conductive layer 260 (the conductive layer 260a and the conductive layer 260b) over the insulating layer 250. In this specification, the conductive layer 242a and the conductive layer 242b are collectively referred to as a conductive layer 242 in some cases.

An insulating layer 235 is provided over the conductive layer 242, and an insulating layer 280 is provided over the insulating layer 235. The insulating layer 250 and the conductive layer 260 are provided inside a first opening portion that penetrates the insulating layer 280 and the insulating layer 235 and reaches the semiconductor layer 230. In the plan view, the first opening portion includes a region overlapping with the semiconductor layer 230 and a region extending along the Y direction beyond the end portion of the semiconductor layer 230. Thus, the insulating layer 250 and the conductive layer 260 provided inside the first opening portion also include, in the plan view, a region overlapping with the semiconductor layer 230 and a region extending along the Y direction beyond the end portion of the semiconductor layer 230. The conductive layer 260 also functions as a wiring. The insulating layer 250 includes a region in contact with the semiconductor layer 230 in the first opening portion. An insulating layer 297 is provided over the insulating layer 280 and the conductive layer 260. An insulating layer 298 is provided over the insulating layer 297.

An insulating layer 241a is provided in contact with the side surface of a second opening portion that penetrates the insulating layer 298, the insulating layer 297, the insulating layer 280, and the insulating layer 235 and reaches the conductive layer 242a, and a conductive layer 245a is provided in contact with the insulating layer 241a. The conductive layer 245a includes a region in contact with the conductive layer 242a at a bottom portion of the first opening portion.

An insulating layer 241b is provided in contact with the side surface of a third opening portion that penetrates the insulating layer 298, the insulating layer 297, the insulating layer 280, and the insulating layer 235 and reaches the conductive layer 242b, and a conductive layer 245b is provided in contact with the insulating layer 241b. The conductive layer 245b includes a region in contact with the conductive layer 242b at a bottom portion of the second opening portion.

In this specification, the conductive layer 245a and the conductive layer 245b are sometimes collectively referred to as a conductive layer 245. In addition, the insulating layer 241a and the insulating layer 241b are sometimes collectively referred to as an insulating layer 241.

The semiconductor layer 230 includes a channel formation region of the transistor 200G. The conductive layer 260 includes a region that functions as a gate electrode of the transistor 200G. The insulating layer 250 includes a region functioning as a gate insulating layer of the transistor 200G. In the transistor 200G, a region that is of the semiconductor layer 230 and overlaps with the conductive layer 260 functions as the channel formation region. The region that is of the conductive layer 260 and overlaps with the semiconductor layer 230 functions as a gate electrode. The region of the insulating layer 250 where the insulating layer 250 and the semiconductor layer 230 overlap with each other and the insulating layer 250 and the conductive layer 260 overlap with each other functions as the gate insulating layer.

The conductive layer 242a includes a region functioning as one of a source electrode and a drain electrode of the transistor 200G. The conductive layer 245a functions as a plug connected to the conductive layer 242a. The conductive layer 242b includes a region functioning as the other of the source electrode and the drain electrode of the transistor 200G. The conductive layer 245b functions as a plug connected to the conductive layer 242b.

The semiconductor layer 230 is formed over the insulating layer 292. As illustrated in FIG. 36B, the semiconductor layer 230 has a shape with a high aspect ratio in the cross-sectional view in the channel width direction. Thus, the semiconductor layer 230 can be regarded as having a fin shape. A transistor having a fin-like semiconductor layer is also referred to as a “fin-type transistor”, a “fin transistor”, or the like.

Specifically, the fin-type transistor has a shape in which the channel formation region in the semiconductor layer includes two regions (two surfaces) extending in the Z direction and a length H described later is larger than a length Lx described later in a cross-sectional view in the channel width direction (Y direction). When the length H is larger than the length Lx in the cross-sectional view in the channel width direction, the channel width per unit area can be increased, which is preferable.

In this specification, the maximum length of the semiconductor layer 230 in the Y direction in the channel formation region is the length Lx, and the maximum length of the semiconductor layer 230 in the direction perpendicular to the formation surface (e.g., the top surface of the insulating layer 292) in the channel formation region is the length H.

Note that the length Lx can also be referred to as the maximum width of the semiconductor layer 230 in the channel formation region. Thus, “length Lx” can be replaced with “width Lx”. The length H can also be referred to as the maximum height of the semiconductor layer 230 in the channel formation region. Thus, “length H” can be replaced with “height H”.

The ratio of the length H to the length Lx is referred to as the aspect ratio of the semiconductor layer 230. The aspect ratio of the semiconductor layer 230 is preferably as high as possible to an extent that the semiconductor layer 230 does not collapse in the manufacturing process of the transistor 200G. The aspect ratio of the semiconductor layer 230 is preferably higher than 1 and lower than or equal to 400, further preferably higher than or equal to 2 and lower than or equal to 100, still further preferably higher than or equal to 5 and lower than or equal to 40, still further preferably higher than or equal to 10 and lower than or equal to 20. That is, in the channel formation region in the semiconductor layer 230, the height H of the semiconductor layer 230 is preferably larger than at least the length Lx of the semiconductor layer 230. The height H of the semiconductor layer 230 is preferably greater than 1 time and less than or equal to 400 times, further preferably greater than or equal to 2 times and less than or equal to 100 times, still further preferably greater than or equal to 5 times and less than or equal to 40 times, yet still further preferably greater than or equal to 10 times and less than or equal to 20 times the length Lx of the semiconductor layer 230. For example, the height H is preferably greater than or equal to 2 times and less than or equal to 10 times the length Lx. The length Lx is preferably, for example, greater than or equal to 5 nm and less than or equal to 100 nm, further preferably greater than or equal to 5 nm and less than or equal to 50 nm, still further preferably greater than or equal to 10 nm and less than or equal to 30 nm. The height H is preferably, for example, greater than or equal to 50 nm and less than or equal to 2000 nm, further preferably greater than or equal to 100 nm and less than or equal to 1000 nm. For another example, the height H can be greater than or equal to 50 nm and less than or equal to 100 nm.

In a cross-sectional view in the channel width direction as illustrated in FIG. 36B, an angle θ between the surface of the insulating layer 292 on which the semiconductor layer 230 is formed and the side surface of the semiconductor layer 230 is preferably perpendicular or substantially perpendicular. For example, the angle θ is preferably greater than or equal to 80° and less than or equal to 100°, further preferably greater than or equal to 85° and less than or equal to 95°.

The insulating layer 250, the conductive layer 260, and the conductive layer 242 are provided to cover the semiconductor layer 230 having such an aspect ratio. The insulating layer 250 and the conductive layer 260 are provided in the transistor 200G such that part of each of the insulating layer 250 and the conductive layer 260 is folded in half to sandwich the semiconductor layer 230, as illustrated in FIG. 36B. Thus, in a cross-sectional view in the channel width direction, the semiconductor layer 230 and the conductive layer 260 face each other with the insulating layer 250 therebetween in the upper portion, the side surface on the A1 side, and the side surface on the A2 side of the semiconductor layer 230. That is, the upper portion, the side surface on the A1 side, and the side surface on the A2 side of the semiconductor layer 230 function as a channel formation region. Accordingly, the channel width of the transistor 200G is greater than that of the case where the semiconductor layer 230 has a planar shape by the side surface on the A1 side and the side surface on the A2 side of the semiconductor layer 230.

The transistor 200G having such a large channel width can have a high on-state current, high mutual conductance, excellent frequency characteristics, and the like. Thus, a semiconductor device that operates at high speed can be provided. In the structure of the transistor 200G, the channel width can be increased without increasing the footprint of the semiconductor layer 230. Accordingly, scaling down or high integration of the semiconductor device can be achieved.

As illustrated in FIG. 36B and the like, the upper portion of the semiconductor layer 230 preferably has a curved shape. Such a curved shape can prevent formation of a defect such as a void in the insulating layer 250 and the conductive layer 242 in the vicinity of the upper portion of the semiconductor layer 230. Although the upper portion of the semiconductor layer 230 has a symmetrical structure with a curved shape on both the A1 side (the A3 side) and the A2 side (the A4 side) of the upper portion in FIG. 36B and the like, the present invention is not limited thereto. For example, the upper portion of the semiconductor layer 230 can have an asymmetrical structure with a curved shape on either the A1 side (the A3 side) or the A2 side (the A4 side) of the upper portion.

In the case where an oxide semiconductor is used for the semiconductor layer 230, a structure including semiconductor layers 230a, 230b, and 230c, which is disclosed in Embodiment 4, can be used as illustrated in FIGS. 36A and 36B.

In the case where an oxide semiconductor is used for the semiconductor layer 230, the insulating layer 250 preferably has a stacked-layer structure of an insulating layer 250a in contact with the semiconductor layer 230, an insulating layer 250b over the insulating layer 250a, an insulating layer 250c over the insulating layer 250b, and an insulating layer 250d over the insulating layer 250c, as illustrated in FIGS. 36A and 36B. In that case, the insulating layer 250a and the insulating layer 250c preferably have a function of capturing or fixing hydrogen.

An example of the insulating layer having a function of capturing or fixing hydrogen is a metal oxide having an amorphous structure. As each of the insulating layer 250a and the insulating layer 250c, for example, a metal oxide, such as magnesium oxide or an oxide containing aluminum and/or hafnium, is preferably used. In such a metal oxide having an amorphous structure, an oxygen atom has a dangling bond with which hydrogen is captured or fixed in some cases. That is, the metal oxide having an amorphous structure has high capability of capturing or fixing hydrogen.

Moreover, a high permittivity (high-k) material is preferably used for each of the insulating layer 250a and the insulating layer 250c. An example of the high-k material is an oxide containing aluminum and/or hafnium. With the use of the high-k material as each of the insulating layer 250a and the insulating layer 250c, a gate potential applied during operation of the transistor can be reduced while the physical thickness of the gate insulating layer is being maintained. Furthermore, the equivalent oxide thickness (EOT) of the insulating layer functioning as the gate insulating layer can be reduced.

For each of the insulating layer 250a and the insulating layer 250c, an oxide containing aluminum and/or hafnium is preferably used, and an oxide containing aluminum and/or hafnium and having an amorphous structure is further preferably used.

In this embodiment, as the insulating layer 250a, aluminum oxide is used. The aluminum oxide preferably has an amorphous structure. When the insulating layer 250a is provided in contact with the semiconductor layer 230 here, hydrogen contained in the semiconductor layer 230 or the like can be captured and fixed in the insulating layer 250a more effectively.

In this embodiment, for the insulating layer 250c, hafnium oxide is used. When the insulating layer 250c is provided between the insulating layer 250b and the insulating layer 250d here, hydrogen contained in the insulating layer 250b or the like can be captured and fixed more effectively.

An insulating layer having thermal stability, such as silicon oxide or silicon oxynitride, is preferably used as the insulating layer 250b. A silicon oxide film used as the insulating layer 250b is preferably formed by a plasma-enhanced ALD (PEALD) method.

In order to inhibit oxidation of the conductive layer 242a, the conductive layer 242b, and the conductive layer 260, a barrier insulating layer against oxygen is preferably provided in the vicinity of each of the conductive layer 242a, the conductive layer 242b, and the conductive layer 260. In the semiconductor device described in this embodiment, the insulating layer corresponds to, for example, the insulating layers 250a, 250d, 250c, and 235.

In this specification and the like, a barrier insulating layer refers to an insulating layer having a barrier property. In this specification and the like, “having a barrier property” means having a property of hindering transmission of a target substance (also referred to as having a low permeability). For example, an insulating layer having a barrier property hardly allows a target substance to be diffused into the insulating layer. For another example, an insulating layer having a barrier property has a function of capturing or fixing (also referred to as gettering) a target substance in the insulating layer.

Examples of a barrier insulating layer against oxygen include an oxide containing aluminum and/or hafnium, magnesium oxide, gallium oxide, silicon nitride, and silicon nitride oxide. Examples of the oxide containing aluminum and/or hafnium include aluminum oxide, hafnium oxide, an oxide containing aluminum and hafnium (hafnium aluminate), and an oxide containing hafnium and silicon (hafnium silicate). For example, each of the insulating layer 250a, the insulating layer 250c, the insulating layer 250d, and the insulating layer 235 preferably has a single-layer structure of the barrier insulating layer against oxygen or a stacked-layer structure of the barrier insulating layers against oxygen.

The insulating layer 250a preferably has a barrier property against oxygen. The insulating layer 250a is preferably less permeable to oxygen than at least the insulating layer 280 is. The insulating layer 250a includes a region in contact with the side surface of the conductive layer 242a and a region in contact with the side surface of the conductive layer 242b. When the insulating layer 250a has a barrier property against oxygen, oxidation of the side surfaces of the conductive layers 242a and 242b, which forms oxide films on the side surfaces, can be inhibited. Accordingly, a reduction in on-state current or field-effect mobility of the transistor 200G can be inhibited.

The insulating layer 250a is provided in contact with the top and side surfaces of the semiconductor layer 230 and the top surface of the insulating layer 292. When the insulating layer 250a has a barrier property against oxygen, release of oxygen from the channel formation region in the semiconductor layer 230 caused by heat treatment or the like can be inhibited. This can inhibit formation of oxygen vacancies in the semiconductor layer 230.

By providing the insulating layer 250a, excessive supply of oxygen from the insulating layer 280 to the semiconductor layer 230 can be inhibited and an appropriate amount of oxygen can be supplied to the semiconductor layer 230. Thus, excessive oxidation of the source and drain regions can be inhibited, and a reduction in on-state current or field-effect mobility of the transistor 200G can be inhibited.

An oxide containing aluminum and/or hafnium has a barrier property against oxygen and thus is suitable for the insulating layer 250a.

The insulating layer 250d also preferably has a barrier property against oxygen. The insulating layer 250d is provided between the conductive layer 260 and the channel formation region in the semiconductor layer 230 and between the insulating layer 280 and the conductive layer 260. Such a structure can inhibit oxygen contained in the channel formation region in the semiconductor layer 230 from being diffused into the conductive layer 260 and thus can inhibit formation of oxygen vacancies in the channel formation region in the semiconductor layer 230. Oxygen contained in the semiconductor layer 230 and oxygen contained in the insulating layer 280 can be inhibited from being diffused into the conductive layer 260 and oxidizing the conductive layer 260. The insulating layer 250d is preferably less permeable to oxygen than at least the insulating layer 280 is. For example, silicon nitride is preferably used as the insulating layer 250d. In this case, the insulating layer 250d is an insulating layer containing at least nitrogen and silicon.

The insulating layer 250d preferably has a barrier property against hydrogen. This can prevent diffusion of impurities contained in the conductive layer 260, such as hydrogen, into the semiconductor layer 230.

The insulating layer 235 also preferably has a barrier property against oxygen. The insulating layer 235 is provided between the insulating layer 280 and each of the conductive layer 242a and the conductive layer 242b. The insulating layer 235 is provided in contact with the side surface of the conductive layer 242, the side surface of the semiconductor layer 230, and the top surface of the insulating layer 292. This structure can inhibit diffusion of oxygen contained in the insulating layer 280 into the conductive layer 242. Accordingly, oxidation of the conductive layer 242 by oxygen contained in the insulating layer 280 can be inhibited, so that an increase in resistivity due to the oxidation can be inhibited. The insulating layer 235 is preferably less permeable to oxygen than at least the insulating layer 280 is. For example, silicon nitride is preferably used for the insulating layer 235. In this case, the insulating layer 235 is an insulating layer containing at least nitrogen and silicon.

In order to inhibit a reduction in hydrogen concentration in the source and drain regions in the semiconductor layer 230, a barrier insulating layer against hydrogen is preferably provided in the vicinity of each of the source and drain regions. In the semiconductor device described in this embodiment, the barrier insulating layer against hydrogen corresponds to, for example, the insulating layer 235.

Examples of the barrier insulating layer against hydrogen include oxides such as aluminum oxide, hafnium oxide, and tantalum oxide and nitrides such as silicon nitride. For example, the insulating layer 235 preferably has a single-layer structure of the barrier insulating layer against hydrogen or a stacked-layer structure of the barrier insulating layers against hydrogen.

Providing the above-described insulating layer 235 can reduce the amount of hydrogen diffused from the source and drain regions to the outside, so that a reduction in the hydrogen concentration in the source and drain regions can be inhibited. Thus, the source and drain regions can be n-type regions.

With the above structure, the i-type or substantially i-type channel formation region and the n-type source and drain regions can be formed; therefore, a semiconductor device with favorable electrical characteristics can be provided. The semiconductor device with the above structure can have excellent electrical characteristics even when being scaled down or highly integrated. Furthermore, scaling down of the transistor 200G can improve the high-frequency characteristics. Specifically, the cutoff frequency can be improved.

The insulating layers 250a to 250d function as part of the gate insulating layer. The insulating layers 250a to 250d are provided together with the conductive layer 260 in an opening formed in the insulating layer 280. The thickness of each of the insulating layers 250a to 250d is preferably small for scaling down of the transistor 200G. The thickness of each of the insulating layers 250a to 250d is preferably greater than or equal to 0.1 nm and less than or equal to 10 nm, further preferably greater than or equal to 0.1 nm and less than or equal to 5.0 nm, still further preferably greater than or equal to 0.5 nm and less than or equal to 5.0 nm, yet further preferably greater than or equal to 1.0 nm and less than 5.0 nm, yet still further preferably greater than or equal to 1.0 nm and less than or equal to 3.0 nm. Note that each of the insulating layers 250a to 250d at least partly includes a region with the above-described thickness.

The thickness of the silicon oxide film used as the insulating layer 250 is preferably greater than or equal to 0.7 nm and less than or equal to 3 nm.

To reduce the thicknesses of the insulating layers 250a to 250d as described above, an atomic layer deposition (ALD) method is preferably used for film formation. Furthermore, to provide the insulating layers 250a to 250d in the opening in the insulating layer 280 and the like, an ALD method is preferably used. By an ALD method, the insulating layer 250 can be formed on the side surface of the first opening portion formed in the insulating layer 280, a side end portion of the conductive layer 242a, a side end portion of the conductive layer 242b, and the like with good coverage.

Although the case where the insulating layer 250 has a four-layer structure of the insulating layers 250a to 250d is described above, the present invention is not limited to this structure. The insulating layer 250 can have a structure including at least one of the insulating layers 250a to 250d. When the insulating layer 250 is formed of one, two, or three layers of the insulating layers 250a to 250d, the manufacturing process of the transistor 200G can be simplified and the productivity of the semiconductor device including the transistor 200G can be improved.

As illustrated in FIG. 35A, the shape of the semiconductor layer 230 in the plan view is preferably an annular shape with no endpoints (also referred to as a frame shape, a ring shape, a doughnut shape, or a closed-curve shape). That is, the semiconductor layer 230 preferably includes a plurality of portions extending in the channel width direction (the A1-A2 direction) and a plurality of portions extending in the channel length direction (the A5-A6 direction). This can inhibit the semiconductor layer 230 formed to have a high aspect ratio from collapsing during the manufacturing process of the transistor. Note that the shape of the semiconductor layer 230 illustrated in FIG. 35A can also be regarded as having an opening in the center portion. Although the shape of the semiconductor layer 230 in the plan view is a line-symmetrical shape with respect to dashed-dotted line A1-A2 in FIG. 35A, the present invention is not limited thereto. For example, the shape of the semiconductor layer 230 in the plan view may be an asymmetrical shape.

The structure illustrated in FIG. 35A is a structure in which two annular-shaped semiconductor layers 230 are formed in the Y direction. As illustrated in FIG. 35A, the semiconductor layer 230 preferably overlaps with the conductive layer 260 at two or more points in the plan view. Thus, the conductive layer 260 preferably includes two or more regions overlapping with the semiconductor layer 230. That is, two or more regions where the semiconductor layer 230 and the conductive layer 260 overlap with each other are preferably included.

With such a structure, the plurality of the fin-shaped semiconductor layers 230 are formed in a cross-sectional view in the channel width direction as illustrated in FIG. 35B. The plurality of the fin-shaped semiconductor layers 230 each include a channel formation region. That is, the transistor 200G functions as a multi-channel transistor. Thus, the channel width can be further increased in the transistor 200G, so that the amount of on-state current can be increased. Accordingly, the operation speed of the semiconductor device including the transistor 200G can be increased.

Although the structure in which the two annular-shaped semiconductor layers 230 are provided is described above, the present invention is not limited thereto. For example, one or three or more annular-shaped semiconductor layers 230 can be provided. Alternatively, the annular-shaped semiconductor layers 230 can be bonded to each other to form the semiconductor layer 230 having a plurality of openings. The semiconductor layer 230 having a lattice shape in the plan view can be used.

### <Structure Example 8 of Transistor>

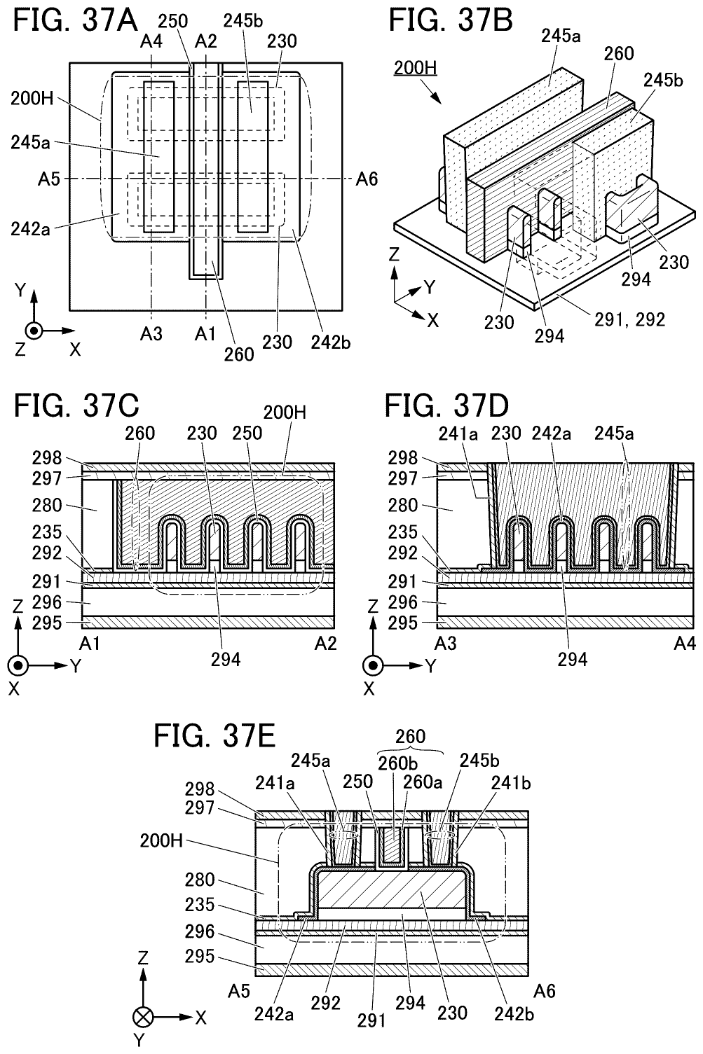

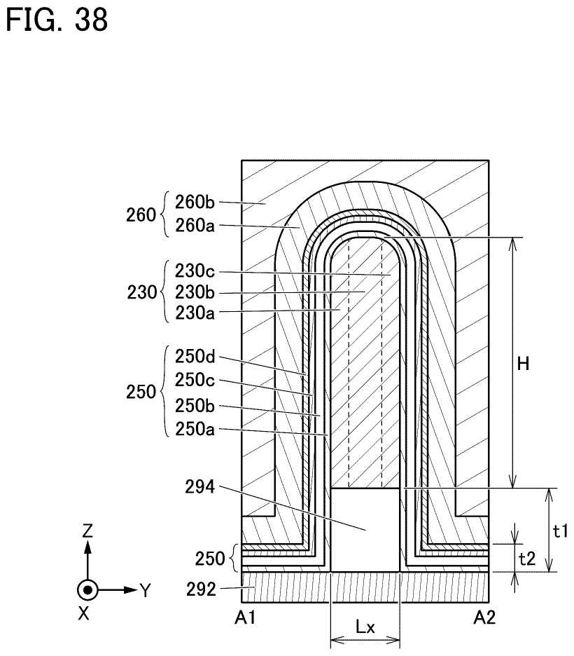

Next, a transistor 200H which is a modification example of the transistor 200G will be described. FIG. 37A is a plan view of the transistor 200H that can be used in the semiconductor device of one embodiment of the present invention. FIG. 37B is a schematic perspective view of the transistor 200H. FIGS. 37C to 37E are cross-sectional views of the transistor 200H. FIG. 37C is a cross-sectional view taken along dashed-dotted line A1-A2 in FIG. 37A, which corresponds to a cross-sectional view of the transistor 200H in the channel length direction (the Y direction). FIG. 37D is a cross-sectional view taken along dashed-dotted line A3-A4 in FIG. 37A, which corresponds to a cross-sectional view in the channel width direction of the transistor 200H. FIG. 37E is a cross-sectional view taken along dashed-dotted line A5-A6 in FIG. 37A, which corresponds to a cross-sectional view of the transistor 200H in the channel length direction (the X direction). Dashed-dotted line A5-A6 is orthogonal to dashed-dotted line A1-A2 and dashed-dotted line A3-A4, and dashed-dotted line A1-A2 is parallel to dashed-dotted line A3-A4. Note that some components are not illustrated in the plan view of FIG. 37A and the schematic perspective view of FIG. 37B. FIG. 38 is an enlarged view of the semiconductor layer 230 in FIG. 37C.

As illustrated in FIGS. 37B to 37E, an insulating layer 294 can be provided below the semiconductor layer 230. The planar shape (the shape seen from the Z direction) of the insulating layer 294 is similar to that of the semiconductor layer 230. The insulating layer 294 overlaps with the semiconductor layer 230 in the plan view. The bottom surface of the insulating layer 294 is in contact with the insulating layer 292, the side surface of the insulating layer 294 is in contact with the insulating layer 250 and the conductive layer 242a, and the top surface of the insulating layer 294 is in contact with the bottom surface of the semiconductor layer 230. As the insulating layer 294, an insulating material that can be used for the insulating layer 250b may be used. For example, silicon oxide can be used for the insulating layer 294.

Here, FIGS. 37A to 37E correspond to FIGS. 35A to 35E. FIG. 38 corresponds to FIG. 36B. Thus, the structures that are illustrated in FIGS. 37A to 37E and FIG. 38 and are not described below can be understood with reference to the above description of FIGS. 35A to 35E and FIG. 36B and the like.

Here, as illustrated in FIG. 38, a thickness t2 of the insulating layer 250 at the bottom portion of the first opening portion is preferably smaller than a thickness t1 of the insulating layer 294 (the length of the insulating layer 294 in the direction perpendicular to the surface on which the insulating layer 294 is formed). With such a structure, the level of the bottom surface of the conductive layer 260 (the conductive layer 260a) positioned in the first opening portion can be lower than the level of the bottom surface of the semiconductor layer 230 by a difference between the thickness t1 and the thickness t2 (t1−t2).

When the level of the bottom surface of the conductive layer 260 is lower than the level of the bottom surface of the semiconductor layer 230, a gate electric field can be adequately applied to the semiconductor layer 230 from its upper end portion to its lower end portion. In other words, in the opening in the insulating layer 280 and the like, the semiconductor layer 230 can be wholly electrically surrounded by an electric field of the conductive layer 260 to function as a channel formation region. Such a structure can prevent the lower end portion of the semiconductor layer 230 from functioning as a parasitic channel, thereby reducing a leakage current between the source electrode and the drain electrode. In addition, poor characteristics of the transistor due to the parasitic channel, such as normally-on characteristics, can be inhibited. That is, the transistor 200H can have excellent electrical characteristics.

When a region from the upper end portion to the lower end portion of the semiconductor layer 230 functions as a channel formation region as described above, the channel width can be increased. Thus, the transistor 200H can have a high on-state current, high mutual conductance, excellent frequency characteristics, and the like.

In this specification and the like, a transistor structure in which a channel formation region is electrically surrounded by the electric field of a gate electrode as in the above structure is referred to as a surrounded channel (S-channel) structure. In the S-channel structure, a gate electrode is provided to cover at least two surfaces (specifically, two surfaces, three surfaces, four surfaces, or the like) of a channel. With the use of the S-channel structure, a transistor with high resistance to the short-channel effects, i.e., a transistor in which the short-channel effects are unlikely to occur, can be obtained.

Since the S-channel structure is a structure in which the channel formation region is electrically surrounded, the S-channel structure is, in a sense, equivalent to a gate all around (GAA) structure or a lateral gate all around (LGAA) structure. In the transistor 200H having any of the S-channel structure, GAA structure, and LGAA structure, the channel formation region that is provided at the interface between the semiconductor layer 230 and the insulating layer 250 functioning as the gate insulating layer or in the vicinity of the interface spreads throughout the entire bulk of the semiconductor layer 230. Consequently, the density of current flowing through the transistor can be improved, so that the on-state current or the field-effect mobility of the transistor can be expected to be increased. In one embodiment of the present invention, the semiconductor layer 230 has a CAAC structure and a fin-shaped structure. With such structures, the source-drain current path in the transistor and the a-b plane of the crystal axis can be parallel to each other. In other words, an oxide semiconductor having the CAAC structure and the fin-shaped structure seems to have a conduction path equivalent to that of a two-dimensional semiconductor material. Furthermore, with the use of such an oxide semiconductor, a device having two-dimensional conduction can be formed.

### <Structure Example 9 of Transistor>

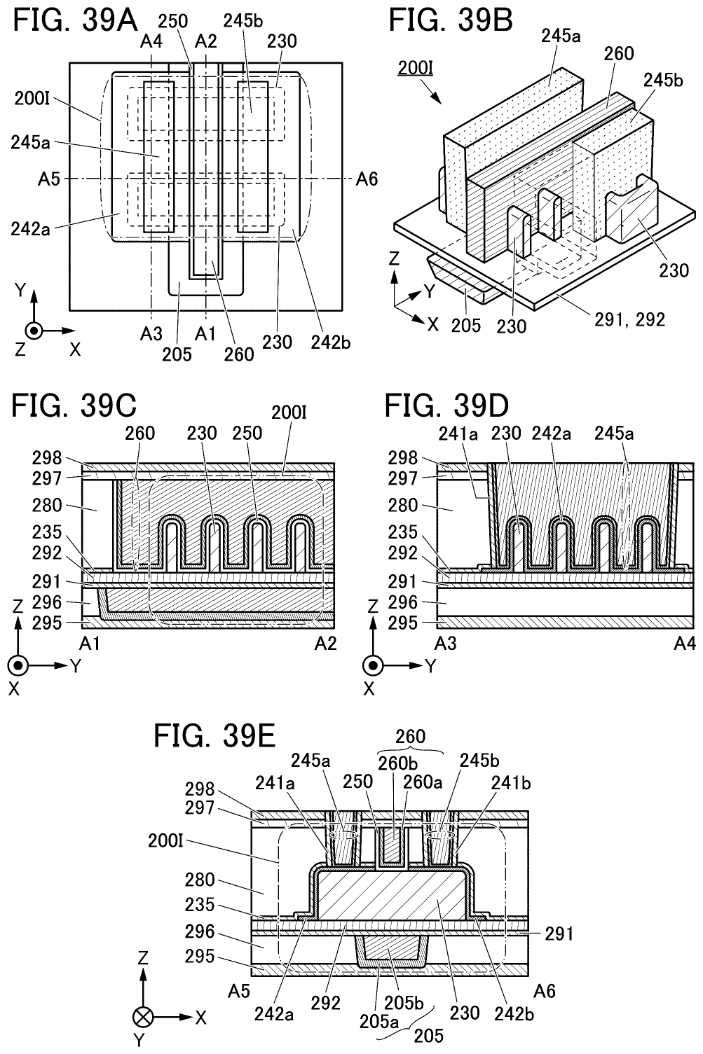

FIGS. 39A to 39E illustrate a transistor 200I, which is a modification example of the transistor 200G. The transistor 200I is different from the transistor 200G in that the conductive layer 205 is provided below the insulating layer 291. Note that FIGS. 39A to 39E correspond to FIGS. 35A to 35E. The structures that are illustrated in FIGS. 39A to 39E and are not described below can be understood with reference to the above description of FIGS. 35A to 35E and the like.

The conductive layer 205 includes a region which overlaps with the channel formation region in the semiconductor layer 230. Thus, like the conductive layer 260, the conductive layer 205 includes a region functioning as a gate electrode. The conductive layer 260 may be referred to as a first gate electrode (an upper gate electrode) of the transistor 200I, and the conductive layer 205 may be referred to as a second gate electrode (a lower gate electrode) of the transistor 200I. In the case where the conductive layer 260 is referred to as a gate electrode of the transistor 200I, the conductive layer 205 is referred to as a back gate electrode of the transistor 200I in some cases.

In the case where the transistor 200I includes the conductive layer 205 under the insulating layer 291, each of the insulating layer 292 and the insulating layer 291 includes a region functioning as a gate insulating layer like the insulating layer 250. Specifically, a region that is of the insulating layer 292 and overlaps with the conductive layer 205 and a region that is of the insulating layer 291 and overlaps with the conductive layer 205 function as a gate insulating layer. The insulating layer 250 may be referred to as a first gate insulating layer (an upper gate insulating layer), and the insulating layer 292 and the insulating layer 291 may be referred to as a second gate insulating layer (a lower gate insulating layer).

In the transistor 200I, the conductive layer 205 is provided to overlap with the semiconductor layer 230 and the conductive layer 260. In FIGS. 39C and 39E, the conductive layer 205 is provided inside a fourth opening portion that penetrates the insulating layer 296 and reaches the insulating layer 295. In the plan view, the fourth opening portion includes a region overlapping with the semiconductor layer 230 and a region extending along the Y direction beyond the end portion of the semiconductor layer 230. Thus, the conductive layer 205 provided inside the fourth opening portion also includes, in the plan view, a region overlapping with the semiconductor layer 230 and a region extending along the Y direction beyond the end portion of the semiconductor layer 230. The conductive layer 205 also functions as a wiring.

As illustrated in FIGS. 39C and 39E, the conductive layer 205 preferably includes a conductive layer 205a and a conductive layer 205b. The conductive layer 205a is provided in contact with a bottom portion and a sidewall of the fourth opening portion. The conductive layer 205b is provided to fill a depressed portion of the conductive layer 205a formed along the bottom portion and the sidewall of the fourth opening portion. Here, the top surface of the conductive layer 205 is preferably level or substantially level with the top surface of the insulating layer 296. That is, when seen from the Y direction, the shortest distance from the top surface of the substrate (not illustrated) to the top surface of the insulating layer 296 is preferably equal or substantially equal to the shortest distance from the top surface of the substrate to the top surface of the conductive layer 205.

The conductive layer 205a preferably contains a conductive material having a function of inhibiting diffusion of impurities such as a hydrogen atom, a hydrogen molecule, a water molecule, a nitrogen atom, a nitrogen molecule, a nitrogen oxide molecule (e.g., N₂O, NO, and NO₂), and a copper atom. Alternatively, the conductive layer 205a preferably contains a conductive material having a function of inhibiting diffusion of oxygen (e.g., at least one of oxygen atoms and oxygen molecules).

When a conductive material having a function of inhibiting diffusion of hydrogen is used for the conductive layer 205a, impurities such as hydrogen contained in the conductive layer 205b can be inhibited from being diffused into the semiconductor layer 230 through the insulating layer 296 and the like. When a conductive material having a function of inhibiting diffusion of oxygen is used for the conductive layer 205a, the conductivity of the conductive layer 205b can be inhibited from being lowered because of oxidation. Examples of the conductive material having a function of inhibiting diffusion of oxygen include titanium, titanium nitride, tantalum, tantalum nitride, ruthenium, and ruthenium oxide. The conductive layer 205a can have a single-layer structure or a stacked-layer structure of the above-described conductive materials. For example, the conductive layer 205a preferably contains titanium nitride.

Furthermore, the conductive layer 205b is preferably formed using a conductive material containing tungsten, copper, or aluminum as its main component. For example, the conductive layer 205b preferably contains tungsten.

As described above, the conductive layer 205 can function as a second gate electrode. In that case, by changing the potential applied to the conductive layer 205 independently of the potential applied to the conductive layer 260, the threshold voltage (Vth) of the transistor 200I can be controlled. Specifically, when a negative potential is applied to the conductive layer 205, the Vth of the transistor 200I can be further increased and the off-state current can be reduced. Thus, a drain current at the time when the potential applied to the conductive layer 260 is 0 V can be smaller in the case where a negative potential is applied to the conductive layer 205 than in the case where the negative potential is not applied to the conductive layer 205.

The electrical resistivity of the conductive layer 205 is designed in consideration of the potential applied to the conductive layer 205, and the thickness of the conductive layer 205 depends on the electrical resistivity. The thickness of the insulating layer 296 is substantially equal to that of the conductive layer 205. The conductive layer 205 and the insulating layer 296 are preferably as thin as possible in the allowable range of the design of the conductive layer 205. The insulating layer 296 with a reduced thickness contains a smaller absolute amount of impurities such as hydrogen, inhibiting diffusion of the impurities into the semiconductor layer 230.

Although the stacked-layer structure of the conductive layer 205a and the conductive layer 205b is described above, the present invention is not limited to this structure. The conductive layer 205 may have a single-layer structure or a stacked-layer structure of three or more layers. For example, in the case where the conductive layer 205 has a three-layer structure, a conductive layer that contains a material similar to that of the conductive layer 205a can be further provided over the conductive layer 205b of the above-described stacked-layer structure of the conductive layer 205a and the conductive layer 205b. In that case, the level of the top surface of the conductive layer 205b is lower than that of an uppermost portion of the conductive layer 205a, and the above-described conductive layer can be formed to fill the depressed portion formed by the conductive layer 205a and the conductive layer 205b.

As materials used for the conductive layers 205, 242, 245, and 260, any of materials of conductive layers described in the other embodiments can be used in addition to the materials disclosed in this embodiment. As materials used for the insulating layers 295, 296, 291, 292, 241, 250, 235, 280, 297, and 298, any of materials of insulating layers described in the other embodiments can be used in addition to the materials disclosed in this embodiment.

The transistor 200I described in this embodiment can be used as a transistor included in the semiconductor device 10. The transistor 200I can have a high on-state current without increasing its footprint.

### <Materials for Transistor>

Next, materials that can be used for the transistors 200 (the transistors 200A, 200B, 200C, 200D, 200E, 200F, 200G, 200H, and 200I) are described.

### [Substrate]

In the case where a transistor is provided over a substrate, there is no particular limitation on materials used for the substrate. The material used for the substrate is determined considering whether it has or does not have light-transmitting properties or it has heat resistance that can withstand treatment with application of heat. As the substrate, an insulator substrate, a semiconductor substrate, or a conductor substrate can be used, for example. As the insulator substrate, a glass substrate of barium borosilicate glass, aluminoborosilicate glass, or the like, a ceramic substrate, a quartz substrate, a sapphire substrate, or a stabilized zirconia substrate (e.g., an yttria-stabilized zirconia substrate) can be used, for example. Alternatively, as the substrate, a semiconductor substrate, a flexible substrate, a resin substrate, or the like can be used.

Examples of the semiconductor substrate include a semiconductor substrate containing a material such as silicon or germanium and a compound semiconductor substrate containing a material such as silicon carbide, silicon germanium, gallium arsenide, indium phosphide, zinc oxide, or gallium oxide. Other examples include a semiconductor substrate in which an insulator region is provided in the above semiconductor substrate such as a silicon on insulator (SOI) substrate. The semiconductor substrate may be a single crystal semiconductor or a polycrystalline semiconductor.

Examples of the conductor substrate include a graphite substrate, a metal substrate, an alloy substrate, and a conductive resin substrate. Alternatively, a substrate including a metal nitride, a substrate including a metal oxide, or the like is given. Other examples include an insulator substrate provided with a conductive layer or a semiconductor layer, a semiconductor substrate provided with a conductive layer or an insulating layer, and a conductor substrate provided with a semiconductor layer or an insulating layer.

For the material of the flexible substrate, the resin substrate, or the like, polyester such as polyethylene terephthalate (PET) or polyethylene naphthalate (PEN), polyacrylonitrile, an acrylic resin, polyimide, polymethyl methacrylate, polycarbonate (PC), polyethersulfone (PES), polyamide (e.g., nylon or aramid), polysiloxane, a cycloolefin resin, polystyrene, polyamide-imide, polyurethane, polyvinyl chloride, polyvinylidene chloride, polypropylene, polytetrafluoroethylene (PTFE), an ABS resin, or cellulose nanofiber can be used, for example.

With the use of any of the materials described above for the substrate, a lightweight semiconductor device can be provided. Furthermore, with the use of any of the materials described above for the substrate, a shock-resistant semiconductor device can be provided. Furthermore, with the use of any of the materials described above for the substrate, a semiconductor device that is less likely to be broken can be provided. Alternatively, these substrates provided with elements can be used. Examples of the element provided over the substrate include a capacitor, a resistor, a switching element, a light-emitting element, and a memory element.

### [Insulating Layer]

An inorganic insulating film is used as each of the insulating layers (the insulating layers 202, 204, 206, 209, 295, 296, 291, 292, 294, 241, 257, 250, 258, 258a, 258b, 259, 264, 266, 268, 516, 235, 280, 297, 298, 522, 524, 541, 554, 580, 574, 581, and the like). Examples of the inorganic insulating film include an oxide insulating film, a nitride insulating film, an oxynitride insulating film, and a nitride oxide insulating film. Examples of the oxide insulating film include a silicon oxide film, an aluminum oxide film, a magnesium oxide film, a gallium oxide film, a germanium oxide film, an yttrium oxide film, a zirconium oxide film, a lanthanum oxide film, a neodymium oxide film, a hafnium oxide film, a tantalum oxide film, a cerium oxide film, a gallium zinc oxide film, and a hafnium aluminate film. Examples of the nitride insulating film include a silicon nitride film and an aluminum nitride film. Examples of the oxynitride insulating film include a silicon oxynitride film, an aluminum oxynitride film, a gallium oxynitride film, an yttrium oxynitride film, and a hafnium oxynitride film. Examples of the nitride oxide insulating film include a silicon nitride oxide film and an aluminum nitride oxide film. An organic insulating film can also be used as the insulating layer included in the semiconductor device.

Note that in this specification and the like, an oxynitride refers to a material that contains more oxygen than nitrogen, and a nitride oxide refers to a material that contains more nitrogen than oxygen. For example, silicon oxynitride refers to a material that contains more oxygen than nitrogen, and silicon nitride oxide refers to a material that contains more nitrogen than oxygen.

With further miniaturization and higher integration of a transistor, for example, a problem such as generation of a leakage current may arise because of a thinned gate insulating layer. When a high-k material is used for the insulating layer functioning as a gate insulating layer such as the insulating layer 204 and the insulating layer 264, the voltage at the time of operation of the transistor can be reduced while the physical thickness is maintained. In addition, the equivalent oxide thickness (EOT) of the gate insulating layer can be reduced. By contrast, when a material with a low dielectric constant is used for the insulating layer functioning as an interlayer film, parasitic capacitance generated between wirings can be reduced. Thus, it is important to select a material depending on the function of an insulating layer. Note that a material with a low dielectric constant is a material with high dielectric strength.

Examples of a material with a high dielectric constant (a high-k material) include aluminum oxide, gallium oxide, hafnium oxide, tantalum oxide, zirconium oxide, hafnium zirconium oxide, an oxide containing aluminum and hafnium, an oxynitride containing aluminum and hafnium, an oxide containing silicon and hafnium, an oxynitride containing silicon and hafnium, and a nitride containing silicon and hafnium.

Examples of a material with a low dielectric constant include inorganic insulating materials such as silicon oxide, silicon oxynitride, and silicon nitride oxide, and resins such as polyester, polyolefin, polyamide (e.g., nylon and aramid), polyimide, polycarbonate, and an acrylic resin. Other examples of an inorganic insulating material with a low dielectric constant include silicon oxide to which fluorine is added, silicon oxide to which carbon is added, and silicon oxide to which carbon and nitrogen are added. Another example is porous silicon oxide. Note that these silicon oxides may contain nitrogen.

### [Conductive Layer]

For each of the conductive layers (the conductive layers 205, 208, 219, 242, 245, 255, 260, 267, 261, 265, 545, and 560, the conductive layer 505, and the like) included in the transistor 200, it is preferable to use a metal element selected from aluminum, chromium, copper, silver, gold, platinum, zinc, tantalum, nickel, titanium, iron, cobalt, molybdenum, tungsten, hafnium, vanadium, niobium, manganese, magnesium, zirconium, beryllium, indium, ruthenium, iridium, strontium, lanthanum, and the like; an alloy containing any of the above metal elements as a component; an alloy containing a combination of the above metal elements; or the like. As an alloy containing any of the above metal elements, a nitride of the alloy or an oxide of the alloy can be used. For example, tantalum nitride, titanium nitride, a nitride containing titanium and aluminum, a nitride containing tantalum and aluminum, ruthenium oxide, ruthenium nitride, an oxide containing strontium and ruthenium, an oxide containing lanthanum and nickel, or the like is preferably used. Alternatively, a semiconductor having high electric conductivity, typified by polycrystalline silicon containing an impurity element such as phosphorus, or silicide such as nickel silicide can also be used.

A conductive material containing nitrogen, such as a nitride containing tantalum, a nitride containing titanium, a nitride containing molybdenum, a nitride containing tungsten, a nitride containing ruthenium, a nitride containing tantalum and aluminum, or a nitride containing titanium and aluminum; a conductive material containing oxygen, such as ruthenium oxide, an oxide containing strontium and ruthenium, or an oxide containing lanthanum and nickel; or a material containing a metal element such as titanium, tantalum, or ruthenium is preferable because it is a conductive material that is not easily oxidized, a conductive material having a function of inhibiting oxygen diffusion, or a material maintaining its conductivity even after absorbing oxygen. Examples of the conductive material containing oxygen include indium oxide containing tungsten oxide, indium oxide containing titanium oxide, indium tin oxide (also referred to as ITO), indium tin oxide containing titanium oxide, indium tin oxide to which silicon is added (also referred to as ITSO), indium zinc oxide (also referred to as IZO (registered trademark)), and indium zinc oxide containing tungsten oxide. In this specification and the like, a conductive layer formed using the conductive material containing oxygen may be referred to as an oxide conductive layer.

A conductive material containing tungsten, copper, or aluminum as its main component is preferable because it has high conductivity.

Alternatively, conductive layers formed using any of the above materials can be stacked. For example, a stacked-layer structure combining a material containing any of the above metal elements and a conductive material containing oxygen can be employed. Alternatively, a stacked-layer structure combining a material containing any of the above metal elements and a conductive material containing nitrogen can be employed. Further alternatively, a stacked-layer structure combining a material containing any of the above metal elements, a conductive material containing oxygen, and a conductive material containing nitrogen can be employed.

In the case where an oxide semiconductor is used for the semiconductor layer 203 of the transistor 200A or the transistor 200B, for example, the conductive layer functioning as the gate electrode such as the conductive layers 205 and 219 preferably employs a stacked-layer structure combining a material containing any of the above metal elements and a conductive material containing oxygen. In that case, the conductive material containing oxygen is preferably provided on the semiconductor layer 203 side. When the conductive material containing oxygen is provided on the semiconductor layer 203 side, oxygen released from the conductive material is easily supplied to the channel formation region in the semiconductor layer 203.

In the case where an oxide semiconductor, which is one kind of a metal oxide, is used for the semiconductor layer 203, the semiconductor layer 263, or the semiconductor layer 520, each of the conductive layers 208a, 208b, 255, 261, 542a, and 542b is in contact with the semiconductor layer 203, the semiconductor layer 263, or the semiconductor layer 520, and thus is preferably formed using a conductive material that is not easily oxidized, a conductive material that maintains its low electric resistance even after being oxidized, a metal oxide that has conductivity (also referred to as an oxide conductor), or a conductive material that has a function of inhibiting diffusion of oxygen. Examples of the conductive material include a conductive material containing nitrogen and a conductive material containing oxygen. Thus, a decrease in conductivity of the conductive layers 208a, 208b, 255, 261, 542a, and 542b can be inhibited.

When a conductive material containing oxygen is used for each of the conductive layers 208a, 208b, 255, 261, 542a, and 542b, each of the conductive layers 208a, 208b, 255, 261, 542a, and 542b can maintain its conductivity even after absorbing oxygen. It is also preferable that an insulating layer containing excess oxygen be used as the insulating layer in contact with each of the conductive layers 208a, 208b, 255, 261, 542a, and 542b in order that each of the conductive layers 208a, 208b, 255, 261, 542a, and 542b can maintain its conductivity. For each of the conductive layers 208a, 208b, 255, 261, 542a, and 542b, ITO, ITSO, IZO (registered trademark), or the like can be used, for example.

### [Semiconductor Layer]

For each of the semiconductor layers (the semiconductor layers 203, 230, 263, 520, and the like), one or a combination of a single crystal semiconductor, a polycrystalline semiconductor, a microcrystalline semiconductor, an amorphous semiconductor, and the like can be used. As a semiconductor material, silicon and germanium can be used, for example. Alternatively, a compound semiconductor such as silicon germanium, silicon carbide, gallium arsenide, or a nitride semiconductor can be used. As the compound semiconductor, a semiconducting organic substance or a semiconducting metal oxide (also referred to as an oxide semiconductor) can be used. These semiconductor materials can contain impurities as dopants.

Note that a single-element semiconductor or a compound semiconductor can be used for the semiconductor layer. Examples of the single-element semiconductor include silicon and germanium. Examples of the compound semiconductor include gallium arsenide and silicon germanium. Other examples of the compound semiconductor include an organic semiconductor and a nitride semiconductor. Note that the oxide semiconductor is also one kind of the compound semiconductor. These semiconductor materials can contain impurities as dopants.

In the case of using silicon for the semiconductor layer, examples of silicon that can be used for the semiconductor layer include single crystal silicon, polycrystalline silicon, microcrystalline silicon, and amorphous silicon. An example of polycrystalline silicon is low-temperature polysilicon (LTPS).

For example, when the transistor 200A or the transistor 200B contains silicon in the semiconductor layer 203 and contains phosphorus or arsenic as an n-type dopant in the regions 203a and 203c of the semiconductor layer 203, the transistor can function as an n-type transistor. Alternatively, when the transistor 200A or the transistor 200B contains boron as a p-type dopant in the regions 203a and 203c of the semiconductor layer 203, the transistor can function as a p-type transistor. Note that in the case where the regions 203a and 203c of the semiconductor layer 203 contain both an n-type dopant and a p-type dopant, the conductivity type of the dopant with a higher concentration is likely to be exhibited.

For the semiconductor layer of the transistor, a two-dimensional material functioning as a semiconductor can also be used. The two-dimensional material is also referred to as a layered material, and generally refers to a group of materials having a layered crystal structure. In the layered crystal structure, layers formed by covalent bonding or ionic bonding are stacked with bonding such as the van der Waals bonding, which is weaker than covalent bonding or ionic bonding. The layered material has high electrical conductivity in a unit layer, that is, high two-dimensional electrical conductivity. When a material that functions as a semiconductor and has high two-dimensional electrical conductivity is used for a semiconductor layer, the transistor can have a high on-state current.

Examples of the layered material include graphene, silicene, and chalcogenide. Chalcogenide is a compound containing chalcogen (an element belonging to Group 16). Examples of chalcogenide include transition metal chalcogenide and chalcogenide of Group 13 elements. Specific examples of the transition metal chalcogenide which can be used for a semiconductor layer of a transistor include molybdenum sulfide (typically MoS₂), molybdenum selenide (typically MoSe₂), molybdenum telluride (typically MoTe₂), tungsten sulfide (typically WS₂), tungsten selenide (typically WSc₂), tungsten telluride (typically WTe₂), hafnium sulfide (typically HfS₂), hafnium selenide (typically HfSe₂), zirconium sulfide (typically ZrS₂), and zirconium selenide (typically ZrSe₂).

In the case where an oxide semiconductor which is one kind of a metal oxide is used for the semiconductor layer, the band gap of the metal oxide is preferably greater than or equal to 2.0 eV, further preferably greater than or equal to 2.5 eV. The use of such a metal oxide having a wide band gap for the semiconductor layer can significantly reduce the amount of the off-state current of the transistor. The off-state current of the OS transistor is small, so that power consumption of the semiconductor device can be reduced. Note that an oxide semiconductor will be described in detail in Embodiment 3.

The structures described in this embodiment can be used in combination with any of the structures described in the other embodiments as appropriate.

### Embodiment 4

In this embodiment, an oxide semiconductor layer that can be used as the semiconductor layer of the transistor will be described.

### [Oxide Semiconductor Layer]

It is preferable that the oxide semiconductor layer of one embodiment of the present invention contain a metal oxide having crystallinity. Examples of the structure of a metal oxide having crystallinity include a c-axis aligned crystalline (CAAC) structure, a polycrystalline structure, and a nano-crystal (nc) structure. By using a metal oxide having crystallinity for the oxide semiconductor layer, the density of defect states in the oxide semiconductor layer can be reduced. Thus, the reliability of a transistor including the oxide semiconductor layer of one embodiment of the present invention can be increased, and the reliability of a memory device including the transistor can be increased.

It is particularly preferable that the oxide semiconductor layer of one embodiment of the present invention include a metal oxide having a CAAC structure. The CAAC structure is a crystal structure in which a plurality of microcrystals (typically, a plurality of microcrystals each having a hexagonal crystal structure) have c-axis alignment and are connected on the a-b plane without alignment. When a cross section of an oxide semiconductor layer having a CAAC structure is observed using a high-definition transmission electron microscope (TEM) image, it can be confirmed that metal atoms are arranged in a layered manner in a crystal part. Thus, the oxide semiconductor layer having a CAAC structure can be regarded as having a structure including the layered crystal parts.

The crystallinity of the oxide semiconductor layer can be analyzed by X-ray diffraction (XRD), TEM, or electron diffraction (ED), for example. Alternatively, any of these methods may be combined with each other for the analysis.

Note that there is no particular limitation on the crystallinity of a semiconductor material included in the oxide semiconductor layer. For example, the oxide semiconductor layer may include one or more of an amorphous semiconductor (a semiconductor having an amorphous structure), a single crystal semiconductor (a semiconductor having a single crystal structure), and a semiconductor having other crystallinity than single crystal (a microcrystalline semiconductor, a polycrystalline semiconductor, or a semiconductor partly including crystal regions). The oxide semiconductor layer having crystallinity can inhibit deterioration of the transistor characteristics in some cases.

Examples of the metal oxide included in the oxide semiconductor layer of one embodiment of the present invention include indium oxide (InOₓ, x is a given number), gallium oxide (GaOₓ, x is a given number), and zinc oxide (ZnOₓ, x is a given number). The metal oxide of one embodiment of the present invention preferably contains at least indium (In) or zinc (Zn). The metal oxide preferably contains two or three selected from indium, an element M, and zinc. The element M is a metal element or metalloid element that has a high bonding energy with oxygen, such as a metal element or metalloid element whose bonding energy with oxygen is higher than that of indium. Specific examples of the element M include aluminum, gallium, tin, yttrium, titanium, vanadium, chromium, manganese, iron, cobalt, nickel, zirconium, molybdenum, hafnium, tantalum, tungsten, lanthanum, cerium, neodymium, magnesium, calcium, strontium, barium, boron, silicon, germanium, and antimony. The element M contained in the metal oxide is preferably one or more of the above elements, further preferably one or more selected from aluminum, gallium, tin, and yttrium, and still further preferably gallium. When the element M contained in the metal oxide is gallium, the metal oxide of one embodiment of the present invention preferably contains one or more selected from indium, gallium, and zinc. In this specification and the like, a metal element and a metalloid element may be collectively referred to as a “metal element”, and a “metal element” in this specification and the like may refer to a metalloid element.

As the metal oxide of one embodiment of the present invention, for example, indium zinc oxide (In—Zn oxide), indium tin oxide (In—Sn oxide), indium titanium oxide (In—Ti oxide), indium gallium oxide (In—Ga oxide), indium gallium aluminum oxide (In—Ga-Al oxide), indium gallium tin oxide (also referred to as In—Ga—Sn oxide or IGTO), gallium zinc oxide (also referred to as Ga—Zn oxide or GZO), aluminum zinc oxide (also referred to as Al—Zn oxide or AZO), indium aluminum zinc oxide (also referred to as In—Al—Zn oxide or IAZO), indium tin zinc oxide (also referred to as In—Sn—Zn oxide), indium titanium zinc oxide (In—Ti—Zn oxide), indium gallium zinc oxide (also referred to as In—Ga—Zn oxide or IGZO), indium gallium tin zinc oxide (also referred to as In—Ga—Sn—Zn oxide or IGZTO), or indium gallium aluminum zinc oxide (also referred to as In—Ga—Al—Zn oxide, IGAZO, or IAGZO) can be used. Alternatively, indium tin oxide containing silicon (also referred to as ITSO), gallium tin oxide (Ga—Sn oxide), aluminum tin oxide (Al—Sn oxide), or the like can be used.

By increasing the proportion of the number of indium atoms in the total number of atoms of all the metal elements included in the metal oxide, a high on-state current and high frequency characteristics of the transistor can be achieved. Note that also in the case of using indium oxide as the metal oxide, the transistor can have a high on-state current and high frequency characteristics.

Instead of or in addition to indium, the metal oxide can contain one or more kinds of metal elements whose period number in the periodic table is large. The larger the overlap between orbits of metal elements is, the more likely it is that the metal oxide will have high carrier conductivity. Thus, when a metal element with a large period number in the periodic table is contained in the metal oxide, the field-effect mobility of the transistor can be increased in some cases. Examples of the metal element with a large period number in the periodic table include metal elements belonging to Period 5 and metal elements belonging to Period 6. Specific examples of the metal element include yttrium, zirconium, silver, cadmium, tin, antimony, barium, lead, bismuth, lanthanum, cerium, praseodymium, neodymium, promethium, samarium, and europium. Note that lanthanum, cerium, praseodymium, neodymium, promethium, samarium, and europium are called light rare-earth elements.

The metal oxide can contain one or more kinds selected from nonmetallic elements. A transistor including the metal oxide containing a nonmetallic element can have high field-effect mobility in some cases. Examples of the nonmetallic element include carbon, nitrogen, phosphorus, sulfur, selenium, fluorine, chlorine, bromine, and hydrogen.

By increasing the proportion of the number of zinc atoms in the total number of atoms of all the metal elements contained in the metal oxide, the metal oxide has high crystallinity, so that diffusion of impurities in the metal oxide can be inhibited. Consequently, a change in electrical characteristics of the transistor is inhibited and the transistor can have high reliability.

By increasing the proportion of the element M atoms in the total number of atoms of all the metal elements contained in the metal oxide, oxygen vacancies can be inhibited from being formed in the metal oxide. Accordingly, generation of carriers due to oxygen vacancies is inhibited, which makes the off-state current of the transistor low. Furthermore, changes in the electrical characteristics of the transistor can be reduced to improve the reliability of the transistor. In the description of this embodiment, In—Ga—Zn oxide is sometimes taken as an example of the metal oxide.

The oxide semiconductor layer of one embodiment of the present invention has crystallinity. The oxide semiconductor layer of one embodiment of the present invention preferably has a CAAC structure.

The oxide semiconductor layer of one embodiment of the present invention can be formed by forming a metal oxide by at least two kinds of film formation methods. For example, the oxide semiconductor layer of one embodiment of the present invention can be formed by forming a metal oxide using a first film formation method and a second film formation method. Note that the oxide semiconductor layer formed by using at least two kinds of film formation methods may be referred to as a hybrid OS.

The oxide semiconductor layer of one embodiment of the present invention can be formed in the following manner: a metal oxide is formed as a first layer by a first film formation method, and then a metal oxide is formed as a second layer over the first layer by a second film formation method. In that case, as the first film formation method, a film formation method that causes less damage to the formation surface than the second film formation method is preferably used. When a film formation method that causes less damage to the formation surface is used as the first film formation method, formation of a mixed layer at an interface between the oxide semiconductor layer and a layer serving as the formation surface of the oxide semiconductor layer can be inhibited. Moreover, entry of impurities such as silicon into the second layer can be inhibited, so that the crystallinity of the oxide semiconductor layer can be increased.

Examples of the first film formation method include an ALD method, a chemical vapor deposition (CVD) method, a molecular beam epitaxy (MBE) method, and a wet process. Examples of the CVD method include a plasma enhanced CVD (PECVD) method, a thermal CVD method, a photo CVD method, and a metal organic CVD (MOCVD) method. Examples of the wet process include a spray coating method. An ALD method and a CVD method are suitable as the first film formation method because damage to the formation surface can be inhibited as compared with a sputtering method described later.

Examples of the ALD method include a thermal ALD method, in which a precursor and a reactant react with each other only by a thermal energy, and a PEALD method, in which a reactant excited by plasma is used.

An ALD method enables atomic layers to be deposited one by one, and has various advantages such as formation of an extremely thin film, film formation on a component with a high aspect ratio or a surface with a large step, formation of a film with few defects such as pinholes, film formation with excellent coverage, and low-temperature film formation. A PEALD method utilizing plasma is preferable, because film formation at lower temperature is possible in some cases. Note that some precursors used in the ALD method contain carbon or chlorine. Thus, a film formed by the ALD method sometimes contains carbon or chlorine in a larger quantity than a film formed by another film formation method. Note that these elements can be quantified by X-ray photoelectron spectroscopy (XPS) or secondary ion mass spectrometry (SIMS). The film formation method of the metal oxide of one embodiment of the present invention, which employs an ALD method and one or both of a film formation condition with a high substrate temperature and impurity removal treatment, might form a film with smaller amounts of carbon and chlorine than a method employing an ALD method and neither the condition nor the treatment.

Unlike a film formation method in which particles ejected from a target or the like are deposited, in an ALD method, a film is formed by reaction at a surface of an object to be processed. Thus, an ALD method can provide good step coverage, almost regardless of the shape of an object to be processed. In particular, an ALD method allows excellent step coverage and excellent thickness uniformity and can be suitably used to cover a surface of an opening portion with a high aspect ratio, for example.

A high-quality film can be obtained at a relatively low temperature through a plasma CVD method. A thermal CVD method does not use plasma and thus causes less plasma damage to an object to be processed. A thermal CVD method yields a film with few defects because of no plasma damage during film formation.

Examples of the second film formation method include a sputtering method and a pulsed laser deposition (PLD) method. The metal oxide formed by the second film formation method is likely to have a CAAC structure.

Note that as the first layer, a metal oxide having a microcrystalline structure or an amorphous structure that has lower crystallinity than a CAAC structure is formed in some cases, for example. Formation of the second layer having high crystallinity over the first layer having low crystallinity or the formation of the first and second layers followed by heat treatment can increase the crystallinity of the first layer using the second layer as a nucleus. Accordingly, the crystallinity can be increased in the whole oxide semiconductor layer including the vicinity of the interface with the formation surface.

Furthermore, a third layer can be formed over the second layer. Since the second layer has high crystallinity, the crystal growth of the third layer can be achieved with the use of the crystal of the second layer as a nucleus or a seed. Thus, the third layer can be crystallized even when a film formation method that easily gives crystallinity is not used as the film formation method of the third layer. Here, when the third layer is formed by a film formation method that provides higher coverage than that of the second layer, the whole oxide semiconductor layer can have both high crystallinity and high coverage, for example.

For example, the oxide semiconductor layer of one embodiment of the present invention can be formed in the following manner: a metal oxide is formed as the first layer by the first film formation method, a metal oxide is formed as the second layer by the second film formation method, and a metal oxide is formed as the third layer by the first film formation method. Specifically, an ALD method can be used as the first film formation method, and a sputtering method can be used as the second film formation method. An ALD method is a film formation method that achieves higher coverage than a sputtering method, and when an ALD method is used as the film formation method of the first layer and the third layer, the coverage with the oxide semiconductor layer can be improved. Thus, the oxide semiconductor layer can suitably cover a step, an opening portion, or the like with a high aspect ratio.

### [Formation Method of Oxide Semiconductor Layer]

The semiconductor layer 230 that is an oxide semiconductor layer can be formed by, for example, forming the semiconductor layer 230a over a layer 229 serving as the formation surface by an ALD method, forming the semiconductor layer 230b that is an oxide semiconductor layer over the semiconductor layer 230a that is an oxide semiconductor layer by a sputtering method, and forming the semiconductor layer 230c that is an oxide semiconductor layer over the semiconductor layer 230b by an ALD method. Furthermore, heat treatment is preferably performed after the semiconductor layer 230 that is an oxide semiconductor layer is formed. By performing the heat treatment, the crystallinity of the semiconductor layer 230 can be increased. Here, the heat treatment is not limited to the treatment with application of heat. For example, the heat treatment may be performed with heat applied in the manufacturing process.

The layer 229 corresponds to the insulating layer 202, the insulating layer 256, the insulating layer 258, or the like described in the above embodiment. The layer 229 does not necessarily have crystallinity. In the case where the layer 229 has crystallinity, a crystal structure with low lattice compatibility with the metal oxide contained in the semiconductor layer 230 may be employed.

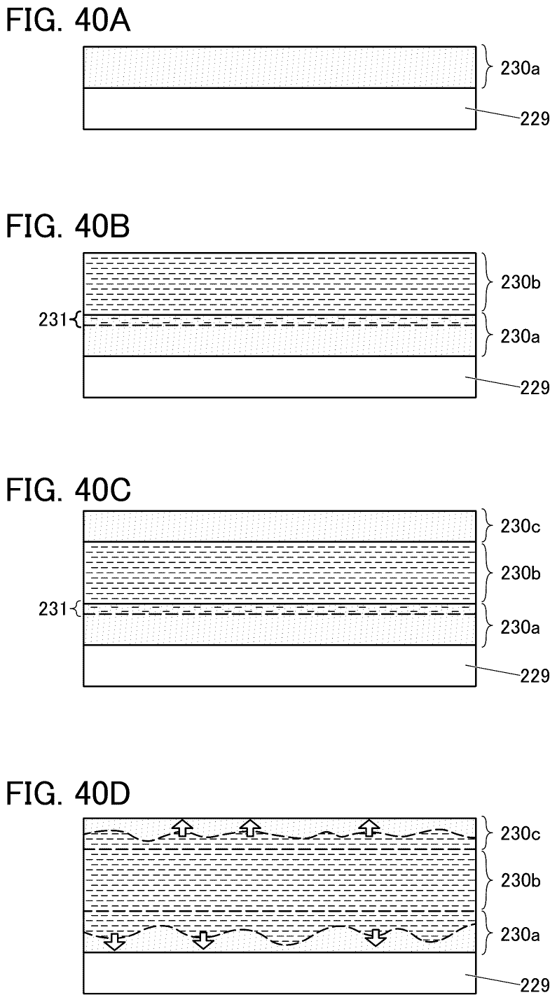

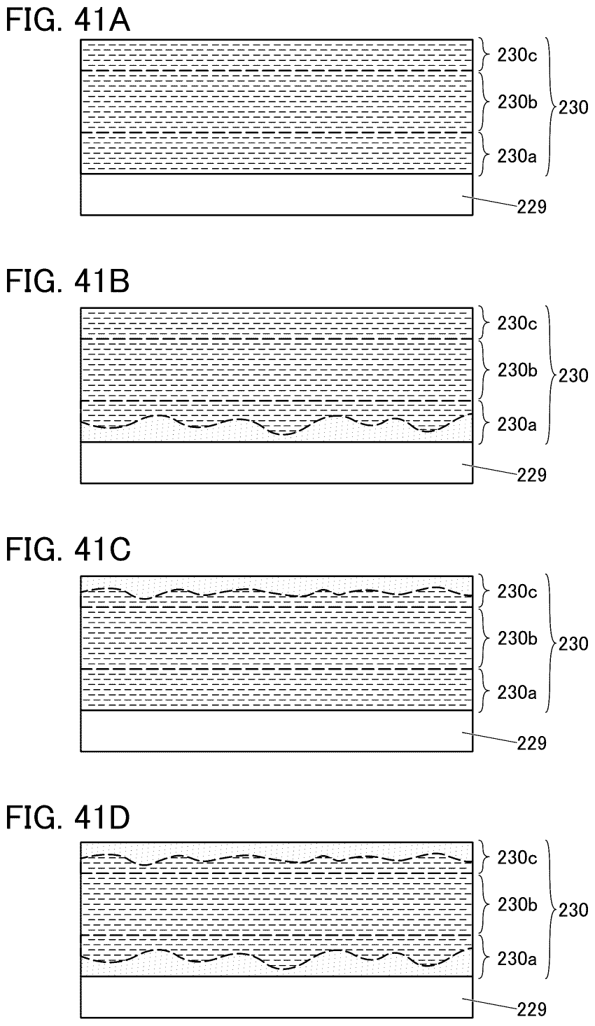

An example of a method for forming the semiconductor layer 230 is described with reference to FIGS. 40A to 40D and FIGS. 41A to 41D.

In the case where a metal oxide film is formed by a sputtering method, damage to the formation surface due to, for example, a sputtering particle or energy applied to the substrate side by a sputtering particle or the like might cause alloying of a component contained in the metal oxide film and a component contained in a layer on which the metal oxide film is formed. In the case where the alloying occurs, it is difficult to increase the crystallinity of the alloyed region even when heat treatment described later is performed. When an oxide semiconductor layer including the alloyed region is used for a transistor, the initial characteristics or reliability of the transistor might be adversely affected. Therefore, it is preferable to inhibit alloying of the component contained in the metal oxide film and the component contained in the layer on which the metal oxide film is formed.

Thus, first, the semiconductor layer 230a is formed over the layer 229 by an ALD method (FIG. 40A). Next, the semiconductor layer 230b is formed over the semiconductor layer 230a by a sputtering method (FIG. 40B).

In the method for forming the oxide semiconductor layer of one embodiment of the present invention, the semiconductor layer 230a is formed between the semiconductor layer 230b and the layer 229 by a film formation method that causes less damage to the formation surface; thus, alloying of a component contained in the semiconductor layer 230 and a component contained in the layer 229 can be inhibited, and the crystallinity of the semiconductor layer 230 can be further increased.

With the above structure, the thickness of the alloyed region can be reduced or reduced to have a thickness that is difficult to observe. For example, the thickness of the alloyed region can be greater than or equal to 0 nm and less than or equal to 3 nm, preferably greater than or equal to 0 nm and less than or equal to 2 nm, further preferably greater than or equal to 0 nm and less than or equal to 1 nm, still further preferably greater than or equal to 0 nm and less than 0.3 nm. Note that FIGS. 40A and 40B illustrate an example where the alloyed region is not formed between the layer 229 and the semiconductor layer 230a.

Note that the thickness of the alloyed region can sometimes be calculated by composition line analysis of the region and its vicinity with SIMS or energy dispersive X-ray spectroscopy (EDX).

For example, EDX line analysis is performed on the region and its vicinity with the direction perpendicular to the formation surface of the semiconductor layer 230a as the depth direction. Next, in the profile of quantitative values of elements in the depth direction, which is obtained from the analysis, the depth at which the quantitative value of a metal that is the main component of the semiconductor layer 230a and is not the main component of a layer (here, the layer 229) serving as a formation surface (the metal is In when the semiconductor layer 230a contains In) becomes half is defined as the depth (position) of the interface between the region and the semiconductor layer 230a. The depth at which the quantitative value of an element (e.g., Si) that is a main component of the layer to be the formation surface and that is not a main component of the semiconductor layer 230a becomes half is defined as the depth (position) of the interface between the region and the layer to be the formation surface. In the above manner, the thickness of the alloyed region can be calculated.

When the thickness of the alloyed region in the oxide semiconductor layer of one embodiment of the present invention is observed by EDX analysis, the thickness is greater than or equal to 0 nm and less than or equal to 3 nm, preferably greater than or equal to 0 nm and less than or equal to 2 nm, further preferably greater than or equal to 0 nm and less than or equal to 1 nm, still further preferably greater than or equal to 0 nm and less than 0.3 nm, for example.

For example, in the case where a silicon oxide layer is used as the layer 229 and SIMS analysis of the semiconductor layer 230 formed over the layer 229 is performed, the depth at which the silicon concentration is the intensity of 50% of the maximum concentration value of the layer 229 is defined as the interface, and the distance between the interface and the depth at which the silicon concentration decreases to 1.0×10²¹ atoms/cm³, preferably 5.0×10²⁰ atoms/cm³, further preferably 1.0×10²⁰ atoms/cm³ is defined as a thickness t_s2. The thickness t_s2 is preferably less than or equal to 3 nm, further preferably less than or equal to 2 nm.

When the thickness of the alloyed region is reduced, the thickness t_s2 can be a value within the above range.

Note that when the alloyed region is reduced, a CAAC structure can be formed in the vicinity of the formation surface. Here, the vicinity of the formation surface refers to, for example, a region ranging from the formation surface of the semiconductor layer 230 to greater than 0 nm and less than or equal to 3 nm, preferably greater than 0 nm and less than or equal to 2 nm, further preferably greater than or equal to 1 nm and less than or equal to 2 nm in a direction substantially perpendicular to the formation surface of the semiconductor layer 230.

Note that the CAAC structure in the vicinity of the formation surface can be confirmed in observation using TEM in some cases. For example, in a cross-sectional observation of the semiconductor layer 230 using a high-definition TEM, bright spots arranged in a layered manner in a direction parallel to the formation surface are observed in the vicinity of the formation surface.

Note that in the case where the semiconductor layer 230a is formed by an ALD method, an oxide semiconductor layer having a microcrystalline structure or an amorphous structure that has lower crystallinity than the CAAC structure is formed in some cases. That is, in the formation stage illustrated in FIG. 40A, the semiconductor layer 230a sometimes includes a region having lower crystallinity than the semiconductor layer 230b.

The semiconductor layer 230b preferably has a composition suitable for forming the CAAC structure.

When the semiconductor layer 230b is formed by a sputtering method, a mixed layer 231 is formed on the surface or its vicinity of the semiconductor layer 230a. A fine crystal region is sometimes formed in the mixed layer 231 by, for example, a sputtering particle or energy applied to the substrate side by a sputtering particle or the like when the semiconductor layer 230b is formed. In the following heat treatment step, the mixed layer 231 or a fine crystal region formed in the mixed layer 231 serves as a nucleus, and at least part of the semiconductor layer 230a is crystallized in some cases.

In the formation of the semiconductor layer 230b by a sputtering method, substrate heating is preferably performed. In formation of the metal oxide, the substrate temperature (stage temperature) at the time of forming the metal oxide is increased, whereby a metal oxide with high crystallinity can be formed in some cases.

Next, the semiconductor layer 230c is formed over the semiconductor layer 230b by an ALD method (FIG. 40C). For the formation of the semiconductor layer 230c by an ALD method, the method for forming the semiconductor layer 230a can be referred to.

When the semiconductor layer 230c is formed over the semiconductor layer 230b having a CAAC structure by an ALD method, the semiconductor layer 230c sometimes epitaxially grows with the semiconductor layer 230b as a nucleus. Thus, the semiconductor layer 230c may include a region having a CAAC structure at the time of forming the semiconductor layer 230c. The region having a CAAC structure is preferably formed throughout the semiconductor layer 230c.

Next, a heat treatment step may be performed. By the heat treatment step, the crystallinity of the region having a CAAC structure in the semiconductor layer 230c is increased in some cases. In the case where the region is formed only below the semiconductor layer 230c after the film formation by an ALD method, the region may be extended upward by the heat treatment step (FIG. 40D). That is, by the heat treatment, the region having a CAAC structure is sometimes formed throughout the semiconductor layer 230c.

At least part of the semiconductor layer 230a preferably has a CAAC structure by the heat treatment step (FIG. 40D). The CAAC structure is expected to be easily generated when the mixed layer 231 formed in the semiconductor layer 230a becomes a nucleus or a seed in the formation of the semiconductor layer 230b. The region of the semiconductor layer 230a having a CAAC structure is preferably wide, and the CAAC structure preferably reaches the vicinity of the layer 229.

Since the CAAC region extends from the upper portion to the lower portion of the semiconductor layer 230a, the CAAC region can extend to the vicinity of the layer 229, regardless of the material and crystallinity of the layer 229. For example, the semiconductor layer 230a with high crystallinity can be formed even when the layer 229 has an amorphous structure. Thus, the method for forming the oxide semiconductor layer of one embodiment of the present invention is particularly suitable in the case where the layer serving as the formation surface has an amorphous structure.

FIGS. 40A to 40D are cross-sectional views illustrating a method for forming the metal oxide of one embodiment of the present invention. FIGS. 40A to 40D can be regarded as conceptual diagrams illustrating a formation model of the metal oxide of one embodiment of the present invention. As illustrated in FIGS. 40A to 40D, the semiconductor layers 230a and 230c have high crystallinity with the use of the semiconductor layer 230b having high crystallinity as a nucleus or a seed. Specifically, the crystallinity of the semiconductor layer 230a may be increased at the time of forming the semiconductor layer 230b or by heat treatment after forming the semiconductor layer 230c. The crystallinity of the semiconductor layer 230c may be increased at the time of forming the semiconductor layer 230c or by heat treatment after forming the semiconductor layer 230c. Note that the heat treatment has an assisting function for increasing crystallinity.

As described above, in the method for forming the metal oxide of one embodiment of the present invention, the crystallinity of the oxide semiconductors (here, the semiconductor layers 230a and 230c) above and below the semiconductor layer 230b can be increased with use of the semiconductor layer 230b with high crystallinity (i.e., CAAC) as a nucleus or a seed. Thus, the crystallinity of the whole oxide semiconductor can be increased. In other words, the semiconductor layer 230b is used as a nucleus or a seed to cause solid-phase growths of the oxide semiconductors above and below the semiconductor layer 230b, so that an oxide semiconductor with high crystallinity can be formed. An oxide semiconductor formed by such a film formation method, here, a CAAC film, can be referred to as an axial growth CAAC (AG CAAC). Although FIGS. 41A to 41D illustrate a structure example including the semiconductor layers 230a, 230b, and 230c, one embodiment of the present invention is not limited thereto. For example, a structure including the semiconductor layers 230a and 230b can also be referred to as an AG CAAC.

A region having a CAAC structure preferably exists widely throughout the semiconductor layer 230. FIG. 41A illustrates a state where the semiconductor layers 230a, 230b, and 230c are crystallized. In that case, a boundary between the semiconductor layer 230b and the semiconductor layer 230a or 230c is not observed in some cases. In some cases, the semiconductor layer 230 can be expressed as one layer in which interfaces are not clearly observed. The semiconductor layer 230 can be expressed as a single layer in some cases.

In addition, part of the semiconductor layer 230a or 230c is not crystallized in some cases. An example in FIG. 41B illustrates a state where the vicinity of the interface between the layer 229 and the semiconductor layer 230a is not crystallized. FIG. 41C illustrates a state where the vicinity of the surface of the semiconductor layer 230c is not crystallized. FIG. 41D illustrates a state where the vicinity of the interface between the layer 229 and the semiconductor layer 230a and the vicinity of the surface of the semiconductor layer 230c are not crystallized.

Increasing the crystallinity of the oxide semiconductor layer inhibits an increase in the electric resistance of the semiconductor layer of the transistor including the oxide semiconductor layer or improves the initial characteristics (in particular, the on-state current) of the transistor, so that a transistor suitable for high-speed driving can be expected to be manufactured. In addition, the reliability of the transistor can be improved and the amount of the on-state current can be increased.

The whole oxide semiconductor layer of one embodiment of the present invention has high crystallinity. Thus, in the semiconductor layer 230 where the semiconductor layers 230a, 230b, and 230c are stacked, a boundary between the stacked films is not observed in some cases. In particular, after heat treatment, a boundary between the stacked films is difficult to observe in some cases. The presence or absence of a boundary between the stacked films can be confirmed with TEM, for example.

As described above, when a metal oxide with a high In content is used for a transistor, the field-effect mobility of the transistor can be increased. Meanwhile, an oxide semiconductor with a high In content tends to be polycrystallized. The use of a metal oxide having a polycrystalline structure for a transistor adversely affects the initial characteristics or reliability of the transistor. Thus, when an oxide semiconductor with a high In content is used for one or both of the semiconductor layer 230a and the semiconductor layer 230c, crystals reflecting orientations of crystals included in the semiconductor layer 230b are formed, so that polycrystallization can be inhibited.

It is preferable that crystals included in the semiconductor layer 230b and crystals included in the semiconductor layer 230a or 230c have a small lattice mismatch degree. Thus, the semiconductor layer 230a or the semiconductor layer 230c can form crystals reflecting the orientation of crystals included in the semiconductor layer 230b. In this case, in cross-sectional observation of the semiconductor layer 230 using a high-definition TEM, for example, bright spots arranged in a layered manner in a direction parallel to the formation surface are observed in the semiconductor layer 230a or 230c.

When the crystals included in the semiconductor layer 230b and the crystals included in the semiconductor layer 230a or 230c have a small lattice mismatch degree, there is no particular limitation on the crystal structure of the semiconductor layer 230a or 230c. The crystal structure of the semiconductor layer 230a or 230c may be any of a cubic crystal structure, a tetragonal crystal structure, an orthorhombic crystal structure, a hexagonal crystal structure, a monoclinic crystal structure, and a trigonal crystal structure.

### [Composition of Oxide Semiconductor Layer]

As described above, the semiconductor layer 230b preferably has a composition suitable for forming a CAAC structure. The semiconductor layer 230b can be formed by a sputtering method, for example. The semiconductor layer 230b preferably contains zinc, for example. The semiconductor layer 230b containing zinc can be a metal oxide with high crystallinity. The semiconductor layer 230b preferably contains the element M in addition to zinc. When the semiconductor layer 230b contains the element M, formation of oxygen vacancies in the metal oxide can be inhibited, for example. Thus, the reliability of the transistor including the oxide semiconductor layer can be improved. For the semiconductor layer 230b, a metal oxide with a composition of In:M:Zn=1:1:1 [atomic ratio] or in the neighborhood thereof, a metal oxide with a composition of In:M:Zn=1:1:1.2 [atomic ratio] or in the neighborhood thereof, a metal oxide with a composition of In:M:Zn=1:1:0.5 [atomic ratio] or in the neighborhood thereof, a metal oxide with a composition of In:M:Zn=1:1:2 [atomic ratio] or in the neighborhood thereof, a metal oxide with a composition of In:M:Zn=4:2:3 [atomic ratio] or in the neighborhood thereof, a metal oxide with a composition of In:M:Zn=1:3:2 [atomic ratio] or in the neighborhood thereof, or a metal oxide with a composition of In:M:Zn=1:3:4 [atomic ratio] or in the neighborhood thereof may be specifically used. Note that the neighborhood of the atomic ratio includes ±30% of an intended atomic ratio. It is preferable to use one or more of gallium, aluminum, and tin as the element M.

It is possible that the semiconductor layer 230b does not contain the element M. For example, In—Zn oxide can be used. Specifically, a composition of In:Zn=1:1 [atomic ratio] or in the neighborhood thereof, a composition of In:Zn=2:1 [atomic ratio] or in the neighborhood thereof, or a composition of In:Zn=4:1 [atomic ratio] or in the neighborhood thereof can be used. Alternatively, indium oxide can be used. A structure containing a slight amount of the element M can be employed. Examples of the composition include a composition of In:Ga:Zn=4:0.1:1 [atomic ratio] or in the neighborhood thereof and a composition of In:Ga:Zn=2:0.1:1 [atomic ratio] or in the neighborhood thereof. Other examples include a composition of In:Sn:Zn=4:0.1:1 [atomic ratio] or in the neighborhood thereof and a composition of In:Sn:Zn=2:0.1:1 [atomic ratio] or in the neighborhood thereof.

Each of the semiconductor layers 230a and 230c can be a metal oxide with a high proportion of In. The semiconductor layers 230a and 230c can be formed by an ALD method, for example. It is particularly preferable to use a metal oxide in which the proportion of In is higher than that of the element M. With the use of a metal oxide with a high proportion of In, the amount of the on-state current can be increased and the frequency characteristics can be increased in the case where an oxide semiconductor layer is used for a transistor.

Alternatively, it is possible that the semiconductor layer 230a and the semiconductor layer 230c do not contain the element M. For example, In—Zn oxide can be used. Specifically, a composition of In:Zn=1:1 [atomic ratio] or in the neighborhood thereof, a composition of In:Zn=2:1 [atomic ratio] or in the neighborhood thereof, or a composition of In:Zn=4:1 [atomic ratio] or in the neighborhood thereof can be used. Alternatively, indium oxide can be used. Each of the semiconductor layer 230a and the semiconductor layer 230c can contain a slight amount of the element M. Specifically, a composition of In:Ga:Zn=4:0.1:1 [atomic ratio] or in the neighborhood thereof, a composition of In:Ga:Zn=2:0.1:1 [atomic ratio] or in the neighborhood thereof, a composition of In:Sn:Zn=4:0.1:1 [atomic ratio] or in the neighborhood thereof, or a composition of In:Sn:Zn=2:0.1:1 [atomic ratio] or in the neighborhood thereof can be used.

Note that when the proportion of zinc in the oxide semiconductor is increased, the crystallinity of the oxide semiconductor can be increased. In particular, the semiconductor layer 230a preferably contains zinc. For example, in the case where the semiconductor layer 230a is formed by an ALD method and the semiconductor layer 230b is formed by a sputtering method, zinc contained in the semiconductor layer 230a is diffused into the semiconductor layer 230b in some cases. Note that the diffusion can occur at the time of sputtering or later heat treatment. The diffusion of zinc from the semiconductor layer 230a into the semiconductor layer 230b is expected to improve the crystallinity. Alternatively, diffusion of zinc from the semiconductor layer 230a into the semiconductor layer 230b is expected to promote the formation of the CAAC structure by lateral growth of a crystal part having c-axis alignment.

The semiconductor layer 230a and the semiconductor layer 230c can each be a metal oxide having a higher proportion of In than the semiconductor layer 230b.

For example, a metal oxide having a higher proportion of Ga than the semiconductor layer 230b can also be used for each of the semiconductor layer 230a and the semiconductor layer 230c. For example, for each of the semiconductor layer 230a and the semiconductor layer 230c, a metal oxide with a composition of In:Ga:Zn=1:1:1 [atomic ratio] or in the neighborhood thereof, a metal oxide with a composition of In:Ga:Zn=1:3:2 [atomic ratio] or in the neighborhood thereof, or a metal oxide with a composition of In:Ga:Zn=1:3:4 [atomic ratio] or in the neighborhood thereof is preferably used. When the proportion of Ga is increased, the band gap of each of the semiconductor layers 230a and 230c can be larger than that of the semiconductor layer 230b in some cases, for example. Thus, the semiconductor layer 230b is sandwiched between the semiconductor layers 230a and 230c each having a wide band gap, and the semiconductor layer 230b mainly functions as a current path (channel). When the semiconductor layer 230b is sandwiched between the semiconductor layers 230a and 230c, the trap states at the interface with the semiconductor layer 230b and its vicinity can be reduced. Accordingly, a buried-channel transistor where a channel is away from the interface with an insulating layer can be achieved, whereby the field-effect mobility can be increased.

In the oxide semiconductor layer of one embodiment of the present invention, even in the case where a composition in which the CAAC structure is less likely to be formed in the formation of a single layer is used for the semiconductor layers 230a and 230c, crystal growth occurs with the semiconductor layer 230b as a nucleus, so that the whole oxide semiconductor layer including the semiconductor layers 230a and 230c can have a CAAC structure. Alternatively, a CAAC structure can be formed in a region including the whole semiconductor layer 230b and a region including at least part of each of the semiconductor layers 230a and 230c.

In particular, even in the composition in which the proportion of In in the semiconductor layers 230a and 230c is high, crystallinity suitable for a semiconductor layer of a transistor can be obtained. The oxide semiconductor layer of one embodiment of the present invention enables both high on-state characteristics and high reliability of a transistor, respectively by having a high proportion of In and by having a CAAC structure with high crystallinity.

Note that the semiconductor layer 230a and the semiconductor layer 230c may have different compositions.

The semiconductor layers 230a and 230c can be formed using a metal oxide having the same composition as the semiconductor layer 230b.

With the use of the oxide semiconductor layer having the CAAC structure formed by the above-described two kinds of film formation methods for a channel formation region of a transistor, the transistor can have excellent characteristics (e.g., a high on-state current, high field-effect mobility, a low S value, high frequency characteristics (also referred to as f characteristics), or high reliability).

Analysis of the composition of the metal oxide used for the semiconductor layer 230 can be performed by EDX, XPS, inductively coupled plasma-mass spectrometry (ICP-MS), or inductively coupled plasma-atomic emission spectrometry (ICP-AES), for example. Alternatively, any of these methods may be combined with each other for the analysis. As for an element whose content is low, the actual content may be different from the content obtained by analysis because of the influence of the analysis accuracy. In the case where the content of the element M is low, for example, the content of the element M obtained by analysis may be lower than the actual content.

[c-Axis Alignment Proportion]

The oxide semiconductor layer of one embodiment of the present invention has a CAAC structure. The degree of the crystallinity of the oxide semiconductor layer of one embodiment of the present invention can be evaluated with the use of crystal orientation, for example.

The crystal orientation can be obtained from a fast fourier transform (FFT) pattern obtained by performing FFT processing on a TEM image. Specifically, the directions of the crystal axes can be obtained using an FFT pattern. The FFT pattern obtained by the FFT processing reflects reciprocal lattice space information like an electron diffraction pattern.

When FFT processing is performed on each region in the TEM image of the oxide semiconductor layer, crystal orientation of each region can be obtained. For example, crystal orientation is obtained by each region in a certain area range, so that a map indicating crystal orientation can be formed. Specifically, two spots with high intensity are observed in the FFT pattern of the region including a layered crystal part. The direction of the crystal axis of the region can be obtained from the angle of the line segment connecting the two spots.

In the map showing crystal orientation, the c-axis alignment proportion can be calculated by calculating the proportion of the region having c-axis alignment. Here, the region having c-axis alignment represents a region where the orientation is aligned with the c-axis and a region where a difference between the orientation and the c-axis is less than or equal to 20°.

In the oxide semiconductor layer of one embodiment of the present invention, the c-axis alignment proportion can be calculated by, for example, a cross-section or a plan-view TEM observation of the oxide semiconductor layer. The region where the FFT is performed (also referred to as an FFT window) can be a circle with a diameter of 1.0 nm, for example. Note that the region where the FFT is performed is not limited to a circle.

In the oxide semiconductor layer of one embodiment of the present invention, the c-axis alignment proportion is higher than or equal to 60%, preferably higher than or equal to 70%, further preferably higher than or equal to 80%, still further preferably higher than or equal to 90%, yet still further preferably higher than or equal to 95%.

Furthermore, the c-axis alignment proportions of the region where the semiconductor layer 230a is formed, the region where the semiconductor layer 230b is formed, and the region where the semiconductor layer 230c is formed are Rc1, Rc2, and Rc3, respectively. Each of Rc2 and Rc3 is higher than or equal to 60%, preferably higher than or equal to 70%, further preferably higher than or equal to 80%, still further preferably higher than or equal to 90%, yet still further preferably higher than or equal to 95%. Rc3/Rc1 is preferably higher than 1. Furthermore, Rc2/Rc1 is preferably higher than 1.

Note that the boundaries between the semiconductor layers 230a, 230b, and 230c are not clearly observed after the formation of the semiconductor layer 230 in some cases.

The semiconductor layer 230 of one embodiment of the present invention can be divided into three regions: a first region, a second region, and a third region in this order from the top of the layer 229. Each of the regions is a layered region.

The first, second, and third regions each have a CAAC structure. In addition, the c-axis alignment proportion in the third region is preferably higher than that in the first region. The c-axis alignment proportion in the second region is preferably higher than that in the first region. The c-axis alignment proportions in the second region and the third region are higher than or equal to 80%, preferably higher than or equal to 90%, further preferably higher than or equal to 95%.

The first region is a region ranging from the top surface of the layer 229 to greater than or equal to 0 nm and less than or equal to 3 nm, and the third region is a region ranging from the top surface of the semiconductor layer 230 to greater than or equal to 0 nm and less than or equal to 3 nm.

The thicknesses of the layers in the regions are substantially the same, for example.

The structures described in this embodiment can be used in combination with any of the structures described in the other embodiments as appropriate.

### Embodiment 5

In this embodiment, a planar layout example and a cross-sectional structure example of the semiconductor device 10A illustrated in FIG. 23A will be described.

In this embodiment, the case is described where the transistor 200A (see FIGS. 29A to 29C) described in Embodiment 3 is used as each of the transistors Tr1 to Tr6, and the transistor 200B (see FIGS. 30A to 30C) is used as the transistor TrD. In order to reduce repeated description, matters that are not described in the other embodiments are mainly described. Matters that are not described in this embodiment can be understood with reference to the other embodiments.

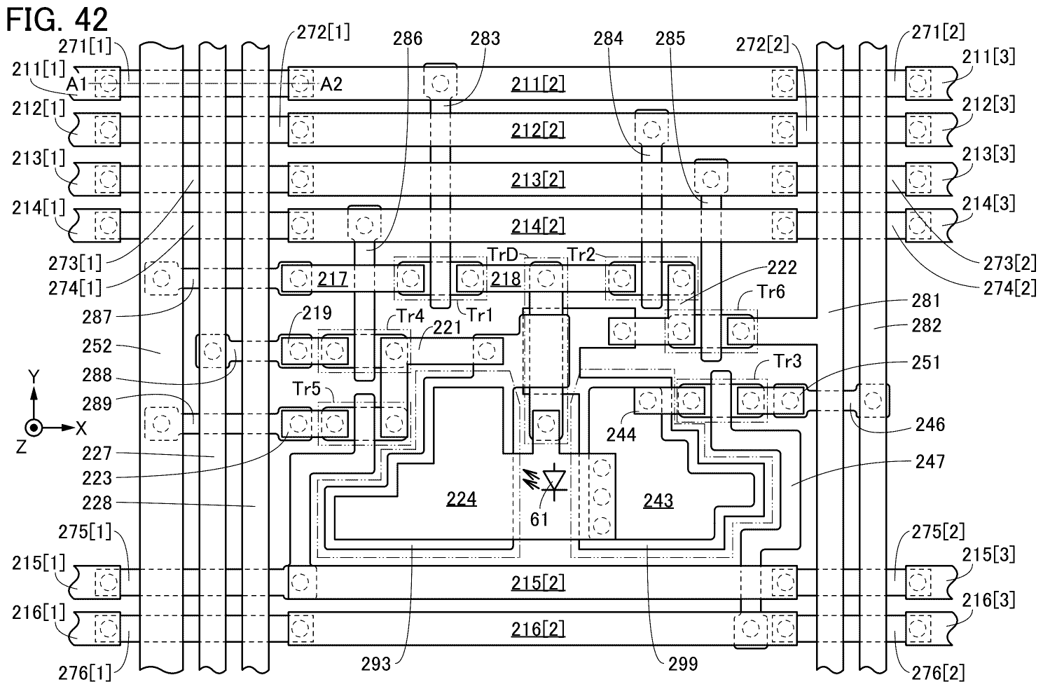

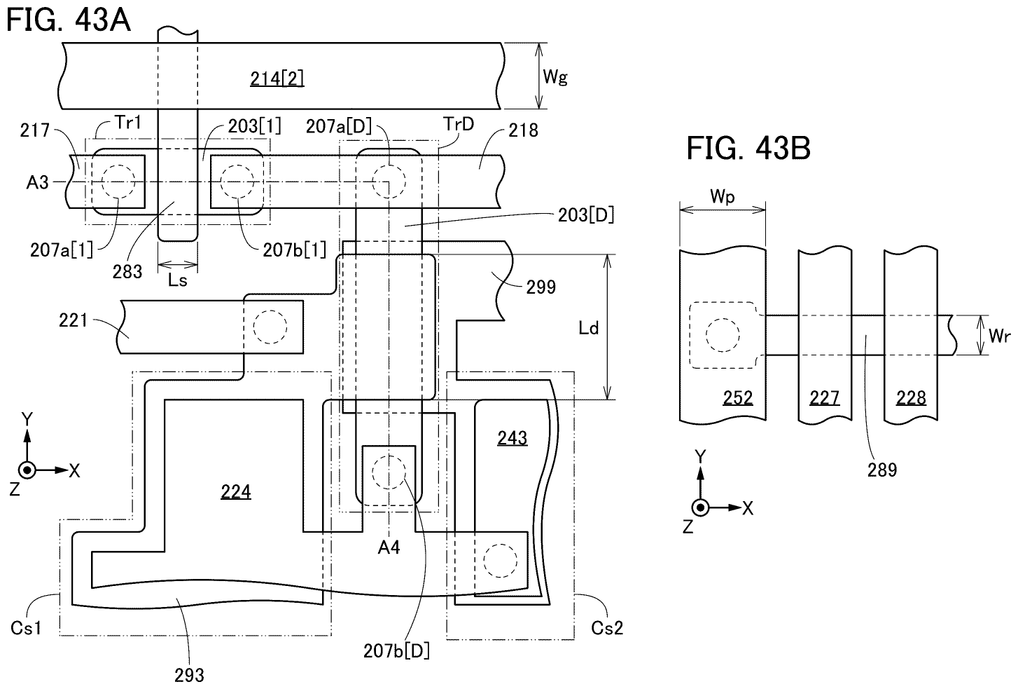

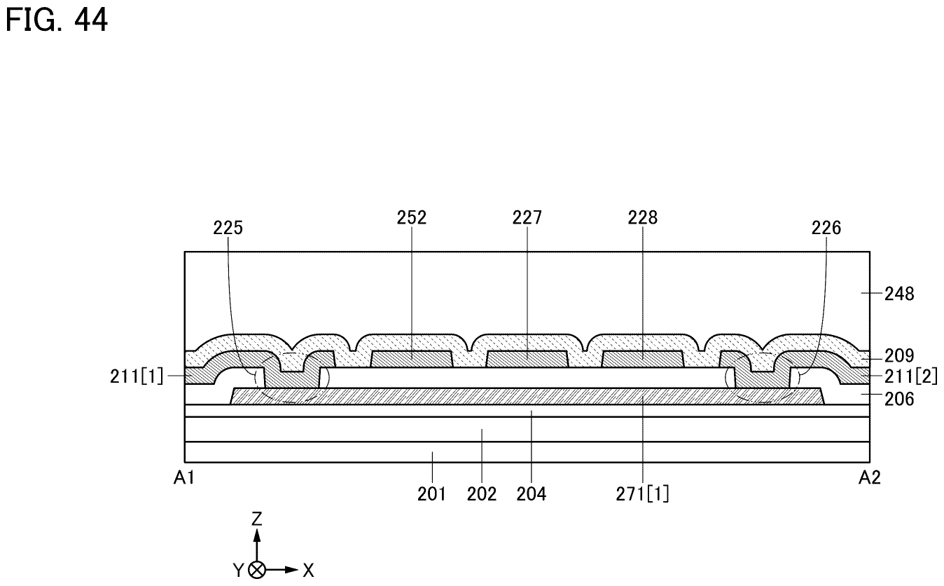

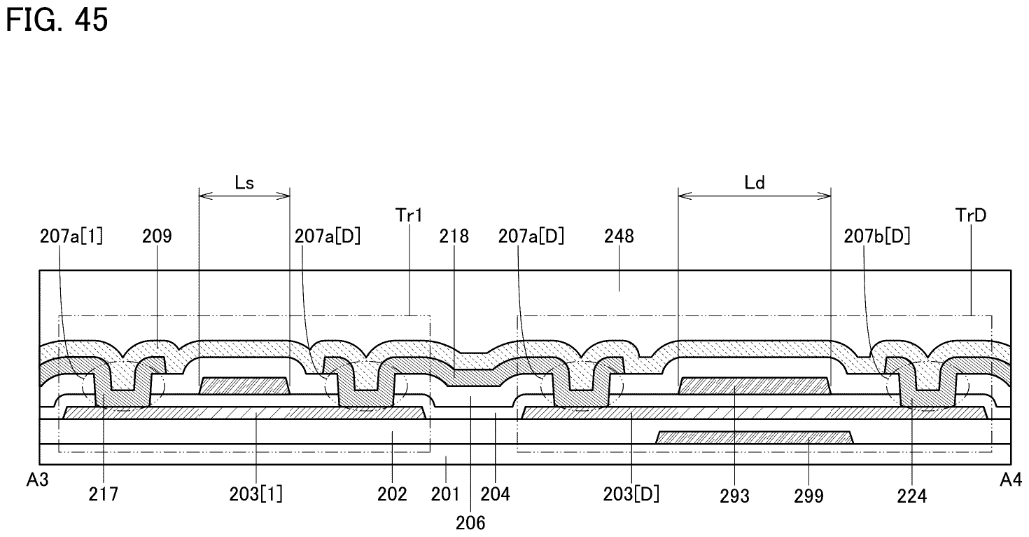

FIG. 42 shows a planar layout example of the semiconductor device 10A illustrated in FIG. 23A. FIG. 43A is an enlarged view of a portion of FIG. 42 including the transistors Tr1 and TrD and the capacitors Cs1 and Cs2. FIG. 43B is an enlarged view of a portion including a connection portion between a conductive layer 252 and a conductive layer 289. FIG. 44 is a cross-sectional view taken along dashed-dotted line A1-A2 in FIG. 42. FIG. 45 is a cross-sectional view taken along dashed-dotted line A3-A4 in FIG. 43A.

The semiconductor device 10A described in this embodiment includes a conductive layer 299 over the substrate 201.

Over the insulating layer 204, a conductive layer 271[1], a conductive layer 271[2], a conductive layer 272[1], a conductive layer 272[2], a conductive layer 273[1], a conductive layer 273[2], a conductive layer 274[1], a conductive layer 274[2], a conductive layer 275[1], a conductive layer 275[2], a conductive layer 276[1], a conductive layer 276[2], a conductive layer 283, a conductive layer 284, a conductive layer 285, a conductive layer 286, a conductive layer 287, a conductive layer 288, the conductive layer 289, a conductive layer 246, a conductive layer 247, a conductive layer 293, and a conductive layer 243 are provided.

The conductive layers 271[1], 271[2], 272[1], 272[2], 273[1], 273[2], 274[1], 274[2], 275[1], 275[2], 276[1], 276[2], 283, 284, 285, 286, 287, 288, 289, 246, 247, 293, and 243 can be formed using the same material in the same step at the same time.

Over the insulating layer 206, a conductive layer 211[1], a conductive layer 211[2], a conductive layer 211[3], a conductive layer 212[1], a conductive layer 212[2], a conductive layer 212[3], a conductive layer 213[1], a conductive layer 213[2], a conductive layer 213[3], a conductive layer 214[1], a conductive layer 214[2], a conductive layer 214[3], a conductive layer 215[1], a conductive layer 215[2], a conductive layer 215[3], a conductive layer 216[1], a conductive layer 216[2], a conductive layer 216[3], a conductive layer 217, a conductive layer 218, the conductive layer 219, a conductive layer 221, a conductive layer 222, a conductive layer 223, a conductive layer 224, a conductive layer 251, the conductive layer 252, a conductive layer 227, a conductive layer 228, a conductive layer 281, a conductive layer 282, and a conductive layer 244 are provided.

The conductive layer 211[1], 211[2], 211[3], 212[1], 212[2], 212[3], 213[1], 213[2], 213[3], 214[1], 214[2], 214[3], 215[1], 215[2], 215[3], 216[1], 216[2], 216[3], 217, 218, 219, 221, 222, 223, 224, 251, 252, 227, 228, 281, 282, and 244 can be formed using the same material in the same step at the same time.

The conductive layer 211[1] is connected to the conductive layer 211[2] through the conductive layer 271[1]. Specifically, an opening 225 and an opening 226 are each provided in part of the insulating layer 206 in a region overlapping with the conductive layer 271[1], and the conductive layer 271[1] is in contact with the conductive layer 211[1] in the region overlapping with the opening 225, and in contact with the conductive layer 211[2] in the region overlapping with the opening 226 (see FIG. 42 and FIG. 44).

A plurality of the openings 225 through which the conductive layers 211[1] and 271[1] are connected to each other can be provided. When the plurality of the openings 225 are provided, the contact resistance between the conductive layers 211[1] and 271[1] can be reduced. Similarly, a plurality of the openings 226 through which the conductive layers 211[2] and 271[1] are connected to each other can be provided. When the plurality of the openings 226 are provided, the contact resistance between the conductive layers 211[2] and 271[1] can be reduced.

The conductive layer 211[2] is connected to the conductive layer 211[3] through the conductive layer 271[2]. The conductive layers 211[1], 271[1], 211[2], 271[2], and 211[3] function as the wiring GL1. In FIG. 42, the wiring GL1 extends in the X direction.

The conductive layer 212[1] is connected to the conductive layer 212[2] through the conductive layer 272[1], and the conductive layer 212[2] is connected to the conductive layer 213[3] through the conductive layer 272[2]. The conductive layers 212[1], 272[1], 212[2], 272[2], and 212[3] function as the wiring GL2. In FIG. 42, the wiring GL2 extends in the X direction.

The conductive layer 213[1] is connected to the conductive layer 213[2] through the conductive layer 273[1], and the conductive layer 213[2] is connected to the conductive layer 213[3] through the conductive layer 273[2]. The conductive layers 213[1], 273[1], 213[2], 273[2], and 213[3] function as the wiring GL3. In FIG. 42, the wiring GL3 extends in the X direction.

The conductive layer 214[1] is connected to the conductive layer 214[2] through the conductive layer 274[1], and the conductive layer 214[2] is connected to the conductive layer 214[3] through the conductive layer 274[2]. The conductive layers 214[1], 274[1], 214[2], 274[2], and 214[3] function as the wiring GL4. In FIG. 42, the wiring GL4 extends in the X direction.

The conductive layer 215[1] is connected to the conductive layer 215[2] through the conductive layer 275[1], and the conductive layer 215[2] is connected to the conductive layer 215[3] through the conductive layer 275[2]. The conductive layers 215[1], 275[1], 215[2], 275[2], and 215[3] function as the wiring GL5. In FIG. 42, the wiring GL5 extends in the X direction.

The conductive layer 216[1] is connected to the conductive layer 216[2] through the conductive layer 276[1], and the conductive layer 216[2] is connected to the conductive layer 216[3] through the conductive layer 276[2]. The conductive layers 216[1], 276[1], 216[2], 276[2], and 216[3] function as the wiring GL6. In FIG. 42, the wiring GL6 extends in the X direction.

The conductive layers 252, 227, 228, 281, and 282 function as the wirings Pw1, DL, Vref3, Vref1, and Vref2, respectively. The conductive layers 252, 227, 228, 281, and 282 extend in the Y direction in FIG. 42.

The conductive layer 217 is connected to the conductive layer 252 through the conductive layer 287. Part of the conductive layer 217 functions as one of a source electrode and a drain electrode of the transistor Tr1. The conductive layer 283 is connected to the conductive layer 211[2]. Part of the conductive layer 283 functions as a gate electrode of the transistor Tr1.

Part of the conductive layer 218 functions as the other of the source electrode and the drain electrode of the transistor Tr1. Another part of the conductive layer 218 functions as one of a source electrode and a drain electrode of the transistor TrD. Another part of the conductive layer 218 functions as one of a source electrode and a drain electrode of the transistor Tr2.

The conductive layer 284 is connected to the conductive layer 212[2]. Part of the conductive layer 284 functions as a gate electrode of the transistor Tr2. Part of the conductive layer 222 functions as the other of the source electrode and the drain electrode of the transistor Tr2. Another part of the conductive layer 222 functions as one of a source electrode and a drain electrode of the transistor Tr6. The conductive layer 222 is connected to the conductive layer 299. Part of the conductive layer 281 functions as the other of the source electrode and the drain electrode of the transistor Tr6. The conductive layer 285 is connected to the conductive layer 213[2]. Part of the conductive layer 285 functions as a gate electrode of the transistor Tr6.

The conductive layer 219 is connected to the conductive layer 227 through the conductive layer 288. Part of the conductive layer 219 functions as one of a source electrode and a drain electrode of the transistor Tr4. The conductive layer 286 is connected to the conductive layer 214[2]. Part of the conductive layer 286 functions as a gate electrode of the transistor Tr4. Part of the conductive layer 221 functions as one of a source electrode and a drain electrode of the transistor Tr4. Another part of the conductive layer 221 functions as one of a source electrode and a drain electrode of the transistor Tr5. The conductive layer 221 is connected to the conductive layer 293.

Part of the conductive layer 275[1] functions as a gate electrode of the transistor Tr5. The conductive layer 223 is connected to the conductive layer 252 through the conductive layer 289. Part of the conductive layer 224 functions as the other of the source electrode and the drain electrode of the transistor TrD. Part of the conductive layer 293 functions as a gate electrode of the transistor TrD, and part of the conductive layer 299 functions as a back gate electrode of the transistor TrD. The conductive layer 224 is connected to the conductive layer 243.

The conductive layer 244 is connected to the conductive layer 243. Part of the conductive layer 244 functions as one of a source electrode and a drain electrode of the transistor Tr3. The conductive layer 251 is connected to the conductive layer 282 through the conductive layer 246. Part of the conductive layer 251 functions as the other of the source electrode and the drain electrode of the transistor Tr3. The conductive layer 247 is connected to the conductive layer 216[2]. Part of the conductive layer 247 functions as a gate electrode of the transistor Tr3.

There is a region where the conductive layer 293 and the conductive layer 224 overlap with each other with the insulating layer 206 therebetween. The region functions as the capacitor Cs1. The capacitance of the capacitor Cs1 can be determined by the area of the region where the conductive layer 293 and the conductive layer 224 overlap with each other and the relative permittivity and thickness of the insulating layer 206.

There is a region where the conductive layer 299 and the conductive layer 243 overlap with each other with the insulating layers 202 and 204 therebetween. The region functions as the capacitor Cs2. The capacitance of the capacitor Cs2 can be determined by the area of the region where the conductive layer 299 and the conductive layer 243 overlap with each other and the relative permittivity and thickness of each of the insulating layers 202 and 204.

The conductive layer 218 functions as the node Na. The conductive layers 224, 243, and 244 function as the node Nb. The conductive layers 221 and 293 function as the node Nc. The conductive layers 222 and 299 function as the node Nd.

Note that in this specification, the semiconductor layer 203 of the transistor Tr1 is referred to as a semiconductor layer 203[1] (see FIG. 43A and FIG. 45). One of the openings 207 overlapping with the semiconductor layer 203[1] in a plan view is referred to as an opening 207a[1], and the other is referred to as an opening 207b[1].

Moreover, in this specification, the semiconductor layer 203 of the transistor TrD is referred to as a semiconductor layer 203[D]. One of the openings 207 overlapping with the semiconductor layer 203[D] in the plan view is referred to as an opening 207a[D], and the other is referred to as an opening 207b[D].

Note that in this embodiment, an insulating layer 248 having a flat top surface is provided over the insulating layer 209. An insulating layer containing an organic material is suitable as the insulating layer 248. For example, any of an acrylic resin, polyimide, polyamide, polyimide-amide, an epoxy resin, a siloxane resin, a benzocyclobutene-based resin, a phenol resin, and precursors of these resins can be used for the insulating layer 248. Alternatively, the insulating layer 248 may be formed using an inorganic material, and CMP treatment may be performed on the top surface of the insulating layer 248. By reducing the top surface unevenness of the insulating layer 248, coverage with an insulating layer and a conductive layer to be formed later can be increased.

In the semiconductor device 10A, the width Wg of the conductive layer 214[2] that is illustrated in FIG. 43A and functions as the wiring GL1 (the length of the conductive layer 214[2] in the Y direction or the length of the conductive layer 214[2] in the direction orthogonal to the direction in which the conductive layer 214[2] extends) is preferably larger than the channel length Ls of the transistor connected to the wiring GL1. Specifically, in the semiconductor device 10A, the minimum value of the width Wg is preferably larger than the maximum value of the channel length Ls. This can reduce signal delay caused when signals are supplied to a plurality of transistors connected to the wiring GL1. Note that this description on the wiring GL1 can also be applied to the wirings GL2 to GL6. Note that FIG. 43A illustrates the width Wg of the conductive layer 214[2].

In the semiconductor device 10A, the width Wp of the conductive layer 252 that is illustrated in FIG. 43B and functions as the wiring Pw1 (the length of the conductive layer 252 in the X direction or the length of the conductive layer 252 in the direction orthogonal to the direction in which the conductive layer 252 extends) is preferably larger than the width Wr of the conductive layer 289 which is connected to the conductive layer 252 and functions as a lead wiring of the semiconductor device 10A (see FIG. 43B). Specifically, in the semiconductor device 10A, the minimum value of the width Wp is preferably larger than the maximum value of the width Wr. This can inhibit a reduction in the power supply capability of the conductive layer functioning as a power supply line, enabling the semiconductor device 10A to operate stably. Accordingly, the reliability of the semiconductor device 10A can be improved. Note that the relation between the wirings Pw2, DL, Vref1, Vref2, Vref3, and GL1 to GL6 and the conductive layers connected thereto can be considered in a manner similar to the above.

As described above, when the transistors Tr1 to Tr6 each have a shorter channel length than the transistor TrD functioning as a driving transistor, the operation speed of the semiconductor device 10A and the reproducibility of the luminance of the light emission from the light-emitting element 61 in response to the video signal can be improved. For example, the channel length Ls of the transistor Tr1 is preferably shorter than the channel length Ld of the transistor TrD (see FIG. 43A).

The structures described in this embodiment can be used in combination with any of the structures described in the other embodiments as appropriate.

### Embodiment 6

The semiconductor device of one embodiment of the present invention can be used for a display apparatus or the like. The semiconductor device of one embodiment of the present invention can be used for a module including the display apparatus (also referred to as a “display module”), or the like. In this embodiment, a display apparatus including the semiconductor device of one embodiment of the present invention is described.

Examples of the display module include a module in which a connector such as a flexible printed circuit board (FPC) or a tape carrier package (TCP) is attached to the display apparatus and a module in which the display apparatus is mounted with an integrated circuit (IC) by a chip on glass (COG) method, a chip on film (COF) method, or the like.

### <Structure Example of Display Apparatus>

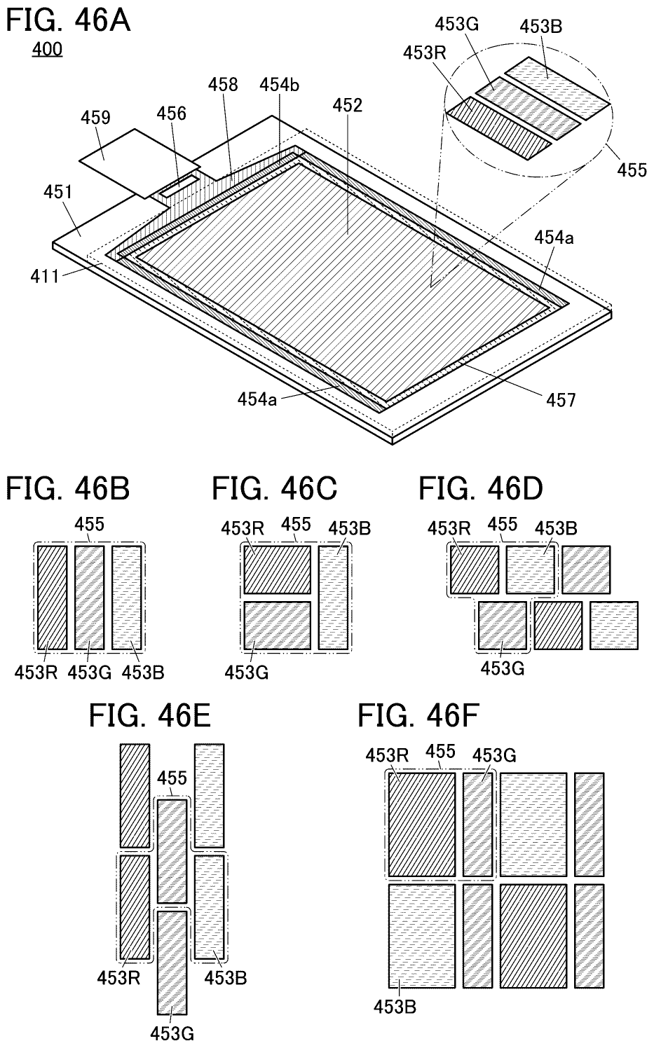

FIG. 46A is a perspective view showing a structure example of a display apparatus 400 of one embodiment of the present invention.

In the display apparatus 400, a substrate 411 and a substrate 451 are bonded to each other. In FIG. 46A, the substrate 411 is indicated by a dashed line.

The display apparatus 400 includes a display portion 452, a circuit portion 454a, a circuit portion 454b, a connection portion 457, and a wiring portion 458. FIG. 46A shows an example where an IC 456 and an FPC 459 are mounted on the display apparatus 400. Thus, the structure illustrated in FIG. 46A can be regarded as a display module including the display apparatus 400, the IC, and the FPC.

The circuit portion 454a includes a scan line driver circuit (also referred to as a gate driver or a scan driver), for example. The circuit portion 454b includes a signal line driver circuit (also referred to as a source driver or a data driver), for example.

The wiring portion 458 has a function of supplying a signal and power to the display portion 452 and the circuit portions 454b and 454a. The signal and power are input to the wiring portion 458 from the outside of the display apparatus 400 through the FPC 459 or from the IC 456.

FIG. 46A shows an example where the IC 456 is provided on the substrate 451 by a COG method, a COF method, or the like. An IC including one or both of a scan line driver circuit and a signal line driver circuit can be used as the IC 456, for example. Note that it is also possible that the display apparatus 400 and the display module are not provided with an IC. The IC 456 can be mounted on the FPC by a COF method or the like.

One or both of the IC 456 and the circuit portion 454a can construct the scan line driver circuit, in which case the IC 456 may be referred to as a gate driver IC. One or both of the IC 456 and the circuit portion 454b can construct the signal line driver circuit, in which case the IC 456 may be referred to as a source driver IC.

The display portion 452 of the display apparatus 400 is a region where an image is to be displayed, and includes a plurality of pixels 455 that are periodically arranged. FIG. 46A shows an enlarged view of one of the pixels 455.

The pixel 455 illustrated in FIG. 46A includes a pixel 453R that emits red (R) light, a pixel 453G that emits green (G) light, and a pixel 453B that emits blue (B) light. One pixel 453R, one pixel 453G, and one pixel 453B form one pixel 455, which achieves full-color display. The pixels 453R, 453G, and 453B each serve as a subpixel. In the display apparatus 400 illustrated in FIG. 46A, the pixels 453R, 453B, and 453G serving as subpixels are arranged in a stripe pattern, for example. The number of subpixels forming one pixel 455 is not limited to three, and can be four or more. For example, one pixel 455 can include four subpixels which emit light of four colors, R, G, B, and white (W). Alternatively, one pixel 455 can include four subpixels which emit light of four colors, R, G, B, and yellow (Y).

In the description in this specification, identification signs such as “R,” “G,” and “B” are sometimes used to indicate the components related to red light, green light, and blue light, respectively. Such identification signs are sometimes omitted in the description common to the components. For example, a plurality of the pixels 453 are sometimes shown individually as the pixel 453R, the pixel 453G, and the pixel 453B when they need to be distinguished from each other. For example, the pixels 453R, 453G, and 453B are sometimes shown simply as the pixel 453 when there is no need to distinguish between them.

The pixels 453R, 453G, and 453B each include a light-emitting element and a circuit controlling the emission luminance of the light-emitting element. Any of the semiconductor devices 10 (the semiconductor devices 10A to 10M) of one embodiment of the present invention can be used for the pixel 453.

The connection portion 457 is provided outside the display portion 452. The connection portion 457 can be provided along one or more sides of the display portion 452. The number of connection portions 457 may be one or more. FIG. 46A shows an example where the connection portion 457 is provided to surround the four sides of the display portion. In the connection portion 457, a common electrode of a display element is connected to the wiring portion 458 so that a potential can be supplied to the common electrode.

Here, the transistor described in the above embodiment can be used for at least part of the display portion 452 and the circuit portions 454b and 454a of the display apparatus 400, for example.

When a vertical transistor such as the above-described transistor 200C is used for one or both of the circuit portions 454b and 454a, the footprints of the circuit portions 454b and 454a can be reduced and the display apparatus can have a narrow bezel, for example.

When a vertical transistor such as the above-described transistor 200C or 200D is used for a pixel circuit of the display portion 452, the footprint of the pixel circuit can be reduced and the display apparatus can have high definition, for example. For example, the definition of the display apparatus can be higher than or equal to 300 ppi, higher than or equal to 500 ppi, higher than or equal to 1000 ppi, higher than or equal to 2000 ppi, or higher than or equal to 3000 ppi.

The display apparatus of one embodiment of the present invention can have a function of a touch panel. The display apparatus can employ any of various sensor elements that can sense proximity or touch of a sensing target such as a finger, for example.

For example, various types such as a capacitive type, a resistive type, a surface acoustic wave type, an infrared type, an optical type, and a pressure-sensitive type can be used for the sensor.

Examples of the capacitive touch sensor are a surface capacitive touch sensor and a projected capacitive touch sensor. Examples of the projected capacitive touch sensor include a self-capacitive touch sensor and a mutual capacitive touch sensor. The use of a mutual capacitive touch sensor is preferable because multiple points can be sensed simultaneously.

Examples of a touch panel include an out-cell touch type, an on-cell type, and an in-cell type. An in-cell touch panel has a structure in which an electrode included in a sensor element is provided on one or both of a substrate supporting a display element (also referred to as a display device) and a counter substrate.

### [Pixel Arrangement]

FIGS. 46B to 46F are plan views each illustrating pixel arrangement. In the display apparatus of one embodiment of the present invention, there is no particular limitation on the pixel arrangement and various arrangements can be employed. Examples of the pixel arrangement include a stripe arrangement (see FIG. 46B), an S-stripe arrangement (see FIG. 46C), a delta arrangement (see FIG. 46D), a zigzag arrangement (see FIG. 46E), and a PenTile arrangement (see FIG. 46F). Other examples include a mosaic arrangement, a diamond arrangement, and a Bayer arrangement.

Furthermore, examples of the top surface shape of each subpixel (pixel 453R, 453G, or 453B) in FIGS. 46B to 46F include polygons such as a triangle, a tetragon (including a rectangle and a square), and a pentagon, polygons with rounded corners, an ellipse, and a circle. Here, a top surface shape of the subpixel corresponds to a top surface shape of a display region of the display element included in the subpixel. The top surface shapes and sizes of the subpixels can be determined independently. Note that the positions of the pixels 453R, 453G, and 453B can be interchanged with each other as appropriate. The arrangement of the display elements and the arrangement of the pixel circuits can be the same or different.

Since a PenTile arrangement is a unique pixel arrangement that increases definition in a pseudo manner, for example, a stripe arrangement can be employed for the display apparatus. According to one embodiment of the present invention, for example, a vertical transistor such as the above-described transistor 200C or 200D is used as some or all of the transistors included in the pixel circuit, whereby the footprint of the pixel circuit can be reduced. This permits the employment of a stripe arrangement or the like, not a PenTile arrangement, without involving a reduction in the definition of the display apparatus.

### [Light-Emitting Element]

As the light-emitting element, a self-luminous light-emitting element such as an LED, an organic EL element (also referred to as an Organic LED (OLED)), or a semiconductor laser can be used. Examples of the LED include a mini LED and a micro LED.

Examples of a light-emitting substance contained in the light-emitting element include a substance exhibiting fluorescence (a fluorescent material), a substance exhibiting phosphorescence (a phosphorescent material), a substance exhibiting thermally activated delayed fluorescence (a thermally activated delayed fluorescent (TADF) material), and an inorganic compound (e.g., a quantum dot material).

The light-emitting element can emit infrared, red, green, blue, cyan, magenta, yellow, or white light, for example. When the light-emitting element has a microcavity structure, higher color purity can be achieved.

One of the pair of electrodes or terminals of the light-emitting element serves as an anode (also referred to as an anode electrode), and the other electrode or terminal serves as a cathode (also referred to as a cathode electrode).

In this embodiment, the case where an organic EL element is used as a light-emitting element is described as an example. Thus, the display apparatus 400 of one embodiment of the present invention is a display apparatus using an organic EL element.

The display apparatus 400 of one embodiment of the present invention suitably has any of the following structures: a top-emission structure in which light is emitted in a direction opposite to the substrate where the light-emitting element is formed, a bottom-emission structure in which light is emitted toward the substrate where the light-emitting element is formed, and a dual-emission structure in which light is emitted toward both surfaces.

Since the footprint of the pixel circuit can be reduced with the use of a vertical transistor such as the above-described transistor 200C or 200D, the aperture ratio of a pixel can be increased particularly in a display apparatus having a bottom-emission structure and a display apparatus having a dual-emission structure. For example, the aperture ratio can be higher than or equal to 50%, higher than or equal to 55%, or higher than or equal to 60% in the display apparatus.

In this specification and the like, the aperture ratio refers to a proportion of the area of the region, where light is transmitted, to the area of a pixel.

### <Structure Example of Light-Emitting Element>

The light-emitting element 61 that can be used in the display apparatus of one embodiment of the present invention will be described.

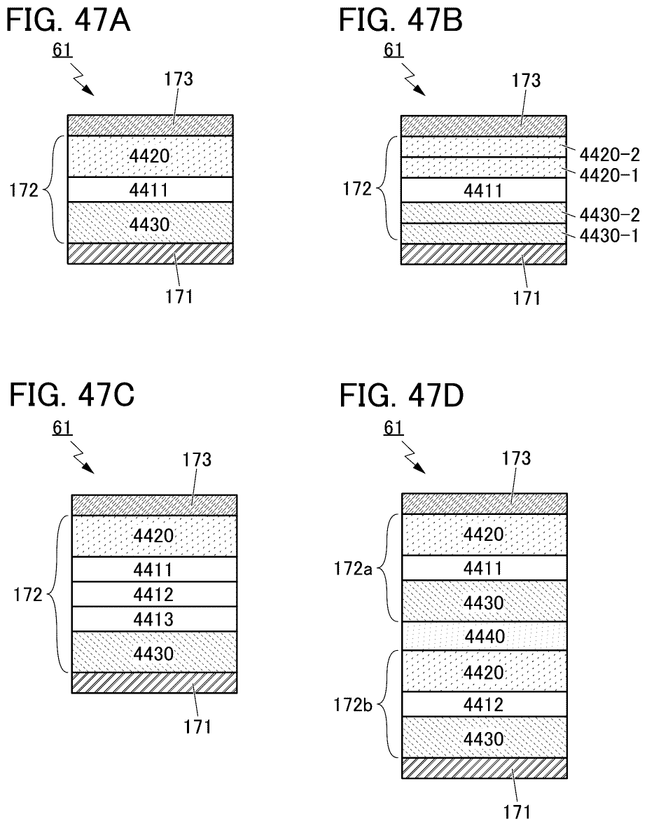

As illustrated in FIG. 47A, the light-emitting element 61 includes an EL layer 172 between a conductive layer 171 and a conductive layer 173. The EL layer 172 can be formed of a plurality of layers such as a layer 4420, a light-emitting layer 4411, and a layer 4430. The layer 4420 can include, for example, a layer containing a substance with a high electron-injection property (an electron-injection layer) and a layer containing a substance with a high electron-transport property (an electron-transport layer). The light-emitting layer 4411 contains a light-emitting compound, for example. The layer 4430 can include, for example, a layer containing a substance with a high hole-injection property (a hole-injection layer) and a layer containing a substance with a high hole-transport property (a hole-transport layer).

The structure including the layer 4420, the light-emitting layer 4411, and the layer 4430, which is provided between the conductive layers 171 and 173 functioning as electrodes, can function as a single light-emitting unit, and the structure in FIG. 47A is referred to as a single structure in this specification and the like.

FIG. 47B is a modification example of the EL layer 172 included in the light-emitting element 61 illustrated in FIG. 47A. Specifically, the light-emitting element 61 illustrated in FIG. 47B includes a layer 4430-1 over the conductive layer 171, a layer 4430-2 over the layer 4430-1, the light-emitting layer 4411 over the layer 4430-2, a layer 4420-1 over the light-emitting layer 4411, a layer 4420-2 over the layer 4420-1, and the conductive layer 173 over the layer 4420-2. For example, in the case where the conductive layer 171 serves as an anode and the conductive layer 173 serves as a cathode, the layer 4430-1 serves as a hole-injection layer, the layer 4430-2 serves as a hole-transport layer, the layer 4420-1 serves as an electron-transport layer, and the layer 4420-2 serves as an electron-injection layer. Alternatively, in the case where the conductive layer 171 serves as a cathode and the conductive layer 173 serves as an anode, the layer 4430-1 serves as an electron-injection layer, the layer 4430-2 serves as an electron-transport layer, the layer 4420-1 serves as a hole-transport layer, and the layer 4420-2 serves as a hole-injection layer. With such a layer structure, carriers can be efficiently injected to the light-emitting layer 4411, and the efficiency of the recombination of carriers in the light-emitting layer 4411 can be enhanced.

The structure in which a plurality of light-emitting layers (the light-emitting layer 4411, a light-emitting layer 4412, and a light-emitting layer 4413) are provided between the layer 4420 and the layer 4430 as illustrated in FIG. 47C is another example of the single structure.

The structure in which a plurality of light-emitting units (an EL layer 172a and an EL layer 172b) are connected in series with an intermediate layer (charge-generation layer) 4440 therebetween as illustrated in FIG. 47D is referred to as a tandem structure or a stack structure in this specification and the like. The tandem structure can achieve a light-emitting element capable of high luminance light emission.

In the case where the light-emitting element 61 has the tandem structure illustrated in FIG. 47D, the EL layers 172a and 172b preferably emit light of the same color. For example, the EL layers 172a and 172b preferably both emit green light.

Note that full color display can be achieved by forming one pixel with three subpixels of the light-emitting element 61 emitting red light (R), the light-emitting element 61 emitting green light (G), and the light-emitting element 61 emitting blue light (B). In the case where one pixel includes three kinds of subpixels of R, G, and B, the light-emitting elements 61 each preferably have a tandem structure. Specifically, the EL layers 172a and 172b in the subpixel of R each contain a material capable of emitting red light, the EL layers 172a and 172b in the subpixel of G each contain a material capable of emitting green light, and the EL layers 172a and 172b in the subpixel of B each contain a material capable of emitting blue light. In other words, the light-emitting layers 4411 and 4412 can contain the same material. When the EL layers 172a and 172b emit light of the same color, the current density per unit emission luminance can be reduced. Thus, the reliability of the light-emitting element 61 can be improved.

The emission color of the light-emitting element can be changed to red, green, blue, cyan, magenta, yellow, white, or the like depending on the material of the EL layer 172. When the light-emitting element has a microcavity structure, the color purity can be further increased.

The light-emitting layer can contain two or more substances selected from light-emitting substances emitting light of red (R), green (G), blue (B), yellow (Y), orange (O), and the like. For example, in a light-emitting element emitting white light, a light-emitting layer preferably contains two or more kinds of light-emitting substances. In order to obtain white light, light-emitting substances may be selected so that colors of light emitted by the two light-emitting substances are complementary colors, or light-emitting substances may be selected so that colors of light emitted by two or more light-emitting substances are combined to be white. For example, in the case where white light is obtained with use of two light-emitting layers, the emission colors of the two light-emitting layers are complementary, so that the light-emitting element can emit white light as a whole. In the case where three or more light-emitting layers are used to obtain white light, the light-emitting element can be configured to emit white light as a whole by combining emission colors of the three or more light-emitting layers.

The light-emitting layer preferably contains two or more light-emitting substances emitting light of red (R), green (G), blue (B), yellow (Y), orange (O), or the like. Alternatively, the light-emitting layer preferably contains two or more light-emitting substances emitting light containing two or more of spectral components of R, G, and B. As the light-emitting substance, a substance that emits near-infrared light can also be used.

Examples of a light-emitting substance include a substance exhibiting fluorescence (a fluorescent material), a substance exhibiting phosphorescence (a phosphorescent material), and a substance exhibiting thermally activated delayed fluorescence (a thermally activated delayed fluorescent (TADF) material). Examples of the light-emitting substance contained in the EL element include not only organic compounds but also inorganic compounds (e.g., quantum dot materials).

### <Method for Forming Light-Emitting Element>

An example of a method for forming the light-emitting element 61 is described below.

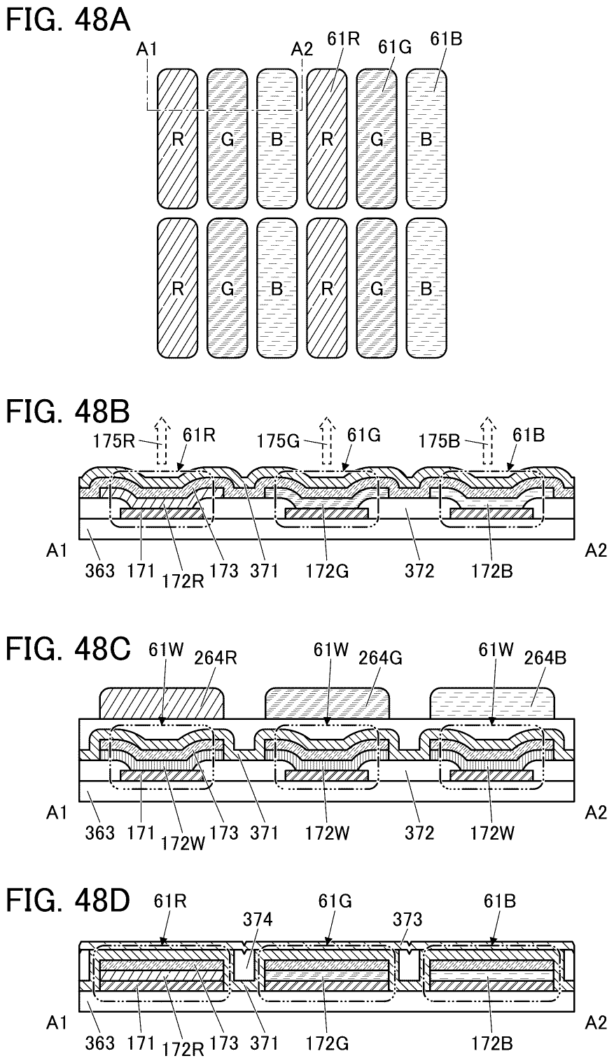

FIG. 48A is a schematic top view of the light-emitting element 61. The light-emitting element 61 includes a plurality of light-emitting elements 61R emitting red light, a plurality of light-emitting elements 61G emitting green light, and a plurality of light-emitting elements 61B emitting blue light. In FIG. 48A, light-emitting regions of the light-emitting elements are denoted by R, G, and B to easily differentiate the light-emitting elements. Although the structure exemplified in FIG. 48A has three emission colors of red (R), green (G), and blue (B), one embodiment of the present invention is not limited thereto. For example, the structure can have four or more colors.

The light-emitting elements 61R, the light-emitting elements 61G, and the light-emitting elements 61B are arranged in a matrix. Although FIG. 48A illustrates what is called a stripe arrangement in which the light-emitting elements of the same color are arranged in one direction, the arrangement of the light-emitting elements is not limited thereto.

As the light-emitting elements 61R, 61G, and 61B, an organic EL device such as an OLED or a quantum-dot OLED (QOLED) is preferably used. Examples of a light-emitting substance contained in the EL element include a substance exhibiting fluorescence (a fluorescent material), a substance exhibiting phosphorescence (a phosphorescent material), and a substance exhibiting thermally activated delayed fluorescence (a thermally activated delayed fluorescent (TADF) material). Examples of the light-emitting substance contained in the EL element include not only organic compounds but also inorganic compounds (e.g., quantum dot materials).

FIG. 48B is a schematic cross-sectional view taken along dashed-dotted line A1-A2 in FIG. 48A. FIG. 48B illustrates a cross section of the light-emitting elements 61R, 61G, and 61B. The light-emitting elements 61R, 61G, and 61B are provided over an insulating layer 363, and include the conductive layer 171 functioning as a pixel electrode and the conductive layer 173 functioning as a common electrode. For the insulating layer 363, one or both of an inorganic insulating film and an organic insulating film can be used. An inorganic insulating film is preferably used for the insulating layer 363. Examples of the inorganic insulating film include an oxide insulating film and a nitride insulating film, such as a silicon oxide film, a silicon oxynitride film, a silicon nitride oxide film, a silicon nitride film, an aluminum oxide film, an aluminum oxynitride film, and a hafnium oxide film.

The light-emitting element 61R includes an EL layer 172R between the conductive layer 171 functioning as a pixel electrode and the conductive layer 173 functions as a common electrode. The EL layer 172R contains at least a light-emitting organic compound that emits light with a peak in a red wavelength range. An EL layer 172G included in the light-emitting element 61G contains at least a light-emitting organic compound that emits light with a peak in a green wavelength range. An EL layer 172B included in the light-emitting element 61B contains at least a light-emitting organic compound that emits light with a peak in a blue wavelength range.

The EL layers 172R, 172G, and 172B can each include one or more of an electron-injection layer, an electron-transport layer, a hole-injection layer, and a hole-transport layer in addition to the layer containing a light-emitting substance (the light-emitting layer).

The conductive layer 171 functioning as a pixel electrode is provided for each of the light-emitting elements. The conductive layer 173 functioning as a common electrode is provided as a layer common to the light-emitting elements. A conductive film that has a property of transmitting visible light is used for either the conductive layer 171 functioning as a pixel electrode or the conductive layer 173 functioning as a common electrode, and a reflective conductive film is used for the other. When the conductive layer 171 functioning as a pixel electrode is a light-transmitting electrode and the conductive layer 173 functioning as a common electrode is a reflective electrode, a bottom-emission display apparatus can be obtained. When the conductive layer 171 functioning as a pixel electrode is a reflective electrode and the conductive layer 173 functioning as a common electrode is a light-transmitting electrode, a top-emission display apparatus can be obtained. Note that when both the conductive layer 171 functioning as a pixel electrode and the conductive layer 173 functioning as a common electrode are light-transmitting electrodes, a dual-emission display apparatus can be obtained.

For example, in the case where the light-emitting element 61R has a top-emission structure, light 175R is emitted from the light-emitting element 61R to the conductive layer 173 side. In the case where the light-emitting element 61G has a top-emission structure, light 175G is emitted from the light-emitting element 61G to the conductive layer 173 side. In the case where the light-emitting element 61B has a top-emission structure, light 175B is emitted from the light-emitting element 61B to the conductive layer 173 side.

An insulator 372 is provided to cover an end portion of the conductive layer 171 functioning as a pixel electrode. An end portion of the insulator 372 is preferably tapered. For the insulator 372, a material similar to the material that can be used for the insulating layer 363 can be used.

The insulator 372 is provided to prevent an unintentional electric short-circuit between adjacent light-emitting elements 61 and unintended light emission therefrom. The insulator 372 also has a function of preventing the contact of a metal mask with the conductive layer 171 in the case where the metal mask is used for forming the EL layer 172.

The EL layers 172R, 172G, and 172B each include a region in contact with the top surface of the conductive layer 171 functioning as a pixel electrode and a region in contact with a surface of the insulator 372. End portions of the EL layers 172R, 172G, and 172B are positioned over the insulator 372.

As illustrated in FIG. 48B, there is a gap between the EL layers of two light-emitting elements with different colors. The EL layers 172R, 172G, and 172B are thus preferably provided not to be in contact with each other. This suitably prevents unintentional light emission (also referred to as crosstalk) from being caused by a current flowing through two adjacent EL layers. As a result, the contrast can be increased to achieve a display apparatus with high display quality.

The EL layers 172R, 172G, and 172B can be formed separately by a vacuum evaporation method or the like using a shadow mask such as a metal mask. These layers can also be formed separately by a photolithography method. The use of the photolithography method achieves a display apparatus with high definition, which is difficult to obtain in the case of using a metal mask.

In this specification and the like, a device formed using a metal mask or a fine metal mask (FMM) may be referred to as a device having a metal mask (MM) structure. In this specification and the like, a device formed without using a metal mask or an FMM may be referred to as a device having a metal maskless (MML) structure. A display apparatus having an MML structure is manufactured without using a metal mask and thus has higher flexibility in designing the pixel arrangement, the pixel shape, and the like than a display apparatus having an MM structure.

A protective layer 371 is provided over the conductive layer 173 functioning as a common electrode to cover the light-emitting elements 61R, 61G, and 61B. The protective layer 371 has a function of preventing diffusion of impurities such as water into the light-emitting elements from the above.

The protective layer 371 can have, for example, a single-layer structure or a stacked-layer structure at least including an inorganic insulating film. Examples of the inorganic insulating film include an oxide film and a nitride film such as a silicon oxide film, a silicon oxynitride film, a silicon nitride oxide film, a silicon nitride film, an aluminum oxide film, an aluminum oxynitride film, and a hafnium oxide film. Alternatively, a semiconductor material such as indium gallium oxide or indium gallium zinc oxide (IGZO) can be used for the protective layer 371. The protective layer 371 can be formed by an ALD method, a CVD method, or a sputtering method. Although the protective layer 371 includes an inorganic insulating film in this example, one embodiment of the present invention is not limited thereto. For example, the protective layer 371 can have a stacked-layer structure of an inorganic insulating film and an organic insulating film.

Note that in this specification, a nitride oxide refers to a compound in which the nitrogen content is higher than the oxygen content. An oxynitride refers to a compound in which the oxygen content is higher than the nitrogen content. The content of each element can be measured by Rutherford backscattering spectrometry (RBS), for example.

In the case where indium gallium zinc oxide is used for the protective layer 371, the indium gallium zinc oxide can be processed by a wet etching method or a dry etching method. For example, in the case where IGZO is used for the protective layer 371, a chemical solution of oxalic acid, phosphoric acid, a mixed chemical solution (e.g., a mixed chemical solution of phosphoric acid, acetic acid, nitric acid, and water, which is also referred to as a mixed acid aluminum etchant), or the like can be used. Note that the volume ratio of phosphoric acid, acetic acid, nitric acid, and water mixed in the mixed acid aluminum etchant can be 53.3:6.7:3.3:36.7 or in the neighborhood thereof.

Note that the structure illustrated in FIG. 48B may be referred to as a side-by-side (SBS) structure described later.

FIG. 48C shows an example different from the above example. Specifically, in FIG. 48C, a light-emitting element 61W emitting white light is provided. The light-emitting element 61W includes an EL layer 172W emitting white light between the conductive layer 171 functioning as a pixel electrode and the conductive layer 173 functioning as a common electrode.

The EL layer 172W can have, for example, a stacked structure of two or more light-emitting layers that are selected so as to emit light of complementary colors. It is also possible to use a stacked EL layer in which a charge-generation layer is provided between light-emitting layers.

FIG. 48C illustrates three light-emitting elements 61W side by side. A coloring layer 264R is provided above the left light-emitting element 61W. The coloring layer 264R functions as a band pass filter transmitting red light. Similarly, a coloring layer 264G transmitting green light is provided above the middle light-emitting element 61W, and a coloring layer 264B transmitting blue light is provided above the right light-emitting element 61W. This enables the semiconductor device to display color images.

The EL layer 172W and the conductive layer 173 functioning as a common electrode are each separated between adjacent two light-emitting elements 61W. This can prevent unintentional light emission from being caused by a current flowing through the EL layers 172W in the two adjacent light-emitting elements 61W. Particularly when the EL layer 172W is a stacked EL layer in which a charge-generation layer is provided between two light-emitting layers, the effect of crosstalk is more significant as the definition increases, i.e., as the distance between adjacent pixels decreases, leading to lower contrast. Thus, the above structure can achieve a display apparatus having both high definition and high contrast.

The EL layer 172W and the conductive layer 173 functioning as a common electrode are each preferably separated by a photolithography method. This can reduce the distance between light-emitting elements, achieving a display apparatus with a higher aperture ratio than that formed using, for example, a shadow mask such as a metal mask.

Note that in the case of a bottom-emission light-emitting element, coloring layers are provided between the conductive layer 171 functioning as a pixel electrode and the insulating layer 363.

FIG. 48D shows an example different from the above example. Specifically, in FIG. 48D, the insulators 372 are not provided between the light-emitting elements 61R, 61G, and 61B. With such a structure, a display apparatus with a high aperture ratio can be obtained. When the insulator 372 is not provided, unevenness formed by the light-emitting elements 61 can be reduced, thereby improving the viewing angle of the display apparatus. Specifically, the viewing angle can be greater than or equal to 150° and less than 180°, preferably greater than or equal to 160° and less than 180°.

The protective layer 371 covers the side surfaces of the EL layers 172R, 172G, and 172B. With this structure, impurities (typically, water or the like) can be inhibited from entering the EL layers 172R, 172G, and 172B through their side surfaces. In addition, a leakage current between adjacent light-emitting elements 61 is reduced, so that color saturation and contrast ratio are improved and power consumption is reduced.

In the structure illustrated in FIG. 48D, the conductive layer 171, the EL layer 172R, and the conductive layer 173 have substantially the same planar shape. This structure can be formed in such a manner that the conductive layer 171, the EL layer 172R, and the conductive layer 173 are formed, and collectively processed using a resist mask or the like. In this process, the EL layer 172R and the conductive layer 173 are processed using the conductive layer 173 as a mask, and thus this process can be called self-alignment patterning. Although the EL layer 172R is described here, the EL layer 172G and the EL layer 172B can each have a similar structure.

In FIG. 48D, a protective layer 373 is further provided over the protective layer 371. For example, the protective layer 371 is formed with an apparatus that can form a film with excellent coverage (typically, an ALD apparatus or the like), and the protective layer 373 is formed with an apparatus that can form a film with coverage inferior to that of the protective layer 371 (typically, a sputtering apparatus or the like), whereby a region 374 can be provided between the protective layer 371 and the protective layer 373. In other words, the regions 374 are positioned between the EL layer 172R and the EL layer 172G and between the EL layer 172G and the EL layer 172B.

Note that the region 374 contains, for example, one or more selected from air, nitrogen, oxygen, carbon dioxide, and Group 18 elements (typically, helium, neon, argon, xenon, and krypton). Furthermore, a gas used during the formation of the protective layer 373 is sometimes contained in the region 374. For example, in the case where the protective layer 373 is formed by a sputtering method, one or more of the above-described Group 18 elements may be contained in the region 374. In the case where a gas is contained in the region 374, a gas can be identified with a gas chromatography method or the like. Alternatively, in the case where the protective layer 373 is formed by a sputtering method, a gas used in the sputtering is sometimes contained also in the protective layer 373. In this case, an element such as argon may be detected when the protective layer 373 is analyzed by EDX analysis or the like.

In the case where the refractive index of the region 374 is lower than that of the protective layer 371, light emitted from the EL layer 172R, the EL layer 172G, or the EL layer 172B is reflected at the interface between the protective layer 371 and the region 374. Thus, light emitted from the EL layer 172R, the EL layer 172G, or the EL layer 172B can be inhibited from entering an adjacent pixel in some cases. This can inhibit color mixture of light emitted from adjacent pixels and thus can improve the display quality of the display apparatus.

In the structure illustrated in FIG. 48D, a region between the light-emitting elements 61R and 61G or a region between the light-emitting elements 61G and 61B (hereinafter simply referred to as a distance between the light-emitting elements) can be shortened. Specifically, the distance between the light-emitting elements can be 1 μm or shorter, preferably 500 nm or shorter, further preferably 200 nm or shorter, 100 nm or shorter, 90 nm or shorter, 70 nm or shorter, 50 nm or shorter, 30 nm or shorter, 20 nm or shorter, 15 nm or shorter, or 10 nm or shorter. In other words, the display apparatus includes a region in which an interval between the side surface of the EL layer 172R and the side surface of the EL layer 172G or an interval between the side surface of the EL layer 172G and the side surface of the EL layer 172B is 1 μm or shorter, preferably 0.5 μm (500 nm) or shorter, further preferably 100 nm or shorter.

In the case where the region 374 contains a gas, for example, the light-emitting elements can be isolated from each other and color mixture of light from the light-emitting elements, crosstalk, or the like can be inhibited.

Alternatively, the region 374 may be a space or may be filled with a filler. Examples of the filler include an epoxy resin, an acrylic resin, a silicone resin, a phenol resin, a polyimide resin, an imide resin, a polyvinyl chloride (PVC) resin, a polyvinyl butyral (PVB) resin, and an ethylene vinyl acetate (EVA) resin. Alternatively, a photoresist can be used as the filler. The photoresist used as the filler may be a positive photoresist or a negative photoresist.

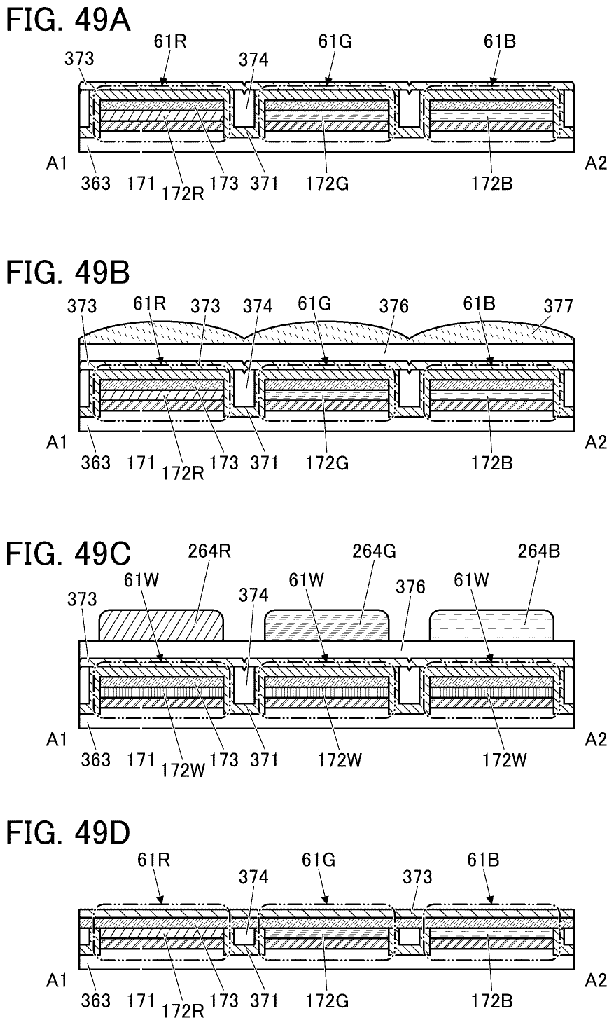

FIG. 49A shows an example different from the above example. Specifically, the structure illustrated in FIG. 49A is different from that in FIG. 48D in the structure of the insulating layer 363. The insulating layer 363 has a depressed portion in its top surface that is formed by being partially etched when the light-emitting elements 61R, 61G, and 61B are processed. In addition, the protective layer 371 is formed in the depressed portion. In other words, in the cross-sectional view, there is a region in which the bottom surface of the protective layer 371 is positioned below the bottom surface of the conductive layer 171. With the region, impurities (typically, water or the like) can be suitably inhibited from entering the light-emitting elements 61R, 61G, and 61B from the bottom. It is likely that the depressed portion can be formed when impurities (also referred to as residue) that could be attached to the side surfaces of the light-emitting elements 61R, 61G, and 61B in processing of the light-emitting elements are removed by wet etching or the like. After the residue is removed, the side surfaces of the light-emitting elements are covered with the protective layer 371, whereby a highly reliable display apparatus can be provided.

FIG. 49B shows an example different from the above example. Specifically, the structure illustrated in FIG. 49B includes an insulator 376 and a microlens array 377 in addition to the structure illustrated in FIG. 49A. The insulator 376 has a function of an adhesive layer. Note that when the refractive index of the insulator 376 is lower than that of the microlens array 377, the microlens array 377 can condense light emitted from the light-emitting elements 61R, 61G, and 61B. This can increase the outcoupling efficiency of the display apparatus. In particular, this is suitable, because a user can see bright images when the user sees the display surface from the front of the display apparatus. As the insulator 376, various curable adhesives such as a reactive curable adhesive, a thermosetting adhesive, an anaerobic adhesive, and a photocurable adhesive such as an ultraviolet curable adhesive can be used. Examples of these adhesives include an epoxy resin, an acrylic resin, a silicone resin, a phenol resin, a polyimide resin, an imide resin, a PVC resin, a PVB resin, and an EVA resin. In particular, a material with low moisture permeability, such as an epoxy resin, is preferable. A two-component-mixture-type resin can be used. An adhesive sheet or the like can be used.

FIG. 49C shows an example different from the above example. Specifically, the structure illustrated in FIG. 49C includes three light-emitting elements 61W instead of the light-emitting elements 61R, 61G, and 61B in the structure illustrated in FIG. 49A. In addition, the insulator 376 is provided over the three light-emitting elements 61W, and the coloring layers 264R, 264G, and 264B are provided over the insulator 376. Specifically, the coloring layer 264R transmitting red light is provided at a position overlapping with the left light-emitting element 61W, the coloring layer 264G transmitting green light is provided at a position overlapping with the middle light-emitting element 61W, and the coloring layer 264B transmitting blue light is provided at a position overlapping with the right light-emitting element 61W. This enables the semiconductor device to display color images. The structure illustrated in FIG. 49C is also a modification example of the structure illustrated in FIG. 48C.

FIG. 49D shows an example different from the above example. Specifically, in the structure illustrated in FIG. 49D, the protective layer 371 is provided adjacent to the side surfaces of the conductive layer 171 and the EL layer 172. The conductive layer 173 is provided as a layer common to the light-emitting elements. In the structure illustrated in FIG. 49D, the region 374 is preferably filled with a filler.

When the light-emitting element 61 has a micro-optical resonator (microcavity) structure, the color purity of each emission color can be increased. In order that the light-emitting element 61 has a microcavity structure, a product of a distance d between the conductive layers 171 and 173 and a refractive index n of the EL layer 172 (optical path length) is preferably set to m times greater than the half of a wavelength λ (m is an integer of 1 or more). The distance d can be obtained by Formula (3).

$$[ Formula 3 ]$$

$$d = m \times λ / ( 2 \times n ) \qquad ( 3 )$$

According to Formula (3), in the light-emitting element 61 having the microcavity structure, the distance d depends on the wavelength (color) of emitted light. The distance d corresponds to the thickness of the EL layer 172. Thus, the EL layer 172G is provided to have a larger thickness than the EL layer 172B, and the EL layer 172R is provided to have a larger thickness than the EL layer 172G in some cases.

To be exact, the distance d is a distance from a reflection region in the conductive layer 171 functioning as a reflective electrode to a reflection region in the conductive layer 173 functioning as an electrode having properties of transmitting and reflecting emitted light (a transflective electrode). For example, in the case where the conductive layer 171 is a stack of silver and ITO that is a transparent conductive film and the ITO is positioned on the EL layer 172 side, the distance d suitable for the emission color can be set by adjusting the thickness of the ITO. That is, even when the EL layers 172R, 172G, and 172B have the same thickness, the distance d suitable for the emission color can be obtained by adjusting the thickness of the ITO.

However, it is sometimes difficult to determine the exact position of the reflection region in each of the conductive layers 171 and 173. In this case, it is assumed that the effect of the microcavity structure can be obtained sufficiently with a certain position in each of the conductive layers 171 and 173 being supposed as the reflective region.

The light-emitting element 61 includes a hole-injection layer, a hole-transport layer, a light-emitting layer, an electron-transport layer, an electron-injection layer, and the like. A specific structure example of the light-emitting element 61 is described in another embodiment. In order to increase the outcoupling efficiency in the microcavity structure, the optical path length from the conductive layer 171 functioning as a reflective electrode to the light-emitting layer is preferably set to an odd multiple of λ/4. In order to achieve this optical path length, the thicknesses of the layers in the light-emitting element 61 are preferably adjusted as appropriate.

In the case where light is emitted from the conductive layer 173 side, the reflectance of the conductive layer 173 is preferably higher than the transmittance thereof. The transmittance of the conductive layer 173 is preferably higher than or equal to 2% and lower than or equal to 50%, further preferably higher than or equal to 2% and lower than or equal to 30%, still further preferably higher than or equal to 2% and lower than or equal to 10%. When the transmittance of the conductive layer 173 is set low (the reflectance is set high), the effect of the microcavity structure can be enhanced.

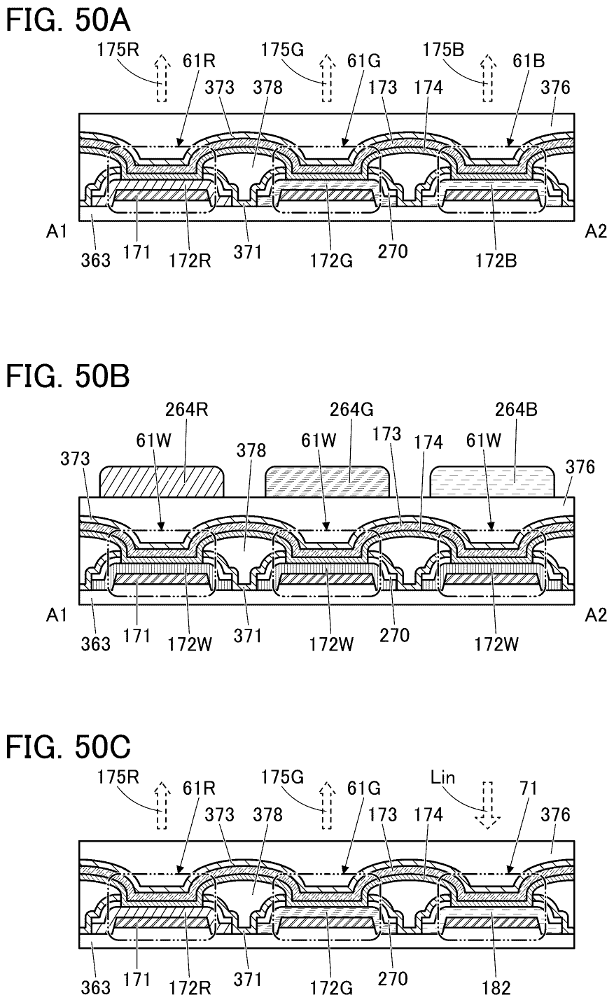

FIG. 50A shows an example different from the above example. Specifically, in the structure illustrated in FIG. 50A, the EL layer 172 extends beyond an end portion of the conductive layer 171 in each of the light-emitting elements 61R, 61G, and 61B. For example, in the light-emitting element 61R, the EL layer 172R extends beyond the end portion of the conductive layer 171. In the light-emitting element 61G, the EL layer 172G extends beyond the end portion of the conductive layer 171. In the light-emitting element 61B, the EL layer 172B extends beyond the end portion of the conductive layer 171.

The light-emitting elements 61R, 61G, and 61B each include a region where the EL layer 172 and the protective layer 371 overlap with each other with an insulating layer 270 therebetween. In a region between adjacent light-emitting elements 61, an insulator 378 is provided over the protective layer 371.

For the insulator 378, an epoxy resin, an acrylic resin, a silicone resin, a phenol resin, a polyimide resin, an imide resin, a PVC resin, a PVB resin, an EVA resin, and the like can be used. Alternatively, a photoresist can be used as the insulator 378. The photoresist used as the insulator 378 may be a positive photoresist or a negative photoresist.

A common layer 174 is provided over the light-emitting element 61R, the light-emitting element 61G, the light-emitting element 61B, and the insulator 378, and the conductive layer 173 is provided over the common layer 174. The common layer 174 includes a region in contact with the EL layer 172R, a region in contact with the EL layer 172G, and a region in contact with the EL layer 172B. The common layer 174 is shared by the light-emitting elements 61R, 61G, and 61B.

One or more of a hole-injection layer, a hole-transport layer, a hole-blocking layer, an electron-blocking layer, an electron-transport layer, and an electron-injection layer can be used as the common layer 174. For example, the common layer 174 may be a carrier-injection layer (a hole-injection layer or an electron-injection layer). The common layer 174 can also be regarded as part of the EL layer 172. Note that the common layer 174 is provided as necessary. In the case where the common layer 174 is provided, a layer having the same function as the common layer 174 is not necessarily provided in the EL layer 172.

In addition, the protective layer 373 is provided over the conductive layer 173, and the insulator 376 is provided over the protective layer 373.

FIG. 50B shows an example different from the above example. Specifically, the structure illustrated in FIG. 50B includes three light-emitting elements 61W instead of the light-emitting elements 61R, 61G, and 61B in the structure illustrated in FIG. 50A. In addition, the insulator 376 is provided over the three light-emitting elements 61W, and the coloring layers 264R, 264G, and 264B are provided over the insulator 376. Specifically, the coloring layer 264R transmitting red light is provided at a position overlapping with the left light-emitting element 61W, the coloring layer 264G transmitting green light is provided at a position overlapping with the middle light-emitting element 61W, and the coloring layer 264B transmitting blue light is provided at a position overlapping with the right light-emitting element 61W. This enables the semiconductor device to display color images. The structure illustrated in FIG. 50B is also a modification example of the structure illustrated in FIG. 49C.

As illustrated in FIG. 50C, the light-emitting element 61R, the light-emitting element 61G, and a light-receiving element 71 can be provided over the insulating layer 363. The light-receiving element 71 illustrated in FIG. 50C is achieved by replacing the EL layer 172 of the light-emitting element 61 with an active layer 182 (also referred to as a “light-receiving layer”) serving as a photoelectric conversion layer. The active layer 182 has a feature of changing a resistance value depending on the wavelength and intensity of the incident light. Like the EL layer 172, the active layer 182 can be formed with an organic compound. Note that an inorganic material such as silicon can also be used for the active layer 182.

The light-receiving element 71 has a function of sensing light Lin entering from the outside of the display apparatus and passing through the protective layer 373, the conductive layer 173, and the common layer 174. A coloring layer transmitting light in a given wavelength range is preferably provided on the incident side of the light Lin so as to overlap with the light-receiving element 71.

<Materials that can be Used for Light-Emitting Element>

Materials that can be used for the light-emitting element will be described.

The hole-injection layer injects holes from the anode to the hole-transport layer and contains a material with a high hole-injection property. Examples of the material with a high hole-injection property include an aromatic amine compound and a composite material containing a hole-transport material and an acceptor material (electron-accepting material).

The hole-transport layer transports holes injected from the anode by the hole-injection layer, to the light-emitting layer. The hole-transport layer contains a hole-transport material. The hole-transport material preferably has a hole mobility higher than or equal to 1×10⁻⁶ cm²/Vs. Note that other substances can also be used as long as the substances have a hole-transport property higher than an electron-transport property. As the hole-transport material, materials having a high hole-transport property, such as a π-electron rich heteroaromatic compound (e.g., a carbazole derivative, a thiophene derivative, and a furan derivative) and an aromatic amine (a compound having an aromatic amine skeleton), are preferable.

The electron-transport layer transports electrons injected from the cathode by the electron-injection layer, to the light-emitting layer. The electron-transport layer contains an electron-transport material. The electron-transport material preferably has an electron mobility higher than or equal to 1×10⁻⁶ cm²/Vs. Note that other substances can also be used as long as the substances have an electron-transport property higher than a hole-transport property. As the electron-transport material, any of the following materials having a high electron-transport property can be used, for example: a metal complex having a quinoline skeleton, a metal complex having a benzoquinoline skeleton, a metal complex having an oxazole skeleton, a metal complex having a thiazole skeleton, an oxadiazole derivative, a triazole derivative, an imidazole derivative, an oxazole derivative, a thiazole derivative, a phenanthroline derivative, a quinoline derivative having a quinoline ligand, a benzoquinoline derivative, a quinoxaline derivative, a dibenzoquinoxaline derivative, a pyridine derivative, a bipyridine derivative, a pyrimidine derivative, and a π-electron deficient heteroaromatic compound such as a nitrogen-containing heteroaromatic compound.

The electron-injection layer injects electrons from the cathode to the electron-transport layer and contains a material with a high electron-injection property. As the material with a high electron-injection property, an alkali metal, an alkaline earth metal, or a compound thereof can be used. As the material with a high electron-injection property, a composite material containing an electron-transport material and a donor material (electron-donating material) can also be used.

The electron-injection layer can be formed using an alkali metal, an alkaline earth metal, or a compound thereof, such as lithium, cesium, ytterbium, lithium fluoride (LiF), cesium fluoride (CsF), calcium fluoride (CaFₓ, x is a given number), 8-(quinolinolato) lithium (abbreviation: Liq), 2-(2-pyridyl) phenolatolithium (abbreviation: LiPP), 2-(2-pyridyl)-3-pyridinolato lithium (abbreviation: LiPPy), 4-phenyl-2-(2-pyridyl) phenolatolithium (abbreviation: LiPPP), lithium oxide (LiOₓ), or cesium carbonate, for example. The electron-injection layer can have a stacked-layer structure of two or more layers. In the stacked-layer structure, for example, lithium fluoride can be used for the first layer and ytterbium can be used for the second layer.

Alternatively, the electron-injection layer can be formed using an electron-transport material. For example, a compound having an unshared electron pair and an electron deficient heteroaromatic ring can be used as the electron-transport material. Specifically, a compound having at least one of a pyridine ring, a diazine ring (a pyrimidine ring, a pyrazine ring, and a pyridazine ring), and a triazine ring can be used.

Note that the lowest unoccupied molecular orbital (LUMO) level of the organic compound having an unshared electron pair is preferably greater than or equal to −3.6 eV and less than or equal to −2.3 eV. In general, the highest occupied molecular orbital (HOMO) level and the LUMO level of an organic compound can be estimated by cyclic voltammetry (CV), photoelectron spectroscopy, optical absorption spectroscopy, inverse photoelectron spectroscopy, or the like.

For example, 4,7-diphenyl-1,10-phenanthroline (abbreviation: BPhen), 2,9-di(naphthalen-2-yl)-4,7-diphenyl-1,10-phenanthroline (abbreviation: NBPhen), 2,2′-(1,3-phenylene)bis(9-phenyl-1,10-phenanthroline) (abbreviation: mPPhen2P), diquinoxalino[2,3-a:2′,3′-c]phenazine (abbreviation: HATNA), or 2,4,6-tris[3′-(pyridin-3-yl)biphenyl-3-yl]-1,3,5-triazine (abbreviation: TmPPPyTz) can be used as the organic compound having an unshared electron pair. Note that NBPhen has a higher glass transition point (Tg) than BPhen and thus has high heat resistance.

### <Circuit Configuration Examples of Display Apparatuses>

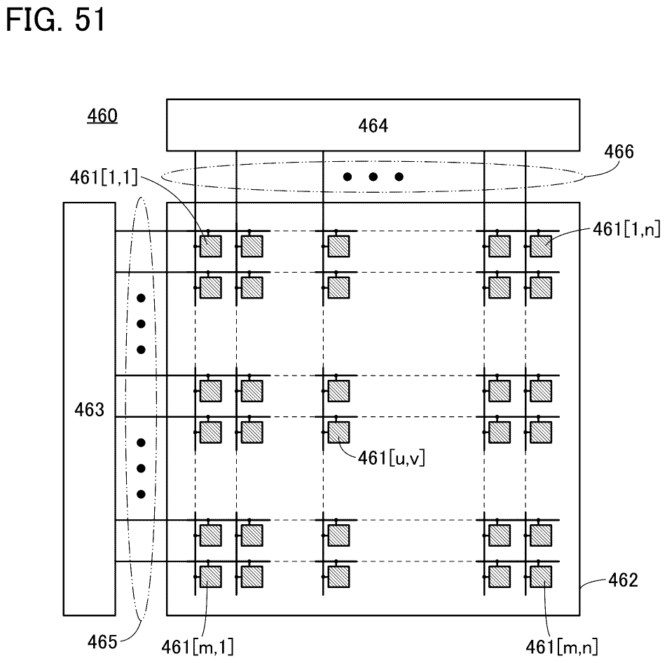

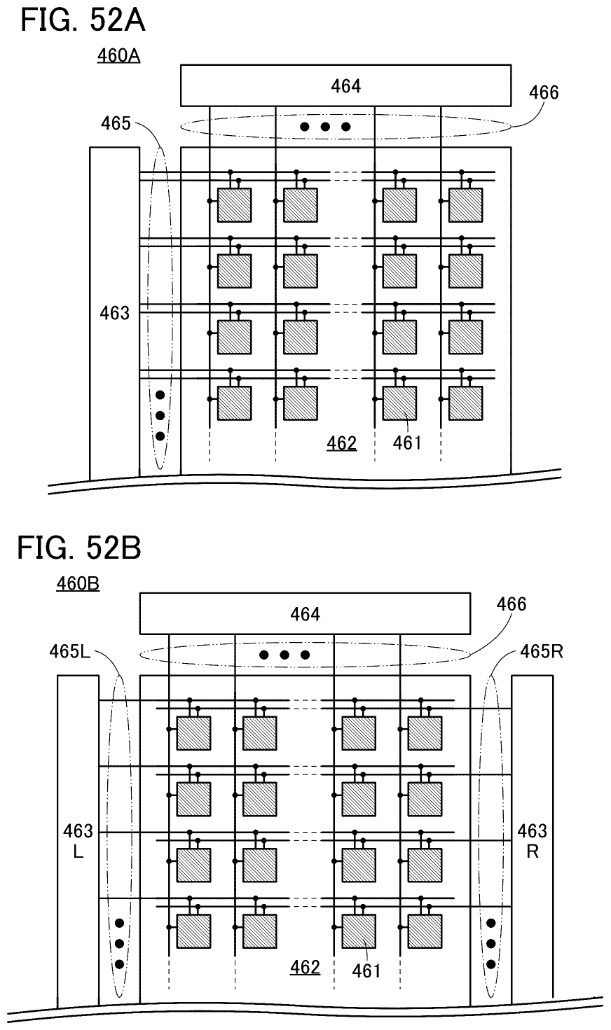

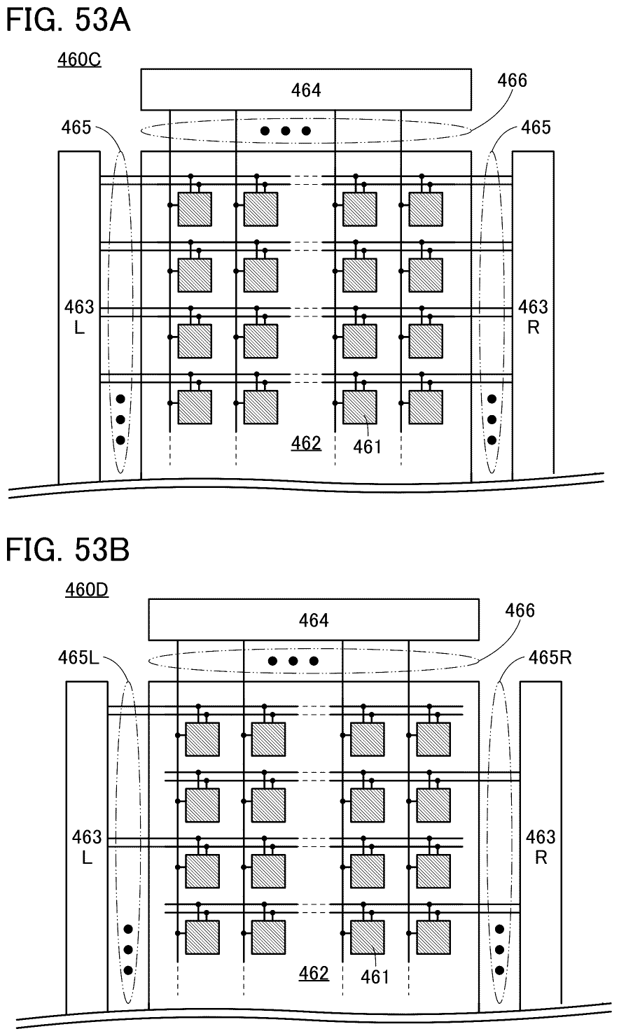

FIG. 51, FIGS. 52A and 52B, and FIGS. 53A, and 53B are block diagrams each showing a configuration example of a display apparatus 460 that can be employed for the display apparatus 400 of one embodiment of the present invention.

As illustrated in FIG. 51, the display apparatus 460 includes a display portion 462, a first driver circuit portion 463, and a second driver circuit portion 464. For example, the display portion 462 includes a plurality of pixels 461 arranged in a matrix of m rows and n columns (m and n are each an integer greater than or equal to 2).

Note that in the case where the above-described display apparatus 400 employs at least part of the structure of the display apparatus 460, the pixel 461, the display portion 462, the first driver circuit portion 463, and the second driver circuit portion 464 correspond to the pixel 453, the display portion 452, the circuit portion 454a, and the circuit portion 454b, respectively. Note that the first driver circuit portion 463 and the second driver circuit portion 464 each include at least part of the IC 456 in some cases.

In FIG. 51, the pixel 461 placed in the first row and the first column is denoted as a pixel 461[1,1], the pixel 461 placed in the first row and an n-th column is denoted as a pixel 461[1,n], the pixel 461 placed in an m-th row and the first column is denoted as a pixel 461[m, 1], and the pixel 461 placed in the m-th row and the n-th column is denoted as a pixel 461[m,n]. Note that the pixel 461 placed in a u-th row and a v-th column is denoted as a pixel 461[u,v] (u is an integer greater than or equal to 1 and less than or equal to m and v is an integer greater than or equal to 1 and less than or equal to n) in some cases.

The display apparatus 460 includes m wirings 465 which are arranged parallel or substantially parallel to each other and whose potentials are controlled by a circuit included in the first driver circuit portion 463. The potential of one wiring 465 is supplied to n pixels 461 arranged in the row direction. Note that a plurality of wirings can form one wiring 465 depending on the circuit configuration of the pixel 461. In a display apparatus 460A illustrated in FIG. 52A, two wirings form one wiring 465.

The display apparatus 460 includes n wirings 466 which are arranged parallel or substantially parallel to each other and whose potentials are controlled by a circuit included in the second driver circuit portion 464. The potential of one wiring 466 is supplied to n pixels 461 arranged in the column direction. Note that a plurality of wirings can form one wiring 466 depending on the circuit configuration of the pixel 461.

The pixel 461 is configured such that when a data potential is written to a pixel circuit selected by the potential of the wiring 465 through the wiring 466, the light-emitting element emits light with an emission intensity corresponding to the data potential, for example.

The circuit included in the first driver circuit portion 463 serves as, for example, a scan line driver circuit (sometimes referred to as a gate line driver circuit, a gate driver, a scan driver, or a row driver).

The circuit included in the second driver circuit portion 464 serves as, for example, a signal line driver circuit (sometimes referred to as a source line driver circuit, a source driver, a data driver, or a column driver). For example, the circuit can have a function of converting data of an image to be displayed on the display apparatus 460 into a video signal to be supplied to each pixel (digital-to-analog conversion).

Note that the pixel 461 can be configured such that a current flowing through the light-emitting element is output to a monitor line (not illustrated), for example. The current output to the monitor line can be output to the outside of the display apparatus 460 after being subjected to conversion into an analog voltage (current-to-voltage conversion) or into a digital signal (analog-to-digital conversion) in the second driver circuit portion 464, for example. The analog voltage or the digital signal can be used for video signal correction outside the display apparatus (also referred to as external correction), for example.

Specific configuration examples of the constituent circuits that can be used for the circuits included in the first driver circuit portion 463 and the second driver circuit portion 464 will be described later. Note that a semiconductor device 480 described later can be used for at least part of the circuits included in the first driver circuit portion 463 and the second driver circuit portion 464, for example.

In one embodiment of the present invention, any of various configurations can be employed for modification examples of the display apparatus 460. For example, as illustrated in FIGS. 52A and 52B and FIGS. 53A and 53B, a first driver circuit portion 463L and a first driver circuit portion 463R can be arranged to face each other across the display portion 462.

A display apparatus 460B illustrated in FIG. 52B includes m wirings 465L whose potentials are controlled by the circuit included in the first driver circuit portion 463L and m wirings 465R whose potentials are controlled by the circuit included in the first driver circuit portion 463R. The potentials of one wiring 465L and one wiring 465R are supplied to n pixels 461 arranged in the row direction.

A display apparatus 460C illustrated in FIG. 53A includes m wirings 465 whose potentials are controlled by both the circuit included in the first driver circuit portion 463L and the circuit included in the first driver circuit portion 463R. The potential of one wiring 465 is supplied to n pixels 461 arranged in the row direction. Such a configuration reduces substantial loads on the wiring (parasitic capacitance and parasitic resistance) to a quarter of the load on the wiring of the display apparatus 460A. Accordingly, the display apparatus can achieve higher speed, definition, and resolution, a narrower bezel, and a larger screen, for example.

A display apparatus 460D illustrated in FIG. 53B includes m wirings 465L whose potentials are controlled by the circuit included in the first driver circuit portion 463L and m wirings 465R whose potentials are controlled by the circuit included in the first driver circuit portion 463R. The potential of one wiring 465L is supplied to n pixels 461 arranged in odd-numbered rows in the row direction. The potential of one wiring 465R is supplied to n pixels 461 arranged in even-numbered rows in the row direction. Such a configuration can reduce the number of stages of the shift register to half of that of the display apparatus 460A, for example. Accordingly, the display apparatus can achieve higher speed, definition, and resolution, a narrower bezel, and a larger screen, for example.

Although not illustrated, for example, two second driver circuit portions 464 can be arranged to face each other across the display portion 462.

According to one embodiment of the present invention, for example, the display apparatus 460 can employ not only any of various configurations described above but also include a sensor portion provided to overlap with the display portion 462 in a top view. The sensor portion can serve as, for example, a touch sensor, a near touch sensor, or a fingerprint sensor. Such a sensor can be a capacitive touch sensor or an optical touch sensor, for example.

In the display apparatus 460 provided with the sensor portion, the first driver circuit portion 463 (or the first driver circuit portions 463L and 463R) can include a circuit having a function of driving the sensor portion, for example. The second driver circuit portion 464 can include a circuit having a function of outputting a signal detected by the sensor portion to the outside of the display apparatus, for example.

### [Peripheral Driver Circuit]

Next, configuration examples of the constituent circuits that can be used for the peripheral driver circuit included in the display apparatus 460 are described.

In this specification and the like, circuits included in the first driver circuit portion 463 and the second driver circuit portion 464 in the display apparatus 460 are collectively referred to as a “peripheral driver circuit” in some cases.

The peripheral driver circuit can be formed with various constituent circuits. Examples of the constituent circuits include a shift register circuit, a flip-flop circuit, a latch circuit, a buffer circuit, an inverter circuit, and a level shifter circuit. Other examples include a multiplexer circuit, a demultiplexer circuit, a source follower circuit, a source-grounded amplifier circuit, a sample-and-hold circuit, and a switch circuit (such as a transmission gate or an analog switch). Other examples include a current-to-voltage converter circuit, an analog-to-digital converter circuit, a digital-to-analog converter circuit, an operational amplifier circuit, a comparator circuit, a pass transistor logic circuit, an encoder circuit, a decoder circuit, and a gate circuit (such as an AND circuit, an OR circuit, or a NOT circuit). Other examples include circuits combining these circuits. Note that these constituent circuits can be formed with, for example, a transistor, a capacitor, and the like.

In one embodiment of the present invention, various transistors can be used as transistors included in the peripheral driver circuit. For example, some or all of the transistors included in the peripheral driver circuit can be vertical transistors such as the above-described transistor 200C.

The use of vertical transistors as some or all of the transistors included in the peripheral driver circuit can reduce the footprint of a buffer circuit or the like included in circuits included in the first driver circuit portion 463, for example. Accordingly, the display apparatus can have a narrower bezel, for example. Furthermore, for example, the footprint of a demultiplexer, a source follower circuit, or the like included in circuits included in the second driver circuit portion 464 can be reduced. This leads to the higher resolution and definition of the display apparatus.

As some or all of the transistors included in the peripheral driver circuit, OS transistors can be used, for example. Alternatively, both OS transistors and Si transistors can be used, for example.

As described above, an OS transistor has a characteristic of an extremely low off-state current. The OS transistor is also characterized by its off-state current that hardly increases and its on-state current that is less likely to decrease even in a high-temperature environment. A Si transistor has higher operation speed than an OS transistor. The gate of an n-type transistor and the gate of a p-type transistor are connected to each other, for example, to form a CMOS circuit (for example, a circuit where the transistors operate complementarily, a CMOS logic gate, or a CMOS logic circuit).

In addition, a CMOS circuit can be formed using an OS transistor as an n-type transistor and a Si transistor as a p-type transistor. The combination of an OS transistor and a Si transistor enables a semiconductor device with low power consumption and high operation speed. Depending on the specifications of the display apparatus, an OS transistor and a Si transistor are used appropriately as the transistors included in the peripheral driver circuit.

### [Shift Register]

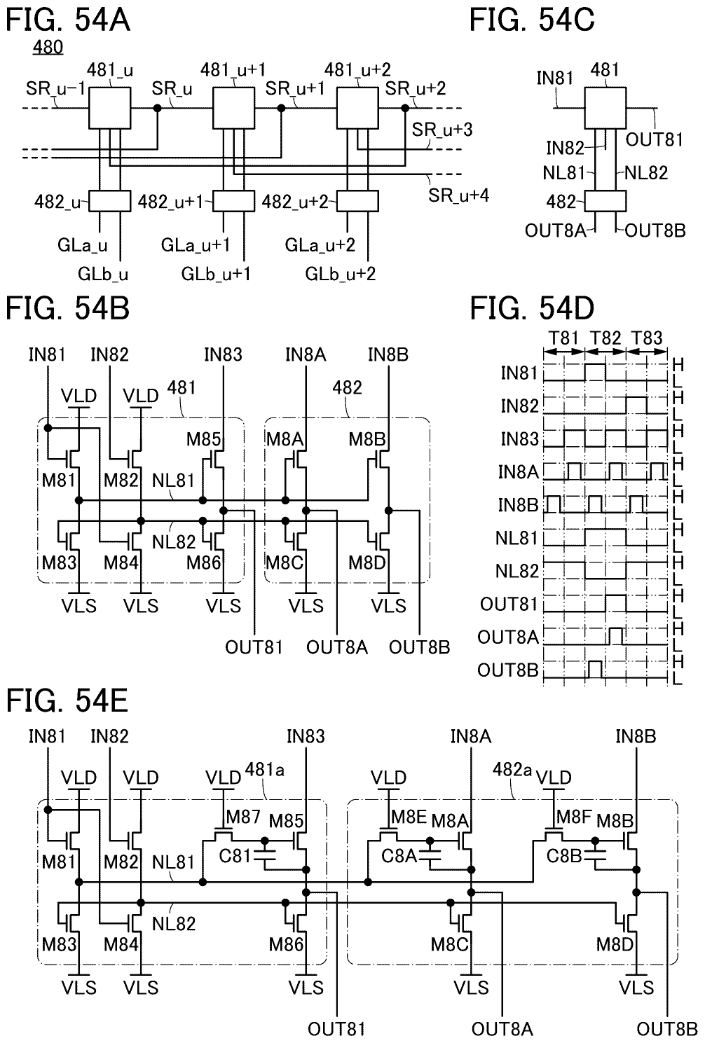

FIGS. 54A to 54E are circuit diagrams showing configuration examples of the semiconductor device that can be used for the peripheral driver circuit. The semiconductor device can be used as a part of the scan line driver circuit (the circuit included in the first driver circuit portion 463 or the like) or as a part of a shift register, for example.

The semiconductor device 480 illustrated in FIG. 54A includes m register portions 481 and m buffer portions 482. The semiconductor device 480 is connected to m wirings GLa and m wirings GLb. The m register portions 481 are connected to each other through m wirings SR. FIG. 54A illustrates a register portion 481_u to a register portion 481_u+2, a buffer portion 482_u to a buffer portion 482_u+2, a wiring SR_u−1 to a wiring SR_u+4, a wiring GLa_u to a wiring GLa_u+2, and a wiring GLb_u to a wiring GLb_u+2, which are components of the semiconductor device 480. Note that m is an integer greater than or equal to 2. In addition, u is an integer greater than or equal to 1 and less than or equal to m. Note that u+α (α is an integer greater than or equal to 1) does not exceed m. In addition, u−α is not below 1.

FIG. 54B is a circuit diagram showing a configuration example of the register portion 481 and the buffer portion 482. FIG. 54C illustrates a circuit block corresponding to the register portion 481 and the buffer portion 482. The register portion 481 can be used as each of a register portion 481_1 to a register portion 481_m. The buffer portion 482 can be used as each of a buffer portion 482_1 to a buffer portion 482_m. Thus, for example, in the register portion 481_u, a wiring IN81 is connected to the wiring SR_u−1, a wiring IN82 is connected to the wiring SR_u+2, and a wiring OUT81 is connected to the wiring SR_u. For example, in the buffer portion 482_u, a wiring OUT8A is connected to the wiring GLa_u and a wiring OUT8B is connected to the wiring GLb_u. Note that the wirings IN81, IN8A, IN8B, VLD, and VLS are not illustrated in FIGS. 54A and 54C. The same applies to the register portion 481_1 to a register portion 481_u−1 and a register portion 481_u+1 to a register portion 481_m. The same applies to the buffer portion 482_1 to a buffer portion 482_u−1 and a buffer portion 482_u+1 to a buffer portion 482_m.

Specifically, in the semiconductor device 480, the wiring OUT81 in the register portion 481_u−1 is connected to the wiring IN81 in the register portion 481_u through the wiring SR_u−1, and the wiring OUT81 in the register portion 481_u is connected to the wiring IN81 in the register portion 481_u+1 through the wiring SR_u. In such a configuration, the register portions 481_1 to 481_m are selected sequentially, and a desired potential can be supplied to each of the wirings GLa_u and GLb_u in the buffer portion 482_u connected to the register portion 481_u that is selected. Note that the potential of the wiring VLS is supplied to each of the wirings GLa_u and GLb_u in the buffer portion 482_u connected to the register portion 481_u that is not selected, in the semiconductor device 480.

The register portion 481 illustrated in FIG. 54B includes a transistor M81, a transistor M82, a transistor M83, a transistor M84, a transistor M85, and a transistor M86. The transistor M81 has a function of establishing or breaking electrical continuity between the wiring VLD and a wiring NL81 in accordance with the potential of the wiring IN81. The transistor M82 has a function of establishing or breaking electrical continuity between the wiring VLD and a wiring NL82 in accordance with the potential of the wiring IN82. The transistor M83 has a function of establishing or breaking electrical continuity between the wiring VLS and the wiring NL81 in accordance with the potential of the wiring NL82. The transistor M84 has a function of establishing or breaking electrical continuity between the wiring VLS and the wiring NL82 in accordance with the potential of the wiring IN81. The transistor M85 has a function of establishing or breaking electrical continuity between the wiring IN83 and the wiring OUT81 in accordance with the potential of the wiring NL81. The transistor M86 has a function of establishing or breaking electrical continuity between the wiring VLS and the wiring OUT81 in accordance with the potential of the wiring NL82.

The buffer portion 482 illustrated in FIG. 54B includes a transistor M8A, a transistor M8B, a transistor M8C, and a transistor M8D. The transistor M8A has a function of establishing or breaking electrical continuity between the wiring IN8A and the wiring OUT8A in accordance with the potential of the wiring NL81. The transistor M8B has a function of establishing or breaking electrical continuity between the wiring IN8B and the wiring OUT8B in accordance with the potential of the wiring NL81. The transistor M8C has a function of establishing or breaking electrical continuity between the wiring VLS and the wiring OUT8A in accordance with the potential of the wiring NL82. The transistor M8D has a function of establishing or breaking electrical continuity between the wiring VLS and the wiring OUT8B in accordance with the potential of the wiring NL82.

FIG. 54D is a timing chart showing an operation example of the register portion 481 and the buffer portion 482 illustrated in FIG. 54B.

In the following description of the operation, a potential H is supplied to the wiring VLD and a potential L is supplied to the wiring VLS. The potential H or the potential L is supplied to each of the wirings IN81, IN82, IN83, IN8A, and IN8B. The potential H is higher than the potential L. The difference between the potential H and the potential L is assumed to be sufficiently higher than the threshold voltage of the transistor.

The timing chart in FIG. 54D shows the potentials (H and L) supplied to the wirings IN81, IN82, IN83, IN8A, and IN8B in the operation periods (Periods T81 to T83). In addition, changes in the potentials of the wirings NL81, NL82, OUT81, OUT8A, and OUT8B are shown.

In Period T81, the potential L is supplied to each of the wirings IN81 and IN82. The potential of the wiring NL82 is the potential H. Accordingly, the potential L is supplied to the wiring NL81. Here, the transistors M85, M8A, and M8B are each in an off state (in a non-conduction state) and the transistors M86, M8C, and M8D are each in an on state (in a conduction state). Accordingly, the potential L is supplied to each of the wirings OUT81, OUT8A, and OUT8B regardless of the potential (H or L) of each of the wirings IN83, IN8A, and IN8B. Note that in the following description of the operation, unless otherwise specified, the potentials of the wirings supplied in the immediately preceding period are maintained.

In Period T82, the potential H is supplied to the wiring IN81, and accordingly, the potential of the wiring NL82 is changed to the potential L and the potential of the wiring NL81 is changed to the potential H. Thus, the transistors M85, M8A, and M8B are each turned on and the transistors M86, M8C, and M8D are each turned off. Accordingly, the potentials (H or L) of the wirings IN83, IN8A, and IN8B are supplied to the wirings OUT81, OUT8A, and OUT8B through the transistors M85, M8A, and M8B, respectively. After that, even if the potential L is supplied to the wiring IN81, the potentials of the wirings NL82 and NL81 are maintained.

In Period T83, the potential H is supplied to the wiring IN82, and accordingly, the potential of the wiring NL82 is changed to the potential H and the potential of the wiring NL81 is changed to the potential L. Thus, the transistors M85, M8A, and M8B are each turned off and the transistors M86, M8C, and M8D are each turned on. Accordingly, the potential L is supplied to each of the wirings OUT81, OUT8A, and OUT8B regardless of the potential (H or L) of each of the wirings IN83, IN8A, and IN8B. After that, even if the potential L is supplied to the wiring IN82, the potentials of the wirings NL82 and NL81 are maintained.

FIG. 54E is a circuit diagram illustrating modification examples of the register portion 481 and the buffer portion 482. A register portion 481a and a buffer portion 482a illustrated in FIG. 54E are different from the register portion 481 and the buffer portion 482 in including bootstrap circuits. That is, the register portion 481a includes a transistor M87 and a capacitor C81 in addition to the register portion 481 while the buffer portion 482a includes a transistor M8E, a transistor M8F, a capacitor C8A, and a capacitor C8B in addition to the buffer portion 482. Note that the capacitors C81, C8A, and C8B are referred to as bootstrap capacitors in some cases.

A gate of the transistor M87 is connected to the wiring VLD. A gate of the transistor M85 is connected to the wiring NL81 through a source and a drain of the transistor M87. The gate of the transistor M85 is also connected to the wiring OUT81 through the capacitor C81.

A gate of the transistor M8E is connected to the wiring VLD. A gate of the transistor M8A is connected to the wiring NL81 through a source and a drain of the transistor M8E. The gate of the transistor M8A is also connected to the wiring OUT8A through the capacitor C8A.

A gate of the transistor M8F is connected to the wiring VLD. A gate of the transistor M8B is connected to the wiring NL81 through a source and a drain of the transistor M8F. The gate of the transistor M8B is also connected to the wiring OUT8B through the capacitor C8B.

In the register portion 481, transmission of the potential H from the wiring IN83 to the wiring OUT81 causes a potential decrease depending on the threshold voltage in the transistor M85. Hence, with the use of the bootstrap circuit as in the register portion 481a, capacitive coupling between the bootstrap capacitors can maintain the on state of the transistor M85. In this manner, the potential H can be transmitted to the wiring OUT81 without causing the potential decrease depending on the threshold voltage.

In the buffer portion 482, similarly, transmission of the potential H from the wiring IN8A to the wiring OUT8A causes a potential decrease depending on the threshold voltage in the transistor M8A and transmission of the potential H from the wiring IN8B to the wiring OUT8B causes a potential decrease depending on the threshold voltage in the transistor M8B. Hence, with the use of the bootstrap circuit as in the buffer portion 482a, capacitive coupling between the bootstrap capacitors can maintain the on state in each of the transistors M8A and M8B. In this manner, the potential H can be transmitted to each of the wirings OUT8A and OUT8B without causing the potential decrease depending on the threshold voltage.

### <Cross-Sectional Structure Example of Display Apparatus>

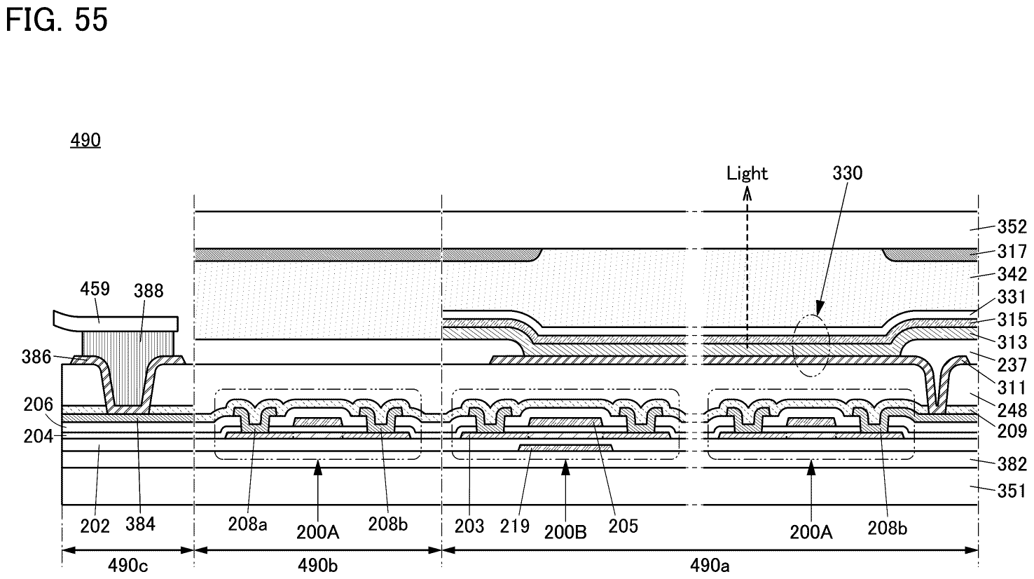

FIG. 55 is a cross-sectional view illustrating a cross-sectional structure example of a display apparatus of one embodiment of the present invention.

The display apparatus 400 can employ structures illustrated in regions 490a, 490b, and 490c in a display apparatus 490 illustrated in FIG. 55. For example, the structure illustrated in the region 490a can be employed for a region where the pixel 453 is provided. The structure illustrated in the region 490b can be employed for a region where the circuit portions 454a and 454b and the like are provided. The structure illustrated in the region 490c can be employed for a region where the FPC 459 is provided.

The display apparatus 490 includes a substrate 351 and a substrate 352. An adhesive layer 342 is provided between the substrate 351 and the substrate 352. The substrate 352 faces the substrate 351 with the adhesive layer 342 therebetween. Note that the substrate 352 and the adhesive layer 342 are not provided in the region 490c.

An insulating layer 382 is provided on a surface of the substrate 351 on the substrate 352 side. A transistor, a light-emitting element, and the like are provided over the insulating layer 382.

In the structure illustrated here as an example, the transistors 200A and 200B described in the above embodiment are provided in the region 490a, and the transistor 200A described in the above embodiment is provided in the region 490b. A conductive layer 384 is provided in the region 490c. The conductive layer 384 can be formed in the same step as the conductive layers 208a and 208b.

The insulating layer 248 is provided to cover the transistors 200A and 200B.

In the region 490a, a pixel electrode 311 is provided over the insulating layer 248. The pixel electrode 311 is connected to the conductive layer 208b through an opening provided in the insulating layers 248 and 209. An insulating layer 237 is provided over the insulating layer 248. The insulating layer 237 includes a region covering an end portion of the pixel electrode 311.

An EL layer 313 is provided to cover the insulating layer 237 and the pixel electrode 311. A common electrode 315 is provided to cover the EL layer 313. A protective layer 331 is provided to cover the common electrode 315.

A region where the pixel electrode 311 and the common electrode 315 overlap with each other with the EL layer 313 therebetween and the EL layer 313 is in contact with each of the pixel electrode 311 and the common electrode 315 functions as a light-emitting element 330. The pixel electrode 311 functions as one electrode (or a first terminal) of the light-emitting element 330, and the common electrode 315 functions as the other electrode (or a second terminal) thereof. The EL layer 313 has a function of emitting light with luminance corresponding to the amount of current flowing between the pixel electrode 311 and the common electrode 315 through the EL layer 313.

A light-blocking layer 317 is provided on a surface of the substrate 352 on the substrate 351 side.

In the region 490a, an opening is provided in the light-blocking layer 317 to include a region overlapping with the light-emitting element 330. Thus, light from the light-emitting element 330 is emitted to the outside of the display apparatus 490 through the opening provided in the light-blocking layer 317. FIG. 55 illustrates this state with a dashed arrow and a term “Light”.

In the region 490c, a conductive layer 386 is provided over part of the insulating layer 248. The conductive layer 386 includes a region in contact with the conductive layer 384 through an opening provided in the insulating layers 248 and 209.

The conductive layer 386 is connected to the FPC 459 through a connection layer 388. For the connection layer 388, an anisotropic conductive film (ACF), an anisotropic conductive paste (ACP), or the like can be used, for example.

### <Structure Example of Light-Emitting Element>

In one embodiment of the present invention, any of light-emitting elements with various structures can be used as the light-emitting elements included in the display apparatus.

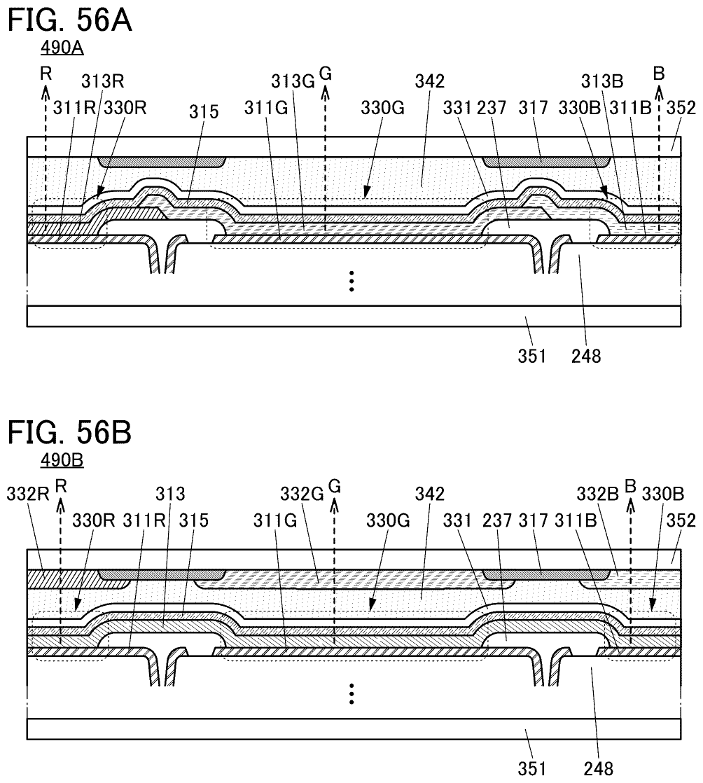

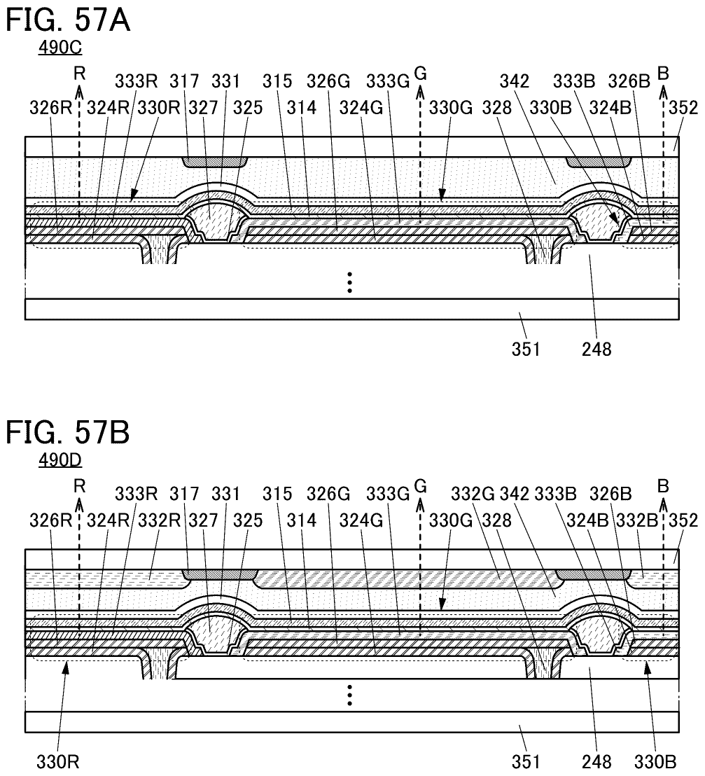

FIGS. 56A and 56B and FIGS. 57A and 57B are cross-sectional views illustrating light-emitting elements with various structures.

### Structure Example 1

A display apparatus 490A illustrated in FIG. 56A includes a light-emitting element 330R, a light-emitting element 330G, a light-emitting element 330B, and the like between the substrate 351 and the substrate 352. The light-emitting elements 330R, 330G, and 330B are display elements included in the pixel that emits red light, the pixel that emits green light, and the pixel that emits blue light, respectively. Note that the “light-emitting element 330” is merely stated in some cases describing a matter common to the light-emitting elements 330R, 330G, and 330B.

Note that in FIG. 56A, some components between the light-emitting element 330 and the substrate 351 and some components between the light-emitting element 330 and the substrate 352 are not illustrated. The display apparatus 490A includes, between the substrate 351 and the light-emitting element 330, a transistor included in the pixel circuit and the insulating layer 248 provided to cover the transistor, for example.

The display apparatus 490A employs an SBS structure. The SBS structure can optimize materials and structures of light-emitting elements and thus can extend freedom of choice of materials and structures, whereby the emission intensity and the reliability can be easily improved.

The display apparatus 490A has a top-emission structure. The aperture ratio of pixels in a top-emission structure can be higher than that of pixels in a bottom-emission structure because a transistor and the like can be provided so as to overlap with a light-emitting region of a light-emitting element in the top-emission structure.

The light-emitting elements 330R, 330G, and 330B are provided over the insulating layer 248.

The light-emitting element 330R includes the pixel electrode 311R over the insulating layer 248, an EL layer 313R over the pixel electrode 311R, and the common electrode 315 over the EL layer 313R. The light-emitting element 330R illustrated in FIG. 56A emits red (R) light. The EL layer 313R includes a light-emitting layer that emits red light.

The light-emitting element 330G includes the pixel electrode 311G over the insulating layer 248, an EL layer 313G over the pixel electrode 311G, and the common electrode 315 over the EL layer 313G. The light-emitting element 330G illustrated in FIG. 56A emits green (G) light. The EL layer 313G includes a light-emitting layer that emits green light.

The light-emitting element 330B includes the pixel electrode 311B over the insulating layer 248, an EL layer 313B over the pixel electrode 311B, and the common electrode 315 over the EL layer 313B. The light-emitting element 330B illustrated in FIG. 56A emits blue (B) light. The EL layer 313B includes a light-emitting layer that emits blue light.

Although the EL layers 313R, 313G, and 313B have the same thickness in FIG. 56A, one embodiment of the present invention is not limited thereto. The thicknesses of the EL layers 313R, 313G, and 313B can be made different from each other as necessary. For example, the thicknesses of the EL layers 313R, 313G, and 313B are preferably set to match an optical path length that intensifies light emitted from each EL layer. In that case, a microcavity structure is obtained, and the color purity of light emitted from each light-emitting element can be improved.

The pixel electrode 311R is connected to a transistor (not illustrated) included in a pixel circuit corresponding to the light-emitting element 330R through an opening provided in the insulating layers 209 and 248. The pixel electrode 311G is connected to a transistor (not illustrated) included in a pixel circuit corresponding to the light-emitting element 330G. The pixel electrode 311B is connected to a transistor (not illustrated) included in a pixel circuit corresponding to the light-emitting element 330B.

End portions of the pixel electrodes 311R, 311G, and 311B are covered with the insulating layer 237. The insulating layer 237 serves as a partition. The insulating layer 237 can have a single-layer structure or a stacked-layer structure including one or both of an inorganic insulating material and an organic insulating material. A material that can be used for the insulating layer 209 and a material that can be used for the insulating layer 248 can be used for the insulating layer 237, for example. The insulating layer 237 can insulate the pixel electrode from the common electrode. Furthermore, the insulating layer 237 can insulate adjacent light-emitting elements from each other.

The common electrode 315 is one continuous film shared by the light-emitting elements 330R, 330G, and 330B. In a region not provided with the light-emitting device, the common electrode 315 shared by the light-emitting elements is connected to a conductive layer formed using the same material through the same process as the pixel electrodes 311R, 311G, and 311B.

In the display apparatus of one embodiment of the present invention, a conductive film that transmits visible light is preferably used for the electrode through which light is extracted, which is either the pixel electrode or the common electrode. A conductive film that reflects visible light is preferably used for the electrode through which light is not extracted.

A conductive film that transmits visible light can be used also for the electrode through which light is not extracted. In that case, this electrode is preferably provided between a reflective layer and the EL layer. In other words, light emitted by the EL layer is reflected by the reflective layer to be extracted from the display apparatus.

As the material of the pair of electrodes of the light-emitting element, a metal, an alloy, an electrically conductive compound, a mixture thereof, or the like can be used as appropriate. Specific examples of the material include metals such as aluminum, magnesium, titanium, chromium, manganese, iron, cobalt, nickel, copper, gallium, zinc, indium, tin, molybdenum, tantalum, tungsten, palladium, gold, platinum, silver, yttrium, and neodymium, and an alloy containing any of these metals in appropriate combination. Other examples of the material include indium tin oxide (also referred to as In—Sn oxide), In—Si—Sn oxide (also referred to as ITSO), indium zinc oxide (In—Zn oxide), and In—W—Zn oxide. Other examples of the material include an alloy containing aluminum (aluminum alloy), such as an alloy of aluminum, nickel, and lanthanum (Al—Ni—La), and an alloy containing silver, such as an alloy of silver and magnesium and an alloy of silver, palladium, and copper (also referred to as Ag—Pd—Cu or APC). Other examples of the material include an element belonging to Group 1 or Group 2 of the periodic table that is not described above (e.g., lithium, cesium, calcium, or strontium), a rare earth metal such as europium or ytterbium, an alloy containing an appropriate combination of any of these elements, and graphene.

The light-emitting element preferably employs a microcavity structure. Therefore, one electrode of the light-emitting element preferably includes an electrode having properties of transmitting and reflecting visible light (a transflective electrode), and the other electrode preferably includes an electrode having a property of reflecting visible light (a reflective electrode). When the light-emitting element has a microcavity structure, light obtained from the light-emitting layer can be resonated between the electrodes, whereby light emitted from the light-emitting element can be intensified.

The transparent electrode has a light transmittance higher than or equal to 40%. For example, an electrode having a visible light (light with wavelengths greater than or equal to 400 nm and less than 750 nm) transmittance higher than or equal to 40% is preferably used as the transparent electrode of the light-emitting element. The transflective electrode has a visible light reflectance higher than or equal to 10% and lower than or equal to 95%, preferably higher than or equal to 30% and lower than or equal to 80%. The reflective electrode has a visible light reflectance higher than or equal to 40% and lower than 100%, preferably higher than or equal to 70% and lower than 100%. These electrodes preferably have a resistivity lower than or equal to 1×10⁻² Ωcm.

The EL layers 313R, 313G, and 313B are each provided to have an island shape. In FIG. 56A, end portions of the EL layers 313R and 313G adjacent to each other overlap with each other, and end portions of the EL layers 313G and 313B adjacent to each other overlap with each other. Although not illustrated, end portions of the EL layers 313R and 313B adjacent to each other overlap with each other. When island-shaped EL layers are formed using a metal mask (or a fine metal mask), end portions of the EL layers adjacent to each other may overlap with each other as illustrated in FIG. 56A; however, the present invention is not limited thereto. That is, it is also possible that the EL layers adjacent to each other do not overlap with each other and are apart from each other. It is also possible that the display apparatus includes both a portion where the EL layers adjacent to each other overlap with each other and a portion where the EL layers adjacent to each other do not overlap with each other and are apart from each other.

Each of the EL layers 313R, 313G, and 313B includes at least a light-emitting layer. The light-emitting layer contains one or more kinds of light-emitting substances. As the light-emitting substance, a substance whose emission color is blue, violet, bluish violet, green, yellowish green, yellow, orange, red, or the like is appropriately used. Alternatively, as the light-emitting substance, a substance that emits near-infrared light can be used.

Examples of the light-emitting substance include a fluorescent material, a phosphorescent material, a TADF material, and a quantum dot material.

The light-emitting layer can contain one or more kinds of organic compounds (e.g., a host material or an assist material) in addition to the light-emitting substance (a guest material). As one or more kinds of organic compounds, one or both of a substance with a good hole-transport property (a hole-transport material) and a substance with a good electron-transport property (an electron-transport material) can be used. As one or more kinds of organic compounds, a substance with a bipolar property (a substance with a good electron-transport property and a good hole-transport property) or a TADF material can be used.

The light-emitting layer preferably includes a phosphorescent material and a combination of a hole-transport material and an electron-transport material that easily forms an exciplex, for example. With such a structure, light emission can be efficiently obtained by exciplex-triplet energy transfer (ExTET), which is energy transfer from the exciplex to the light-emitting substance (the phosphorescent material). When a combination of materials is selected so as to form an exciplex that emits light whose wavelength overlaps with the wavelength of a lowest-energy-side absorption band of the light-emitting substance, energy can be transferred smoothly and light emission can be obtained efficiently. With this structure, high efficiency, low-voltage driving, and a long lifetime of the light-emitting element can be achieved at the same time.

In addition to the light-emitting layer, the EL layer can include one or more of a layer containing a substance having a good hole-injection property (a hole-injection layer), a layer containing a hole-transport material (a hole-transport layer), a layer containing a substance having a good electron-blocking property (an electron-blocking layer), a layer containing a substance having a good electron-injection property (an electron-injection layer), a layer containing an electron-transport material (an electron-transport layer), and a layer containing a substance having a good hole-blocking property (a hole-blocking layer). The EL layer can further include one or both of a bipolar substance and a TADF material.

Either a low molecular compound or a high molecular compound can be used in the light-emitting element, and an inorganic compound can also be included. Each layer included in the light-emitting element can be formed by any of the following methods: an evaporation method (including a vacuum evaporation method), a transfer method, a printing method, an inkjet method, a coating method, and the like.

The light-emitting element can employ a single structure (a structure including only one light-emitting unit) or a tandem structure (a structure including a plurality of light-emitting units). The light-emitting unit includes at least one light-emitting layer. In a tandem structure, a plurality of light-emitting units are connected in series with a charge-generation layer therebetween. The charge-generation layer has a function of injecting electrons into one of two light-emitting units and injecting holes to the other when a voltage is applied between the pair of electrodes. A tandem structure enables a light-emitting element capable of emitting light with high emission intensity. Furthermore, the amount of current needed for obtaining a predetermined emission intensity can be lower in a tandem structure than in a single structure; thus, a tandem structure enables higher reliability. A tandem structure can also be referred to as a stack structure.

In the case of using a tandem light-emitting element in FIG. 56A, the EL layer 313R preferably includes a plurality of light-emitting units that emit red light, the EL layer 313G preferably includes a plurality of light-emitting units that emit green light, and the EL layer 313B preferably includes a plurality of light-emitting units that emit blue light.

The protective layer 331 is provided over the light-emitting elements 330R, 330G, and 330B. The protective layer 331 and the substrate 352 are bonded to each other with the adhesive layer 342. The substrate 352 is provided with the light-blocking layer 317. A solid sealing structure, a hollow sealing structure, or the like can be employed to seal the light-emitting elements. In FIG. 56A, a solid sealing structure is employed, in which a space between the substrate 352 and the substrate 351 is filled with the adhesive layer 342. Alternatively, a hollow sealing structure can be employed, in which the space is filled with an inert gas (e.g., nitrogen or argon). In that case, the adhesive layer 342 is preferably provided not to overlap with the light-emitting element. Alternatively, the space can be filled with a resin other than the frame-shaped adhesive layer 342.

By providing the protective layer 331 over the light-emitting elements 330R, 330G, and 330B, the reliability of the light-emitting elements can be increased.

The protective layer 331 can have a single-layer structure or a stacked-layer structure of two or more layers. There is no limitation on the conductivity of the protective layer 331. For the protective layer 331, at least one of an insulating film, a semiconductor film, and a conductive film can be used.

The protective layer 331 including an inorganic film can inhibit deterioration of the light-emitting elements by preventing oxidation of the common electrode 315 and inhibiting entry of impurities (e.g., moisture and oxygen) into the light-emitting elements, for example; thus, the reliability of the display apparatus can be improved.

An inorganic insulating film can be used as the protective layer 331. Examples of the material that can be used for the inorganic insulating film include an oxide, a nitride, an oxynitride, and a nitride oxide. Specific examples of these inorganic insulating films are as described above. In particular, the protective layer 331 preferably includes a nitride or a nitride oxide, and further preferably includes a nitride.

An inorganic film containing ITO, In—Zn oxide, Ga—Zn oxide, Al—Zn oxide, IGZO, or the like can be used for the protective layer 331. The inorganic film preferably has high resistance, specifically, higher resistance than the common electrode 315. The inorganic film can further contain nitrogen.

When light emitted from the light-emitting element is extracted through the protective layer 331, the protective layer 331 preferably has a good visible-light-transmitting property. For example, ITO, IGZO, and aluminum oxide are preferable because they are inorganic materials having a good visible-light-transmitting property.

The protective layer 331 can be, for example, a stack of aluminum oxide and silicon nitride over the aluminum oxide, or a stack of aluminum oxide and IGZO over the aluminum oxide. Such a stacked-layer structure can inhibit entry of impurities (e.g., water and oxygen) into the EL layer.

Furthermore, the protective layer 331 can include an organic film. For example, the protective layer 331 can include both an organic film and an inorganic film. Examples of an organic film that can be used for the protective layer 331 include organic insulating films that can be used for the insulating layer 248.

The display apparatus 490A has a top-emission structure. Light from the light-emitting element is emitted toward the substrate 352. For the substrate 352, a material having a good visible-light-transmitting property is preferably used. The pixel electrodes 311R, 311G, and 311B contain a material that reflects visible light, and the counter electrode (the common electrode 315) contains a material that transmits visible light.

The light-blocking layer 317 is preferably provided on the surface of the substrate 352 on the substrate 351 side. The light-blocking layer 317 can be provided over a region between adjacent light-emitting elements, for example.

A coloring layer such as a color filter can be provided on the surface of the substrate 352 on the substrate 351 side or over the protective layer 331. When the color filter is provided so as to overlap with the light-emitting element, the color purity of light emitted from the pixel can be increased.

The coloring layer is a colored layer that selectively transmits light in a specific wavelength range and absorbs light in the other wavelength ranges. For example, a red (R) color filter for transmitting light in the red wavelength range, a green (G) color filter for transmitting light in the green wavelength range, a blue (B) color filter for transmitting light in the blue wavelength range, or the like can be used. Each coloring layer can be formed using one or more of a metal material, a resin material, a pigment, and a dye. Each coloring layer is formed in a desired position by a printing method, an ink-jet method, an etching method using a photolithography method, or the like.

Various optical members can be provided on the outer surface of the substrate 352 (the surface opposite to the substrate 351). Examples of the optical members include a polarizing plate, a retardation plate, a light diffusion layer (e.g., a diffusion film), an anti-reflective layer, and a light-condensing film. Furthermore, an antistatic film inhibiting the attachment of dust, a water repellent film inhibiting the attachment of stain, a hard coat film inhibiting generation of a scratch caused by the use, an impact-absorbing layer, or the like is preferably provided as a surface protective layer on the outer surface of the substrate 352. For example, a glass layer or a silica layer (SiOₓ layer) is preferably provided as the surface protective layer to inhibit the surface contamination and damage. The surface protective layer can be formed using diamond-like carbon (DLC), aluminum oxide (AlOₓ), a polyester-based material, a polycarbonate-based material, or the like. For the surface protective layer, a material having a high visible light transmittance is preferably used. The surface protective layer is preferably formed using a material with high hardness.

For each of the substrates 351 and 352, glass, quartz, ceramic, sapphire, a resin, a metal, an alloy, a semiconductor, or the like can be used. The substrate on the side from which light from the light-emitting element is extracted is formed using a material that transmits the light. The use of a material having flexibility for each of the substrates 351 and 352 can increase the flexibility of the display apparatus and can offer a flexible display (e.g., a bendable display, a foldable display, a rollable display, a slidable display, or a stretchable display). Furthermore, a polarizing plate can be used as at least one of the substrates 351 and 352.

For each of the substrates 351 and 352, any of the following can be used, for example: polyester such as polyethylene terephthalate and polyethylene naphthalate, polyacrylonitrile, an acrylic resin, polymethyl methacrylate, polycarbonate (PC), polyethersulfone, polyimide, polyamide (e.g., nylon and aramid), polysiloxane, a cycloolefin resin, polystyrene, polyamide-imide, polyurethane, polyvinyl chloride, polyvinylidene chloride, polypropylene, polytetrafluoroethylene, an ABS resin, and cellulose nanofiber. Glass that is thin enough to have flexibility can be used as at least one of the substrates 351 and 352.

In the case where a circularly polarizing plate overlaps with the display apparatus, a highly optically isotropic substrate is preferably used as the substrate included in the display apparatus. A highly optically isotropic substrate has a low birefringence (in other words, a small amount of birefringence). In the case of using a film as the substrate, examples of a highly optically isotropic film include a triacetyl cellulose (TAC, also referred to as cellulose triacetate) film, a cycloolefin polymer (COP) film, a cycloolefin copolymer (COC) film, and an acrylic film.

For the adhesive layer 342, various curable adhesives such as a reactive curable adhesive, a thermosetting adhesive, an anaerobic adhesive, and a photocurable adhesive such as an ultraviolet curable adhesive can be used. Examples of these adhesives include an epoxy resin, an acrylic resin, a silicone resin, a phenol resin, polyimide, PVC, PVB, and EVA. In particular, a material with low moisture permeability, such as an epoxy resin, is preferred. A two-component-mixture-type resin can be used. An adhesive sheet or the like can be used.

For manufacture of the light-emitting elements, a vacuum process such as an evaporation method and a solution process such as a spin coating method or an inkjet method can be used in one embodiment of the present invention. Examples of an evaporation method include physical vapor deposition methods (PVD methods) such as a sputtering method, an ion plating method, an ion beam evaporation method, a molecular beam evaporation method, and a vacuum evaporation method, and a chemical vapor deposition method (CVD method). Specifically, functional layers (e.g., a hole-injection layer, a hole-transport layer, a hole-blocking layer, a light-emitting layer, an electron-blocking layer, an electron-transport layer, an electron-injection layer, and a charge-generation layer) included in the EL layer can be formed by an evaporation method (e.g., a vacuum evaporation method), a coating method (e.g., a dip coating method, a die coating method, a bar coating method, a spin coating method, or a spray coating method), a printing method (e.g., ink-jetting, screen printing (stencil), offset printing (planography), flexography (relief printing), gravure printing, or micro-contact printing), or the like.

### Structure Example 2

In a display apparatus 490B illustrated in FIG. 56B, the light-emitting elements 330R, 330G, and 330B, a coloring layer 332R transmitting red light, a coloring layer 332G transmitting green light, a coloring layer 332B transmitting blue light, and the like are provided. The display apparatus 490B is different from the display apparatus 490A mainly in that the subpixels of different colors include respective coloring layers (color filters or the like) and the light-emitting elements that share the EL layer 313. Note that portions similar to those in the above-described display apparatus are not described in some cases.

The light-emitting element 330R includes the pixel electrode 311R, the EL layer 313 over the pixel electrode 311R, and the common electrode 315 over the EL layer 313. Light emitted from the light-emitting element 330R is extracted as red light to the outside of the display apparatus 490B through the coloring layer 332R.

The light-emitting element 330G includes the pixel electrode 311G, the EL layer 313 over the pixel electrode 311G, and the common electrode 315 over the EL layer 313. Light emitted from the light-emitting element 330G is extracted as green light to the outside of the display apparatus 490B through the coloring layer 332G.

The light-emitting element 330B includes the pixel electrode 311B, the EL layer 313 over the pixel electrode 311B, and the common electrode 315 over the EL layer 313. Light emitted from the light-emitting element 330B is extracted as blue light to the outside of the display apparatus 490B through the coloring layer 332B.

The EL layer 313 and the common electrode 315 are shared between the light-emitting elements 330R, 330G, and 330B. The number of manufacturing steps can be smaller in the case where the EL layer 313 is shared between the subpixels of different colors than the case where the subpixels of different colors include different EL layers.

The light-emitting elements 330R, 330G, and 330B illustrated in FIG. 56B emit white light, for example. When white light emitted from the light-emitting elements 330R, 330G, and 330B passes through the coloring layers 332R, 332G, and 332B, light of desired colors can be obtained.

In the light-emitting element that emits white light, two or more light-emitting layers are preferably included. When two light-emitting layers are used to obtain white light, two light-emitting layers that emit light of complementary colors are preferably selected. For example, when the emission colors of the first light-emitting layer and the second light-emitting layer are made complementary, the light-emitting element can be configured to emit white light as a whole. In the case where three or more light-emitting layers are used to obtain white light, the light-emitting element is preferably configured to emit white light as a whole by combining emission colors of the three or more light-emitting layers.

For example, the EL layer 313 preferably includes a light-emitting layer containing a light-emitting substance that emits blue light and a light-emitting layer containing a light-emitting substance that emits visible light having a longer wavelength than blue light. The EL layer 313 preferably includes a light-emitting layer that emits yellow light and a light-emitting layer that emits blue light, for example. Alternatively, the EL layer 313 preferably includes a light-emitting layer that emits red light, a light-emitting layer that emits green light, and a light-emitting layer that emits blue light, for example.

A light-emitting element that emits white light preferably has a tandem structure. Specific examples include the following structures: a two-unit tandem structure including a light-emitting unit that emits yellow (Y) light and a light-emitting unit that emits blue (B) light; a two-unit tandem structure including a light-emitting unit that emits red (R) light and green (G) light and a light-emitting unit that emits blue light; a three-unit tandem structure in which a light-emitting unit that emits blue light, a light-emitting unit that emits yellow, yellowish-green, or green light, and a light-emitting unit that emits blue light are stacked in this order; and a three-unit tandem structure in which a light-emitting unit that emits blue light, a light-emitting unit that emits yellow, yellowish-green, or green light and red light, and a light-emitting unit that emits blue light are stacked in this order. Examples of the number of stacked light-emitting units and the order of colors from the anode side include a two-unit structure of B and Y; a two-unit structure of B and X (a light-emitting unit X); a three-unit structure of B, Y, and B; and a three-unit structure of B, X, and B. Examples of the number of stacked light-emitting layers and the order of colors from the anode side in the light-emitting unit X include a two-unit structure of R and Y; a two-unit structure of R and G; a two-unit structure of G and R; a three-unit structure of G, R, and G; and a three-unit structure of R, G, and R. Another layer can be provided between two light-emitting layers.

In the case where the light-emitting element configured to emit white light has a microcavity structure, light with a specific wavelength (e.g., red, green, or blue) is sometimes intensified to be emitted.

Alternatively, the light-emitting elements 330R, 330G, and 330B illustrated in FIG. 56B emit blue light, for example. In this case, the EL layer 313 includes one or more light-emitting layers that emit blue light. In the pixel that emits blue light, blue light emitted from the light-emitting element 330B can be extracted. In each of the pixel that emits red light and the pixel that emits green light, a color conversion layer is provided between the light-emitting element 330R or 330G and the substrate 352 so that blue light emitted from the light-emitting element 330R or 330G is converted into light with a longer wavelength, whereby red light or green light can be extracted. Furthermore, it is preferable that over the light-emitting element 330R, the coloring layer 332R be provided between the color conversion layer and the substrate 352 and over the light-emitting element 330G, the coloring layer 332G be provided between the color conversion layer and the substrate 352. In some cases, part of light emitted from the light-emitting element is transmitted through the color conversion layer without being converted. When light transmitted through the color conversion layer is extracted through the coloring layer, light other than light of the intended color can be absorbed by the coloring layer, and color purity of light exhibited by a subpixel can be improved.

### Structure Example 3

A display apparatus 490C illustrated in FIG. 57A is an example of a display apparatus having an MML structure. In other words, the display apparatus 490C includes a light-emitting element that is formed without using a metal mask (or a fine metal mask). The stacked-layer structure from the substrate 351 to the insulating layer 248 and the stacked-layer structure from the protective layer 331 to the substrate 352 are similar to those in the display apparatus 490A; therefore, description thereof is omitted.

A light-emitting element having the MML structure can be manufactured without using a metal mask. Such a light-emitting element enables a display apparatus that breaks through the definition limit due to alignment accuracy of the metal mask. Furthermore, the need for the manufacturing equipment of a metal mask and the cleaning step of the metal mask can be eliminated. This enables mass production of display apparatuses.

Furthermore, the display apparatus employing the MML structure enables the display apparatus in which minute light-emitting elements are integrated. Without a pseudo improvement in definition by employing a unique pixel arrangement such as a PenTile arrangement, the display apparatus can achieve definition higher than or equal to 500 ppi, higher than or equal to 1000 ppi, higher than or equal to 2000 ppi, higher than or equal to 3000 ppi, or higher than or equal to 5000 ppi while having what is called a stripe arrangement where R, G, and B subpixels are arranged in one direction.

In the light-emitting element having an MML structure, the layer including the light-emitting layer is formed not by using a fine metal mask but by processing a light-emitting layer formed on the entire surface with a photolithography method. Accordingly, a high-definition display apparatus or a display apparatus with a high aperture ratio, which has been difficult to form so far, can be obtained. Moreover, light-emitting layers can be formed separately for the respective colors, enabling the display apparatus to perform extremely clear display with high contrast and high display quality. Moreover, providing a sacrificial layer over the light-emitting layer can reduce damage to the light-emitting layer in the manufacturing process of the display apparatus, resulting in an increase in reliability of the light-emitting element.

For example, in the case where the display apparatus includes three kinds of light-emitting elements, which are a light-emitting element that emits blue light, a light-emitting element that emits green light, and a light-emitting element that emits red light, three kinds of island-shaped light-emitting layers can be formed by repeating formation of a light-emitting layer and processing by photolithography three times.

In FIG. 57A, the light-emitting elements 330R, 330G, and 330B are provided over the insulating layer 248.

The light-emitting element 330R includes a conductive layer 324R over the insulating layer 248, a conductive layer 326R over the conductive layer 324R, a layer 333R over the conductive layer 326R, a common layer 314 over the layer 333R, and the common electrode 315 over the common layer 314. The light-emitting element 330R illustrated in FIG. 57A emits red (R) light. The layer 333R includes a light-emitting layer that emits red light. In the light-emitting element 330R, the layer 333R and the common layer 314 can be collectively referred to as an EL layer. One or both of the conductive layer 324R and the conductive layer 326R can be referred to as a pixel electrode.

The light-emitting element 330G includes a conductive layer 324G over the insulating layer 248, a conductive layer 326G over the conductive layer 324G, a layer 333G over the conductive layer 326G, the common layer 314 over the layer 333G, and the common electrode 315 over the common layer 314. The light-emitting element 330G illustrated in FIG. 57A emits green (G) light. The layer 333G includes a light-emitting layer that emits green light. In the light-emitting element 330G, the layer 333G and the common layer 314 can be collectively referred to as an EL layer. One or both of the conductive layer 324G and the conductive layer 326G can be referred to as a pixel electrode.

The light-emitting element 330B includes a conductive layer 324B over the insulating layer 248, a conductive layer 326B over the conductive layer 324B, a layer 333B over the conductive layer 326B, the common layer 314 over the layer 333B, and the common electrode 315 over the common layer 314. The light-emitting element 330B illustrated in FIG. 57A emits blue (B) light. The layer 333B includes a light-emitting layer that emits blue light. In the light-emitting element 330B, the layer 333B and the common layer 314 can be collectively referred to as an EL layer. One or both of the conductive layer 324B and the conductive layer 326B can be referred to as a pixel electrode.

In this specification and the like, in the EL layers included in the light-emitting elements, the island-shaped layer provided in each light-emitting element is referred to as the layer 333B, the layer 333G, or the layer 333R, and the layer shared by the light-emitting elements is referred to as the common layer 314. Note that in this specification and the like, only the layers 333R, 333G, and 333B are sometimes referred to as island-shaped EL layers, EL layers formed in an island shape, or the like, in which case the common layer 314 is not included in the EL layer.

The layers 333R, 333G, and 333B are isolated from each other. When the EL layer is provided to have an island shape for each light-emitting element, a leakage current between adjacent light-emitting elements can be inhibited. This can prevent crosstalk-induced unintended light emission, so that a display apparatus with extremely high contrast can be obtained.

Although the layers 333R, 333G, and 333B have the same thickness in FIG. 57A, one embodiment of the present invention is not limited thereto. The layers 333R, 333G, and 333B may have different thicknesses.

The conductive layer 324R is connected to the transistor (not illustrated) included in a pixel circuit corresponding to the light-emitting element 330R through an opening provided in the insulating layers 209 and 248. The conductive layer 324G is connected to the transistor (not illustrated) included in a pixel circuit corresponding to the light-emitting element 330G. The conductive layer 324B is connected to the transistor (not illustrated) included in a pixel circuit corresponding to the light-emitting element 330B.

The conductive layers 324R, 324G, and 324B are formed to cover the openings provided in the insulating layer 248. A layer 328 is embedded in each of the depressed portions of the conductive layers 324R, 324G, and 324B.

The layer 328 has a function of filling the depressed portions of the conductive layers 324R, 324G, and 324B. The conductive layers 326R, 326G, and 326B connected to the conductive layers 324R, 324G, and 324B, respectively, are provided over the conductive layers 324R, 324G, and 324B and the layer 328. Thus, regions overlapping with the depressed portions of the conductive layers 324R, 324G, and 324B can also be used as the light-emitting regions, increasing the aperture ratio of the pixels. As each of the conductive layers 324R and 326R, a conductive layer functioning as a reflective electrode is preferably used.

The layer 328 may be an insulating layer or a conductive layer. Any of various inorganic insulating materials, organic insulating materials, and conductive materials can be used for the layer 328 as appropriate. Specifically, the layer 328 is preferably formed using an insulating material and is particularly preferably formed using an organic insulating material. For the layer 328, an organic insulating material that can be used for the insulating layer 237 can be used, for example.

Although FIG. 57A shows an example where the top surface of the layer 328 includes a flat portion, the shape of the layer 328 is not particularly limited. The top surface of the layer 328 may include at least one of a convex surface, a concave surface, and a flat surface.

The level of the top surface of the layer 328 and the level of the top surface of the conductive layer 324R may be the same or substantially the same, or may be different from each other. For example, the level of the top surface of the layer 328 may be either lower or higher than the level of the top surface of the conductive layer 324R.

An end portion of the conductive layer 326R may be aligned with an end portion of the conductive layer 324R or may cover the side surface of the end portion of the conductive layer 324R. The end portions of the conductive layers 324R and 326R each preferably have a tapered shape. Specifically, the end portions of the conductive layers 324R and 326R each preferably have a tapered shape with a taper angle greater than 0° and less than 90°. In the case where the end portion of the pixel electrode has a tapered shape, the layer 333R provided along the side surface of the pixel electrode has an inclined portion. When the side surface of the pixel electrode has a tapered shape, coverage with an EL layer provided along the side surface of the pixel electrode can be improved.

Since the conductive layers 324G and 326G and the conductive layers 324B and 326B are similar to the conductive layers 324R and 326R, the detailed description thereof is omitted.

The top and side surfaces of the conductive layer 326R are covered with the layer 333R. Similarly, the top and side surfaces of the conductive layers 326G are covered with the layer 333G, and the top and side surfaces of the conductive layers 326B are covered with the layer 333B. Accordingly, regions provided with the conductive layers 326R, 326G, and 326B can be entirely used as the light-emitting regions of the light-emitting elements 330R, 330G, and 330B, thereby increasing the aperture ratio of the pixels.

The side surface and part of the top surface of each of the layers 333R, 333G, and 333B are covered with the insulating layers 325 and 327. The common layer 314 is provided over the layers 333R, 333G, and 333B and the insulating layers 325 and 327, and the common electrode 315 is provided over the common layer 314. The common layer 314 and the common electrode 315 are each one continuous film shared by a plurality of light-emitting elements.

In FIG. 57A, the insulating layer 237 illustrated in FIG. 56A or the like is not provided between the conductive layer 326R and the layer 333R. That is, an insulating layer (also referred to as a partition wall, a bank, a spacer, or the like) covering and in contact with an upper end portion of the pixel electrode is not provided in the display apparatus 490C. Thus, the interval between adjacent light-emitting elements can be extremely shortened. Accordingly, the display apparatus can have high definition and high resolution. In addition, a mask (e.g., a photomask) for forming the insulating layer is not needed, which leads to a reduction in manufacturing cost of the display apparatus.

As described above, the layers 333R, 333G, and 333B each include the light-emitting layer. The layers 333R, 333G, and 333B each preferably include the light-emitting layer and a carrier-transport layer (an electron-transport layer or a hole-transport layer) over the light-emitting layer. Alternatively, the layers 333R, 333G, and 333B each preferably include a light-emitting layer and a carrier-blocking layer (a hole-blocking layer or an electron-blocking layer) over the light-emitting layer. Alternatively, the layers 333R, 333G, and 333B each preferably include a light-emitting layer, a carrier-blocking layer over the light-emitting layer, and a carrier-transport layer over the carrier-blocking layer. Since surfaces of the layers 333R, 333G, and 333B are exposed in the manufacturing process of the display apparatus, providing one or both of the carrier-transport layer and the carrier-blocking layer over the light-emitting layer inhibits the light-emitting layer from being exposed on the outermost surface, so that damage to the light-emitting layer can be reduced. Thus, the reliability of the light-emitting element can be increased.

The common layer 314 includes, for example, an electron-injection layer or a hole-injection layer. For example, the common layer 314 can be a stack of an electron-transport layer and an electron-injection layer, or can be a stack of a hole-transport layer and a hole-injection layer. The common layer 314 is shared by the light-emitting elements 330R, 330G, and 330B.

The side surfaces of the layers 333R, 333G, and 333B are each covered with the insulating layer 325. The insulating layer 327 covers the side surfaces of the layers 333R, 333G, and 333B with the insulating layer 325 therebetween.

The side surfaces (and part of the top surfaces) of the layers 333R, 333G, and 333B are covered with at least one of the insulating layer 325 and the insulating layer 327, so that the common layer 314 (or the common electrode 315) can be inhibited from being in contact with the side surfaces of the pixel electrodes and the layers 333R, 333G, and 333B, leading to inhibition of a short circuit of the light-emitting elements. Thus, the reliability of the light-emitting element can be increased.

The insulating layer 325 is preferably in contact with the side surfaces of the layers 333R, 333G, and 333B. The insulating layer 325 in contact with the layers 333R, 333G, and 333B can prevent film separation of the layers 333R, 333G, and 333B, whereby the reliability of the light-emitting element can be increased.

The insulating layer 327 is provided over the insulating layer 325 to fill a depressed portion of the insulating layer 325. The insulating layer 327 preferably covers at least part of the side surface of the insulating layer 325.

The insulating layers 325 and 327 can fill a gap between adjacent island-shaped layers, whereby the formation surface of the layers (e.g., the carrier-injection layer and the common electrode) provided over the island-shaped layers can have higher flatness with small unevenness. Consequently, coverage with the carrier-injection layer, the common electrode, and the like can be improved.

The common layer 314 and the common electrode 315 are provided over the layers 333R, 333G, and 333B and the insulating layers 325 and 327. Before the insulating layers 325 and 327 are provided, a level difference is caused due to a region where the pixel electrode and the island-shaped EL layer are provided and a region where neither the pixel electrode nor the island-shaped EL layer is provided (a region between the light-emitting elements). In the display apparatus of one embodiment of the present invention, the insulating layers 325 and 327 can eliminate the level difference and improve the coverage with the common layer 314 and the common electrode 315. Thus, connection defects caused by step disconnection can be inhibited. In addition, an increase in electric resistance, which is caused by local thinning of the common electrode 315 due to the level difference, can be inhibited.

The top surface of the insulating layer 327 preferably has a shape with high flatness. The top surface of the insulating layer 327 can include at least one of a flat surface, a convex surface, and a concave surface. For example, the top surface of the insulating layer 327 preferably has a convex shape with a large radius of curvature.

An inorganic insulating film can be used as the insulating layer 325. Examples of the material that can be used for the inorganic insulating film include an oxide, a nitride, an oxynitride, and a nitride oxide. Specific examples of these inorganic insulating films are as described above. The insulating layer 325 may have a single-layer structure or a stacked-layer structure. In particular, aluminum oxide is preferably used because it has high selectivity with respect to the EL layer in etching and has a function of protecting the EL layer in forming the insulating layer 327 described later. In particular, when an inorganic insulating film such as an aluminum oxide film, a hafnium oxide film, or a silicon oxide film is formed by an ALD method as the insulating layer 325, the insulating layer 325 can have few pinholes and an excellent function of protecting the EL layer. The insulating layer 325 can have a stacked-layer structure of a film formed by an ALD method and a film formed by a sputtering method. The insulating layer 325 may have a stacked-layer structure of an aluminum oxide film formed by an ALD method and a silicon nitride film formed by a sputtering method, for example.

The insulating layer 325 preferably has a function of a barrier insulating layer against at least one of water and oxygen. The insulating layer 325 preferably has a function of inhibiting diffusion of at least one of water and oxygen. Alternatively, the insulating layer 325 preferably has a function of capturing or fixing (also referred to as gettering) at least one of water and oxygen.

When the insulating layer 325 has a function of the barrier insulating layer, entry of impurities (typically, at least one of water and oxygen) that would be diffused into the light-emitting elements from the outside can be inhibited. With this structure, a highly reliable light-emitting element and a highly reliable display apparatus can be provided.

The insulating layer 325 preferably has a low impurity concentration. Accordingly, degradation of the EL layer, which is caused by entry of impurities into the EL layer from the insulating layer 325, can be inhibited. In addition, when the impurity concentration is reduced in the insulating layer 325, a barrier property against at least one of water and oxygen can be increased. For example, the insulating layer 325 preferably has a sufficiently low hydrogen concentration or a sufficiently low carbon concentration, and further preferably has both a sufficiently low hydrogen concentration and a sufficiently low carbon concentration.

The insulating layer 327 provided over the insulating layer 325 has a function of filling large unevenness of the insulating layer 325, which is formed between the adjacent light-emitting elements. In other words, the insulating layer 327 has an effect of improving the planarity of the formation surface of the common electrode 315.

As the insulating layer 327, an insulating layer containing an organic material can be used. As the organic material, a photosensitive organic resin is preferably used, and for example, a photosensitive resin composite containing an acrylic resin is preferably used. Note that in this specification and the like, an acrylic resin refers to not only a polymethacrylic acid ester or a methacrylic resin, but also all the acrylic polymer in a broad sense in some cases.

For the insulating layer 327, an acrylic resin, polyimide, polyamide, polyimide-amide, an epoxy resin, a silicone resin, a siloxane resin, a benzocyclobutene-based resin, a phenol resin, precursors of these resins, or the like can be used. For the insulating layer 327, an organic material such as polyvinyl alcohol (PVA), polyvinyl butyral, polyvinylpyrrolidone, polyethylene glycol, polyglycerin, pullulan, water-soluble cellulose, or alcohol-soluble polyamide can be used. A photoresist can be used as the photosensitive resin. As the photosensitive organic resin, either a positive-type material or a negative-type material can be used.

The insulating layer 327 is preferably formed using a material absorbing visible light. When the insulating layer 327 absorbs light emitted from the light-emitting element, light leakage (stray light) from the light-emitting element to the adjacent light-emitting element through the insulating layer 327 can be inhibited. Thus, the display quality of the display apparatus can be improved. Since no polarizing plate is required to improve the display quality of the display apparatus, the weight and thickness of the display apparatus can be reduced.

Examples of the material absorbing visible light include a material containing a pigment of black or any other color, a material containing a dye, a light-absorbing resin material (e.g., polyimide), and a resin material that can be used for color filters (a color filter material). Using a resin material obtained by stacking or mixing color filter materials of two or three or more colors is particularly preferred to enhance the effect of blocking visible light. In particular, mixing color filter materials of three or more colors enables the formation of a black or nearly black resin layer.

### Structure Example 4

In a display apparatus 490D illustrated in FIG. 57B, the light-emitting elements 330R, 330G, and 330B, the coloring layer 332R transmitting red light, the coloring layer 332G transmitting green light, the coloring layer 332B transmitting blue light, and the like are provided. The display apparatus 490D is different from the display apparatus 490C mainly in that the subpixels of different colors include light-emitting elements including the layers 333R, 333G, and 333B and respective coloring layers (color filters or the like). Note that portions similar to those in the above-described display apparatus are not described in some cases.

Light emitted from the light-emitting element 330R is extracted as red light to the outside of the display apparatus 490D through the coloring layer 332R. Similarly, light emitted from the light-emitting element 330G is extracted as green light to the outside of the display apparatus 490D through the coloring layer 332G. Light emitted from the light-emitting element 330B is extracted as blue light to the outside of the display apparatus 490D through the coloring layer 332B.

The light-emitting elements 330R, 330G, and 330B include the layers 333R, 333G, and 333B, respectively. The layers 333R, 333G, and 333B are formed using the same material in the same step. The layers 333R, 333G, and 333B are isolated from each other. When the EL layer is provided to have an island shape for each light-emitting element, a leakage current between adjacent light-emitting elements can be inhibited. This can prevent crosstalk-induced unintended light emission, so that a display apparatus with extremely high contrast can be obtained.

The light-emitting elements 330R, 330G, and 330B illustrated in FIG. 57B emit white light, for example. When white light emitted from the light-emitting elements 330R, 330G, and 330B passes through the coloring layers 332R, 332G, and 332B, light of desired colors can be obtained.

Alternatively, the light-emitting elements 330R, 330G, and 330B illustrated in FIG. 57B emit blue light, for example. In this case, the layers 333R, 333G, and 333B each include one or more light-emitting layers that emit blue light. In the pixel that emits blue light, blue light emitted from the light-emitting element 330B can be extracted. In each of the pixel that emits red light and the pixel that emits green light, a color conversion layer is provided between the light-emitting element 330R or 330G and the substrate 352 so that blue light emitted from the light-emitting element 330R or 330G is converted into light with a longer wavelength, whereby red light or green light can be extracted. Furthermore, it is preferable that over the light-emitting element 330R, the coloring layer 332R be provided between the color conversion layer and the substrate 352 and over the light-emitting element 330G, the coloring layer 332G be provided between the color conversion layer and the substrate 352. When light transmitted through the color conversion layer is extracted through the coloring layer, light other than light of the intended color can be absorbed by the coloring layer, and color purity of light exhibited by a subpixel can be improved.

The structures described in this embodiment can be used in combination with any of the structures described in the other embodiments as appropriate.

### Embodiment 7

This embodiment will describe a structure example of a display apparatus 500, which is a modification example of the display apparatus 400 disclosed in the above embodiment.

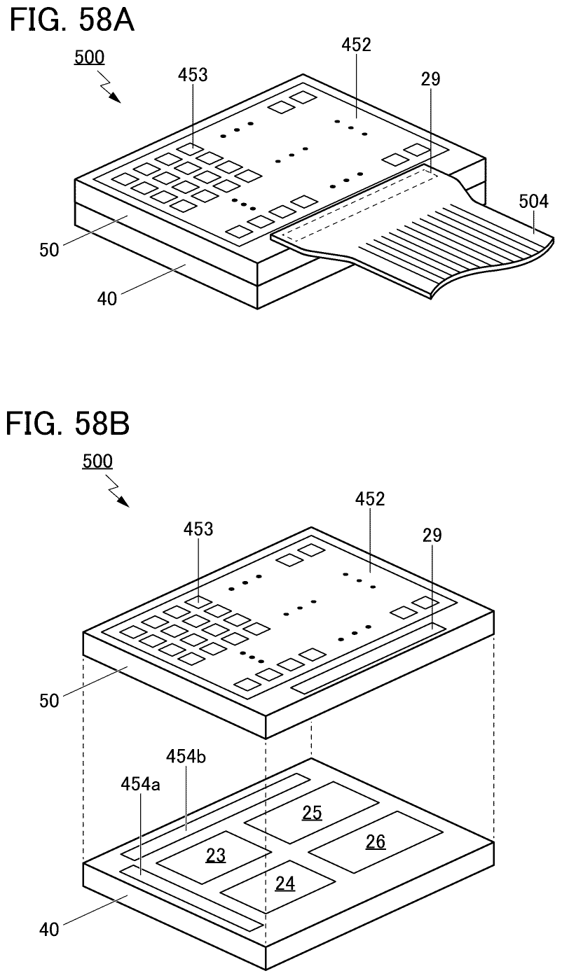

FIG. 58A is a perspective view of the display apparatus 500. FIG. 58A illustrates a state where an FPC 504 is connected to an input terminal portion 29 of the display apparatus 500. The display apparatus 500 includes an element layer 40 and an element layer 50 overlapping with the element layer 40. FIG. 58B is a perspective view illustrating the element layer 40 and the element layer 50 separated from each other.

The element layer 50 includes the input terminal portion 29 and the display portion 452. The display portion 452 includes a plurality of the pixels 453 arranged in a matrix. As disclosed in the above embodiment, the semiconductor device 10 can be used as the pixel 453. Power, a signal, and the like necessary for the operation of the display apparatus 500 are supplied through the input terminal portion 29.

In the display apparatus 500, the circuit portions 454a and 454b are provided in the element layer 40. By providing the circuit portions 454a and 454b in a layer different from the layer where the display portion 452 is provided, the width of the bezel around the display portion 452 can be small; thus, the area of the display portion 452 can be increased.

The resolution of the display portion 452 can be increased with increasing area of the display portion 452. Under a fixed resolution of the display portion 452, the footprint of one pixel can be increased. Thus, the emission luminance of the display portion 452 can be increased. In addition, the proportion of the light-emitting region to the footprint of one pixel (also referred to as an “aperture ratio”) can be increased. For example, the pixel aperture ratio can be greater than or equal to 40% and less than 100%, preferably greater than or equal to 50% and less than or equal to 95%, further preferably greater than or equal to 60% and less than or equal to 95%. The density of current supplied to the light-emitting element 61 can be reduced with increasing area of one pixel. Thus, the load on the light-emitting element 61 can be reduced, leading to improved reliability of the display apparatus 500.

The display portion 452 and the circuit portions 454a and 454b are stacked, whereby the wiring for connection between them can be shortened. Thus, the wiring resistance and the parasitic capacitance can be lowered, and the operation speed of the display apparatus 500 can be increased. Furthermore, power consumption of the display apparatus 500 is reduced.

The element layer 40 may include a central processing unit (CPU) 23, a graphics processing unit (GPU) 24, a memory circuit portion 25, a neural processing unit (NPU) 26, and the like in addition to a peripheral driver circuit. In this embodiment and the like, the peripheral driver circuit, the CPU 23, the GPU 24, the memory circuit portion 25, and the NPU 26 are collectively referred to as a “functional circuit” in some cases.

For example, the CPU 23 has a function of controlling the operations of the circuits provided in the element layer 40, such as the GPU 24 and the NPU 26, in accordance with a program stored in the memory circuit portion 25. The GPU 24 has a function of performing arithmetic processing for generating image data. Furthermore, the GPU 24 can perform a large number of matrix operations (product-sum arithmetics) in parallel. The GPU 24 has a function of correcting image data using correction data stored in the memory circuit portion 25, for example. The GPU 24 has a function of generating image data in which brightness, hue, contrast, and/or the like are/is corrected, for example. Moreover, the NPU 26 can perform arithmetic processing for artificial intelligence (AI) at high speed. Each of the GPU 24 and the NPU 26 can perform arithmetic processing using a neural network at high speed, for example.

Upconversion or downconversion of image data may be performed using the GPU 24. A super-resolution circuit may be provided in the element layer 40, for example. The super-resolution circuit has a function of determining a potential of any pixel included in the display portion 452 by a product-sum arithmetic of weights and potentials of pixels in the periphery of the pixel. The super-resolution circuit has a function of upconverting image data with a resolution lower than that of the display portion 452 to an image data with a resolution equivalent to that of the display portion 452. The super-resolution circuit has a function of downconverting image data with a resolution higher than that of the display portion 452 to an image data with a resolution equivalent to that of the display portion 452.

Providing the super-resolution circuit can reduce the load on the GPU 24. For example, the GPU 24 executes processing up to 2K resolution (or 4K resolution) and the super-resolution circuit performs upconversion to 4K resolution (or 8K resolution), whereby the load on the GPU 24 can be reduced. Downconversion can be performed in a similar manner.

Note that the functional circuit included in the element layer 40 does not necessarily include all of these components, and may include another component. For example, a potential generating circuit that generates a plurality of different potentials and a power management circuit that controls supply and stop of power for each circuit included in the display apparatus 500 may be provided. As the functional circuit, a DSP circuit, a sensor circuit, a communication circuit, a field programmable gate array (FPGA), or the like may be included.

The supply and stop of power may be performed per circuit included in the CPU 23. For example, power consumption can be reduced by stopping supply of power to a circuit, which is determined to be not used for a while, of the circuits included in the CPU 23, and restarting the supply of power to the circuit as needed. Data necessary for restarting supply of power may be stored in a memory circuit in the CPU 23, the memory circuit portion 25, or the like before the circuit is stopped. By storing data necessary for recovery of the circuit, high-speed recovery of the circuit stopped can be performed. Note that supply of a clock signal may be stopped to stop the circuit operation.

Some of the transistors in the functional circuit included in the element layer 40 can be provided in the element layer 50. Some of the transistors in the pixel 453 included in the element layer 50 can be provided in the element layer 40. Thus, the functional circuit can include a Si transistor and an OS transistor. The pixel 453 can include a Si transistor and an OS transistor.

Transistors included in the display apparatus 500 can be either n-type transistors or p-type transistors. Both n-type transistors and p-type transistors can be used as the transistors included in the display apparatus 500. For example, a CMOS circuit in which an n-type transistor and a p-type transistor are combined can be employed as the circuit included in the display apparatus 500.

A crystalline silicon substrate can be used as the element layer 40, and the functional circuit included in the element layer 40 can be formed using a crystalline Si transistor. Alternatively, an SOI substrate can be used as the element layer 40. A thin film transistor can be used as the transistor forming the display portion 452 included in the element layer 40. The thin film transistor can be provided over various substrates and is suitable as a transistor provided to overlap with the element layer 40.

The structures described in this embodiment can be used in combination with any of the structures described in the other embodiments as appropriate.

### Embodiment 8

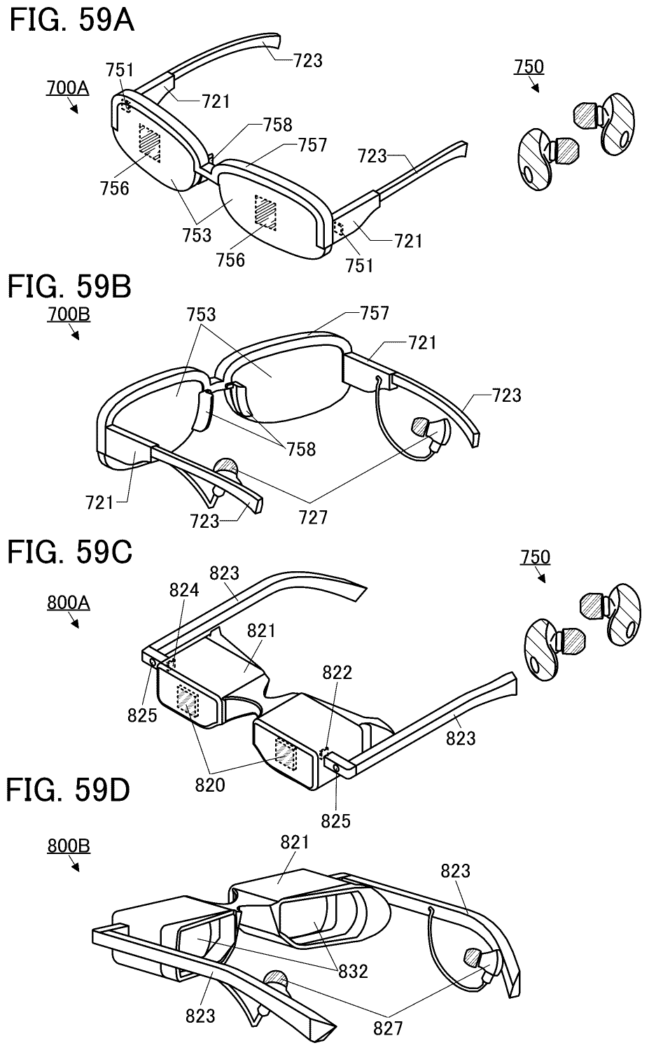

In this embodiment, electronic devices of embodiments of the present invention will be described with reference to FIGS. 59A to 59D, FIGS. 60A to 60F, and FIGS. 61A to 61G.

In the electronic device of this embodiment, a display portion includes a display apparatus using the semiconductor device of one embodiment of the present invention (hereinafter, also simply referred to as a “display apparatus”). The display apparatus can be easily increased in definition and resolution. Thus, the display apparatus can be used for a display portion of various electronic devices.

Examples of the electronic devices include a digital camera, a digital video camera, a digital photo frame, a mobile phone, a portable game console, a portable information terminal, and an audio reproducing device, in addition to electronic devices with a relatively large screen, such as a television device, desktop and notebook computers, a monitor of a computer and the like, digital signage, and a large game machine such as a pachinko machine.

In particular, the display apparatus of one embodiment of the present invention can have a high definition, and thus can be used for an electronic device having a relatively small display portion. Examples of such an electronic device include wearable devices such as watch-type and bracelet-type information terminal devices capable of being worn on a wrist, wearable devices capable of being worn on a head, such as a virtual reality (VR) device like a head-mounted display, a glasses-type augmented reality (AR) device, a substitutional reality (SR) device, and a mixed reality (MR) device.

The resolution of the display apparatus of one embodiment of the present invention can be as high as HD (number of pixels: 1280×720), FHD (number of pixels: 1920×1080), WQHD (number of pixels: 2560×1440), WQXGA (number of pixels: 2560×1600), 4K (number of pixels: 3840×2160), or 8K (number of pixels: 7680×4320). In particular, the resolution can be 4K, 8K, or higher. The pixel density (definition) of the display apparatus of one embodiment of the present invention can be 300 ppi or higher, 500 ppi or higher, or 1000 ppi or higher. Alternatively, the definition can be 3000 ppi or higher or 5000 ppi or higher. The use of the display apparatus having one or both of such high resolution and high definition can further increase realistic sensation, sense of depth, and the like. There is no particular limitation on the screen ratio (aspect ratio) of the display apparatus of one embodiment of the present invention. For example, the display apparatus of one embodiment of the present invention is compatible with various screen ratios such as 1:1 (a square), 4:3, 16:9, and 16:10.

The electronic device in this embodiment can include a sensor (a sensor having a function of sensing, detecting, or measuring force, displacement, position, speed, acceleration, angular velocity, rotational frequency, distance, light, liquid, magnetism, temperature, a chemical substance, sound, time, hardness, electric field, current, voltage, power, radiation, flow rate, humidity, gradient, oscillation, a smell, or infrared rays).

The electronic device in this embodiment can have various functions. For example, the electronic device in this embodiment can have a function of displaying various information (a still image, a moving image, a text image, and the like) on the display portion, a touch panel function, a function of displaying a calendar, date, time, and the like, a function of executing various software (programs), a wireless communication function, and a function of reading out a program or data stored in a recording medium.

Examples of head-mounted wearable devices will be described with reference to FIGS. 59A to 59D. The wearable devices have at least one of a function of displaying AR contents, a function of displaying VR contents, a function of displaying SR contents, and a function of displaying MR contents. The electronic device having a function of displaying contents of at least one of AR, VR, SR, MR, and the like enables the user to feel a higher level of immersion.

An electronic device 700A illustrated in FIG. 59A and an electronic device 700B illustrated in FIG. 59B each include a pair of display panels 751, a pair of housings 721, a communication portion (not illustrated), a pair of wearing portions 723, a control portion (not illustrated), an image capturing portion (not illustrated), a pair of optical members 753, a frame 757, and a pair of nose pads 758.

The display apparatus of one embodiment of the present invention can be used for the display panels 751. Thus, the electronic devices are capable of performing ultrahigh-definition display.

The electronic devices 700A and 700B can each project images displayed on the display panels 751 onto display regions 756 of the optical members 753. Since the optical members 753 have a light-transmitting property, the user can see images displayed on the display regions, which are superimposed on transmission images seen through the optical members 753. Accordingly, the electronic devices 700A and 700B are electronic devices capable of AR display.

In the electronic devices 700A and 700B, a camera capable of capturing images of the front side can be provided as the image capturing portion. Furthermore, when the electronic devices 700A and 700B are each provided with an acceleration sensor such as a gyroscope sensor, the orientation of the user's head can be sensed and an image corresponding to the orientation can be displayed on the display regions 756.

The communication portion includes a wireless communication device, and a video signal and the like can be supplied by the wireless communication device. Instead of or in addition to the wireless communication device, a connector that can be connected to a cable for supplying a video signal and a power supply potential can be provided.

The electronic devices 700A and 700B are each provided with a battery so that they can be charged wirelessly and/or by wire.

A touch sensor module can be provided in the housing 721. The touch sensor module has a function of detecting a touch on the outer surface of the housing 721. Detecting a tap operation, a slide operation, or the like by the user with the touch sensor module enables various types of processing. For example, a video can be paused or restarted by a tap operation, and can be fast-forwarded or fast-reversed by a slide operation. When the touch sensor module is provided in each of the two housings 721, the range of the operation can be increased.

Various touch sensors can be applied to the touch sensor module. For example, any of touch sensors of the following types can be used: a capacitive type, a resistive type, an infrared type, an electromagnetic induction type, a surface acoustic wave type, and an optical type. In particular, a capacitive touch sensor or an optical touch sensor is preferably used for the touch sensor module.

In the case of using an optical touch sensor, a photoelectric conversion element can be used as a light-receiving element. One or both of an inorganic semiconductor and an organic semiconductor can be used for an active layer of the photoelectric conversion element.

An electronic device 800A illustrated in FIG. 59C and an electronic device 800B illustrated in FIG. 59D each include a pair of display portions 820, a housing 821, a communication portion 822, a pair of wearing portions 823, a control portion 824, a pair of image capturing portions 825, and a pair of lenses 832.

The display apparatus of one embodiment of the present invention can be used in the display portions 820. Thus, the electronic devices are capable of performing ultrahigh-definition display. Such electronic devices provide a high sense of immersion to the user.

The display portions 820 are positioned inside the housing 821 so as to be seen through the lenses 832. When the pair of display portions 820 display different images, three-dimensional display using parallax can be performed.

The electronic devices 800A and 800B can be regarded as VR electronic devices. The user who wears the electronic device 800A or the electronic device 800B can see images displayed on the display portions 820 through the lenses 832.

The electronic devices 800A and 800B each preferably include a mechanism for adjusting the lateral positions of the lenses 832 and the display portions 820 so that the lenses 832 and the display portions 820 are positioned optimally in accordance with the positions of the user's eyes. Moreover, the electronic devices 800A and 800B each preferably include a mechanism for adjusting focus by changing the distance between the lenses 832 and the display portions 820.

The electronic device 800A or the electronic device 800B can be mounted on the user's head with the wearing portions 823. FIG. 59C and the like show examples where the wearing portion 823 has a shape like a temple of glasses; however, one embodiment of the present invention is not limited thereto. The wearing portion 823 can have any shape with which the user can wear the electronic device, such as a shape of a helmet or a band.

The image capturing portion 825 has a function of obtaining information on the external environment. Data obtained by the image capturing portion 825 can be output to the display portion 820. An image sensor can be used for the image capturing portion 825. Moreover, a plurality of cameras can be provided so as to cover a plurality of fields of view, such as a telescope field of view and a wide field of view.

Although an example where the image capturing portion 825 is provided is shown here, a range sensor (hereinafter also referred to as a sensing portion) capable of measuring a distance between the user and an object just needs to be provided. In other words, the image capturing portion 825 is one embodiment of the sensing portion. As the sensing portion, an image sensor or a range image sensor such as a light detection and ranging (LiDAR) sensor can be used, for example. By using images obtained by the camera and images obtained by the range image sensor, more information can be obtained and a gesture operation with higher accuracy is possible.

The electronic device 800A can include a vibration mechanism that serves as a bone-conduction earphone. For example, at least one of the display portion 820, the housing 821, and the wearing portion 823 can include the vibration mechanism. Thus, without additionally requiring an audio device such as headphones, earphones, or a speaker, the user can enjoy images and sound only by wearing the electronic device 800A.

The electronic devices 800A and 800B can each include an input terminal. To the input terminal, a cable for supplying a video signal from a video output device or the like, power for charging the battery provided in the electronic device, and the like can be connected.

The electronic device of one embodiment of the present invention can have a function of performing wireless communication with earphones 750. The earphones 750 include a communication portion (not illustrated) and have a wireless communication function. The earphones 750 can receive information (e.g., audio data) from the electronic device with the wireless communication function. For example, the electronic device 700A in FIG. 59A has a function of transmitting information to the earphones 750 with the wireless communication function. As another example, the electronic device 800A in FIG. 59C has a function of transmitting information to the earphones 750 with the wireless communication function.

The electronic device 700B in FIG. 59B includes earphone portions 727. For example, the earphone portion 727 can be connected to the control portion by wire. Part of a wiring that connects the earphone portion 727 and the control portion can be positioned inside the housing 721 or the wearing portion 723.

Similarly, the electronic device 800B in FIG. 59D includes earphone portions 827. For example, the earphone portion 827 can be connected to the control portion 824 by wire. Part of a wiring that connects the earphone portion 827 and the control portion 824 can be positioned inside the housing 821 or the wearing portion 823. In addition, the earphone portions 827 and the wearing portions 823 preferably include magnets. In this case, the earphone portions 827 can be fixed to the wearing portions 823 with magnetic force and thus can be easily housed.

The electronic device can include an audio output terminal to which earphones, headphones, or the like can be connected. The electronic device can include one or both of an audio input terminal and an audio input mechanism. As the audio input mechanism, a sound collecting device such as a microphone can be used, for example. The electronic device can have a function of a headset by including the audio input mechanism.

As described above, both the glasses-type device (e.g., the electronic devices 700A and 700B) and the goggles-type device (e.g., the electronic devices 800A and 800B) are preferable as the electronic device of one embodiment of the present invention.

The electronic device of one embodiment of the present invention can transmit information to earphones by wire or wirelessly.

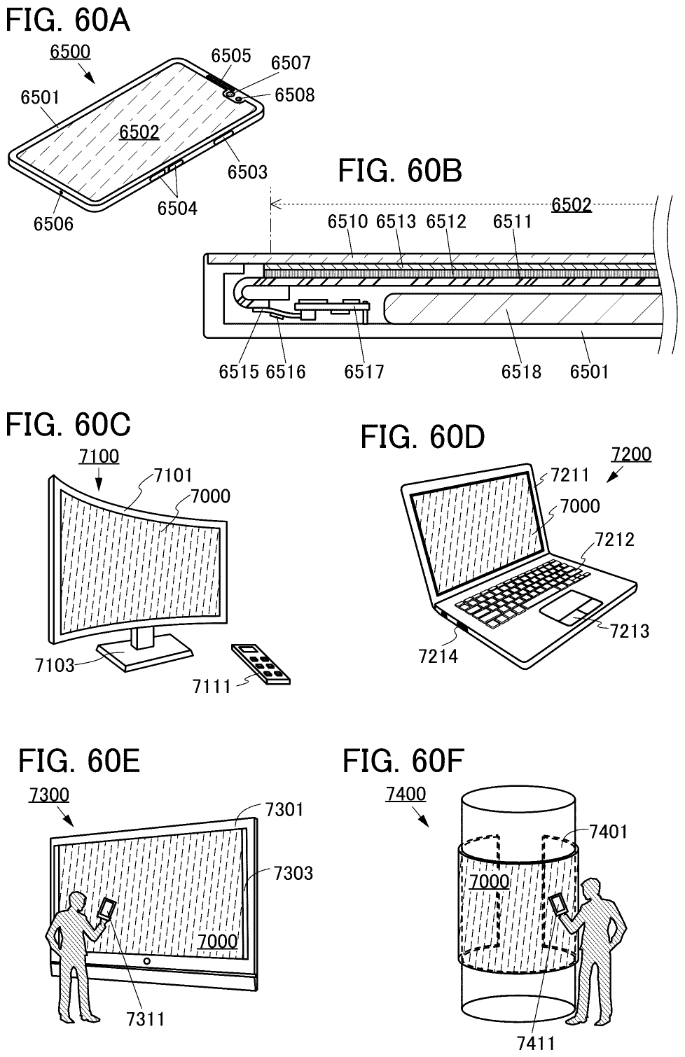

An electronic device 6500 illustrated in FIG. 60A is a portable information terminal that can be used as a smartphone.

The electronic device 6500 includes a housing 6501, a display portion 6502, a power button 6503, buttons 6504, a speaker 6505, a microphone 6506, a camera 6507, a light source 6508, and the like. The display portion 6502 has a touch panel function.

The display apparatus of one embodiment of the present invention can be used in the display portion 6502.

FIG. 60B is a schematic cross-sectional view including an end portion of the housing 6501 on the microphone 6506 side.

A protection member 6510 having a light-transmitting property is provided on the display surface side of the housing 6501. A display panel 6511, an optical member 6512, a touch sensor panel 6513, a printed circuit board 6517, a battery 6518, and the like are provided in a space surrounded by the housing 6501 and the protection member 6510.

The display panel 6511, the optical member 6512, and the touch sensor panel 6513 are fixed to the protection member 6510 with an adhesive layer (not illustrated).

Part of the display panel 6511 is folded back in a region outside the display portion 6502, and an FPC 6515 is connected to the part that is folded back. An IC 6516 is mounted on the FPC 6515. The FPC 6515 is connected to a terminal provided on the printed circuit board 6517.

The display apparatus of one embodiment of the present invention can be used as the display panel 6511. In that case, an extremely lightweight electronic device can be obtained. Since the display panel 6511 is extremely thin, the battery 6518 with high capacity can be mounted without an increase in the thickness of the electronic device. Moreover, part of the display panel 6511 is folded back so that a connection portion with the FPC 6515 is provided on the back side of the pixel portion, whereby an electronic device with a narrow bezel can be obtained.

FIG. 60C shows an example of a television device. In a television device 7100, a display portion 7000 is incorporated in a housing 7101. Here, the housing 7101 is supported by a stand 7103. The display apparatus of one embodiment of the present invention can be used in the display portion 7000 in FIG. 60C.

Operation of the television device 7100 illustrated in FIG. 60C can be performed with an operation switch provided in the housing 7101 and a separate remote controller 7111. Alternatively, the display portion 7000 may include a touch sensor, and the television device 7100 can be operated by touch on the display portion 7000 with a finger or the like. The remote controller 7111 is preferably provided with a display portion for displaying information output from the remote controller 7111. With operation keys or a touch panel provided in the remote controller 7111, channels and volume can be controlled and videos displayed on the display portion 7000 can be controlled.

Note that the television device 7100 includes a receiver, a modem, and the like. A general television broadcast can be received with the receiver. When the television device is connected to a communication network by wire or wirelessly via the modem, one-way (only from a transmitter to a receiver) or two-way (between a transmitter and a receiver) data communication can be performed.

FIG. 60D shows an example of a notebook personal computer. A notebook personal computer 7200 includes a housing 7211, a keyboard 7212, a pointing device 7213, an external connection port 7214, and the like. The display portion 7000 is incorporated in the housing 7211. The display apparatus of one embodiment of the present invention can be used in the display portion 7000 in FIG. 60D.

FIGS. 60E and 60F show examples of digital signage.

Digital signage 7300 illustrated in FIG. 60E includes a housing 7301, the display portion 7000, a speaker 7303, and the like. The digital signage 7300 can also include an LED lamp, an operation key (including a power switch or an operation switch), a connection terminal, various sensors, a microphone, and the like.

FIG. 60F illustrates digital signage 7400 attached to a cylindrical pillar 7401. The digital signage 7400 includes the display portion 7000 provided along a curved surface of the pillar 7401. The display apparatus of one embodiment of the present invention can be used in the display portion 7000 in each of FIGS. 60E and 60F.

A larger area of the display portion 7000 can increase the amount of information that can be provided at a time. The larger display portion 7000 attracts more attention, so that the effectiveness of the advertisement can be increased, for example.

A touch panel is preferably used in the display portion 7000, in which case intuitive operation by a user is possible in addition to display of an image or a moving image on the display portion 7000. Moreover, for an application for providing information such as route information or traffic information, usability can be enhanced by intuitive operation.

As illustrated in FIGS. 60E and 60F, it is preferable that the digital signage 7300 or the digital signage 7400 can work with an information terminal 7311 or an information terminal 7411, such as a smartphone that a user has, through wireless communication. For example, information of an advertisement displayed on the display portion 7000 can be displayed on a screen of the information terminal 7311 or the information terminal 7411. By operation of the information terminal 7311 or the information terminal 7411, display on the display portion 7000 can be switched.

It is possible to make the digital signage 7300 or the digital signage 7400 execute a game with use of the screen of the information terminal 7311 or the information terminal 7411 as an operation means (controller). Thus, an unspecified number of users can join in and enjoy the game concurrently.

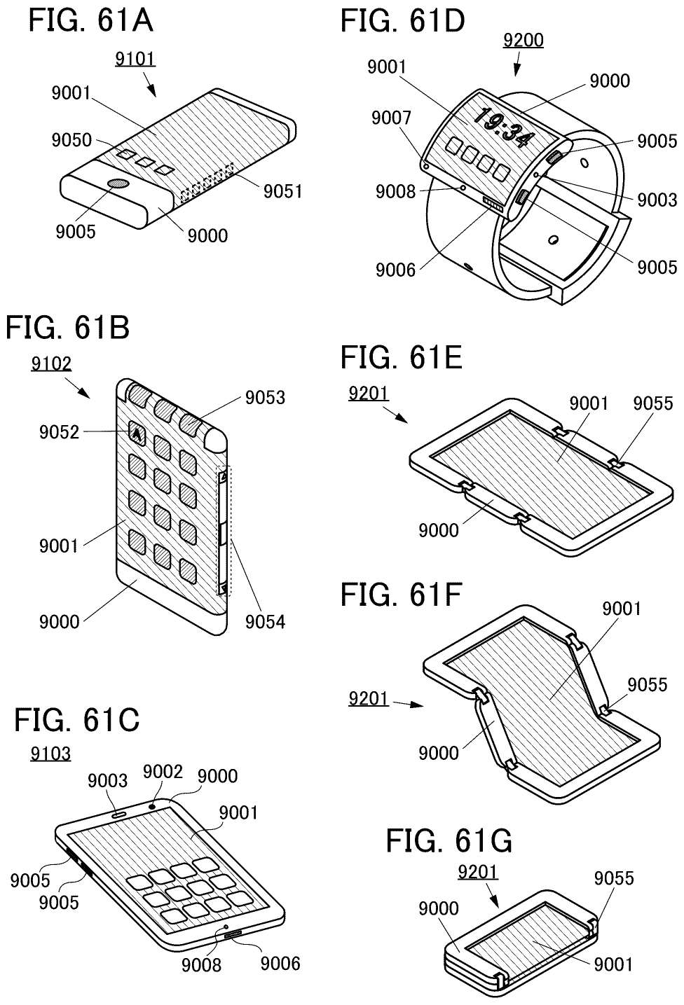

Electronic devices illustrated in FIGS. 61A to 61G include a housing 9000, a display portion 9001, a speaker 9003, an operation key 9005 (including a power switch or an operation switch), a connection terminal 9006, a sensor 9007 (a sensor having a function of sensing, detecting, or measuring force, displacement, position, speed, acceleration, angular velocity, rotational frequency, distance, light, liquid, magnetism, temperature, a chemical substance, sound, time, hardness, electric field, current, voltage, power, radiation, flow rate, humidity, gradient, oscillation, a smell, or infrared rays), a microphone 9008, and the like.

In FIGS. 61A to 61G, the display apparatus of one embodiment of the present invention can be used in the display portion 9001.

The electronic devices illustrated in FIGS. 61A to 61G have various functions. For example, the electronic devices can have a function of displaying various information (a still image, a moving image, a text image, and the like) on the display portion, a touch panel function, a function of displaying a calendar, date, time, and the like, a function of controlling processing with the use of various software (programs), a wireless communication function, and a function of reading out and processing a program or data stored in a recording medium. Note that the functions of the electronic devices are not limited thereto, and the electronic devices can have various functions. The electronic devices can include a plurality of display portions. The electronic devices can be provided with a camera or the like and have a function of capturing a still image or a moving image, a function of storing the captured image in a storage medium (an external storage medium or a storage medium incorporated in the camera), a function of displaying the captured image on the display portion, and the like.

The electronic devices in FIGS. 61A to 61G will be described in detail below.

FIG. 61A is a perspective view of a portable information terminal 9101. The portable information terminal 9101 can be used as a smartphone, for example. The portable information terminal 9101 can include the speaker 9003, the connection terminal 9006, the sensor 9007, and the like. The portable information terminal 9101 can display text and image information on its plurality of surfaces. FIG. 61A shows an example where three icons 9050 are displayed. Furthermore, information 9051 indicated by dashed rectangles can be displayed on another surface of the display portion 9001. Examples of the information 9051 include notification of reception of an e-mail, an SNS message, or an incoming call; the title, sender, date, and time of an e-mail, an SNS message, or the like; the time; remaining battery; and the radio field intensity. Alternatively, the icon 9050 or the like can be displayed at the position where the information 9051 is displayed.

FIG. 61B is a perspective view of a portable information terminal 9102. The portable information terminal 9102 has a function of displaying information on three or more surfaces of the display portion 9001. Here, information 9052, information 9053, and information 9054 are displayed on different surfaces. For example, the user of the portable information terminal 9102 can check the information 9053 displayed such that it can be seen from above the portable information terminal 9102, with the portable information terminal 9102 put in a breast pocket of his/her clothes. The user can see the display without taking out the portable information terminal 9102 from the pocket and decide whether to answer the call, for example.

FIG. 61C is a perspective view of a tablet terminal 9103. The tablet terminal 9103 is capable of executing various applications such as mobile phone calls, e-mailing, viewing and editing texts, music reproduction, Internet communication, and a computer game, for example. The tablet terminal 9103 includes the display portion 9001, the camera 9002, the microphone 9008, and the speaker 9003 on the front surface of the housing 9000; the operation keys 9005 as buttons for operation on the left side surface of the housing 9000; and the connection terminal 9006 on the lower surface of the housing 9000.

FIG. 61D is a perspective view of a watch-type portable information terminal 9200. The portable information terminal 9200 can be used as a Smartwatch (registered trademark), for example. The display surface of the display portion 9001 is curved, and an image can be displayed on the curved display surface. Furthermore, for example, mutual communication between the portable information terminal 9200 and a headset capable of wireless communication can be performed, and thus hands-free calling is possible. With the connection terminal 9006, the portable information terminal 9200 can perform mutual data transmission with another information terminal and charging. Note that the charging operation may be performed by wireless power feeding.

FIGS. 61E to 61G are perspective views of a foldable portable information terminal 9201. FIG. 61E is a perspective view illustrating the portable information terminal 9201 that is opened. FIG. 61G is a perspective view illustrating the portable information terminal 9201 that is folded. FIG. 61F is a perspective view illustrating the portable information terminal 9201 that is shifted from one of the states in FIGS. 61E and 61G to the other. The portable information terminal 9201 is highly portable in the folded state and is highly browsable in the opened state because of a seamless large display region. The display portion 9001 of the portable information terminal 9201 is supported by three housings 9000 joined together by hinges 9055. The display portion 9001 can be folded with a radius of curvature greater than or equal to 0.1 mm and less than or equal to 150 mm, for example.

The structures and the like described in this embodiment can be used in combination with any of the structures and the like described in the other embodiments and the like as appropriate.

This application is based on Japanese Patent Application Serial No. 2024-009561 filed with Japan Patent Office on Jan. 25, 2024 and Japanese Patent Application Serial No. 2024-021212 filed with Japan Patent Office on Feb. 15, 2024, the entire contents of which are hereby incorporated by reference.

What is claimed is:

1. A semiconductor device comprising:
a first transistor comprising a gate and a back gate; and
a light-emitting element, the semiconductor device being configured to perform:
a first operation for supplying a first potential to the back gate of the first transistor;
a second operation for fixing a gate potential and a source potential of the first transistor and establishing electrical continuity between a drain and the back gate of the first transistor to set a potential of the back gate to a second potential;
a third operation for supplying a video signal to the gate of the first transistor; and
a fourth operation for supplying a current corresponding to the video signal to the light-emitting element,
wherein the second potential corresponds to a difference between the source potential and the gate potential of the first transistor,
wherein the second operation is performed less frequently than the third operation, and
wherein the second operation is performed less frequently than the fourth operation.

2. The semiconductor device according to claim 1,
wherein the second potential is lower than the first potential.

3. The semiconductor device according to claim 1,
wherein the first transistor is an n-type transistor.

4. The semiconductor device according to claim 1,
wherein the first transistor comprises an oxide semiconductor in a semiconductor layer where a channel is formed.

5. The semiconductor device according to claim 1,
wherein the light-emitting element is an organic EL element.

6. A semiconductor device comprising:
a first transistor, a second transistor, a third transistor, a fourth transistor, a fifth transistor, a sixth transistor, and a seventh transistor;
a first capacitor and a second capacitor; and
a light-emitting element,
wherein the first transistor comprises a gate, a back gate, a first terminal, and a second terminal,
wherein the second transistor, the third transistor, the fourth transistor, the fifth transistor, the sixth transistor, the seventh transistor, the first capacitor, the second capacitor, and the light-emitting element each comprise a first terminal and a second terminal,
wherein the first terminal of the first transistor is electrically connected to the second terminal of the second transistor and the first terminal of the third transistor,
wherein the second terminal of the third transistor is electrically connected to the back gate of the first transistor, the first terminal of the seventh transistor, and the first terminal of the second capacitor,
wherein the second terminal of the second capacitor is electrically connected to the first terminal of the fourth transistor, the second terminal of the first transistor, the first terminal of the light-emitting element, and the second terminal of the first capacitor,
wherein the gate of the first transistor is electrically connected to the first terminal of the first capacitor, the second terminal of the fifth transistor, and the first terminal of the sixth transistor,
wherein W/L of the third transistor is smaller than W/L of the fifth transistor,
wherein the W/L of the third transistor is smaller than W/L of the sixth transistor,
wherein W/L of the seventh transistor is smaller than the W/L of the fifth transistor, and
wherein the W/L of the seventh transistor is smaller than the W/L of the sixth transistor.

7. The semiconductor device according to claim 6,
wherein the first capacitor is configured to maintain a difference between a potential of the second terminal of the first transistor and a potential of the gate of the first transistor, and
wherein the second capacitor is configured to maintain a difference between the potential of the second terminal of the first transistor and a potential of the back gate of the first transistor.

8. The semiconductor device according to claim 6,
wherein the first terminal of the second transistor is electrically connected to a first wiring,
wherein the first terminal of the fifth transistor is electrically connected to a second wiring,
wherein the second terminal of the sixth transistor is electrically connected to a third wiring,
wherein the second terminal of the seventh transistor is electrically connected to a fourth wiring,
wherein the second terminal of the fourth transistor is electrically connected to a fifth wiring,
wherein the second terminal of the light-emitting element is electrically connected to a sixth wiring,
wherein the first wiring is configured to supply a first potential,
wherein the second wiring is configured to supply a video signal,
wherein the third wiring is configured to supply a second potential,
wherein the fourth wiring is configured to supply a third potential,
wherein the fifth wiring is configured to supply a fourth potential, and
wherein the sixth wiring is configured to supply a fifth potential.

9. The semiconductor device according to claim 6,
wherein the first transistor comprises an oxide semiconductor in a semiconductor layer where a channel is formed.

10. The semiconductor device according to claim 6,
wherein the light-emitting element is an organic EL element.
